(19) United States
(12) Patent Application Publication
(10) Pub. No.: US 2026/0206413 A1
(43) Pub. Date: Jul. 16, 2026

(54) LIGHT-EMITTING DEVICE, DISPLAY APPARATUS INCLUDING THE SAME, AND ELECTRONIC APPARATUS INCLUDING THE DISPLAY APPARATUS

(71) Applicant: Samsung Display Co., LTD., Yongin-si (KR)

(72) Inventors: Kunwook CHO, Yongin-si (KR); Eunjae JEONG, Yongin-si (KR); Jinyoung YUN, Yongin-si (KR); Sanghyun HAN, Yongin-si (KR)

(21) Appl. No.: 19/450,281

(22) Filed: Jan. 15, 2026

(30) Foreign Application Priority Data
Jan. 15, 2025 (KR) 10-2025-0006393

(51) Int. Cl. H10K 50/19; H10K 50/15; H10K 50/16; H10K 85/30; H10K 85/40; H10K 85/60

(52) U.S. Cl. CPC H10K 50/19; H10K 50/156; H10K 50/166; H10K 85/324; H10K 85/342; H10K 85/346; H10K 85/348; H10K 85/40; H10K 85/622; H10K 85/626; H10K 85/633; H10K 85/636; H10K 85/654; H10K 85/6572; H10K 85/6574; H10K 85/6576; H10K 85/658

(57) ABSTRACT

A light-emitting device includes a first electrode, a second electrode facing the first electrode, and an interlayer arranged between the first electrode and the second electrode. The interlayer includes an emission layer, a hole transport region arranged between the first electrode and the emission layer, and a charge generation layer arranged between the first electrode and the hole transport region. The hole transport region includes at least one first compound represented by Formula 1, and the charge generation layer includes at least one second compound represented by Formula 2:

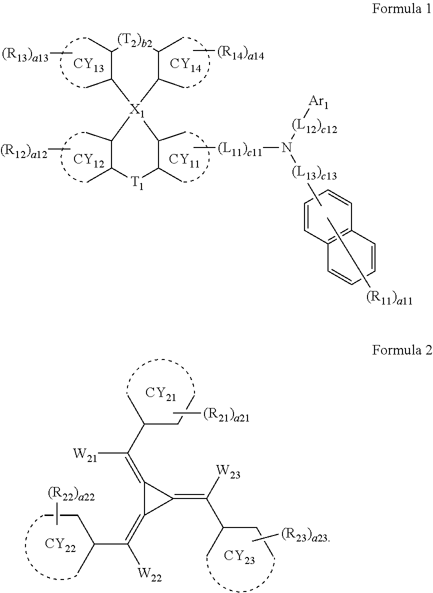

This application claims priority to Korean Patent Application No. 10-2025—0006393, filed on Jan. 15, 2025, and all the benefits accruing therefrom under 35 U.S.C. § 119, the content of which in its entirety is herein incorporated by reference.

### BACKGROUND

### 1. Field

Embodiments relate to a light-emitting device, a display apparatus including the same, and an electronic apparatus including the display apparatus.

### 2. Description of the Related Art

Self-emissive devices (e.g., organic light-emitting devices) among light-emitting devices have wide viewing angles, high contrast ratios, short response times, and excellent characteristics in terms of luminance, driving voltage, and response speed.

In an embodiment, a light-emitting device may include a first electrode, a hole transport region, an emission layer, an electron transport region, and a second electrode that are sequentially arranged. Holes injected from the first electrode may move toward the emission layer through the hole transport region. Electrons injected from the second electrode may move toward the emission layer through the electron transport region. Carriers, such as these holes and electrons, recombine in the emission layer to produce excitons. As the excitons transition from an excited state to a ground state, light may be generated.

### SUMMARY

Embodiments include a light-emitting device with improved controllability by preventing or reducing the lateral flow of current in some layers while maintaining a predetermined level of efficiency and lifespan of the light-emitting device and at the same time, and a display apparatus with reduced color mixing between light-emitting devices, and an electronic apparatus with improved display quality.

Additional features will be set forth in part in the description which follows and, in part, will be apparent from the description, or may be learned by practice of the presented embodiments of the disclosure.

In an embodiment of the disclosure, a light-emitting device includes a first electrode, a second electrode facing the first electrode, and an interlayer arranged between the first electrode and the second electrode, where the interlayer includes an emission layer, a hole transport region arranged between the first electrode and the emission layer, and a charge generation layer arranged between the first electrode and the hole transport region, where the hole transport region includes at least one first compound represented by Formula 1, and the charge generation layer includes at least one second compound represented by Formula 2:

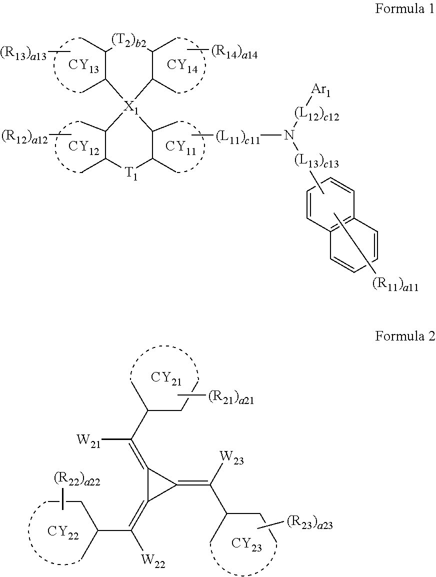

where, in Formulae 1 and 2,
X₁ may be C or Si,
T₁ may be O or S,
T₂ may be O, S, N(R₁₅), C(R₁₆)(R₁₇), or Si(R₁₈)(R₁₉),
b2 may be 0 or 1,
CY₁₁ to CY₁₄ and CY₂₁ to CY₂₃ may each independently be a C₅-C₆₀ carbocyclic group or a C₃-C₆₀ heterocyclic group,
L₁₁ to L₁₃ are each independently a C₅-C₆₀ carbocyclic group unsubstituted or substituted with at least one R₁₀ₐ or a C₃-C₆₀ heterocyclic group unsubstituted or substituted with at least one R₁₀ₐ,
c11 to c13 may each independently be 0, 1, 2, 3, 4, or 5,
Ar₁ may be a C₅-C₆₀ carbocyclic group unsubstituted or substituted with at least one R₁₀ₐ or a C₃-C₆₀ heterocyclic group unsubstituted or substituted with at least one R₁₀ₐ,
R₁₁ to R₁₉ and R₂₁ to R₂₃ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₅-C₆₀ carbocyclic group unsubstituted or substituted with at least one R₁₀ₐ, a C₃—C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂ (Q₁), or —P(═O)(Q₁)(Q₂),
a11 may be an integer selecting from 0 to 7,
a12 to a14 and a21 to a23 may each independently be an integer selecting from 0 to 20,
W₂₁ to W₂₃ may each independently be
—F, —Cl, —Br, —I, a hydroxyl group, a cyano group, or a nitro group,
a C₁-C₆₀ alkyl group substituted with —F, —Cl, —Br, —I, a hydroxyl group, a cyano group, a nitro group, or any combinations thereof,
a C₅-C₆₀ carbocyclic group substituted with —F, —Cl, —Br, —I, a hydroxyl group, a cyano group, a nitro group, or any combinations thereof, or
a C₃-C₆₀ heterocyclic group substituted with —F, —Cl, —Br, —I, a hydroxyl group, a cyano group, a nitro group, or any combinations thereof,
R₁₀ₐ may be
deuterium, —F, —Cl, —Br, —I, a hydroxyl group, a cyano group, or a nitro group,
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₃-C₆₀ heterocyclic group, a C₆-C₆₀ aryloxy group, a C₆-Coo arylthio group, a C₇-C₆₀ aryl alkyl group, a C₃-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combinations thereof,
a C₅-C₆₀ carbocyclic group, a C₃-C₆₀ heterocyclic group, a C₆-C₆₀ aryloxy group, a C₆-C₆₀ arylthio group, a C₇-C₆₀ aryl alkyl group, or a C₃-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₃-C₆₀ heterocyclic group, a C₆-C₆₀ aryloxy group, a C₆-C₆₀ arylthio group, a C₇-C₆₀ aryl alkyl group, a C₃-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combinations thereof, or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be
hydrogen, deuterium, —F, —Cl, —Br, —I, a hydroxyl group, a cyano group, or a nitro group, or
a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, or a C₃-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combinations thereof. In an embodiment of the disclosure, the hole transport region may have a surface resistance in a range of about 1.0×10⁹ ohm/sq to about 1.0×10¹¹ ohm/sq.

In an embodiment of the disclosure, a display apparatus includes a substrate including a first region, a second region, and a third region that are spaced apart from each other, a first light-emitting device including a first-1 electrode arranged on the substrate within the first region, a first-2 electrode facing the first-1 electrode, and a first interlayer arranged between the first-1 electrode and the first-2 electrode, a second light-emitting device including a second-1 electrode arranged on the substrate within the second region, a second-2 electrode facing the second-1 electrode, and a second interlayer arranged between the second-1 electrode and the second-2 electrode; and a third light-emitting device including a third-1 electrode arranged on the substrate within the third region, a third-2 electrode facing the third-1 electrode, and a third interlayer arranged between the third-1 electrode and the third-2 electrode, where the first interlayer includes a first-1 emission layer, a first-1 hole transport region arranged between the first-1 electrode and the first-1 emission layer, and a first-1 charge generation layer arranged between the first-1 electrode and the first-1 hole transport region, the second interlayer includes a second-1 emission layer, a second-1 hole transport region arranged between the second-1 electrode and the second-1 emission layer, and a second-1 charge generation layer arranged between the second-1 electrode and the second-1 hole transport region, and the third interlayer includes a third-1 emission layer, a third-1 hole transport region arranged between the third-1 electrode and the third-1 emission layer, and a third-1 charge generation layer arranged between the third-1 electrode and the third-1 hole transport region, at least one of the first-1 hole transport region, the second-1 hole transport region, and the third-1 hole transport region includes at least one first compound represented by Formula 1, and at least one of the first-1 charge generation layer, the second-1 charge generation layer, and the third-1 charge generation layer includes at least one second compound represented by Formula 2.

In an embodiment, an electronic apparatus includes the display apparatus and a processor configured to transmit signals to the display apparatus.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic view of an embodiment of a light-emitting device;

FIG. 2 is a view of an embodiment of an interlayer included in the light-emitting device of FIG. 1;

FIG. 3 is a view of another embodiment of an interlayer included in the light-emitting device of FIG. 1;

FIG. 4 is a schematic view of an embodiment of a plurality of light-emitting devices included in a display apparatus;

FIG. 5 is a schematic cross-sectional view of an embodiment of a display apparatus;

FIG. 6 is a schematic cross-sectional view of another embodiment of a display apparatus;

FIG. 7 is a block diagram of an embodiment of an electronic apparatus including a display apparatus;

FIG. 8 is a schematic view of an electronic apparatus according to various embodiments;

FIG. 9 is a schematic perspective view of an embodiment of an electronic apparatus including a light-emitting device;

FIG. 10 is a schematic view of an embodiment of the exterior of a vehicle as an electronic apparatus including a light-emitting device; and

FIGS. 11A to 11C are each a view schematically illustrating the interior of the vehicle of FIG. 10.

### DETAILED DESCRIPTION

Reference will now be made in detail to embodiments, illustrative embodiments of which are illustrated in the accompanying drawings, where like reference numerals refer to like elements throughout the specification. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

In the specification, when a component (or a region, a layer, a portion, etc.) is referred to as being “on”, “connected to”, or “combined with” other components, it is intended to refer that the component may be directly arranged/connected/combined with the other components or that a third component may be arranged between the component and the other components.

Like reference numerals designate like components. Also, in the drawings, the thicknesses, proportions, and dimensions of components are exaggerated for the effective explanation of the technical contents.

The expression “and/or” includes any one or more combinations that may be defined by the associated components.

The terms “first, second, and the like” may be used to describe various components, but these components should not be limited by the terms. These terms are only used to distinguish one component from other components. For example, a first element may be named a second element, and similarly, a second element may also be named a first component, without departing from the scope of the disclosure. An expression used in the singular encompasses the expression of the plural, unless it has a clearly different meaning in the context.

Also, the terms “below”, “at the bottom”, “above, “on”, “on top of”, and the like may be used to describe the relationship of components shown in the drawings. These terms are relative concepts and are explained based on the directions indicated in the drawings.

Unless otherwise defined, all terms (including technical and scientific terms) used in the specification have the same meaning as commonly understood by those skilled in the art to which the disclosure belongs to. Also, terms such as those defined in commonly used dictionaries should be interpreted to have a meaning consistent with their meaning in the context of the relevant technology, and should be construed as defined in the specification unless interpreted in an idealized or overly formal sense.

It will be further understood that the term “comprises” or “includes” specifies the presence of stated features, integers, steps, operations, elements, components, or combinations thereof described in the specification, but does not preclude the presence or addition of one or more other features, integers, steps, operations, elements, components, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, or 5% of the stated value, for example.

In an embodiment, a light-emitting device includes: a first electrode 110; a second electrode 150 facing the first electrode 110; and an interlayer arranged between the first electrode 110 and the second electrode 150, where the interlayer includes an emission layer; a hole transport region between the first electrode and the emission layer, and a charge generation layer between the first electrode and the hole transport region, the hole transport region includes at least one first compound represented by Formula 1, and the charge generation layer includes at least one second compound represented by Formula 2:

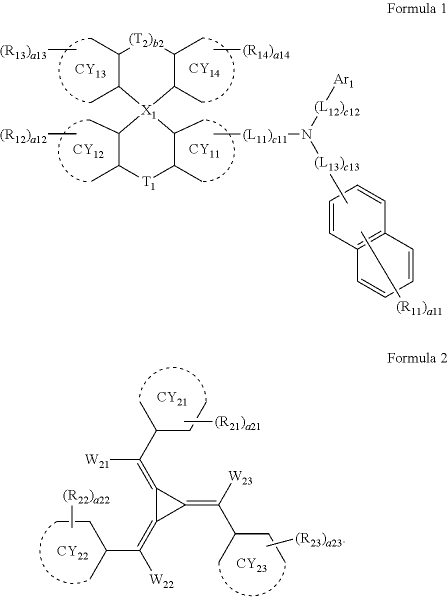

The charge generation layer may further include at least one first compound represented by Formula 1. That is, the charge generation layer may include both the first compound and the second compound.

That is, the light-emitting device includes both the first compound represented by Formula 1 and the second compound represented by Formula 2, and thus is clearly distinguished from a light-emitting device including only one of the first compound and the second compound. When the light-emitting device in an embodiment includes both the first compound and the second compound, the surface resistance of the hole transport region or the charge generation layer may be appropriately increased while securing at least a predetermined level of luminescence efficiency and lifespan. Accordingly, the lateral flow of current through common layers may be prevented or reduced. The controllability of the light-emitting device may be accordingly improved, thereby preventing color mixing between the light-emitting devices. That is, the display quality of an electronic apparatus including the light-emitting device may be improved.

The first compound may be represented by Formula 1:

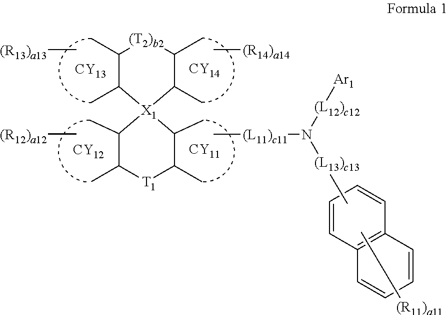

where, in Formula 1,
X₁ may be C or Si,
T₁ may be O or S,
T₂ may be O, S, N(R₁₅), C(R₁₆)(R₁₇), or Si(R₁₈)(R₁₉),
b2 may be 0 or 1, and
*-(T₂)_{b2}-** may be a single bond when b2 is 0.

In Formula 1, CY₁₁ to CY₁₄ may each independently be a C₅-C₆₀ carbocyclic group or a C₃-C₆₀ heterocyclic group.

In an embodiment, CY₁₁ to CY₁₄ may each independently be a C₆-C₆₀ aryl group or a C₃-C₆₀ heteroaryl group.

In an embodiment, CY₁₁ to CY₁₄ may each independently be a 6-membered ring.

CY₁₁ to CY₁₄ may each independently be a benzene group, a pyridine group, a pyrimidine group, a triazine group, a pyridazine group, or a pyrazine group.

In an embodiment, CY₁₁ may be represented by one of Formulae CY₁ to CY₄:

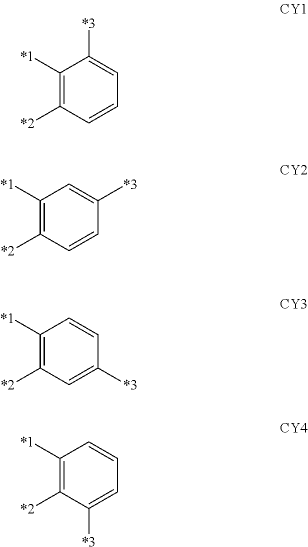

where, in Formulae CY₁ to CY₄,
*1 indicates a binding site to X₁ in Formula 1,
*2 indicates a binding site to T₁ in Formula 1, and
*3 indicates a binding site to (L₁₁)_{c11} in Formula 1.

In Formula 1, L₁₁ to L₁₃ may each independently be a C₅-C₆₀ carbocyclic group unsubstituted or substituted with at least one R₁₀ₐ or a C₃-C₆₀ heterocyclic group unsubstituted or substituted with at least one R₁₀ₐ.

In an embodiment, L₁₁ to L₁₃ may each independently be a benzene group, a naphthalene group, a 1,2,3,4-tetrahydronaphthalene group, a phenanthrene group, a pyridine group, a pyrimidine group, a pyrazine group, a pyridazine group, a triazine group, a quinoline group, an isoquinoline group, a quinoxaline group, a quinazoline group, a phenanthroline group, a benzofuran group, a benzothiophene group, a fluorene group, a carbazole group, a dibenzofuran group, a dibenzothiophene group, a dibenzosilole group, an azafluorene group, an azacarbazole group, an azadibenzofuran group, an azadibenzothiophene group, or an azadibenzosilole group, each unsubstituted or substituted with at least one R₁₀ₐ. In an embodiment, L₁₁ to L₁₃ may each independently be a benzene group unsubstituted or substituted with at least one R₁₀ₐ or a naphthalene group unsubstituted or substituted with at least one R₁₀ₐ, for example.

In Formula 1, c11 to c13 may each independently be 0, 1, 2, 3, 4, or 5. When c11 is 0, *-(L₁₁)_{c11}-*′ may be a single bond. When c12 is 0, *-(L₁₂)_{c12}-*′ may be a single bond. When c13 is 0, *-(L₁₃)_{c13}-* may be a single bond.

In Formula 1, Ar₁ may be a C₅-C₆₀ carbocyclic group unsubstituted or substituted with at least one R₁₀ₐ or a C₃-C₆₀ heterocyclic group unsubstituted or substituted with at least one R₁₀ₐ.

In an embodiment, Ar₁ may include a cyclopentane group, a cyclohexane group, a cycloheptane group, a cyclooctane group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, a benzene group, a naphthalene group, a fluorene group, a spiro-bifluorene group, a carbazole group, a dibenzofuran group, or a dibenzothiophene group.

In Formula 1, R₁₁ to R¹⁹ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₅-C₆₀ carbocyclic group unsubstituted or substituted with at least one R₁₀ₐ, a C₃-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂).

In Formula 1, a11 may be an integer selecting from 0 to 7, and a12 to a14 may each independently be an integer selecting from 0 to 20.
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₃-C₆₀ heterocyclic group, a C₆-C₆₀ aryloxy group, a C₆-C₆₀ arylthio group, a C₇-C₆₀ aryl alkyl group, a C₃-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combinations thereof;
a C₅-C₆₀ carbocyclic group, a C₃-C₆₀ heterocyclic group, a C₆-C₆₀ aryloxy group, a C₆-C₆₀ arylthio group, a C₇-C₆₀ aryl alkyl group, or a C₃-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₃-C₆₀ heterocyclic group, a C₆-C₆₀ aryloxy group, a C₆-C₆₀ arylthio group, a C₇-C₆₀ aryl alkyl group, a C₃-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combinations thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).
Q₁ to Q₃, Q₁₁ to Q₁₃, Q₂₁ to Q₂₃, and Q₃₁ to Q₃₃ may each independently be:
hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, or a C₃-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combinations thereof.

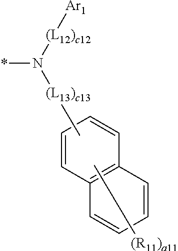

in In an embodiment, a group represented by Formula 1 (* indicates a binding site to (L₁₁)_{c11} or CY₁₁ in Formula 1) may be a group represented by Formula N1 or N2:

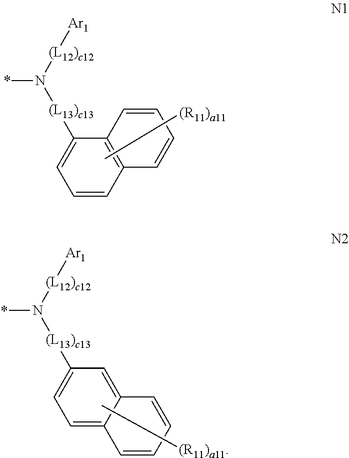

In Formulae N1 and N2, L₁₂, L₁₃, C₁₂, c13, R₁₁, a11, and Ar₁ may each be the same as described in Formula 1.

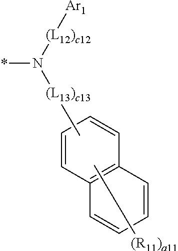

in In an embodiment, a group represented by Formula 1 (where * indicates a binding site to (L₁₁) c11 or CY₁₁ in Formula 1) may be a group represented by one of Formulae N11 to N31:

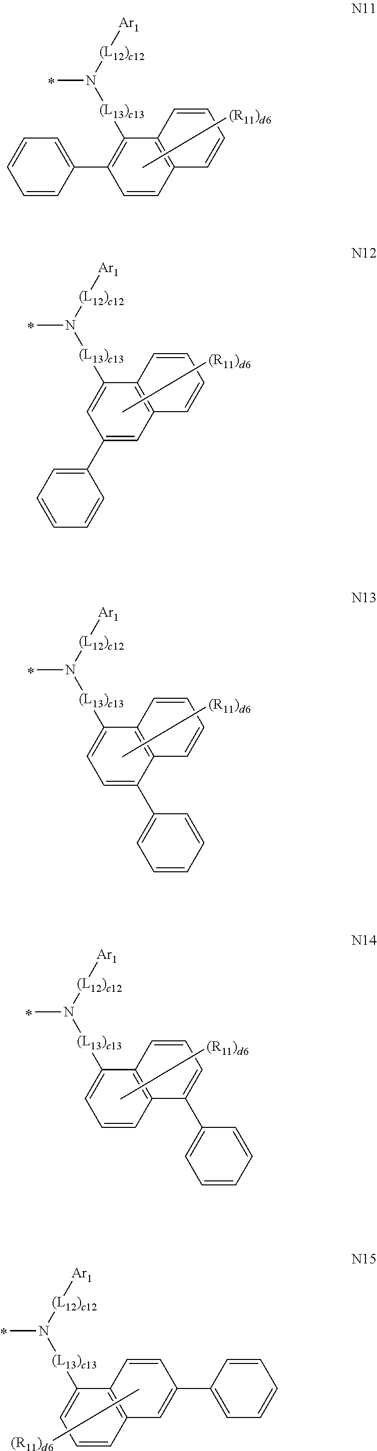

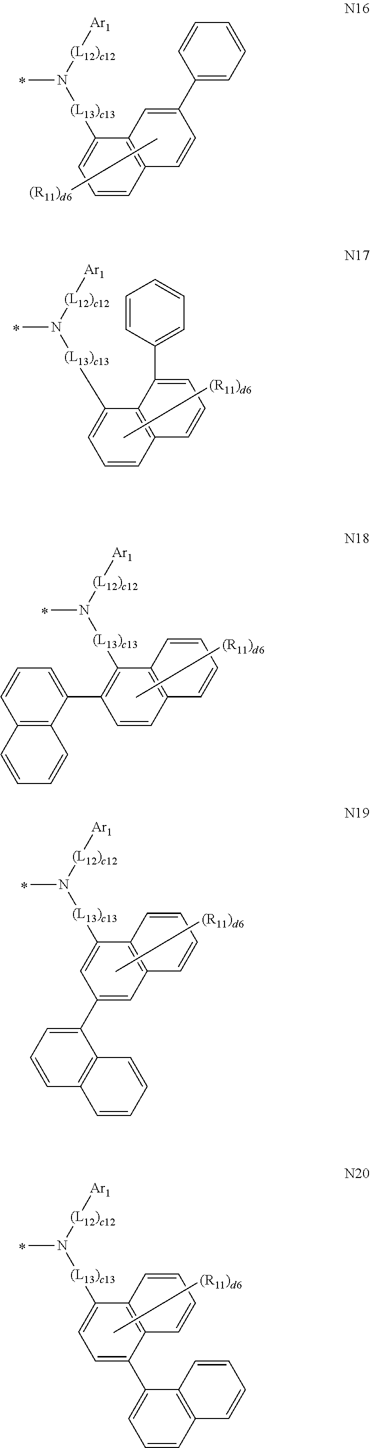

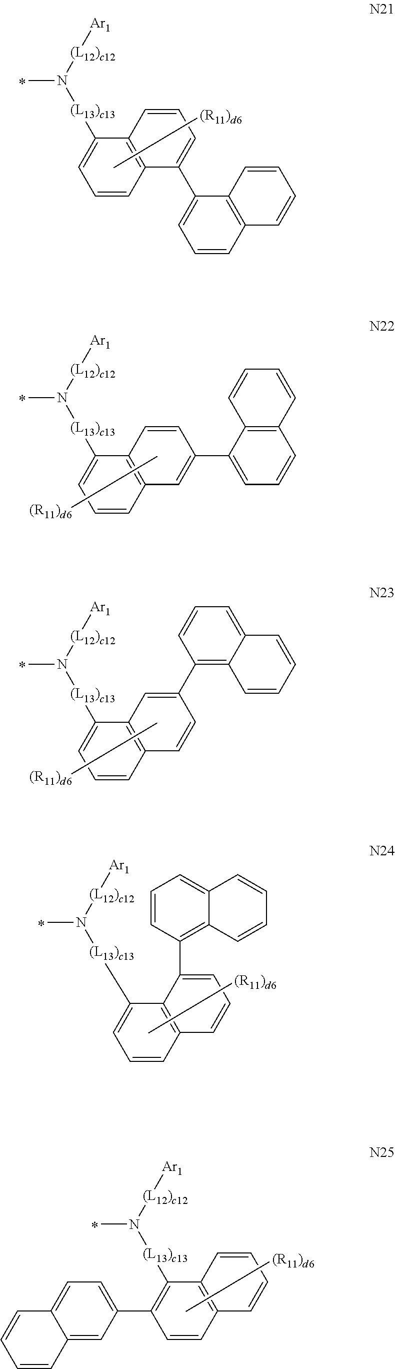

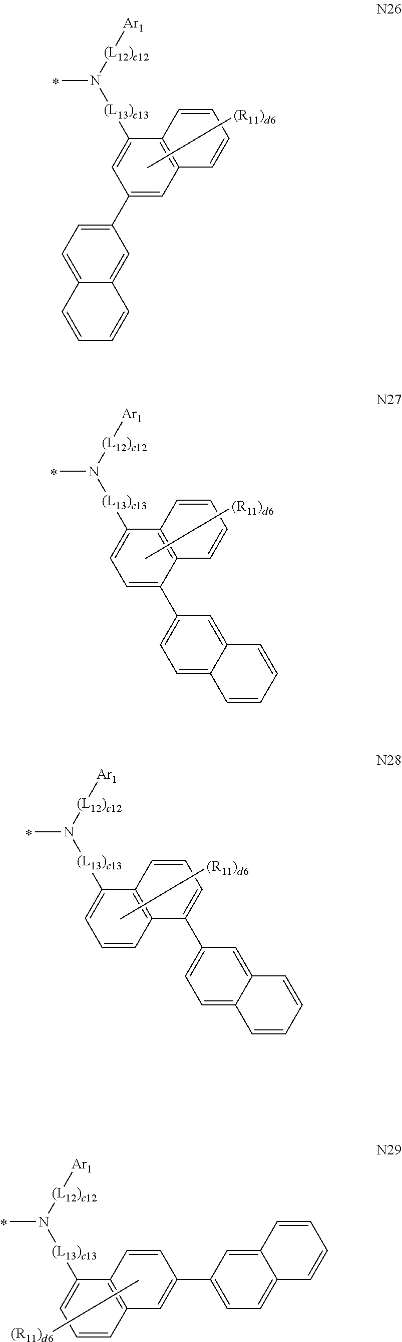

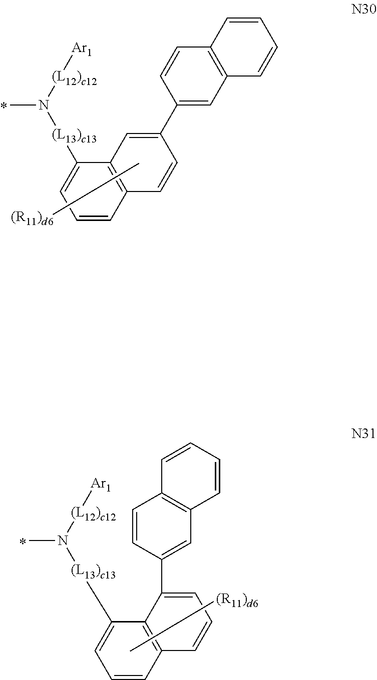

In Formulae N11 to N31,
L₁₂, L₁₃, C₁₂, c13, R₁₁, and Ar₁ may each be the same as described in Formula 1, and
d6 may be an integer selecting from 0 to 6.

In an embodiment, the first compound may be represented by Formula 1-1:

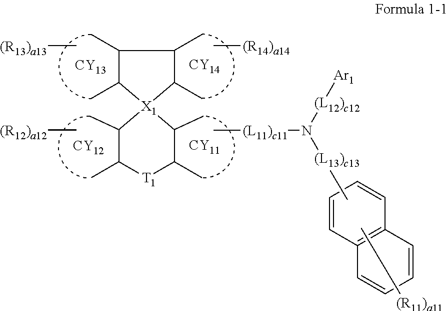

where, in Formula 1-1, X₁, T₁, CY₁₁ to CY₁₄, L₁₁ to L₁₃, Ar₁, R₁₁ to R₁₄, a11 to a14, and c11 to c13 may each be the same as described in Formula 1.

In an embodiment, the first compound may be represented by Formula 1-2:

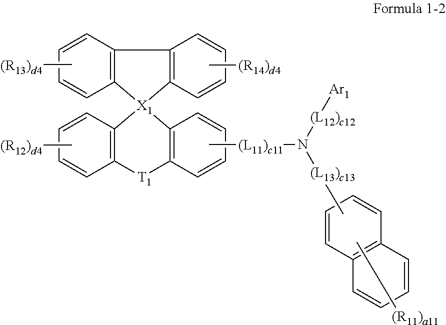

where, in Formula 1-2, X₁, T₁, L₁₁ to L₁₃, Ar₁, a11, R₁₁ to R₁₄, and c11 to c13 may each be the same as described in Formula 1, and
d4 may be an integer selecting from 0 to 4.

In an embodiment, the first compound may be one of Compounds A1 to A174:

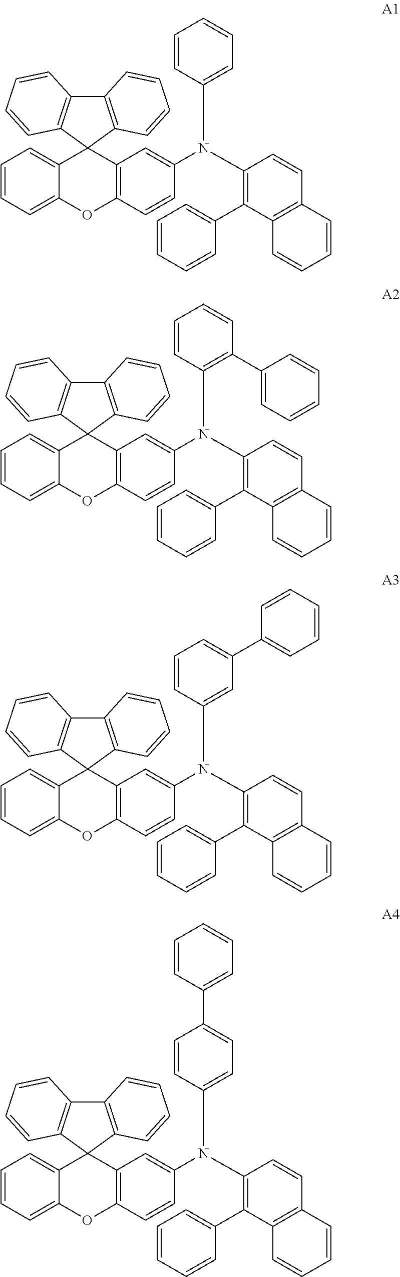

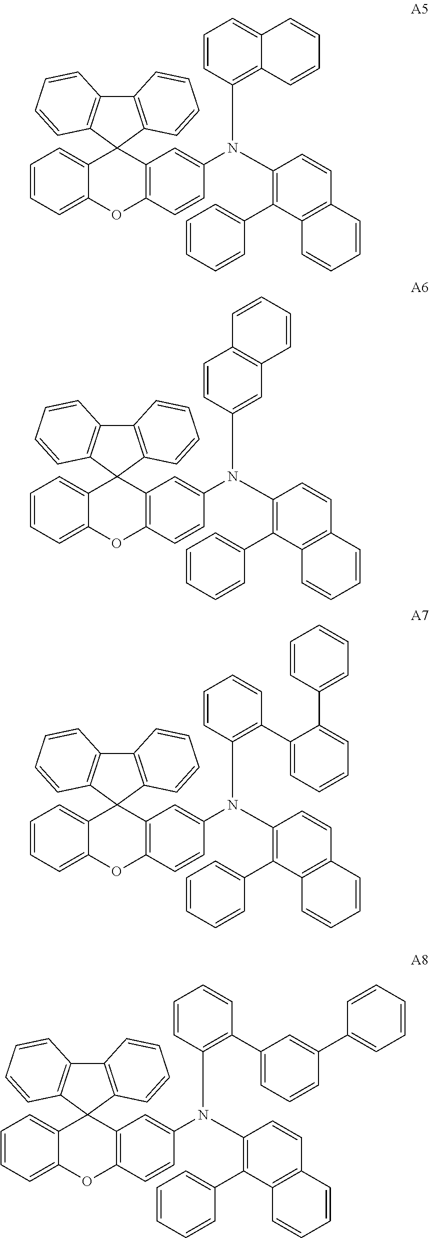

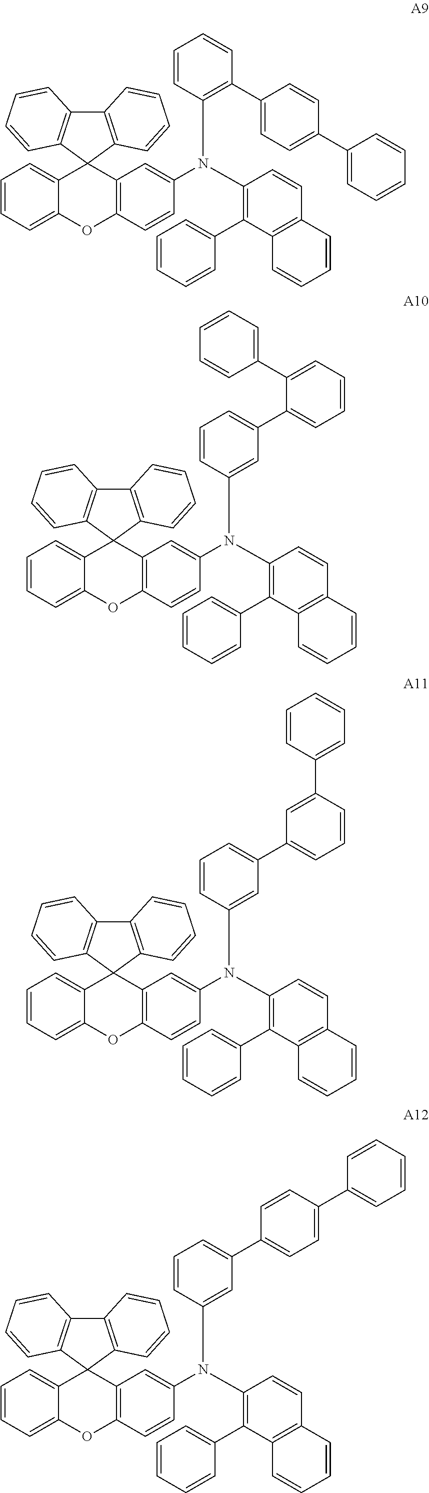

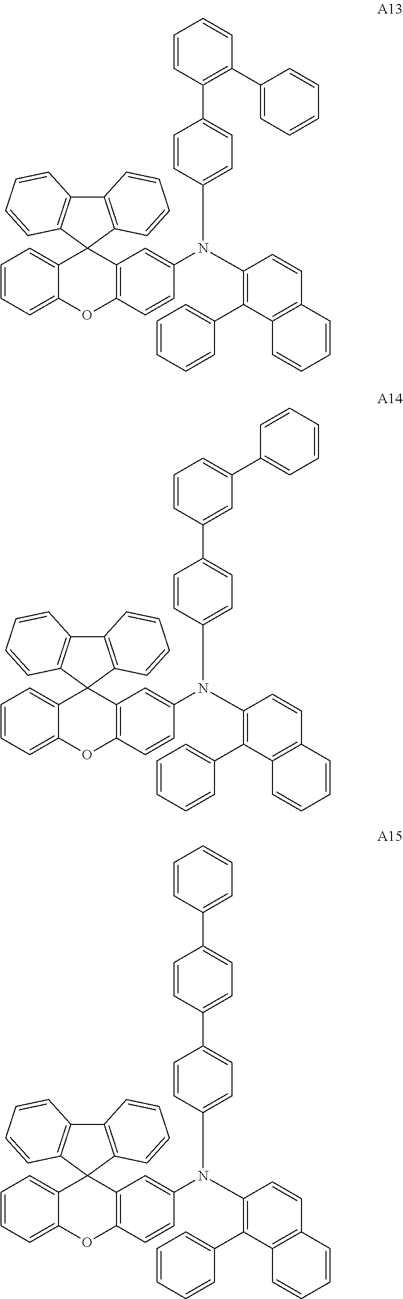

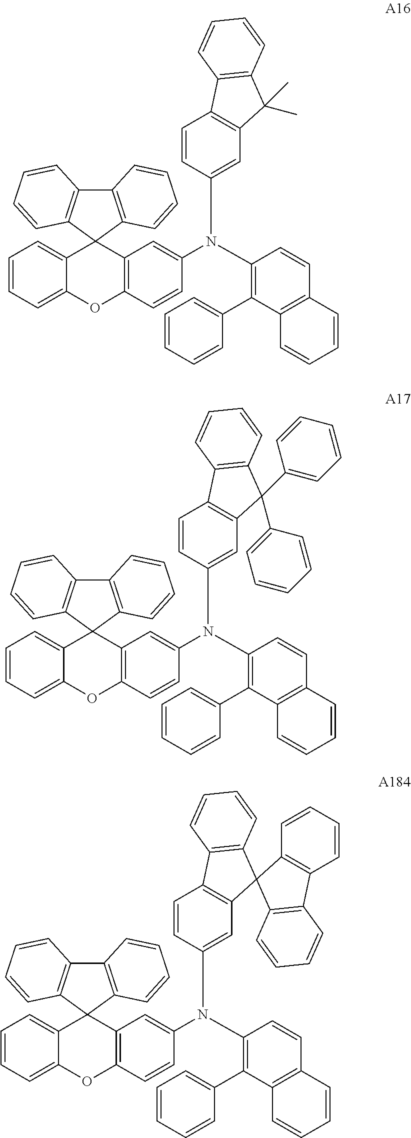

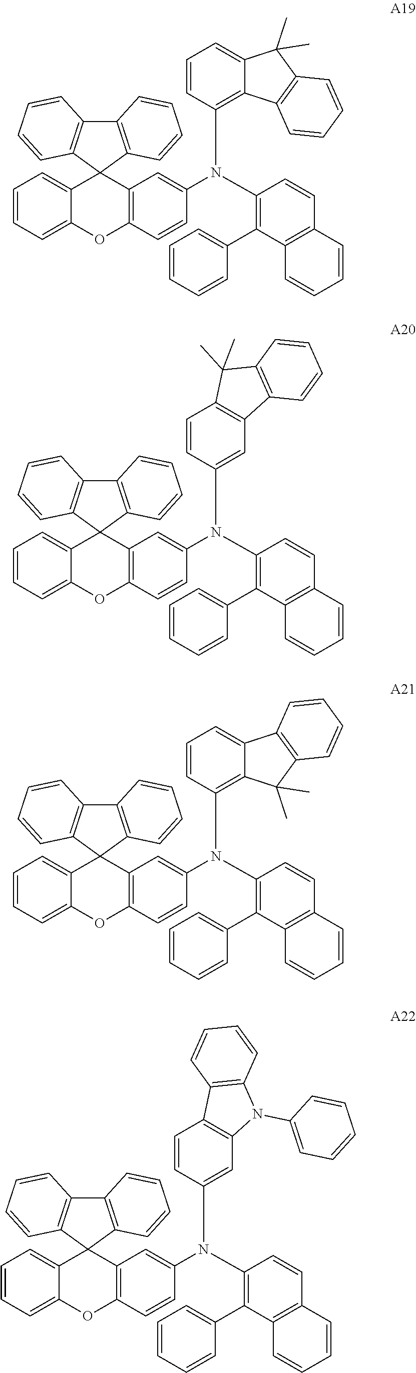

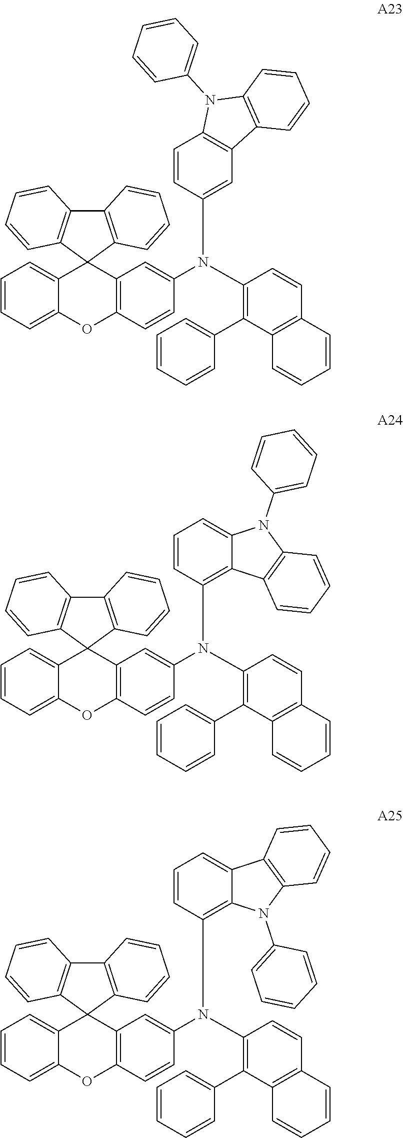

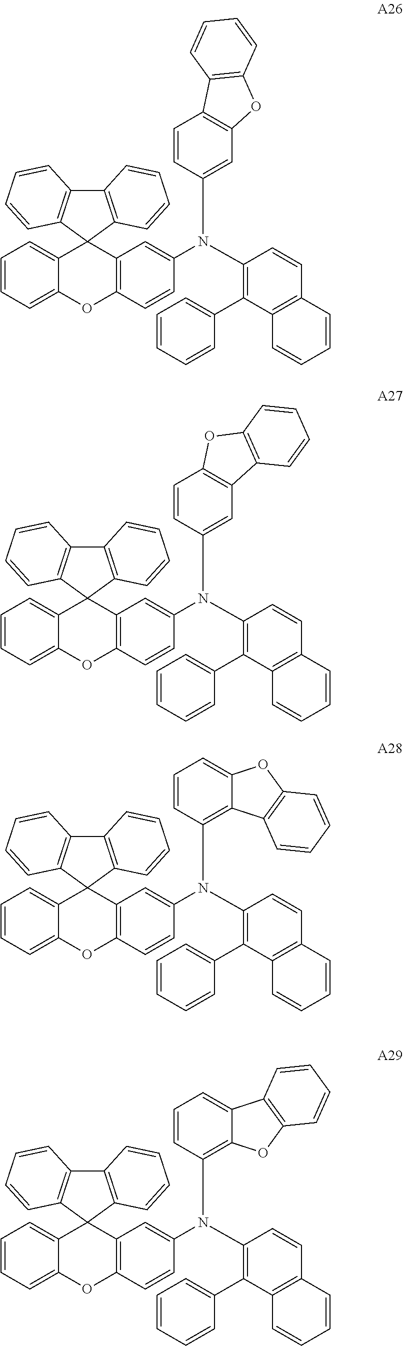

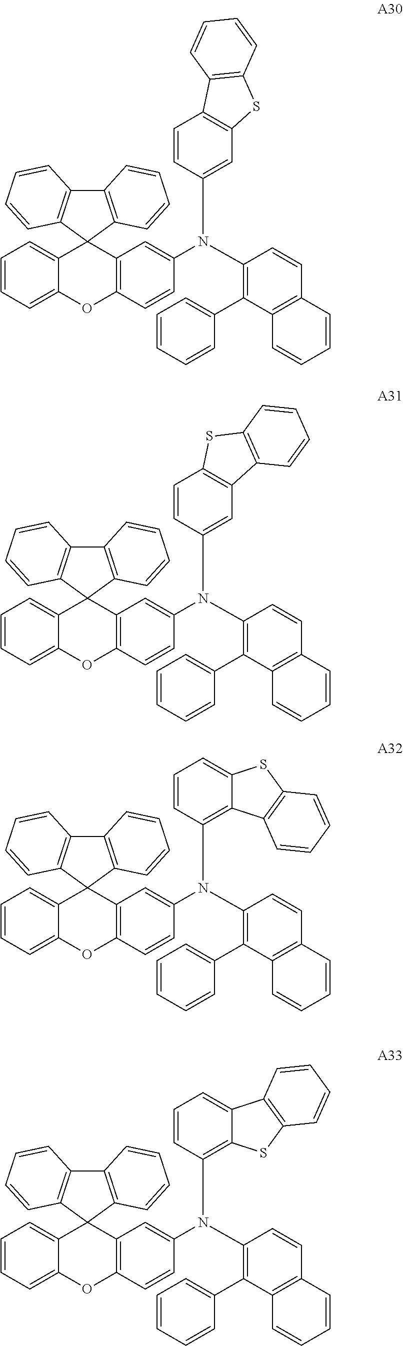

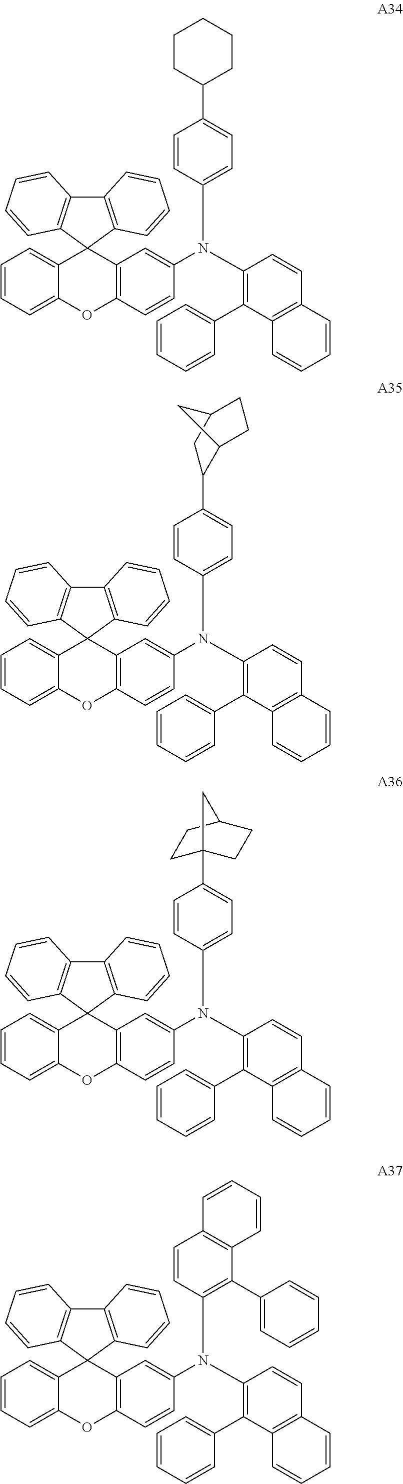

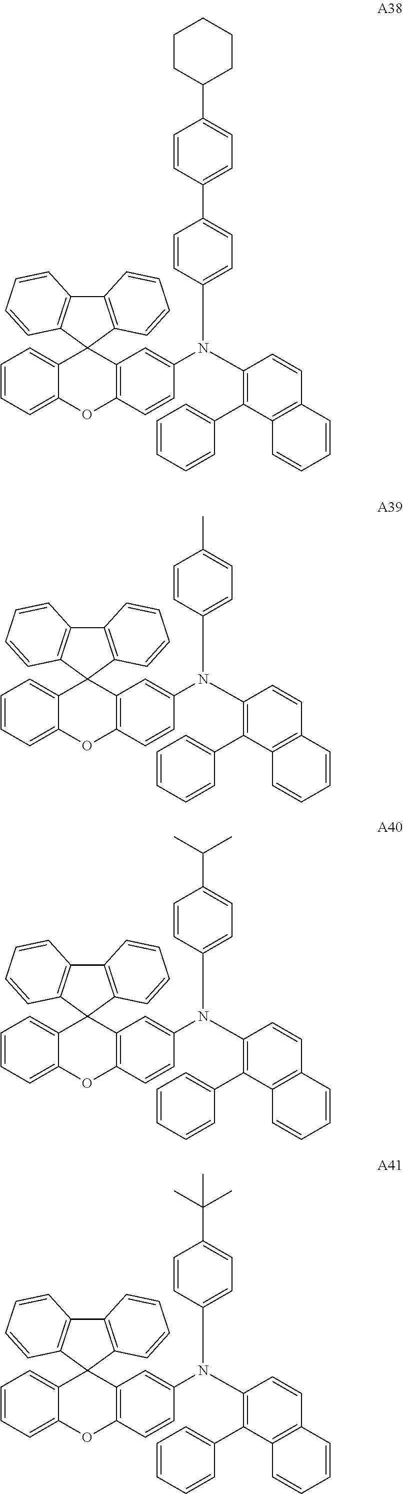

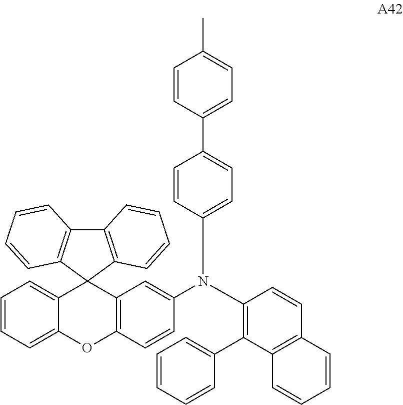 [SMILES: Cc1ccc(-c2ccc(N(c3ccc4c(c3)C3(c5ccccc5O4)c4ccccc4-c4ccccc43)c3ccc4ccccc4c3-c3ccccc3)cc2)cc1]

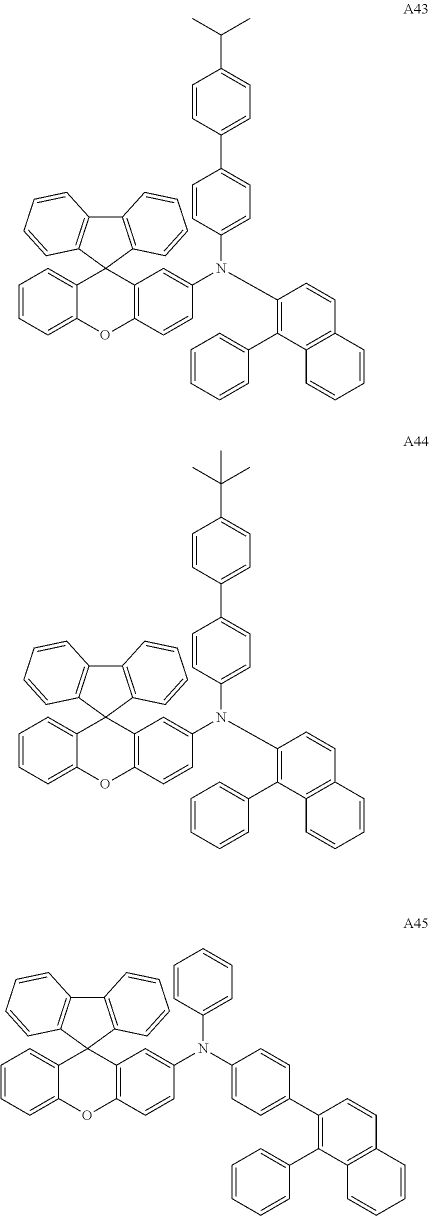 [SMILES: CC(C)c1ccc(-c2ccc(N(c3ccc4c(c3)C3(c5ccccc5O4)c4ccccc4-c4ccccc43)c3ccc4ccccc4c3-c3ccccc3)cc2)cc1 ; CC(C)(C)c1ccc(-c2ccc(N(c3ccc4c(c3)C3(c5ccccc5O4)c4ccccc4-c4ccccc43)c3ccc4ccccc4c3-c3ccccc3)cc2)cc1 ; c1ccc(-c2c(-c3ccc(N(c4ccccc4)c4ccc5c(c4)C4(c6ccccc6O5)c5ccccc5-c5ccccc54)cc3)ccc3ccccc23)cc1]

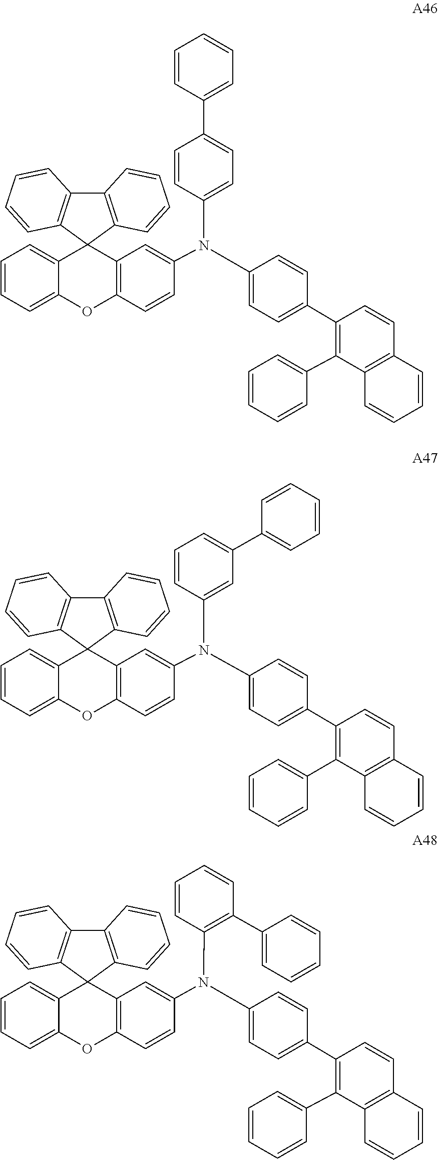 [SMILES: c1ccc(-c2ccc(N(c3ccc(-c4ccc5ccccc5c4-c4ccccc4)cc3)c3ccc4c(c3)C3(c5ccccc5O4)c4ccccc4-c4ccccc43)cc2)cc1 ; c1ccc(-c2cccc(N(c3ccc(-c4ccc5ccccc5c4-c4ccccc4)cc3)c3ccc4c(c3)C3(c5ccccc5O4)c4ccccc4-c4ccccc43)c2)cc1 ; c1ccc(-c2ccccc2N(c2ccc(-c3ccc4ccccc4c3-c3ccccc3)cc2)c2ccc3c(c2)C2(c4ccccc4O3)c3ccccc3-c3ccccc32)cc1]

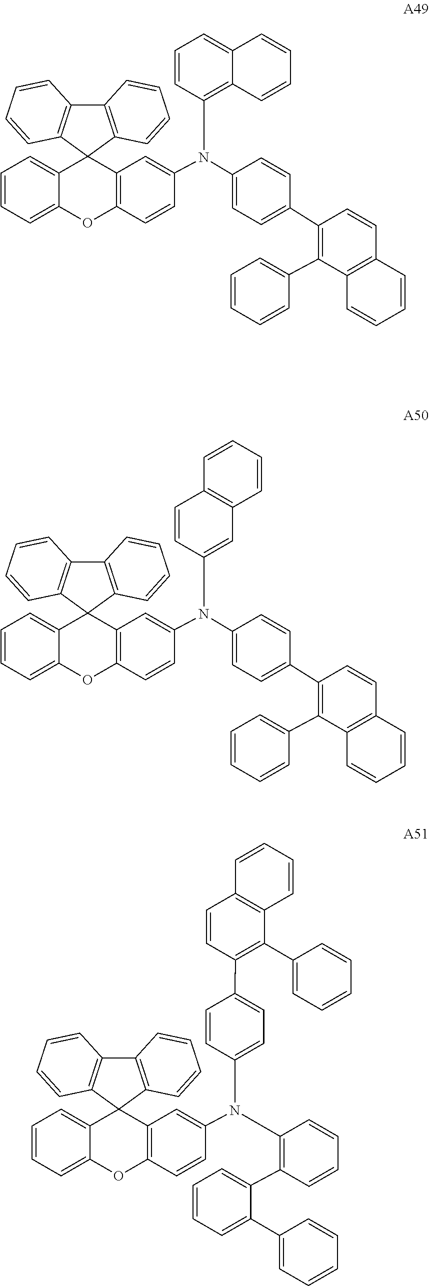 [SMILES: c1ccc(-c2c(-c3ccc(N(c4ccc5c(c4)C4(c6ccccc6O5)c5ccccc5-c5ccccc54)c4cccc5ccccc45)cc3)ccc3ccccc23)cc1 ; c1ccc(-c2c(-c3ccc(N(c4ccc5c(c4)C4(c6ccccc6O5)c5ccccc5-c5ccccc54)c4ccc5ccccc5c4)cc3)ccc3ccccc23)cc1 ; c1ccc(-c2ccccc2-c2ccccc2N(c2ccc(-c3ccc4ccccc4c3-c3ccccc3)cc2)c2ccc3c(c2)C2(c4ccccc4O3)c3ccccc3-c3ccccc32)cc1]

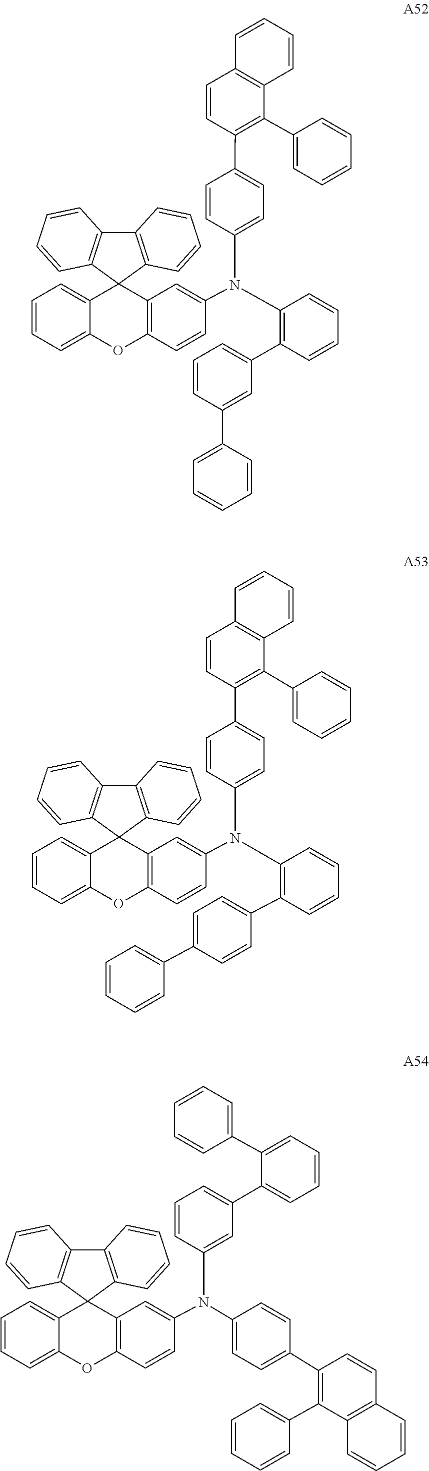 [SMILES: c1ccc(-c2cccc(-c3ccccc3N(c3ccc(-c4ccc5ccccc5c4-c4ccccc4)cc3)c3ccc4c(c3)C3(c5ccccc5O4)c4ccccc4-c4ccccc43)c2)cc1 ; c1ccc(-c2ccc(-c3ccccc3N(c3ccc(-c4ccc5ccccc5c4-c4ccccc4)cc3)c3ccc4c(c3)C3(c5ccccc5O4)c4ccccc4-c4ccccc43)cc2)cc1 ; c1ccc(-c2ccccc2-c2cccc(N(c3ccc(-c4ccc5ccccc5c4-c4ccccc4)cc3)c3ccc4c(c3)C3(c5ccccc5O4)c4ccccc4-c4ccccc43)c2)cc1]

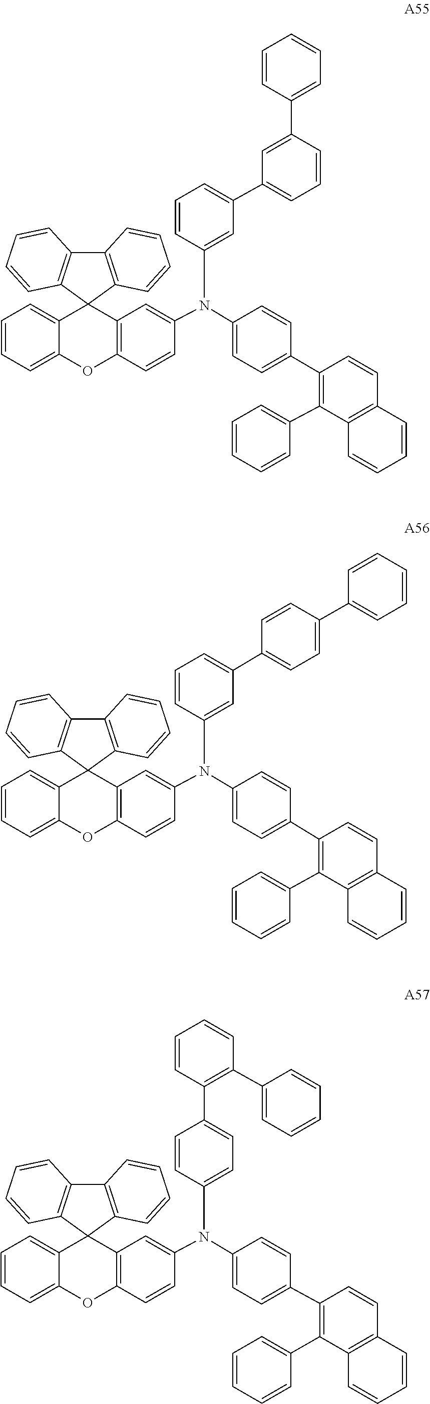 [SMILES: c1ccc(-c2cccc(-c3cccc(N(c4ccc(-c5ccc6ccccc6c5-c5ccccc5)cc4)c4ccc5c(c4)C4(c6ccccc6O5)c5ccccc5-c5ccccc54)c3)c2)cc1 ; c1ccc(-c2ccc(-c3cccc(N(c4ccc(-c5ccc6ccccc6c5-c5ccccc5)cc4)c4ccc5c(c4)C4(c6ccccc6O5)c5ccccc5-c5ccccc54)c3)cc2)cc1 ; c1ccc(-c2ccccc2-c2ccc(N(c3ccc(-c4ccc5ccccc5c4-c4ccccc4)cc3)c3ccc4c(c3)C3(c5ccccc5O4)c4ccccc4-c4ccccc43)cc2)cc1]

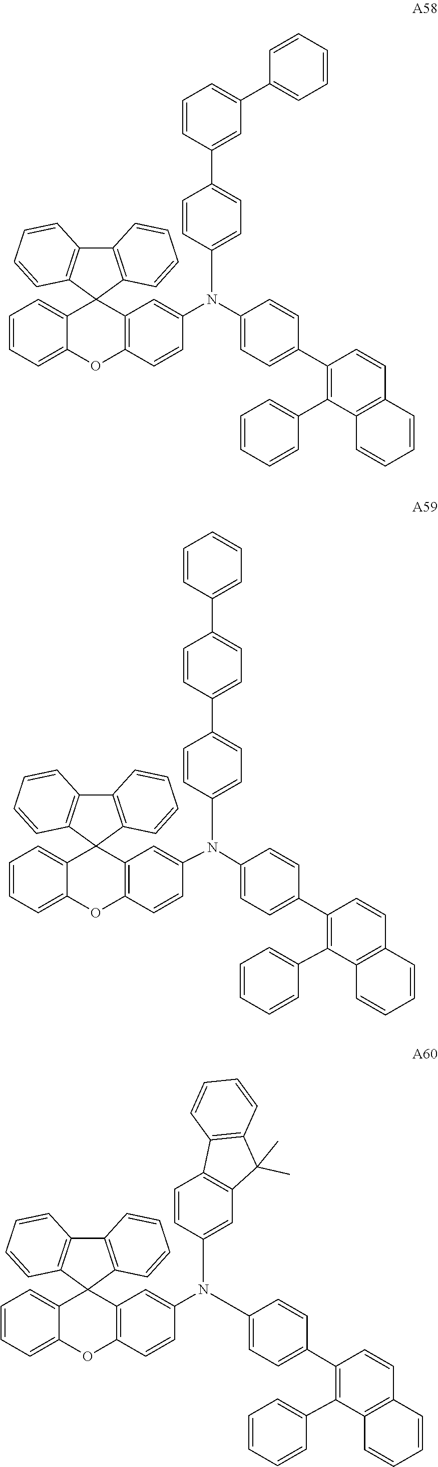 [SMILES: c1ccc(-c2cccc(-c3ccc(N(c4ccc(-c5ccc6ccccc6c5-c5ccccc5)cc4)c4ccc5c(c4)C4(c6ccccc6O5)c5ccccc5-c5ccccc54)cc3)c2)cc1 ; c1ccc(-c2ccc(-c3ccc(N(c4ccc(-c5ccc6ccccc6c5-c5ccccc5)cc4)c4ccc5c(c4)C4(c6ccccc6O5)c5ccccc5-c5ccccc54)cc3)cc2)cc1 ; CC1(C)c2ccccc2-c2ccc(N(c3ccc(-c4ccc5ccccc5c4-c4ccccc4)cc3)c3ccc4c(c3)C3(c5ccccc5O4)c4ccccc4-c4ccccc43)cc21]

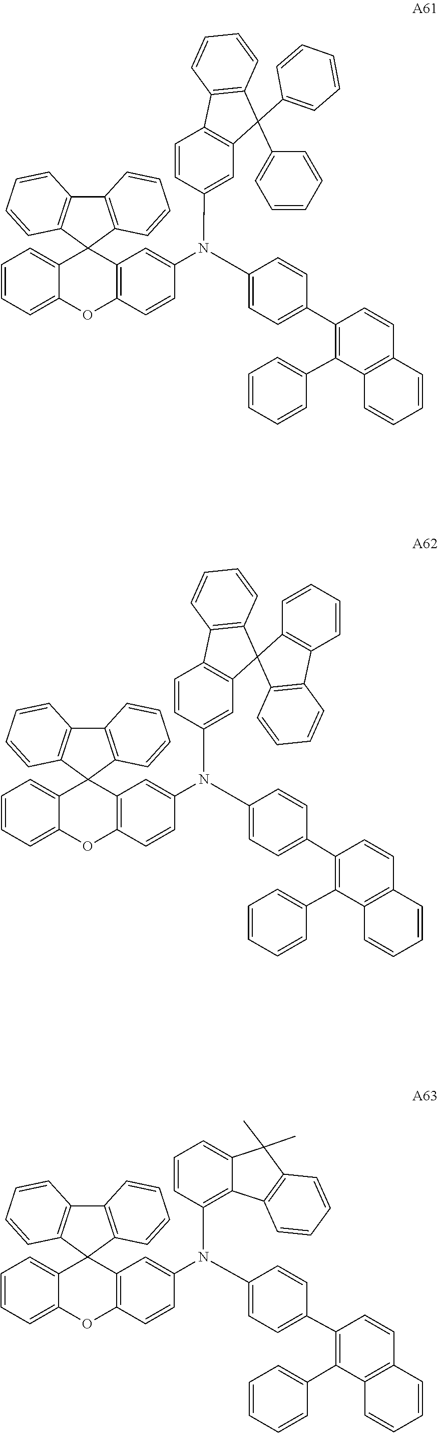 [SMILES: c1ccc(-c2c(-c3ccc(N(c4ccc5c(c4)C4(c6ccccc6O5)c5ccccc5-c5ccccc54)c4ccc5c(c4)C(c4ccccc4)(c4ccccc4)c4ccccc4-5)cc3)ccc3ccccc23)cc1 ; c1ccc(-c2c(-c3ccc(N(c4ccc5c(c4)C4(c6ccccc6O5)c5ccccc5-c5ccccc54)c4ccc5c(c4)C4(c6ccccc6-c6ccccc64)c4ccccc4-5)cc3)ccc3ccccc23)cc1 ; CC1(C)c2ccccc2-c2c(N(c3ccc(-c4ccc5ccccc5c4-c4ccccc4)cc3)c3ccc4c(c3)C3(c5ccccc5O4)c4ccccc4-c4ccccc43)cccc21]

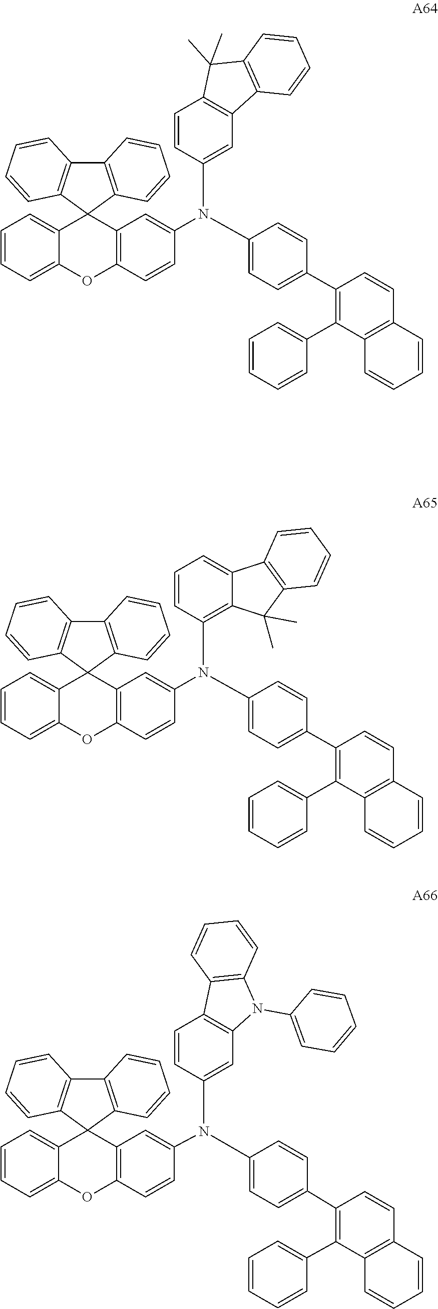 [SMILES: CC1(C)c2ccccc2-c2cc(N(c3ccc(-c4ccc5ccccc5c4-c4ccccc4)cc3)c3ccc4c(c3)C3(c5ccccc5O4)c4ccccc4-c4ccccc43)ccc21 ; CC1(C)c2ccccc2-c2cccc(N(c3ccc(-c4ccc5ccccc5c4-c4ccccc4)cc3)c3ccc4c(c3)C3(c5ccccc5O4)c4ccccc4-c4ccccc43)c21 ; c1ccc(-c2c(-c3ccc(N(c4ccc5c(c4)C4(c6ccccc6O5)c5ccccc5-c5ccccc54)c4ccc5c6ccccc6n(-c6ccccc6)c5c4)cc3)ccc3ccccc23)cc1]

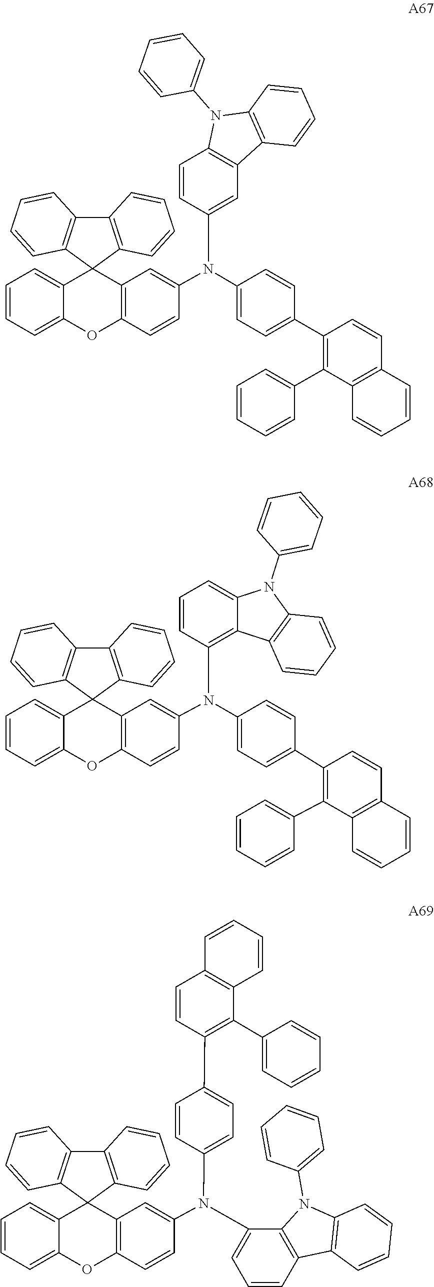 [SMILES: c1ccc(-c2c(-c3ccc(N(c4ccc5c(c4)C4(c6ccccc6O5)c5ccccc5-c5ccccc54)c4ccc5c(c4)c4ccccc4n5-c4ccccc4)cc3)ccc3ccccc23)cc1 ; c1ccc(-c2c(-c3ccc(N(c4ccc5c(c4)C4(c6ccccc6O5)c5ccccc5-c5ccccc54)c4cccc5c4c4ccccc4n5-c4ccccc4)cc3)ccc3ccccc23)cc1 ; c1ccc(-c2c(-c3ccc(N(c4ccc5c(c4)C4(c6ccccc6O5)c5ccccc5-c5ccccc54)c4cccc5c6ccccc6n(-c6ccccc6)c45)cc3)ccc3ccccc23)cc1]

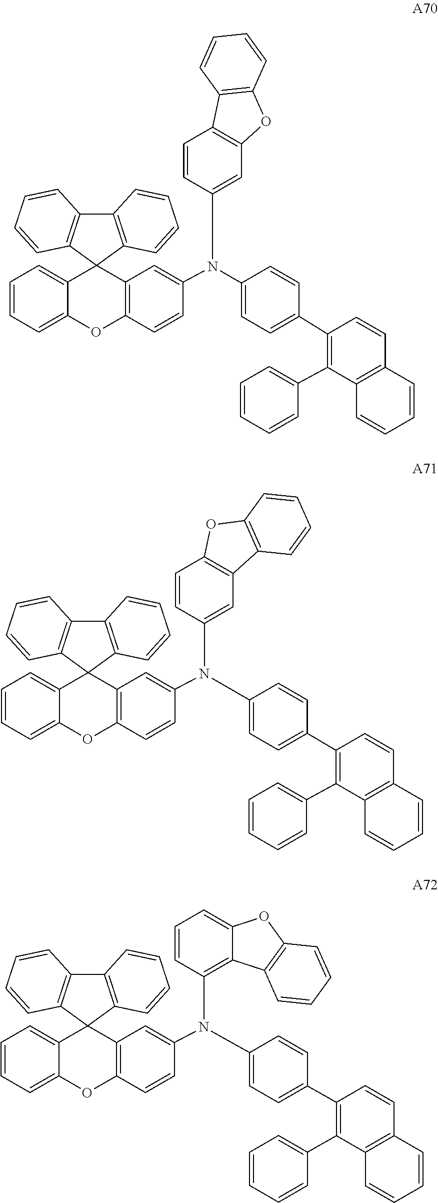 [SMILES: c1ccc(-c2c(-c3ccc(N(c4ccc5c(c4)C4(c6ccccc6O5)c5ccccc5-c5ccccc54)c4ccc5c(c4)oc4ccccc45)cc3)ccc3ccccc23)cc1 ; c1ccc(-c2c(-c3ccc(N(c4ccc5c(c4)C4(c6ccccc6O5)c5ccccc5-c5ccccc54)c4ccc5oc6ccccc6c5c4)cc3)ccc3ccccc23)cc1 ; c1ccc(-c2c(-c3ccc(N(c4ccc5c(c4)C4(c6ccccc6O5)c5ccccc5-c5ccccc54)c4cccc5oc6ccccc6c45)cc3)ccc3ccccc23)cc1]

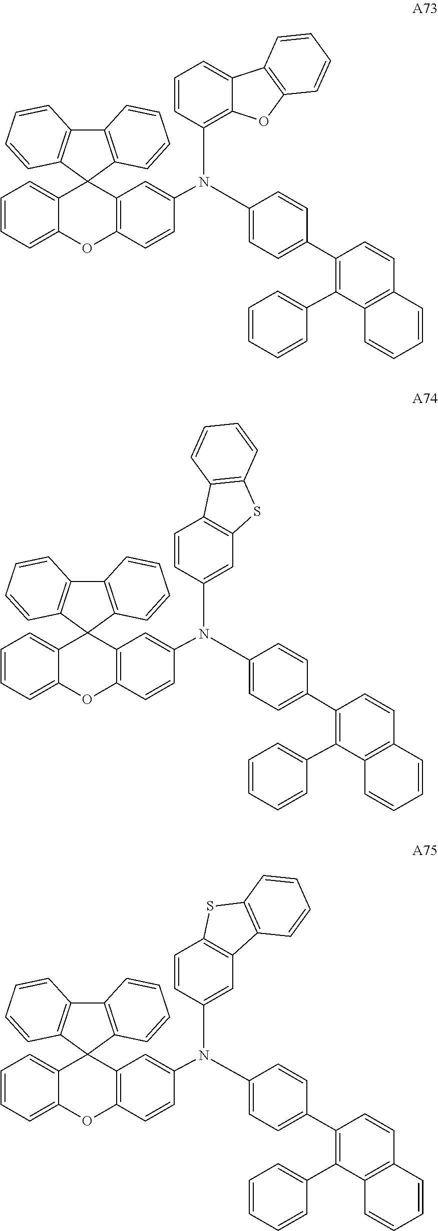 [SMILES: c1ccc(-c2c(-c3ccc(N(c4ccc5c(c4)C4(c6ccccc6O5)c5ccccc5-c5ccccc54)c4cccc5c4oc4ccccc45)cc3)ccc3ccccc23)cc1 ; c1ccc(-c2c(-c3ccc(N(c4ccc5c(c4)C4(c6ccccc6O5)c5ccccc5-c5ccccc54)c4ccc5c(c4)sc4ccccc45)cc3)ccc3ccccc23)cc1 ; c1ccc(-c2c(-c3ccc(N(c4ccc5c(c4)C4(c6ccccc6O5)c5ccccc5-c5ccccc54)c4ccc5sc6ccccc6c5c4)cc3)ccc3ccccc23)cc1]

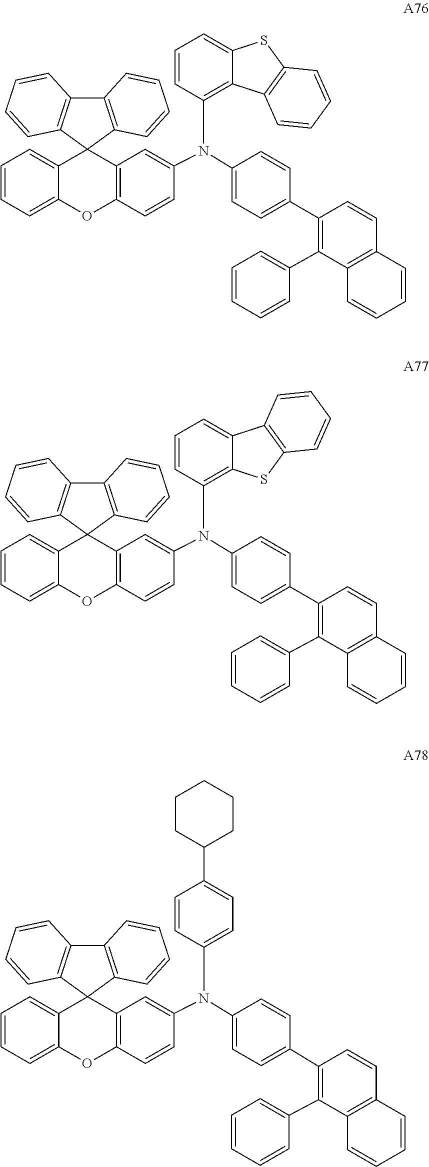 [SMILES: c1ccc(-c2c(-c3ccc(N(c4ccc5c(c4)C4(c6ccccc6O5)c5ccccc5-c5ccccc54)c4cccc5sc6ccccc6c45)cc3)ccc3ccccc23)cc1 ; c1ccc(-c2c(-c3ccc(N(c4ccc5c(c4)C4(c6ccccc6O5)c5ccccc5-c5ccccc54)c4cccc5c4sc4ccccc45)cc3)ccc3ccccc23)cc1 ; c1ccc(-c2c(-c3ccc(N(c4ccc(C5CCCCC5)cc4)c4ccc5c(c4)C4(c6ccccc6O5)c5ccccc5-c5ccccc54)cc3)ccc3ccccc23)cc1]

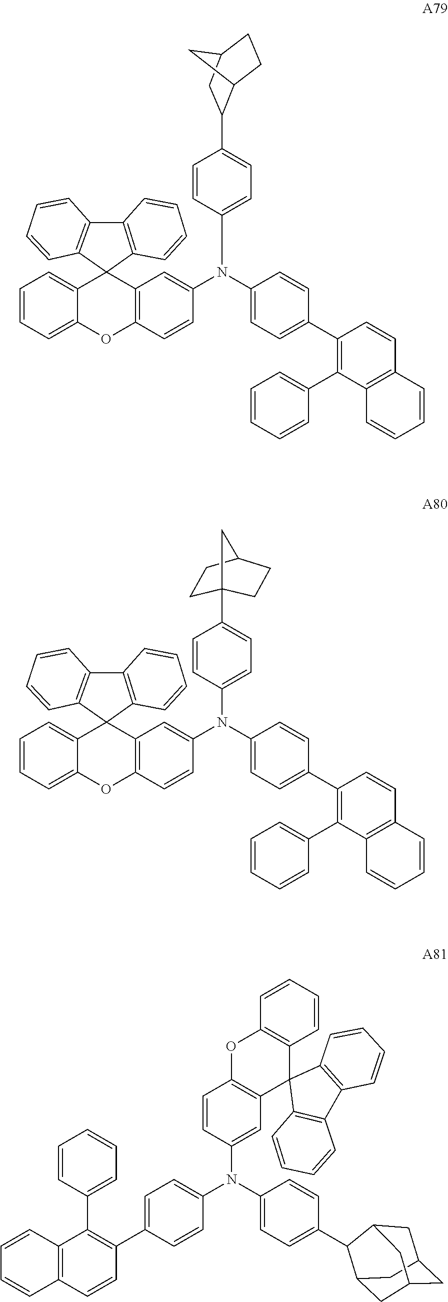 [SMILES: c1ccc(-c2c(-c3ccc(N(c4ccc(C5CC6CCC5C6)cc4)c4ccc5c(c4)C4(c6ccccc6O5)c5ccccc5-c5ccccc54)cc3)ccc3ccccc23)cc1 ; c1ccc(-c2c(-c3ccc(N(c4ccc(C56CCC(CC5)C6)cc4)c4ccc5c(c4)C4(c6ccccc6O5)c5ccccc5-c5ccccc54)cc3)ccc3ccccc23)cc1 ; c1ccc(-c2c(-c3ccc(N(c4ccc(C5C6CC7CC(C6)CC5C7)cc4)c4ccc5c(c4)C4(c6ccccc6O5)c5ccccc5-c5ccccc54)cc3)ccc3ccccc23)cc1]

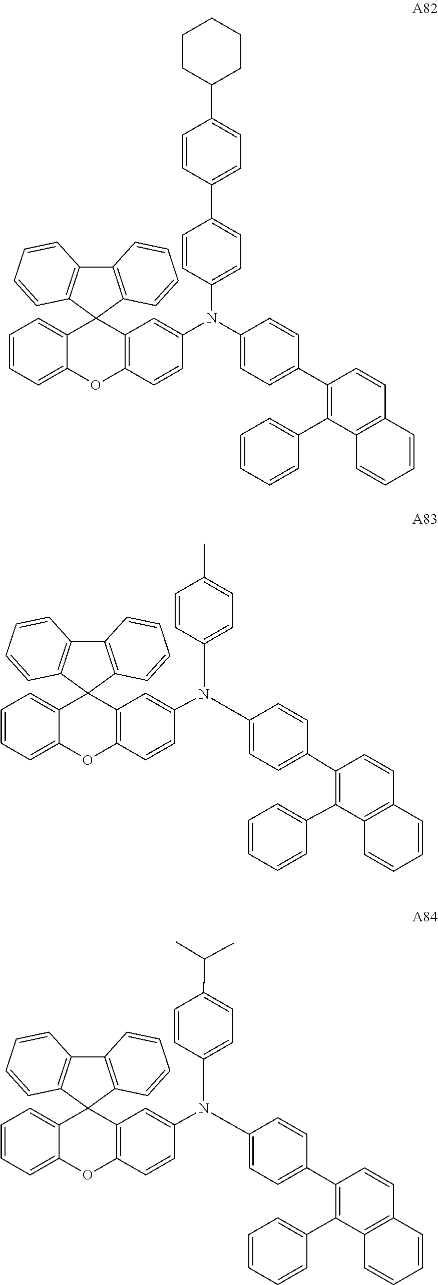 [SMILES: c1ccc(-c2c(-c3ccc(N(c4ccc(-c5ccc(C6CCCCC6)cc5)cc4)c4ccc5c(c4)C4(c6ccccc6O5)c5ccccc5-c5ccccc54)cc3)ccc3ccccc23)cc1 ; Cc1ccc(N(c2ccc(-c3ccc4ccccc4c3-c3ccccc3)cc2)c2ccc3c(c2)C2(c4ccccc4O3)c3ccccc3-c3ccccc32)cc1 ; CC(C)c1ccc(N(c2ccc(-c3ccc4ccccc4c3-c3ccccc3)cc2)c2ccc3c(c2)C2(c4ccccc4O3)c3ccccc3-c3ccccc32)cc1]

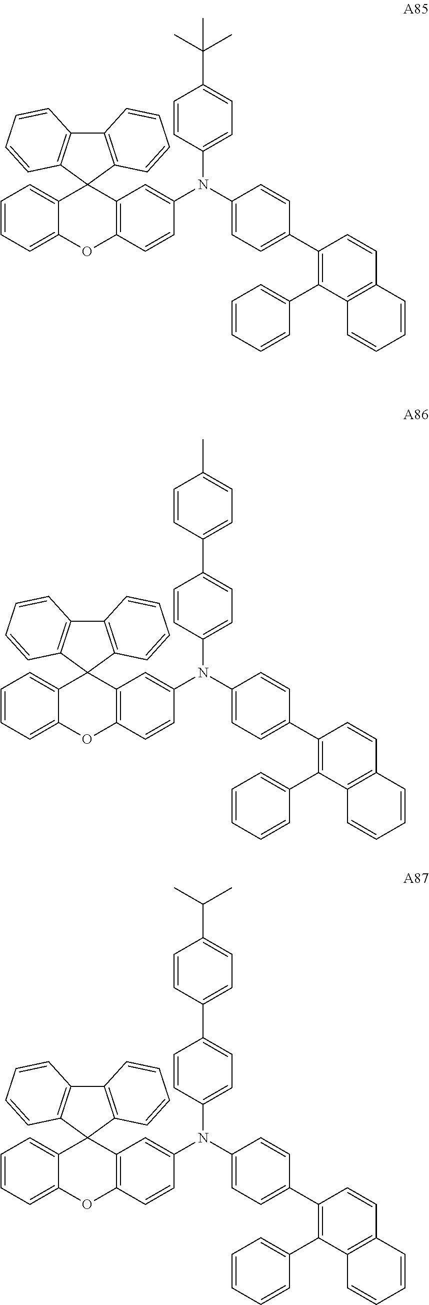 [SMILES: CC(C)(C)c1ccc(N(c2ccc(-c3ccc4ccccc4c3-c3ccccc3)cc2)c2ccc3c(c2)C2(c4ccccc4O3)c3ccccc3-c3ccccc32)cc1 ; Cc1ccc(-c2ccc(N(c3ccc(-c4ccc5ccccc5c4-c4ccccc4)cc3)c3ccc4c(c3)C3(c5ccccc5O4)c4ccccc4-c4ccccc43)cc2)cc1 ; CC(C)c1ccc(-c2ccc(N(c3ccc(-c4ccc5ccccc5c4-c4ccccc4)cc3)c3ccc4c(c3)C3(c5ccccc5O4)c4ccccc4-c4ccccc43)cc2)cc1]

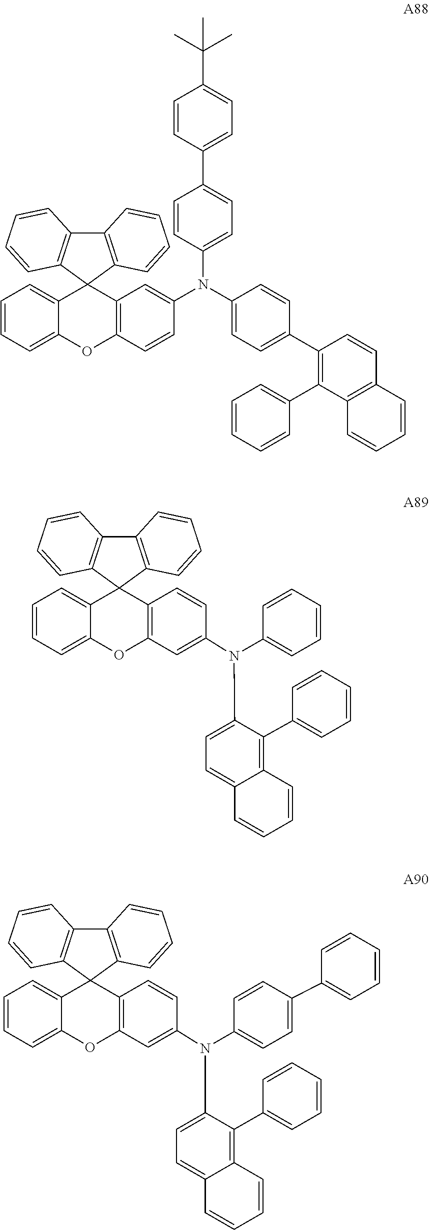 [SMILES: CC(C)(C)c1ccc(-c2ccc(N(c3ccc(-c4ccc5ccccc5c4-c4ccccc4)cc3)c3ccc4c(c3)C3(c5ccccc5O4)c4ccccc4-c4ccccc43)cc2)cc1 ; c1ccc(-c2c(N(c3ccccc3)c3ccc4c(c3)Oc3ccccc3C43c4ccccc4-c4ccccc43)ccc3ccccc23)cc1 ; c1ccc(-c2ccc(N(c3ccc4c(c3)Oc3ccccc3C43c4ccccc4-c4ccccc43)c3ccc4ccccc4c3-c3ccccc3)cc2)cc1]

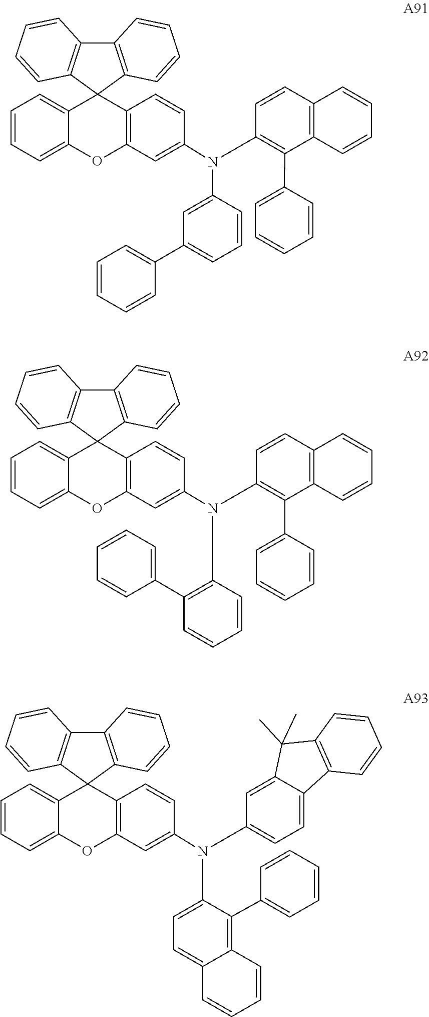 [SMILES: c1ccc(-c2cccc(N(c3ccc4c(c3)Oc3ccccc3C43c4ccccc4-c4ccccc43)c3ccc4ccccc4c3-c3ccccc3)c2)cc1 ; c1ccc(-c2ccccc2N(c2ccc3c(c2)Oc2ccccc2C32c3ccccc3-c3ccccc32)c2ccc3ccccc3c2-c2ccccc2)cc1 ; CC1(C)c2ccccc2-c2ccc(N(c3ccc4c(c3)Oc3ccccc3C43c4ccccc4-c4ccccc43)c3ccc4ccccc4c3-c3ccccc3)cc21]

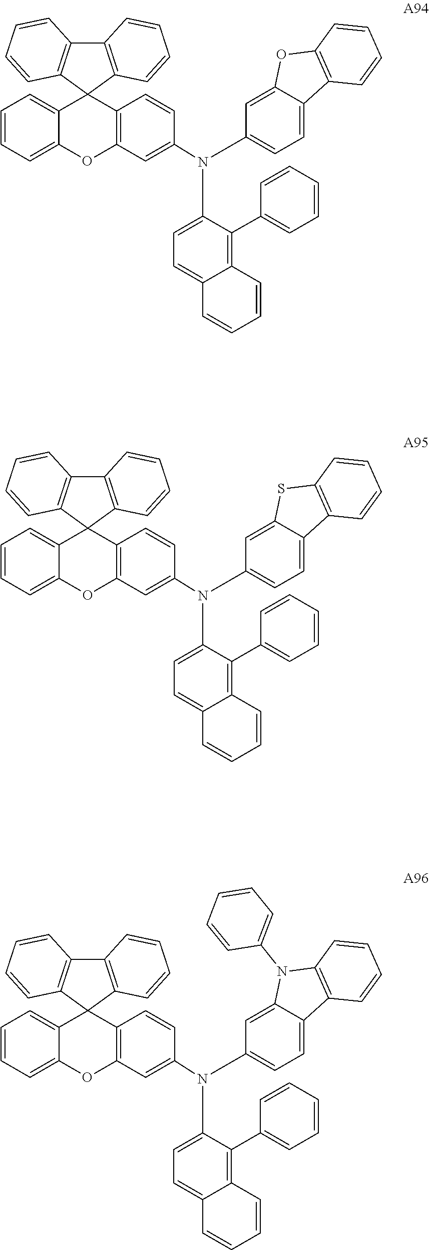 [SMILES: c1ccc(-c2c(N(c3ccc4c(c3)Oc3ccccc3C43c4ccccc4-c4ccccc43)c3ccc4c(c3)oc3ccccc34)ccc3ccccc23)cc1 ; c1ccc(-c2c(N(c3ccc4c(c3)Oc3ccccc3C43c4ccccc4-c4ccccc43)c3ccc4c(c3)sc3ccccc34)ccc3ccccc23)cc1 ; c1ccc(-c2c(N(c3ccc4c(c3)Oc3ccccc3C43c4ccccc4-c4ccccc43)c3ccc4c5ccccc5n(-c5ccccc5)c4c3)ccc3ccccc23)cc1]

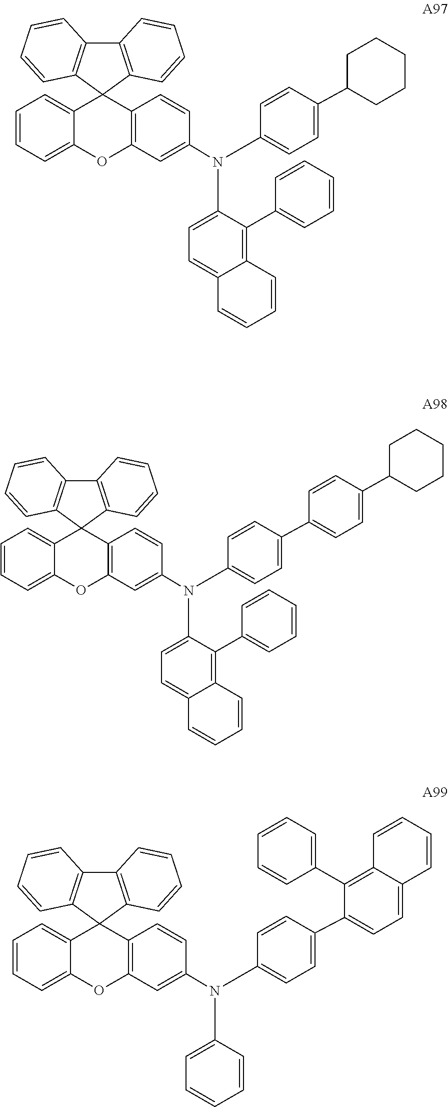 [SMILES: c1ccc(-c2c(N(c3ccc(C4CCCCC4)cc3)c3ccc4c(c3)Oc3ccccc3C43c4ccccc4-c4ccccc43)ccc3ccccc23)cc1 ; c1ccc(-c2c(N(c3ccc(-c4ccc(C5CCCCC5)cc4)cc3)c3ccc4c(c3)Oc3ccccc3C43c4ccccc4-c4ccccc43)ccc3ccccc23)cc1 ; c1ccc(-c2c(-c3ccc(N(c4ccccc4)c4ccc5c(c4)Oc4ccccc4C54c5ccccc5-c5ccccc54)cc3)ccc3ccccc23)cc1]

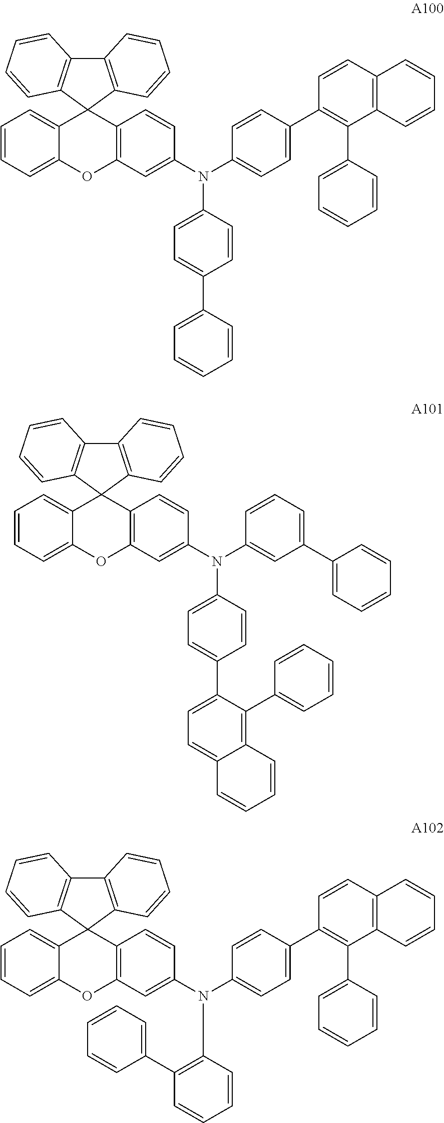 [SMILES: c1ccc(-c2ccc(N(c3ccc(-c4ccc5ccccc5c4-c4ccccc4)cc3)c3ccc4c(c3)Oc3ccccc3C43c4ccccc4-c4ccccc43)cc2)cc1 ; c1ccc(-c2cccc(N(c3ccc(-c4ccc5ccccc5c4-c4ccccc4)cc3)c3ccc4c(c3)Oc3ccccc3C43c4ccccc4-c4ccccc43)c2)cc1 ; c1ccc(-c2ccccc2N(c2ccc(-c3ccc4ccccc4c3-c3ccccc3)cc2)c2ccc3c(c2)Oc2ccccc2C32c3ccccc3-c3ccccc32)cc1]

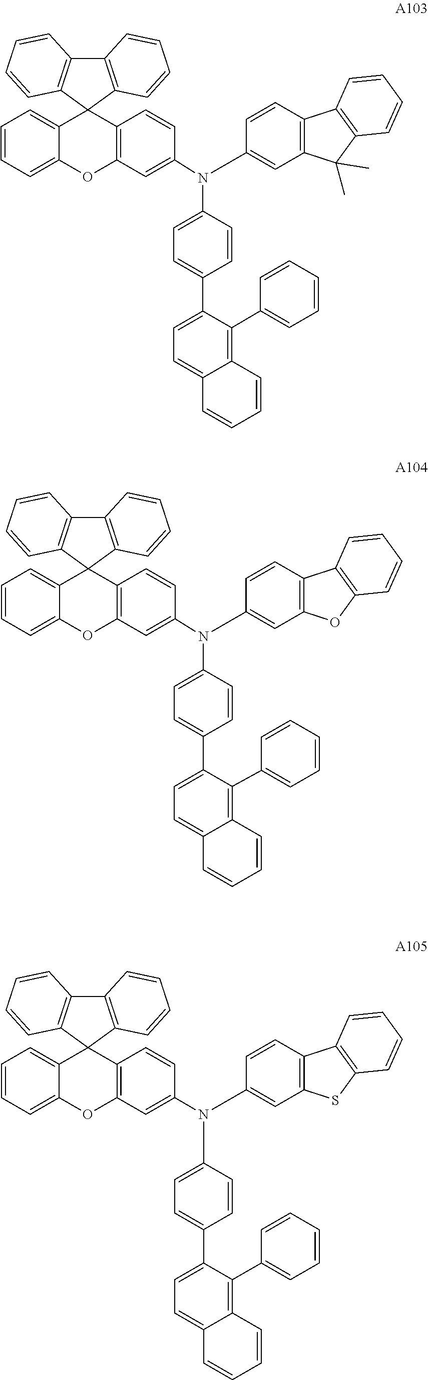 [SMILES: CC1(C)c2ccccc2-c2ccc(N(c3ccc(-c4ccc5ccccc5c4-c4ccccc4)cc3)c3ccc4c(c3)Oc3ccccc3C43c4ccccc4-c4ccccc43)cc21 ; c1ccc(-c2c(-c3ccc(N(c4ccc5c(c4)Oc4ccccc4C54c5ccccc5-c5ccccc54)c4ccc5c(c4)oc4ccccc45)cc3)ccc3ccccc23)cc1 ; c1ccc(-c2c(-c3ccc(N(c4ccc5c(c4)Oc4ccccc4C54c5ccccc5-c5ccccc54)c4ccc5c(c4)sc4ccccc45)cc3)ccc3ccccc23)cc1]

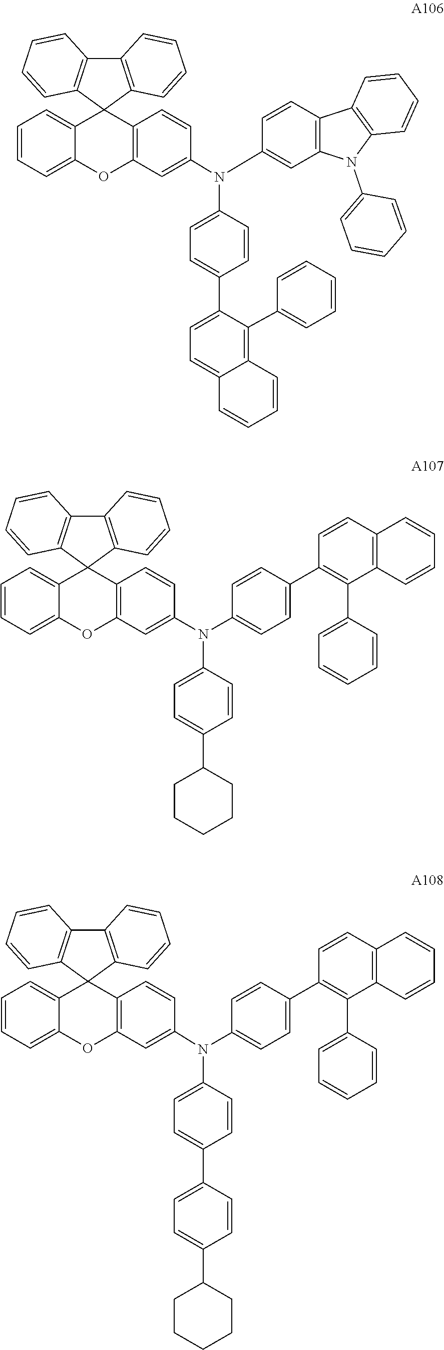 [SMILES: c1ccc(-c2c(-c3ccc(N(c4ccc5c(c4)Oc4ccccc4C54c5ccccc5-c5ccccc54)c4ccc5c6ccccc6n(-c6ccccc6)c5c4)cc3)ccc3ccccc23)cc1 ; c1ccc(-c2c(-c3ccc(N(c4ccc(C5CCCCC5)cc4)c4ccc5c(c4)Oc4ccccc4C54c5ccccc5-c5ccccc54)cc3)ccc3ccccc23)cc1 ; c1ccc(-c2c(-c3ccc(N(c4ccc(-c5ccc(C6CCCCC6)cc5)cc4)c4ccc5c(c4)Oc4ccccc4C54c5ccccc5-c5ccccc54)cc3)ccc3ccccc23)cc1]

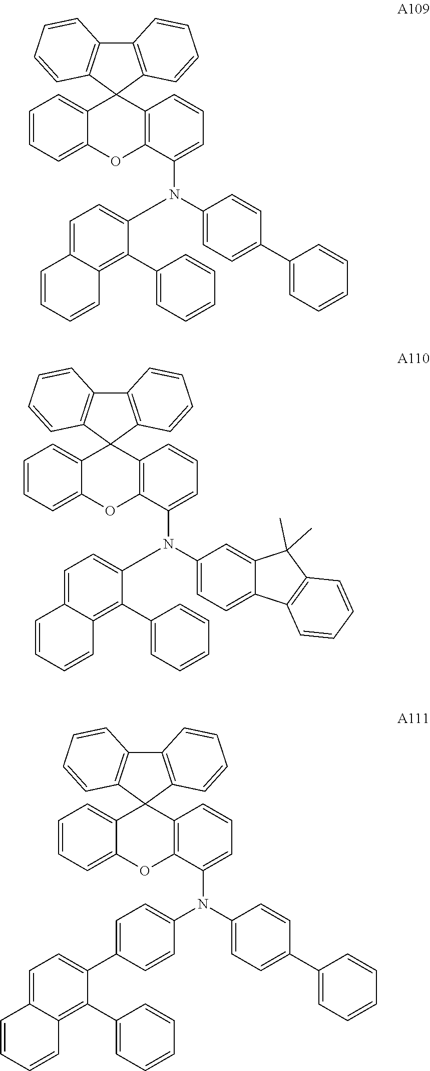 [SMILES: c1ccc(-c2ccc(N(c3cccc4c3Oc3ccccc3C43c4ccccc4-c4ccccc43)c3ccc4ccccc4c3-c3ccccc3)cc2)cc1 ; CC1(C)c2ccccc2-c2ccc(N(c3cccc4c3Oc3ccccc3C43c4ccccc4-c4ccccc43)c3ccc4ccccc4c3-c3ccccc3)cc21 ; c1ccc(-c2ccc(N(c3ccc(-c4ccc5ccccc5c4-c4ccccc4)cc3)c3cccc4c3Oc3ccccc3C43c4ccccc4-c4ccccc43)cc2)cc1]

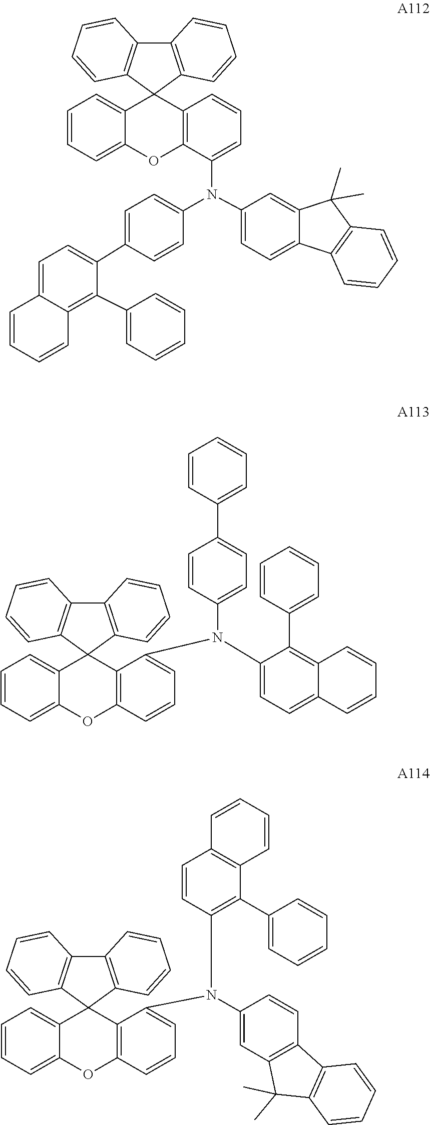 [SMILES: CC1(C)c2ccccc2-c2ccc(N(c3ccc(-c4ccc5ccccc5c4-c4ccccc4)cc3)c3cccc4c3Oc3ccccc3C43c4ccccc4-c4ccccc43)cc21 ; c1ccc(-c2ccc(N(c3cccc4c3C3(c5ccccc5O4)c4ccccc4-c4ccccc43)c3ccc4ccccc4c3-c3ccccc3)cc2)cc1 ; CC1(C)c2ccccc2-c2ccc(N(c3cccc4c3C3(c5ccccc5O4)c4ccccc4-c4ccccc43)c3ccc4ccccc4c3-c3ccccc3)cc21]

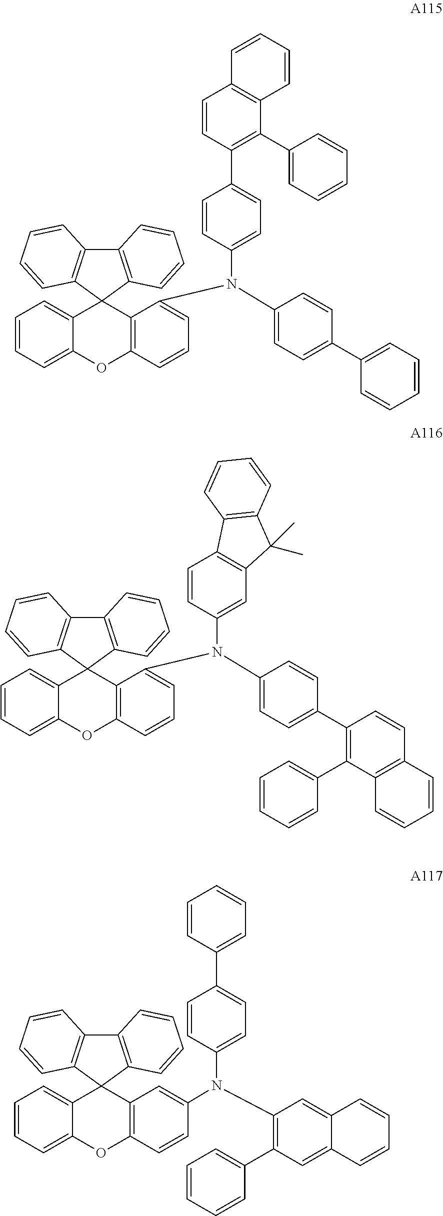 [SMILES: c1ccc(-c2ccc(N(c3ccc(-c4ccc5ccccc5c4-c4ccccc4)cc3)c3cccc4c3C3(c5ccccc5O4)c4ccccc4-c4ccccc43)cc2)cc1 ; CC1(C)c2ccccc2-c2ccc(N(c3ccc(-c4ccc5ccccc5c4-c4ccccc4)cc3)c3cccc4c3C3(c5ccccc5O4)c4ccccc4-c4ccccc43)cc21 ; c1ccc(-c2ccc(N(c3ccc4c(c3)C3(c5ccccc5O4)c4ccccc4-c4ccccc43)c3cc4ccccc4cc3-c3ccccc3)cc2)cc1]

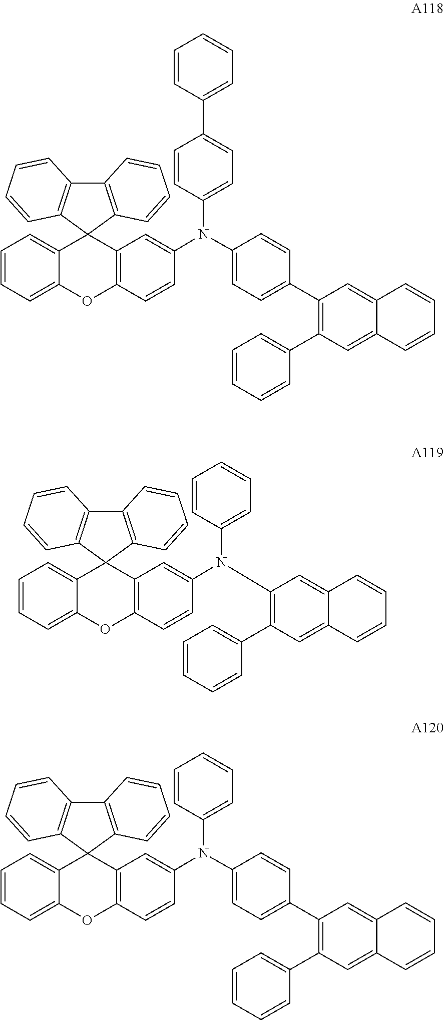 [SMILES: c1ccc(-c2ccc(N(c3ccc(-c4cc5ccccc5cc4-c4ccccc4)cc3)c3ccc4c(c3)C3(c5ccccc5O4)c4ccccc4-c4ccccc43)cc2)cc1 ; c1ccc(-c2cc3ccccc3cc2N(c2ccccc2)c2ccc3c(c2)C2(c4ccccc4O3)c3ccccc3-c3ccccc32)cc1 ; c1ccc(-c2cc3ccccc3cc2-c2ccc(N(c3ccccc3)c3ccc4c(c3)C3(c5ccccc5O4)c4ccccc4-c4ccccc43)cc2)cc1]

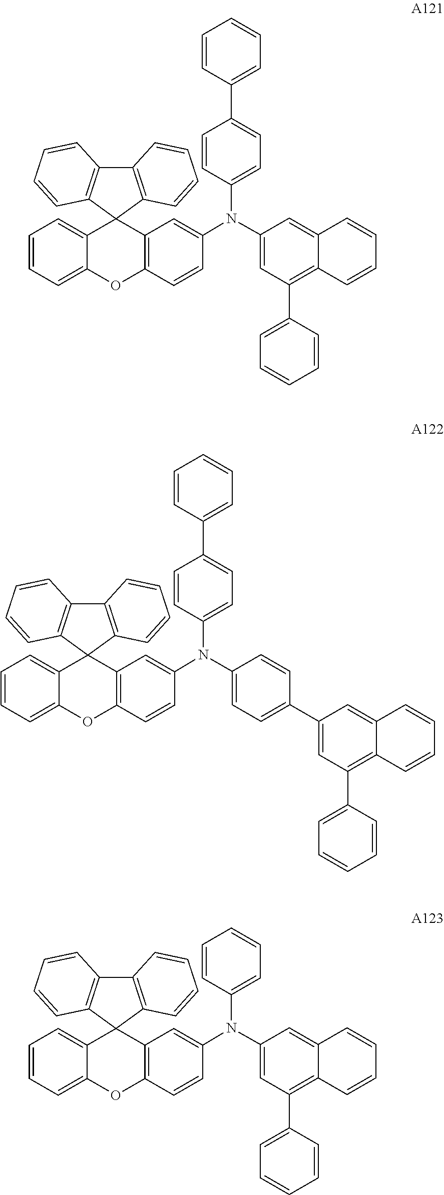 [SMILES: c1ccc(-c2ccc(N(c3ccc4c(c3)C3(c5ccccc5O4)c4ccccc4-c4ccccc43)c3cc(-c4ccccc4)c4ccccc4c3)cc2)cc1 ; c1ccc(-c2ccc(N(c3ccc(-c4cc(-c5ccccc5)c5ccccc5c4)cc3)c3ccc4c(c3)C3(c5ccccc5O4)c4ccccc4-c4ccccc43)cc2)cc1 ; c1ccc(-c2cc(N(c3ccccc3)c3ccc4c(c3)C3(c5ccccc5O4)c4ccccc4-c4ccccc43)cc3ccccc23)cc1]

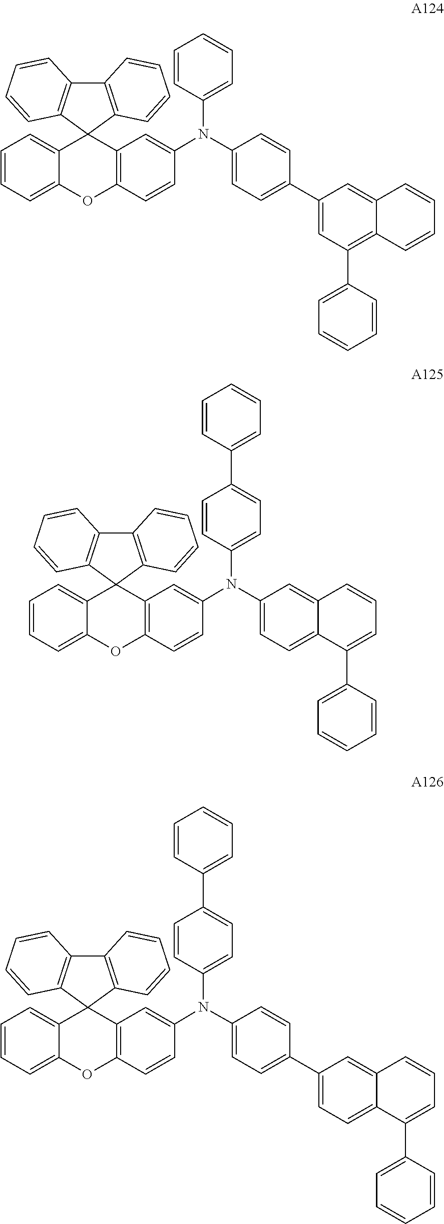 [SMILES: c1ccc(-c2cc(-c3ccc(N(c4ccccc4)c4ccc5c(c4)C4(c6ccccc6O5)c5ccccc5-c5ccccc54)cc3)cc3ccccc23)cc1 ; c1ccc(-c2ccc(N(c3ccc4c(c3)C3(c5ccccc5O4)c4ccccc4-c4ccccc43)c3ccc4c(-c5ccccc5)cccc4c3)cc2)cc1 ; c1ccc(-c2ccc(N(c3ccc(-c4ccc5c(-c6ccccc6)cccc5c4)cc3)c3ccc4c(c3)C3(c5ccccc5O4)c4ccccc4-c4ccccc43)cc2)cc1]

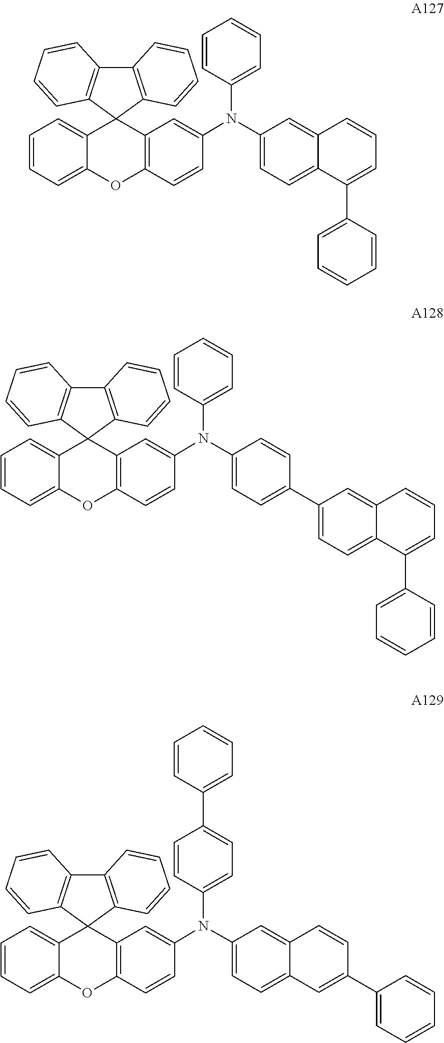 [SMILES: c1ccc(-c2cccc3cc(N(c4ccccc4)c4ccc5c(c4)C4(c6ccccc6O5)c5ccccc5-c5ccccc54)ccc23)cc1 ; c1ccc(-c2cccc3cc(-c4ccc(N(c5ccccc5)c5ccc6c(c5)C5(c7ccccc7O6)c6ccccc6-c6ccccc65)cc4)ccc23)cc1 ; c1ccc(-c2ccc(N(c3ccc4c(c3)C3(c5ccccc5O4)c4ccccc4-c4ccccc43)c3ccc4cc(-c5ccccc5)ccc4c3)cc2)cc1]

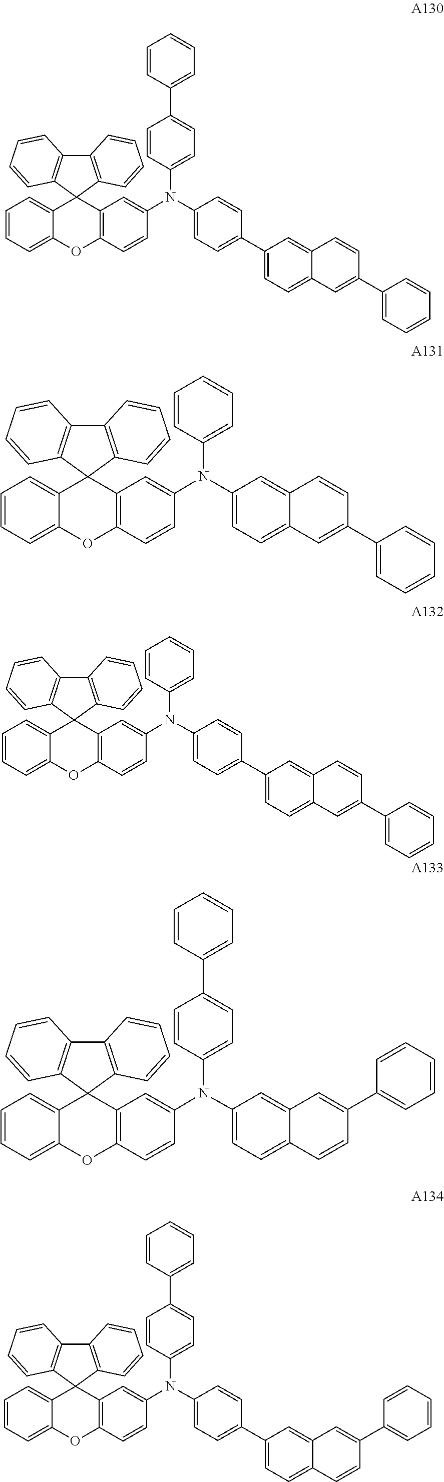 [SMILES: c1ccc(-c2ccc(N(c3ccc(-c4ccc5cc(-c6ccccc6)ccc5c4)cc3)c3ccc4c(c3)C3(c5ccccc5O4)c4ccccc4-c4ccccc43)cc2)cc1 ; c1ccc(-c2ccc3cc(N(c4ccccc4)c4ccc5c(c4)C4(c6ccccc6O5)c5ccccc5-c5ccccc54)ccc3c2)cc1 ; c1ccc(-c2ccc3cc(-c4ccc(N(c5ccccc5)c5ccc6c(c5)C5(c7ccccc7O6)c6ccccc6-c6ccccc65)cc4)ccc3c2)cc1 ; c1ccc(-c2ccc(N(c3ccc4c(c3)C3(c5ccccc5O4)c4ccccc4-c4ccccc43)c3ccc4ccc(-c5ccccc5)cc4c3)cc2)cc1 ; c1ccc(-c2ccc(N(c3ccc(-c4ccc5ccc(-c6ccccc6)cc5c4)cc3)c3ccc4c(c3)C3(c5ccccc5O4)c4ccccc4-c4ccccc43)cc2)cc1]

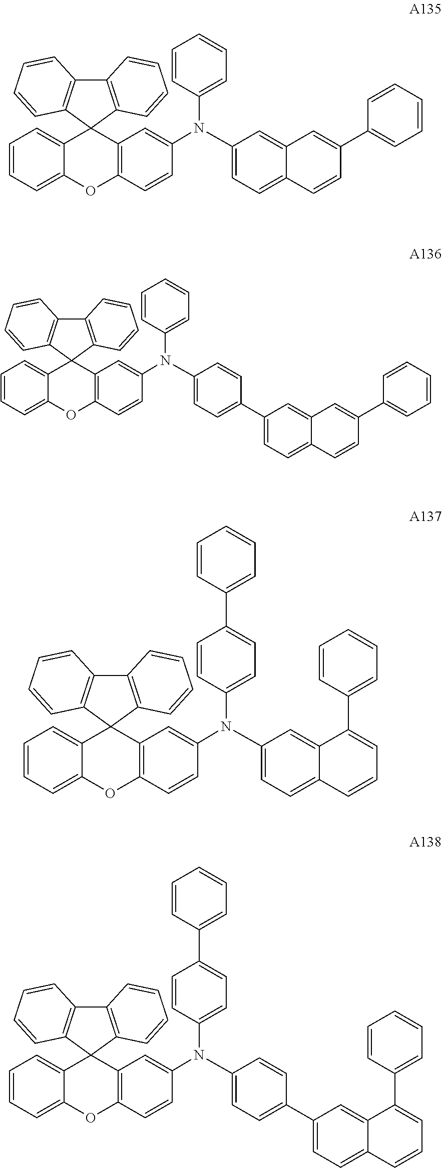 [SMILES: c1ccc(-c2ccc3ccc(N(c4ccccc4)c4ccc5c(c4)C4(c6ccccc6O5)c5ccccc5-c5ccccc54)cc3c2)cc1 ; c1ccc(-c2ccc3ccc(-c4ccc(N(c5ccccc5)c5ccc6c(c5)C5(c7ccccc7O6)c6ccccc6-c6ccccc65)cc4)cc3c2)cc1 ; c1ccc(-c2ccc(N(c3ccc4c(c3)C3(c5ccccc5O4)c4ccccc4-c4ccccc43)c3ccc4cccc(-c5ccccc5)c4c3)cc2)cc1 ; c1ccc(-c2ccc(N(c3ccc(-c4ccc5cccc(-c6ccccc6)c5c4)cc3)c3ccc4c(c3)C3(c5ccccc5O4)c4ccccc4-c4ccccc43)cc2)cc1]

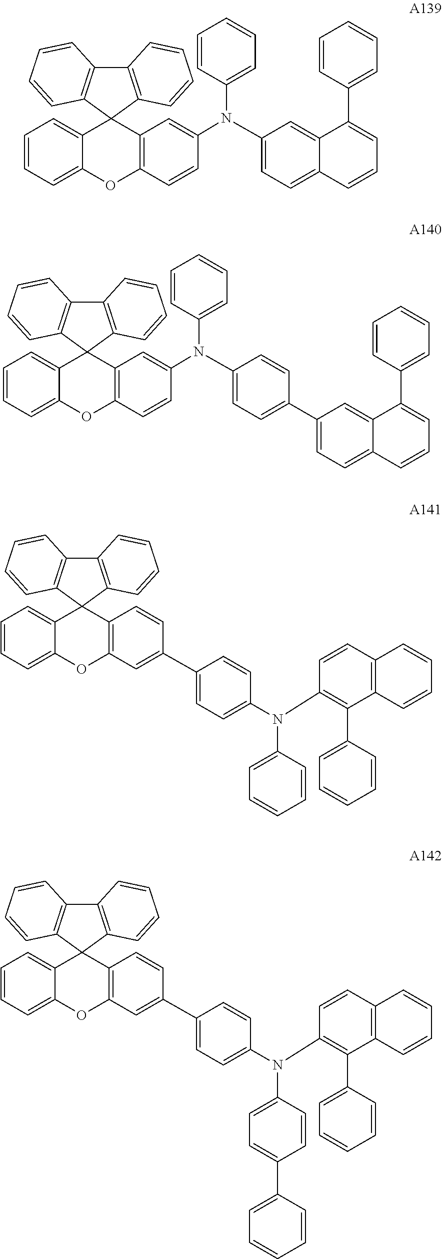 [SMILES: c1ccc(-c2cccc3ccc(N(c4ccccc4)c4ccc5c(c4)C4(c6ccccc6O5)c5ccccc5-c5ccccc54)cc23)cc1 ; c1ccc(-c2cccc3ccc(-c4ccc(N(c5ccccc5)c5ccc6c(c5)C5(c7ccccc7O6)c6ccccc6-c6ccccc65)cc4)cc23)cc1 ; c1ccc(-c2c(N(c3ccccc3)c3ccc(-c4ccc5c(c4)Oc4ccccc4C54c5ccccc5-c5ccccc54)cc3)ccc3ccccc23)cc1 ; c1ccc(-c2ccc(N(c3ccc(-c4ccc5c(c4)Oc4ccccc4C54c5ccccc5-c5ccccc54)cc3)c3ccc4ccccc4c3-c3ccccc3)cc2)cc1]

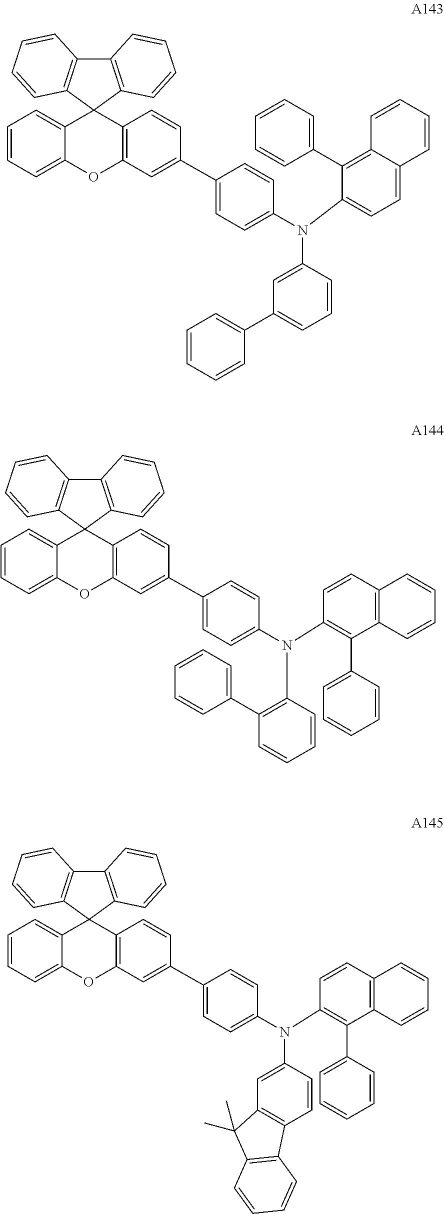 [SMILES: c1ccc(-c2cccc(N(c3ccc(-c4ccc5c(c4)Oc4ccccc4C54c5ccccc5-c5ccccc54)cc3)c3ccc4ccccc4c3-c3ccccc3)c2)cc1 ; c1ccc(-c2ccccc2N(c2ccc(-c3ccc4c(c3)Oc3ccccc3C43c4ccccc4-c4ccccc43)cc2)c2ccc3ccccc3c2-c2ccccc2)cc1 ; CC1(C)c2ccccc2-c2ccc(N(c3ccc(-c4ccc5c(c4)Oc4ccccc4C54c5ccccc5-c5ccccc54)cc3)c3ccc4ccccc4c3-c3ccccc3)cc21]

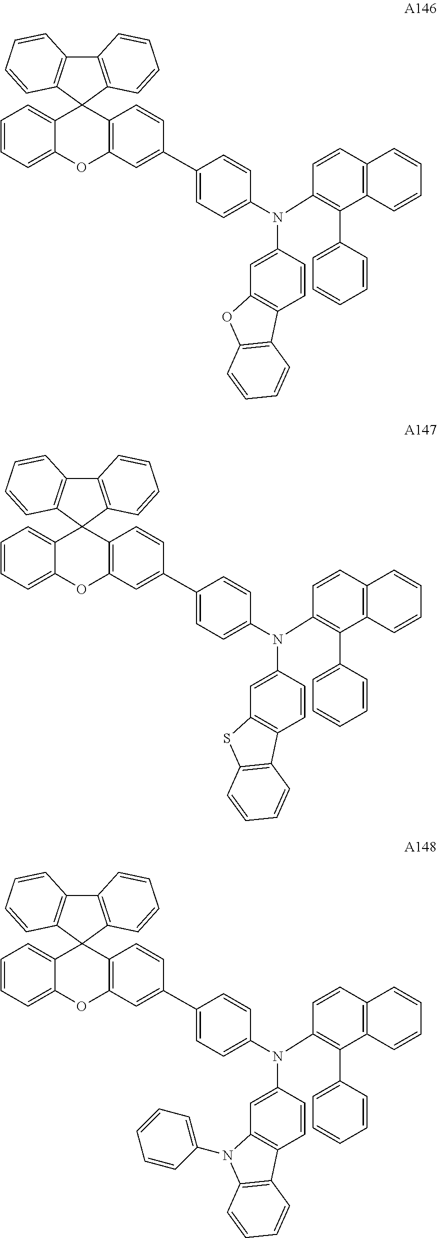 [SMILES: c1ccc(-c2c(N(c3ccc(-c4ccc5c(c4)Oc4ccccc4C54c5ccccc5-c5ccccc54)cc3)c3ccc4c(c3)oc3ccccc34)ccc3ccccc23)cc1 ; c1ccc(-c2c(N(c3ccc(-c4ccc5c(c4)Oc4ccccc4C54c5ccccc5-c5ccccc54)cc3)c3ccc4c(c3)sc3ccccc34)ccc3ccccc23)cc1 ; c1ccc(-c2c(N(c3ccc(-c4ccc5c(c4)Oc4ccccc4C54c5ccccc5-c5ccccc54)cc3)c3ccc4c5ccccc5n(-c5ccccc5)c4c3)ccc3ccccc23)cc1]

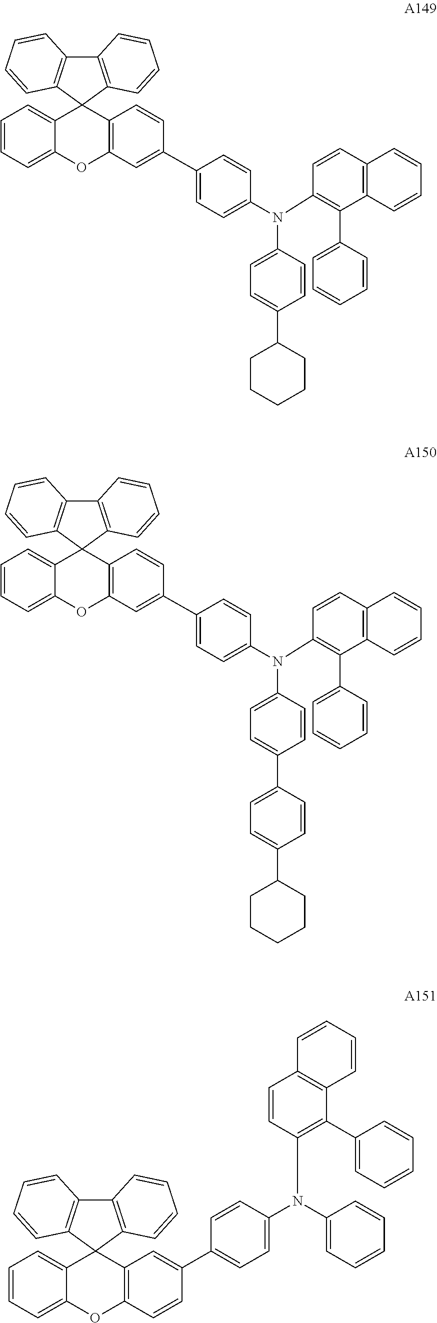 [SMILES: c1ccc(-c2c(N(c3ccc(-c4ccc5c(c4)Oc4ccccc4C54c5ccccc5-c5ccccc54)cc3)c3ccc(C4CCCCC4)cc3)ccc3ccccc23)cc1 ; c1ccc(-c2c(N(c3ccc(-c4ccc(C5CCCCC5)cc4)cc3)c3ccc(-c4ccc5c(c4)Oc4ccccc4C54c5ccccc5-c5ccccc54)cc3)ccc3ccccc23)cc1 ; c1ccc(-c2c(N(c3ccccc3)c3ccc(-c4ccc5c(c4)C4(c6ccccc6O5)c5ccccc5-c5ccccc54)cc3)ccc3ccccc23)cc1]

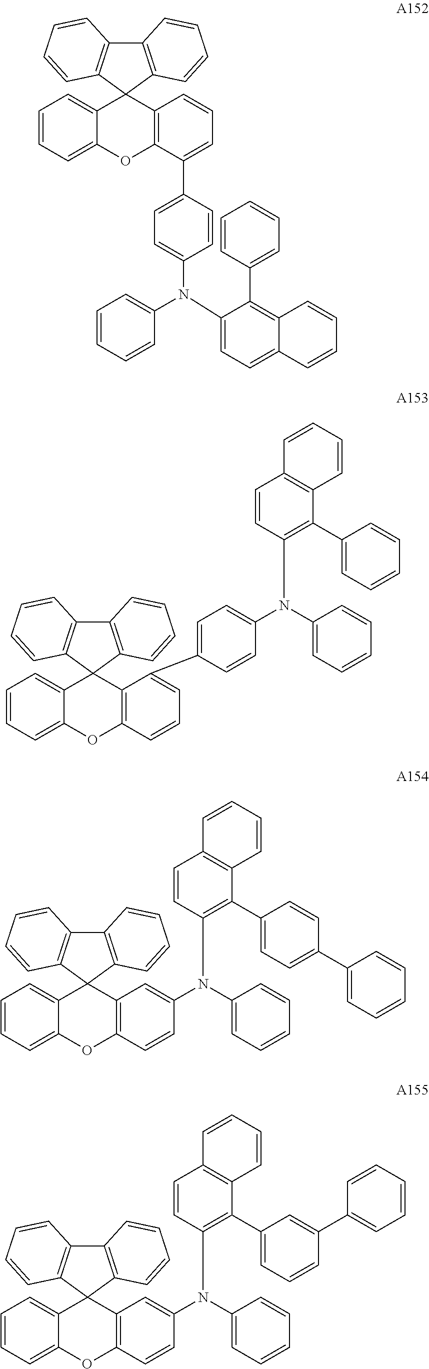 [SMILES: c1ccc(-c2c(N(c3ccccc3)c3ccc(-c4cccc5c4Oc4ccccc4C54c5ccccc5-c5ccccc54)cc3)ccc3ccccc23)cc1 ; c1ccc(-c2c(N(c3ccccc3)c3ccc(-c4cccc5c4C4(c6ccccc6O5)c5ccccc5-c5ccccc54)cc3)ccc3ccccc23)cc1 ; c1ccc(-c2ccc(-c3c(N(c4ccccc4)c4ccc5c(c4)C4(c6ccccc6O5)c5ccccc5-c5ccccc54)ccc4ccccc34)cc2)cc1 ; c1ccc(-c2cccc(-c3c(N(c4ccccc4)c4ccc5c(c4)C4(c6ccccc6O5)c5ccccc5-c5ccccc54)ccc4ccccc34)c2)cc1]

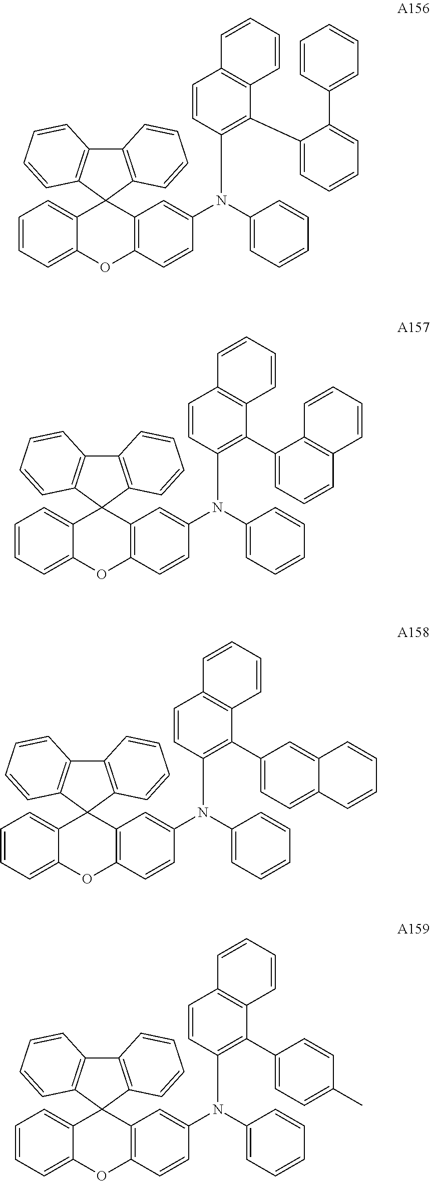 [SMILES: c1ccc(-c2ccccc2-c2c(N(c3ccccc3)c3ccc4c(c3)C3(c5ccccc5O4)c4ccccc4-c4ccccc43)ccc3ccccc23)cc1 ; c1ccc(N(c2ccc3c(c2)C2(c4ccccc4O3)c3ccccc3-c3ccccc32)c2ccc3ccccc3c2-c2cccc3ccccc23)cc1 ; c1ccc(N(c2ccc3c(c2)C2(c4ccccc4O3)c3ccccc3-c3ccccc32)c2ccc3ccccc3c2-c2ccc3ccccc3c2)cc1 ; Cc1ccc(-c2c(N(c3ccccc3)c3ccc4c(c3)C3(c5ccccc5O4)c4ccccc4-c4ccccc43)ccc3ccccc23)cc1]

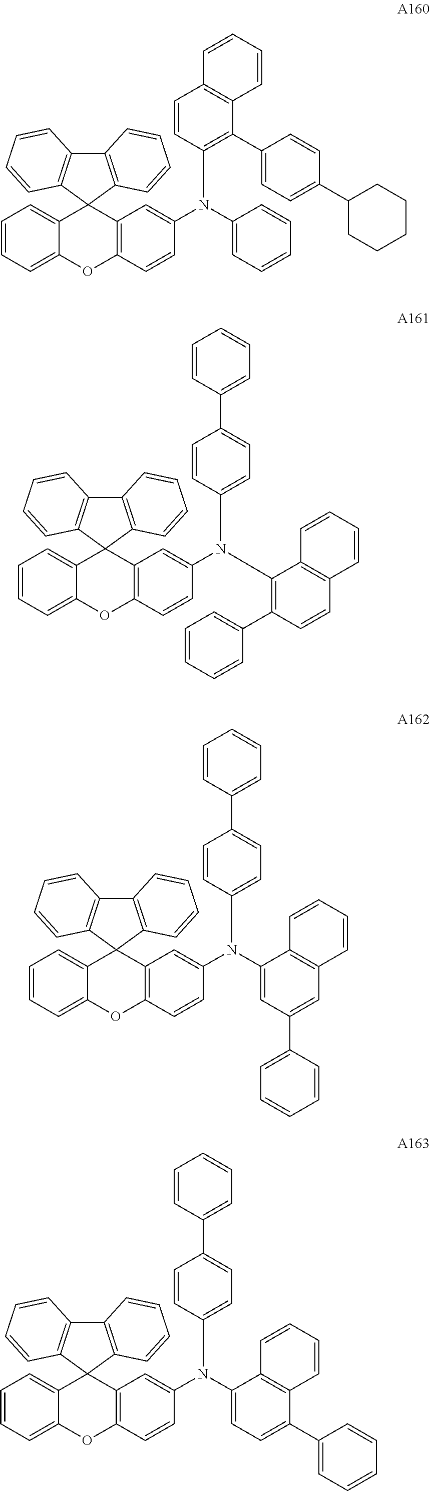 [SMILES: c1ccc(N(c2ccc3c(c2)C2(c4ccccc4O3)c3ccccc3-c3ccccc32)c2ccc3ccccc3c2-c2ccc(C3CCCCC3)cc2)cc1 ; c1ccc(-c2ccc(N(c3ccc4c(c3)C3(c5ccccc5O4)c4ccccc4-c4ccccc43)c3c(-c4ccccc4)ccc4ccccc34)cc2)cc1 ; c1ccc(-c2ccc(N(c3ccc4c(c3)C3(c5ccccc5O4)c4ccccc4-c4ccccc43)c3cc(-c4ccccc4)cc4ccccc34)cc2)cc1 ; c1ccc(-c2ccc(N(c3ccc4c(c3)C3(c5ccccc5O4)c4ccccc4-c4ccccc43)c3ccc(-c4ccccc4)c4ccccc34)cc2)cc1]

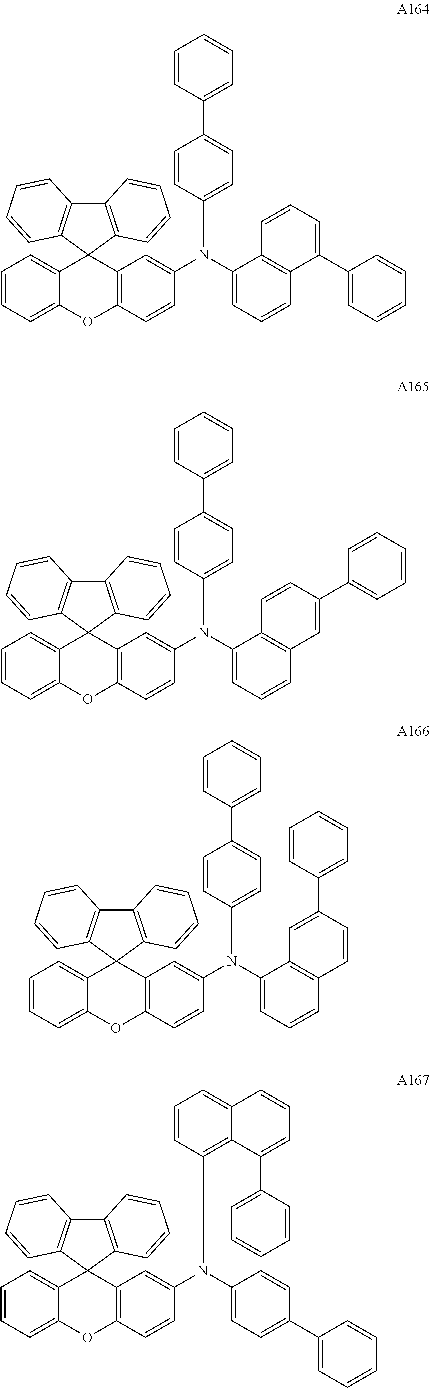 [SMILES: c1ccc(-c2ccc(N(c3ccc4c(c3)C3(c5ccccc5O4)c4ccccc4-c4ccccc43)c3cccc4c(-c5ccccc5)cccc34)cc2)cc1 ; c1ccc(-c2ccc(N(c3ccc4c(c3)C3(c5ccccc5O4)c4ccccc4-c4ccccc43)c3cccc4cc(-c5ccccc5)ccc34)cc2)cc1 ; c1ccc(-c2ccc(N(c3ccc4c(c3)C3(c5ccccc5O4)c4ccccc4-c4ccccc43)c3cccc4ccc(-c5ccccc5)cc34)cc2)cc1 ; c1ccc(-c2ccc(N(c3ccc4c(c3)C3(c5ccccc5O4)c4ccccc4-c4ccccc43)c3cccc4cccc(-c5ccccc5)c34)cc2)cc1]

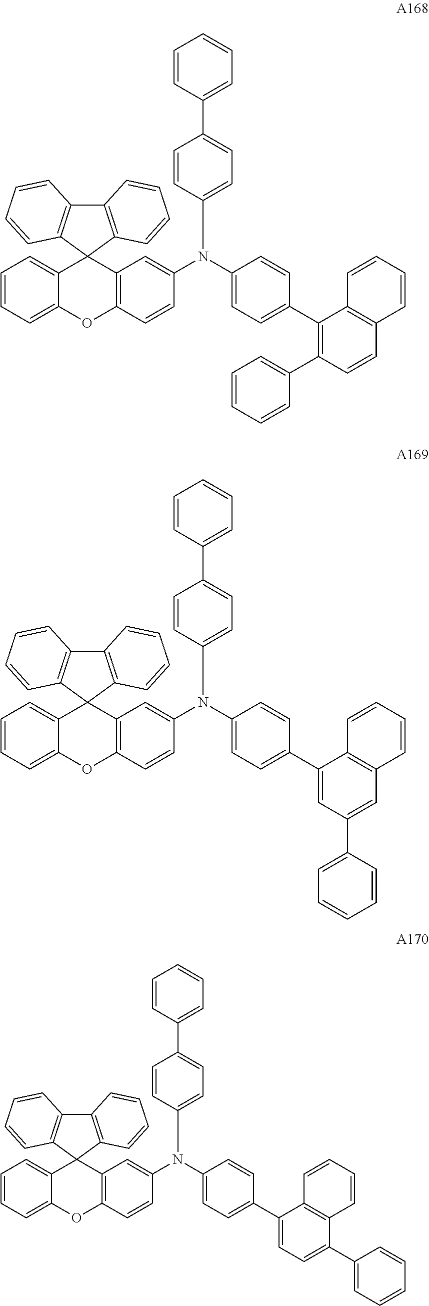 [SMILES: c1ccc(-c2ccc(N(c3ccc(-c4c(-c5ccccc5)ccc5ccccc45)cc3)c3ccc4c(c3)C3(c5ccccc5O4)c4ccccc4-c4ccccc43)cc2)cc1 ; c1ccc(-c2ccc(N(c3ccc(-c4cc(-c5ccccc5)cc5ccccc45)cc3)c3ccc4c(c3)C3(c5ccccc5O4)c4ccccc4-c4ccccc43)cc2)cc1 ; c1ccc(-c2ccc(N(c3ccc(-c4ccc(-c5ccccc5)c5ccccc45)cc3)c3ccc4c(c3)C3(c5ccccc5O4)c4ccccc4-c4ccccc43)cc2)cc1]

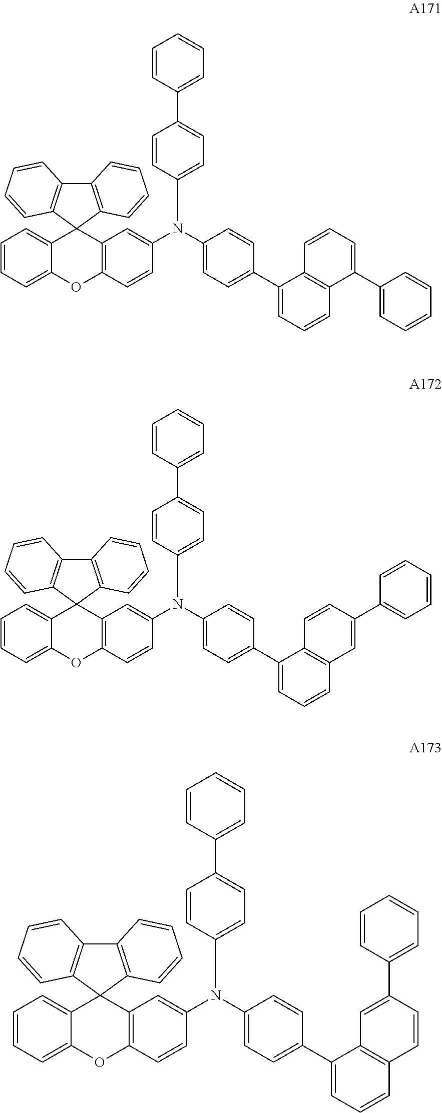 [SMILES: c1ccc(-c2ccc(N(c3ccc(-c4cccc5c(-c6ccccc6)cccc45)cc3)c3ccc4c(c3)C3(c5ccccc5O4)c4ccccc4-c4ccccc43)cc2)cc1 ; c1ccc(-c2ccc(N(c3ccc(-c4cccc5cc(-c6ccccc6)ccc45)cc3)c3ccc4c(c3)C3(c5ccccc5O4)c4ccccc4-c4ccccc43)cc2)cc1 ; c1ccc(-c2ccc(N(c3ccc(-c4cccc5ccc(-c6ccccc6)cc45)cc3)c3ccc4c(c3)C3(c5ccccc5O4)c4ccccc4-c4ccccc43)cc2)cc1]

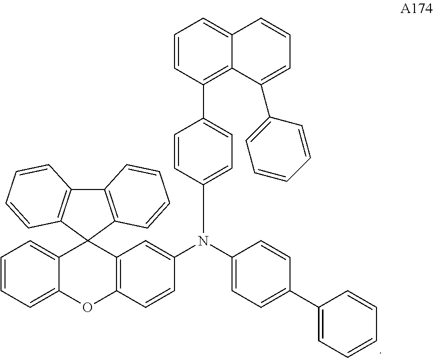 [SMILES: c1ccc(-c2ccc(N(c3ccc(-c4cccc5cccc(-c6ccccc6)c45)cc3)c3ccc4c(c3)C3(c5ccccc5O4)c4ccccc4-c4ccccc43)cc2)cc1]

The second compound may be represented by Formula 2:

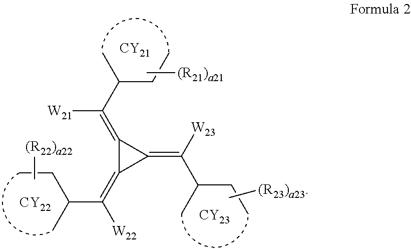

where, in Formula 2,
CY₂₁ to CY₂₃ may each independently be a C₅-C₆₀ carbocyclic group or a C₃-C₆₀ heterocyclic group,
W₂₁ to W₂₃ may each independently be:
—F, —Cl, —Br, —I, a hydroxyl group, a cyano group, or a nitro group;
a C₁-C₆₀ alkyl group substituted with —F, —Cl, —Br, —I, a hydroxyl group, a cyano group, a nitro group, or any combinations thereof;
a C₅-C₆₀ carbocyclic group substituted with —F, —Cl, —Br, —I, a hydroxyl group, a cyano group, a nitro group, or any combinations thereof; or
a C₃-C₆₀ heterocyclic group substituted with —F, —Cl, —Br, —I, a hydroxyl group, a cyano group, a nitro group, or any combinations thereof,
R₂₁ to R₂₃ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₅-C₆₀ carbocyclic group unsubstituted or substituted with at least one R₁₀ₐ, a C₃-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a21 to a23 may each independently be an integer selecting from 0 to 20,
R₁₀ₐ may be the same as R₁₀ₐ described in the specification, and
Q₁ to Q₃ may each be the same as described in connection with Q₁ to Q₃, Q₁₁ to Q₁₃, Q₂₁ to Q₂₃, and Q₃₁ to Q₃₃.

In an embodiment, CY₂₁ to CY₂₃ may each independently be a C₆-C₆₀ aryl group or a C₃-C₆₀ heteroaryl group.

In an embodiment, CY₂₁ to CY₂₃ may each independently be a 6-membered ring.

CY₂₁ to CY₂₃ may each independently be a benzene group, a pyridine group, a pyrimidine group, a triazine group, a pyridazine group, or a pyrazine group.

In an embodiment, at least one of R₂₁(s) in the number of a21 may be:
—F, —Cl, —Br, —I, a hydroxyl group, a cyano group, or a nitro group;
a C₁-C₆₀ alkyl group substituted with —F, —Cl, —Br, —I, a hydroxyl group, a cyano group, a nitro group, or any combinations thereof;
a C₅-C₆₀ carbocyclic group substituted with —F, —Cl, —Br, —I, a hydroxyl group, a cyano group, a nitro group, or any combinations thereof; or
a C₃-C₆₀ heterocyclic group substituted with —F, —Cl, —Br, —I, a hydroxyl group, a cyano group, a nitro group, or any combinations thereof.

In an embodiment, at least one of R₂₂ (s) in the number of a22 may be:
—F, —Cl, —Br, —I, a hydroxyl group, a cyano group, or a nitro group;
a C₁-C₆₀ alkyl group substituted with —F, —Cl, —Br, —I, a hydroxyl group, a cyano group, a nitro group, or any combinations thereof;
a C₅-C₆₀ carbocyclic group substituted with —F, —Cl, —Br, —I, a hydroxyl group, a cyano group, a nitro group, or any combinations thereof; or
a C₃-C₆₀ heterocyclic group substituted with —F, —Cl, —Br, —I, a hydroxyl group, a cyano group, a nitro group, or any combinations thereof.

In an embodiment, at least one of R₂₃(s) in the number of a23 may be:
—F, —Cl, —Br, —I, a hydroxyl group, a cyano group, or a nitro group;
a C₁-C₆₀ alkyl group substituted with —F, —Cl, —Br, —I, a hydroxyl group, a cyano group, a nitro group, or any combinations thereof;
a C₅-C₆₀ carbocyclic group substituted with —F, —Cl, —Br, —I, a hydroxyl group, a cyano group, a nitro group, or any combinations thereof; or
a C₃-C₆₀ heterocyclic group substituted with —F, —Cl, —Br, —I, a hydroxyl group, a cyano group, a nitro group, or any combinations thereof.

In an embodiment, in Formula 2, a group represented by

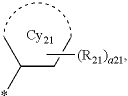

a group represented by

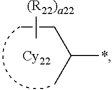

and a group represented by

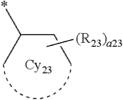

may each independently be a group represented by one of Formulae W₁ to W₁₈ (where * indicates a binding site to a neighboring atom):

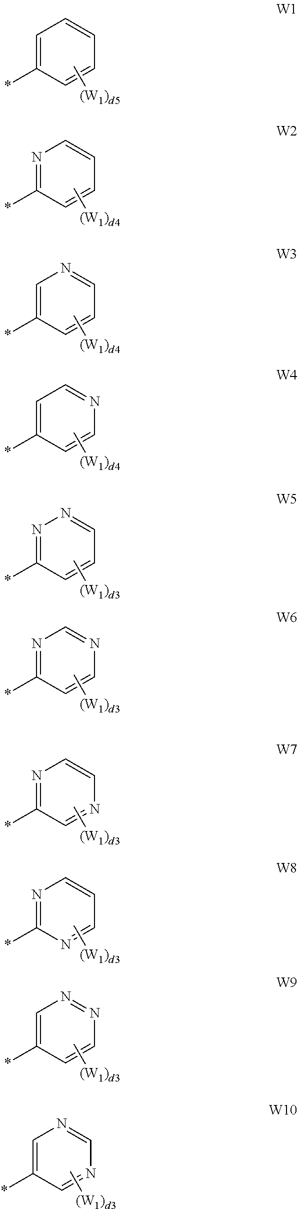

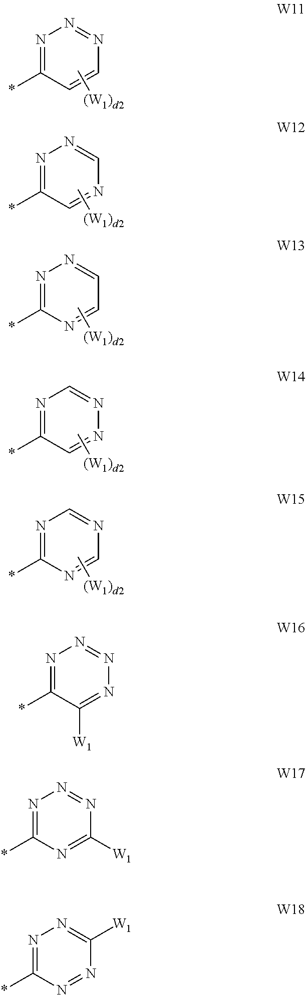

where, in Formulae W₁ to W₁₈,
W₁ may be:
—F, —Cl, —Br, —I, a hydroxyl group, a cyano group, or a nitro group;
a C₁-C₆₀ alkyl group substituted with —F, —Cl, —Br, —I, a hydroxyl group, a cyano group, a nitro group, or any combinations thereof;
a C₅-C₆₀ carbocyclic group substituted with —F, —Cl, —Br, —I, a hydroxyl group, a cyano group, a nitro group, or any combinations thereof; or
a C₃-C₆₀ heterocyclic group substituted with —F, —Cl, —Br, —I, a hydroxyl group, a cyano group, a nitro group, or any combinations thereof,
d2 may be an integer selecting from 0 to 2,
d3 may be an integer selecting from 0 to 3,
d4 may be an integer selecting from 0 to 4, and
d5 may be an integer selecting from 0 to 5.

In an embodiment, the second compound may be one of Compounds B1 to B3:

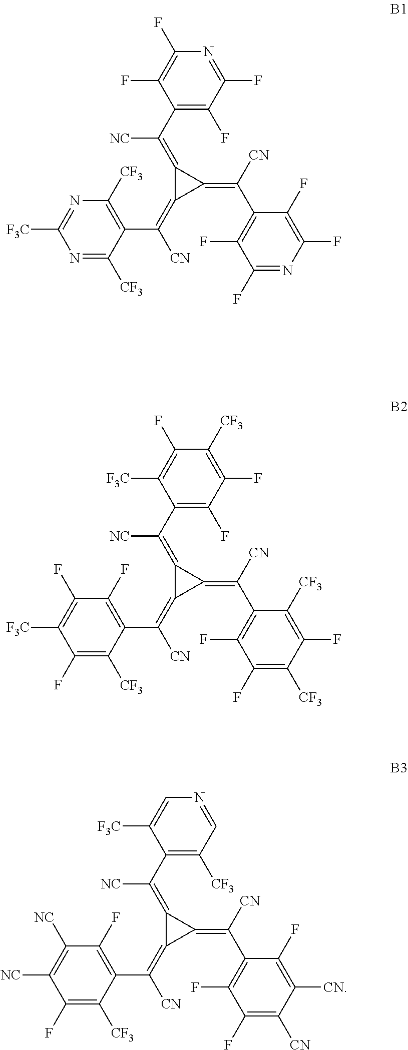 [SMILES: N#C/C(=C1\C(=C(\C#N)c2c(F)c(F)nc(F)c2F)\C1=C(\C#N)c1c(F)c(F)nc(F)c1F)c1c(C(F)(F)F)nc(C(F)(F)F)nc1C(F)(F)F ; N#CC(=C1C(=C(C#N)c2c(F)c(F)c(C(F)(F)F)c(F)c2C(F)(F)F)C1=C(C#N)c1c(F)c(F)c(C(F)(F)F)c(F)c1C(F)(F)F)c1c(F)c(F)c(C(F)(F)F)c(F)c1C(F)(F)F ; N#C/C(=C1/C(=C(\C#N)c2c(C(F)(F)F)cncc2C(F)(F)F)/C1=C(\C#N)c1c(F)c(F)c(C#N)c(C#N)c1F)c1c(F)c(C#N)c(C#N)c(F)c1C(F)(F)F]

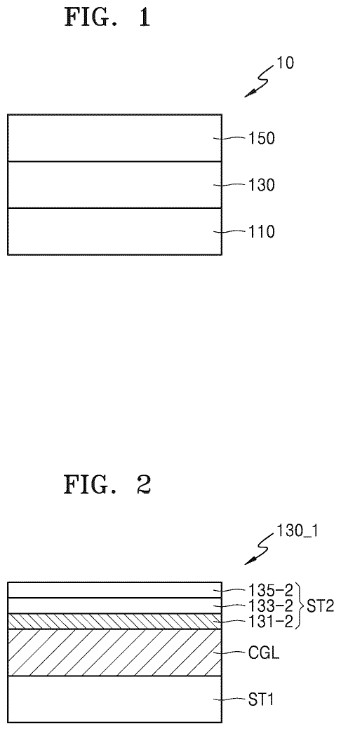

FIG. 1 is a schematic view of an embodiment of a light-emitting device 10.

Referring to FIG. 1, a light-emitting device 10 includes: a first electrode 110; a second electrode 150 facing the first electrode 110; and an interlayer 130 arranged between the first electrode 110 and the second electrode 150. The term “interlayer” as used herein refers to a single layer and/or a plurality of layers arranged between the first electrode and the second electrode of the light-emitting device.

The interlayer 130 may include the hole transport region, the emission layer, and the electron transport region that are sequentially stacked from the first electrode 110. That is, the hole transport region may be arranged between the first electrode 110 and the emission layer, and the electron transport region may be arranged between the emission layer and the second electrode 150. The hole transport region, the emission layer, and the electron transport region may be collectively referred to as a stack. When a plurality of stacks are provided, the light-emitting device 10 may be a tandem light-emitting device. A plurality of stacks may be also referred to as a first stack, a second stack, or the like, and the light-emitting device 10 may further include charge generation layers (CGL in FIG. 2) arranged between the plurality of stacks. The charge generation layer may include an n-type charge generation layer and a p-type charge generation layer that are sequentially arranged from the first electrode 110. The tandem light-emitting device is described with reference to FIG. 2. A thickness each of the n-type charge generation layer and the p-type charge generation layer may be in a range of about 50 angstroms (Å) to about 10,000 Å, e.g., about 100 Å to about 2,000 Å.

In FIG. 1, a substrate may be additionally arranged under the first electrode 110 or on the second electrode 150. For use as the substrate, a glass substrate or a plastic substrate may be used. The substrate may be a flexible substrate. In an embodiment, the substrate may include plastics with excellent heat resistance and durability, such as polyimide, polyethylene terephthalate (“PET”), polycarbonate, polyethylene naphthalate, polyarylate (“PAR”), polyetherimide, or any combinations thereof, for example.

The first electrode 110 may be formed by providing a material for forming the first electrode 110 on the substrate by a deposition method or a sputtering method. When the first electrode 110 is an anode, a material for forming the first electrode 110 may be a high-work function material that facilitates injection of holes.

The first electrode 110 may be a reflective electrode, a semi-transmissive electrode, or a transmissive electrode. In an embodiment, when the first electrode 110 is a transmissive electrode, a material for forming the first electrode 110 may include indium tin oxide (“ITO”), indium zinc oxide (“IZO”), tin oxide (SnO₂), zinc oxide (ZnO), or any combinations thereof. In an embodiment, when the first electrode 110 is a semi-transmissive electrode or a reflective electrode, a material for forming the first electrode 110 may include magnesium (Mg), silver (Ag), aluminum (Al), aluminum-lithium (Al—Li ), calcium (Ca), magnesium-indium (Mg—In), magnesium-silver (Mg—Ag), or any combinations thereof.

The first electrode 110 may have a single-layer structure consisting of a single layer or a multi-layer structure including multiple layers. In an embodiment, the first electrode 110 may have a three-layer structure of ITO/Ag/ITO, for example.

The hole transport region may have i) a single-layer structure consisting of a single layer consisting of a single material, ii) a single-layer structure consisting of a single layer consisting of multiple materials that are different from each other, or iii) a multi-layer structure including multiple layers including multiple materials that are different from each other.

The hole transport region may include a hole injection layer, a hole transport layer, an emission auxiliary layer, an electron blocking layer, or any combinations thereof.

In an embodiment, the hole transport region may have a multi-layer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, where layers in each structure are sequentially stacked from the first electrode 110, for example.

The hole transport region may include a compound represented by Formula 201, a compound represented by Formula 202, or any combinations thereof:

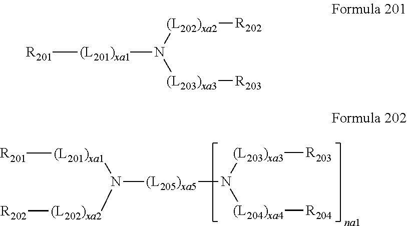

where, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—**, *—S—**, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer selecting from 0 to 5,
xa5 may be an integer selecting from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (e.g., a carbazole group, etc.) unsubstituted or substituted with at least one R₁₀ₐ (e.g., Compound HT16, etc.),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer selecting from 1 to 4.

In an embodiment, each of Formulae 201 and 202 may include at least one of groups represented by Formulae CY201 to CY217, for example:

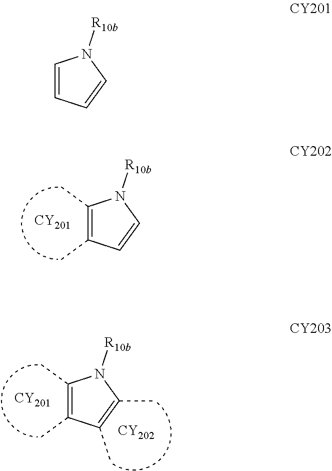

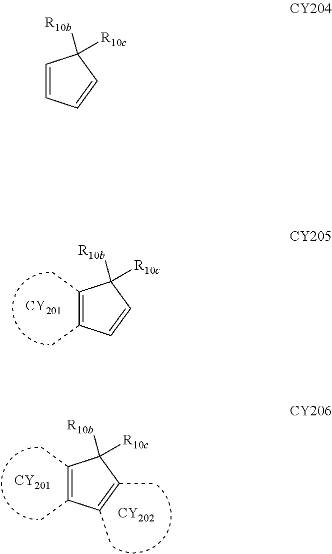

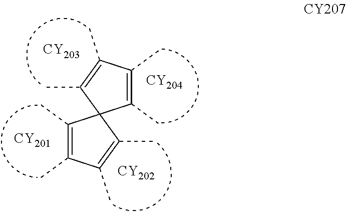

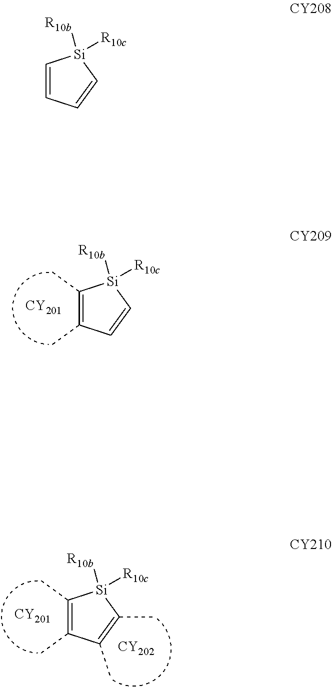

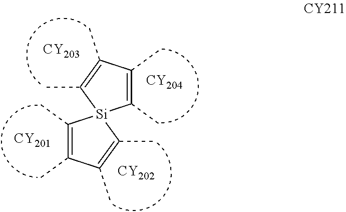

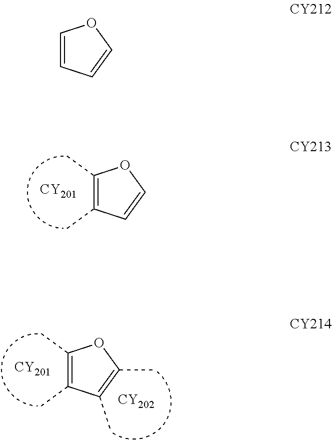

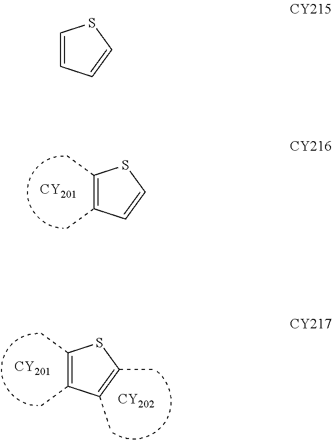

where, in Formulae CY201 to CY217, R_{10b} and R_{10c} may each be the same as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY₂₀₁ to CY₂₁₇ may be unsubstituted or substituted with R₁₀ₐ.

In an embodiment, ring CY₂₀₁ to ring CY₂₀₄ in Formulae CY201 to CY217 may each independently be a benzene group, a naphthalene group, a phenanthrene group, or an anthracene group.

In an embodiment, each of Formulae 201 and 202 may include at least one of groups represented by Formulae CY201 to CY203.

In an embodiment, Formula 201 may include at least one of the groups represented by Formulae CY201 to CY203 and at least one of groups represented by Formulae CY204 to CY217.

In an embodiment, in Formula 201, xa1 may be 1, R₂₀₁ may be a group represented by one of Formulae CY201 to CY203, xa2 may be 0, and R₂₀₂ may be a group represented by one of Formulae CY204 to CY207.

In an embodiment, each of Formulae 201 and 202 may not include groups represented by Formulae CY201 to CY203.

In an embodiment, each of Formulae 201 and 202 may not include groups represented by Formulae CY201 to CY203, and may include at least one of groups represented by Formulae CY204 to CY217.

In an embodiment, each of Formulae 201 and 202 may not include groups represented by Formulae CY201 to CY217.

In an embodiment, the hole transport region may include one of Compounds HT1 to HT46, m-MTDATA, TDATA, 2-TNATA, NPB(or NPD), β-NPB, TPD, spiro-TPD, spiro-NPB, methylated NPB, TAPC, HMTPD, 4,4′,4″-tris(N-carbazolyl)triphenylamine (“TCTA”), polyaniline/dodecylbenzene sulfonic acid (“PANI/DBSA”), poly(3,4-ethylene dioxythiophene)/poly(4-styrene sulfonate)(“PEDOT/PSS”), polyaniline/camphor sulfonic acid (“PANI/CSA”), polyaniline/poly(4-styrene sulfonate)(“PANI/PSS”), or any combinations thereof:

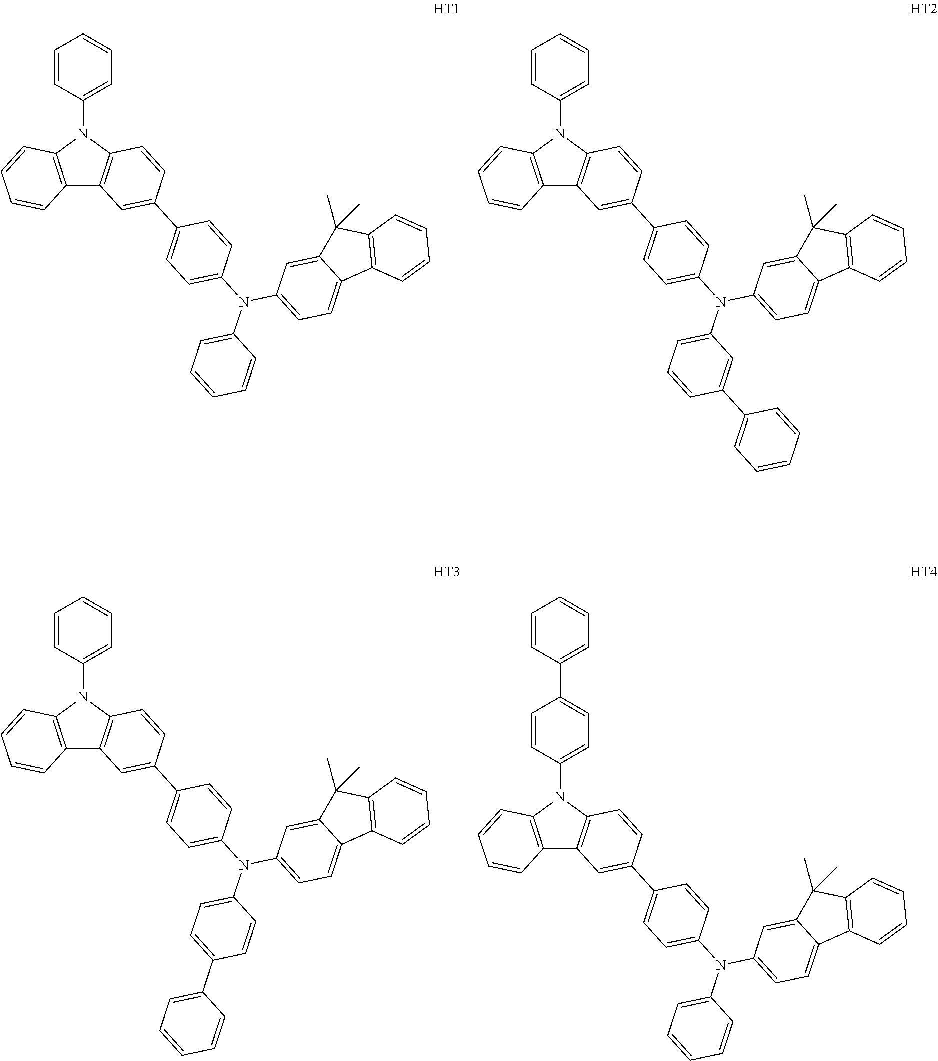 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

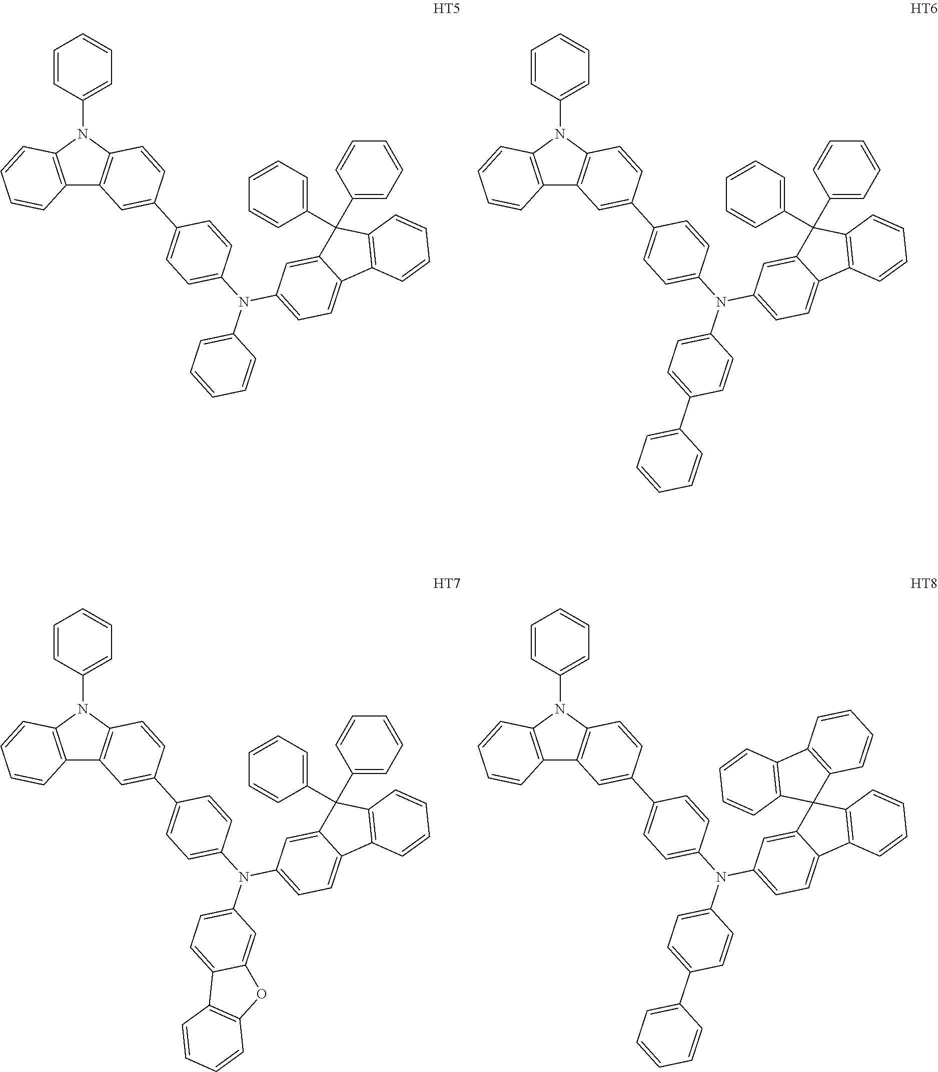 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

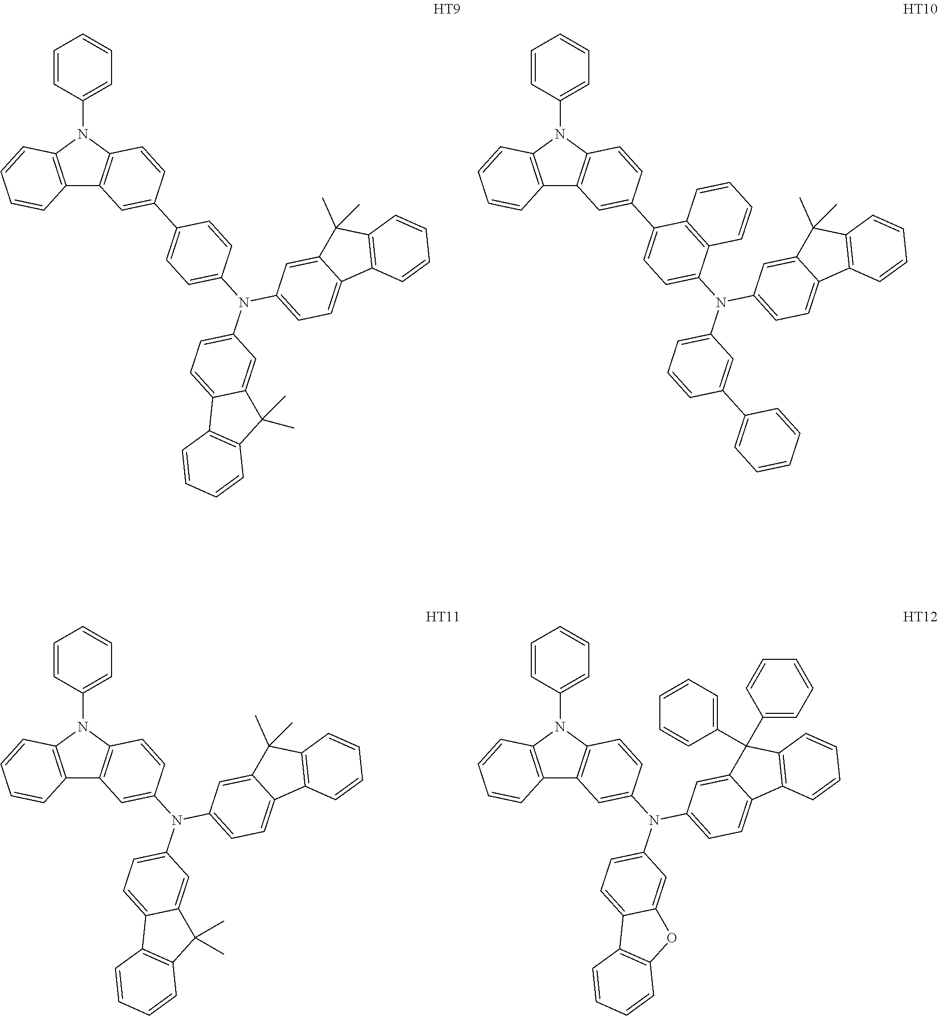 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

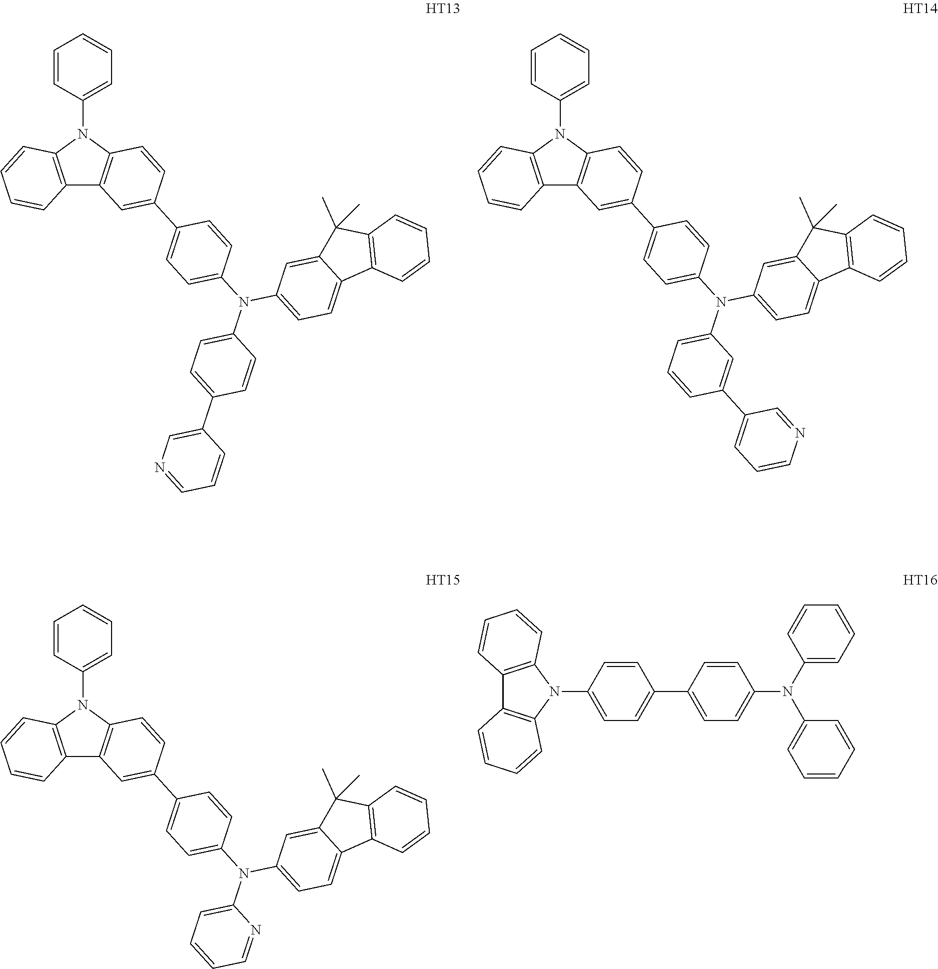 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1]

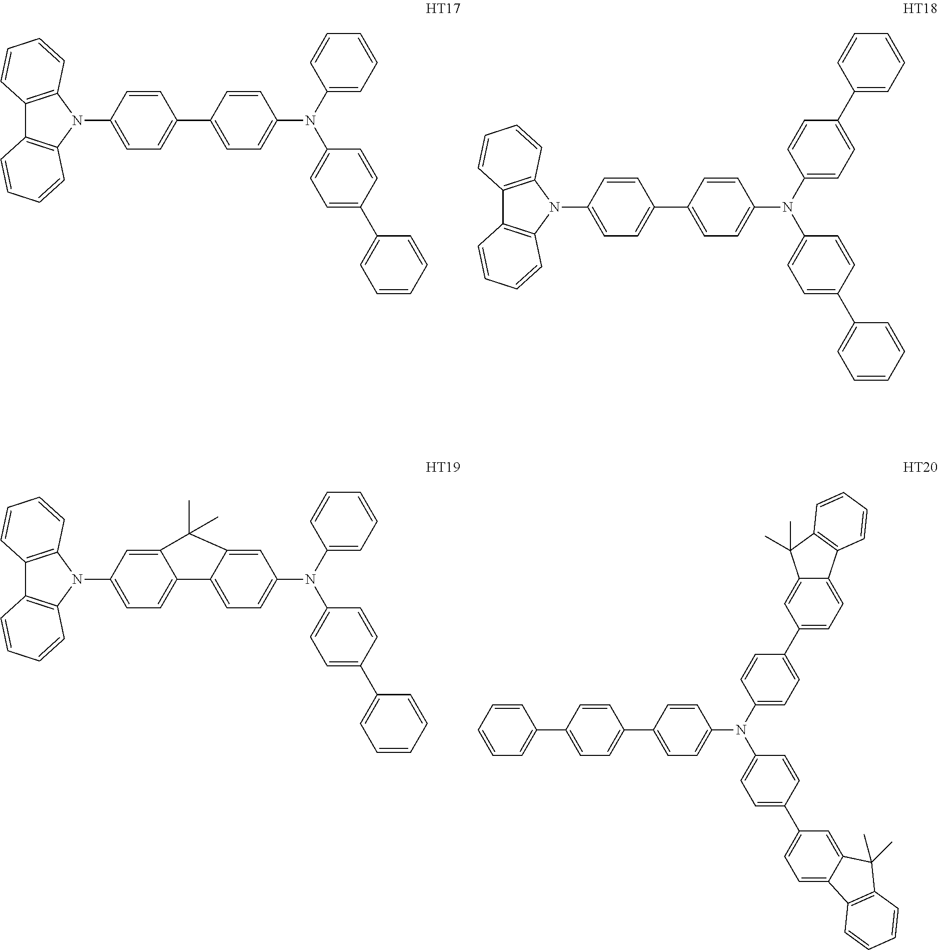 [SMILES: c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21]

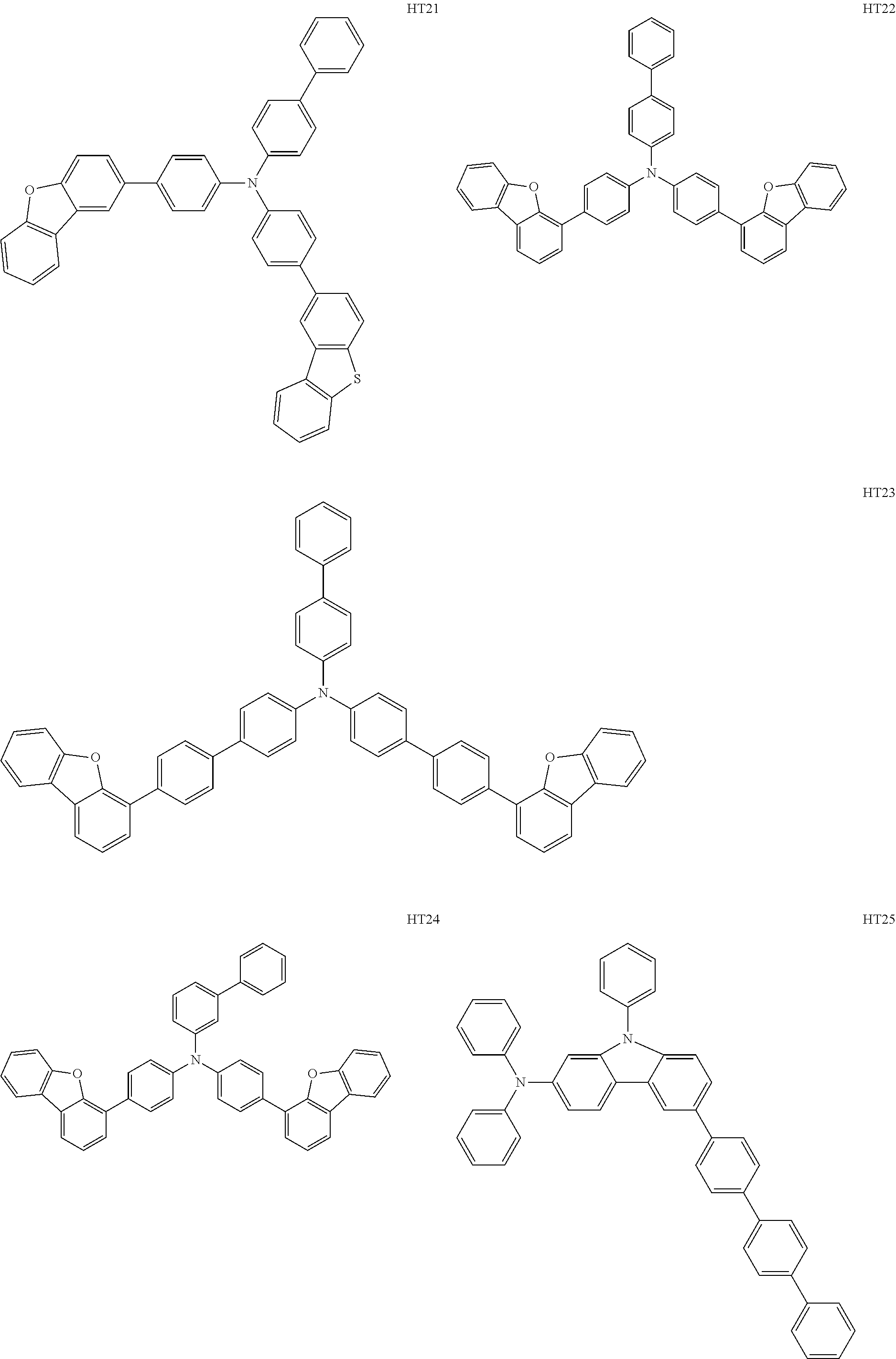 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1]

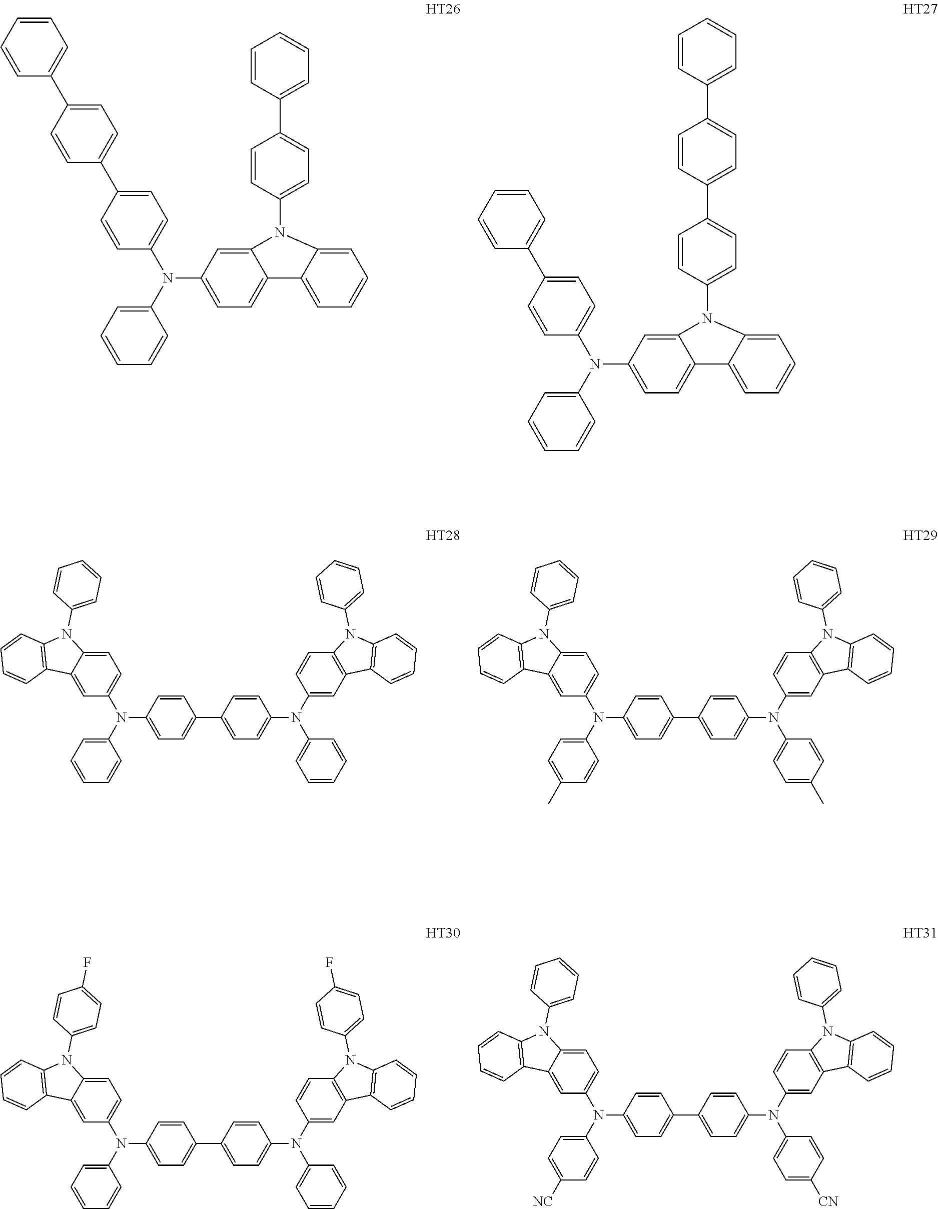

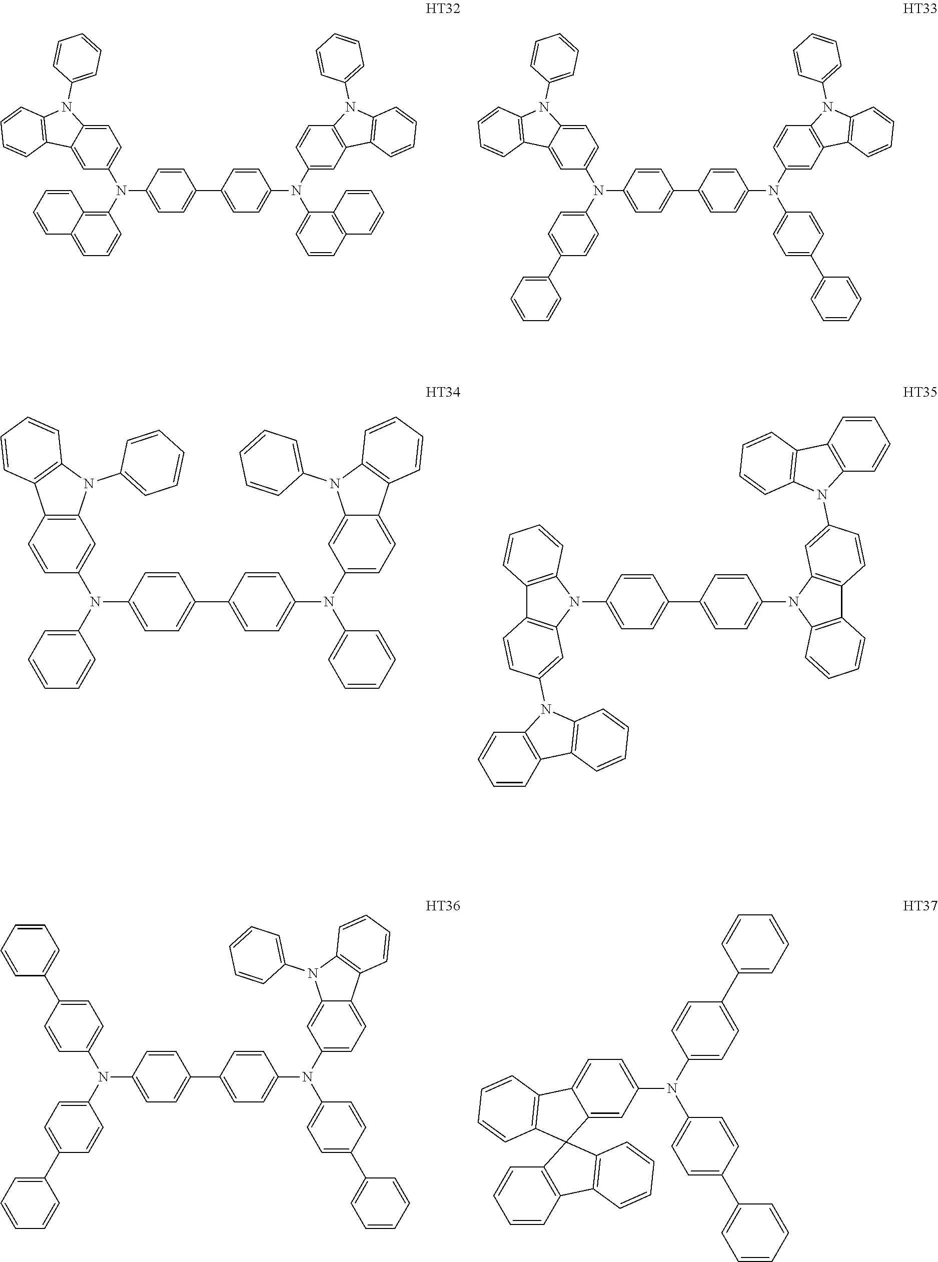

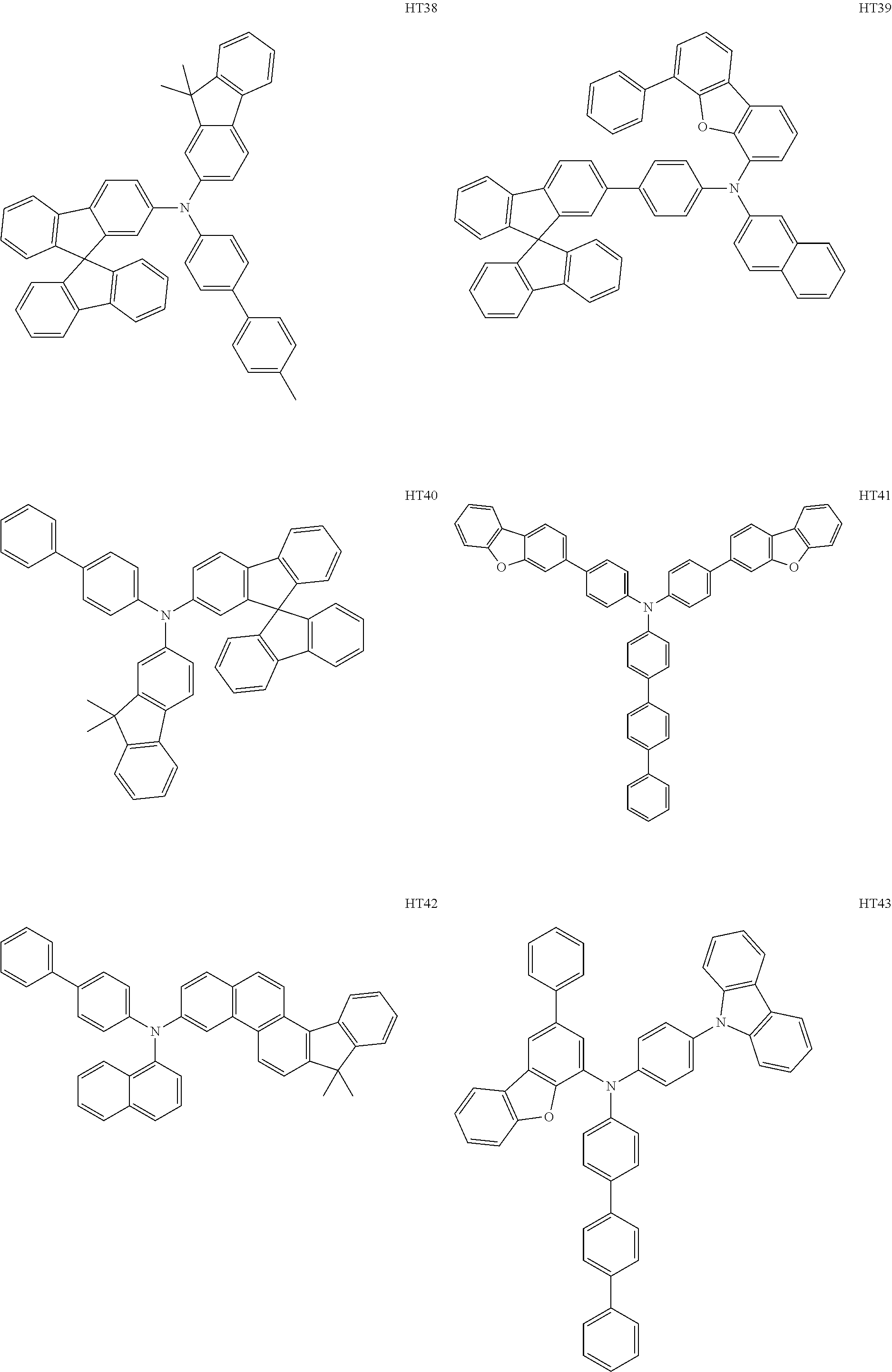

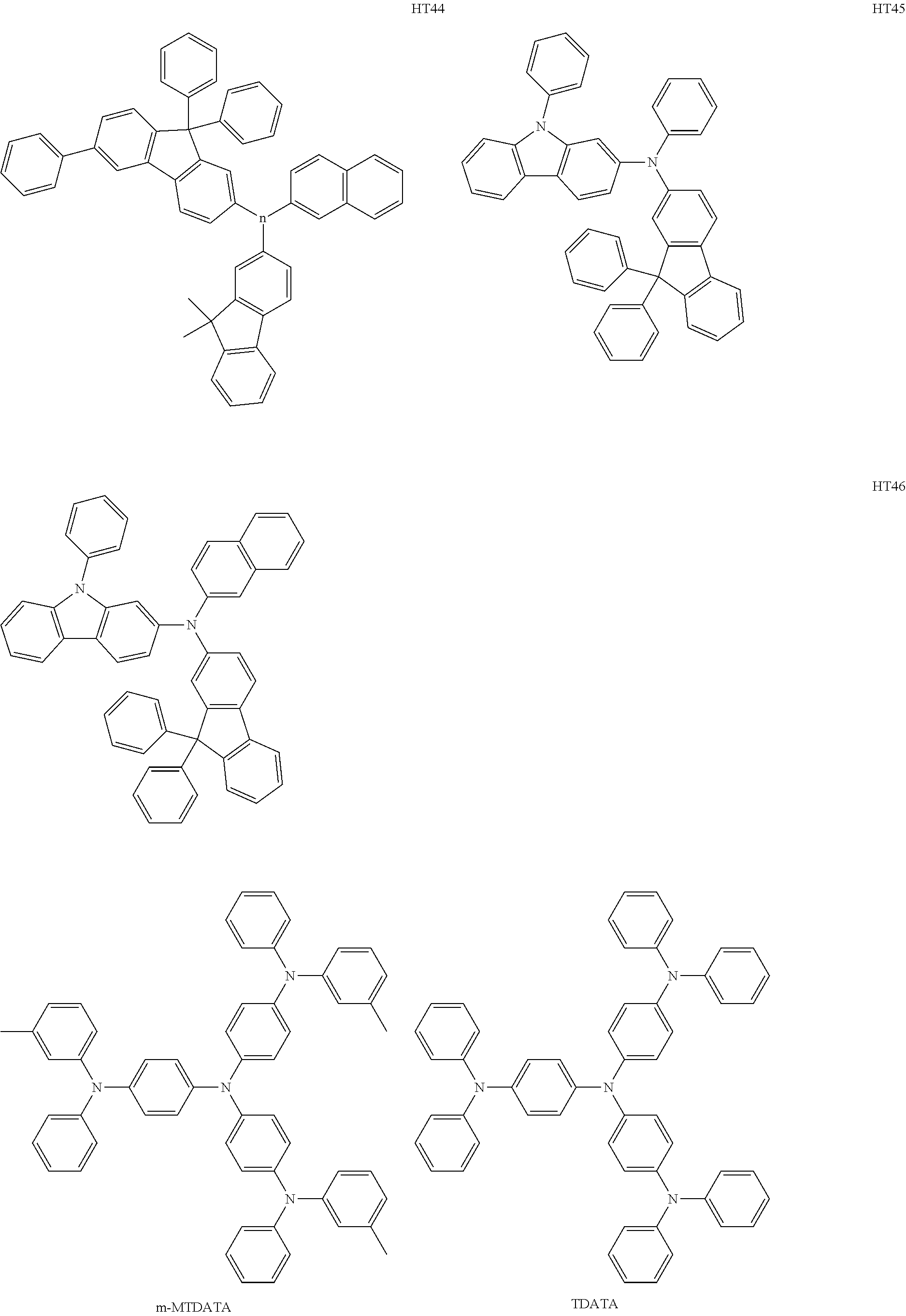

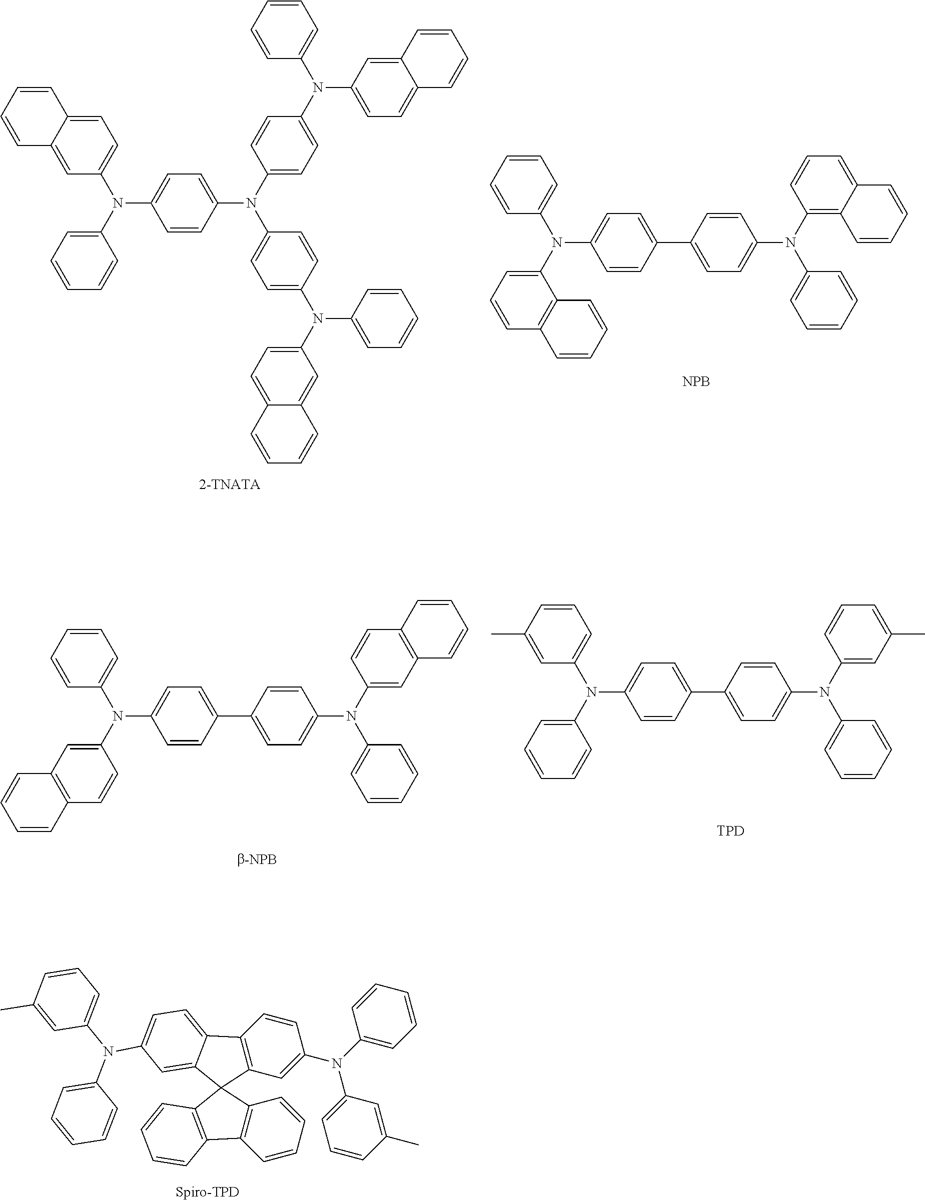

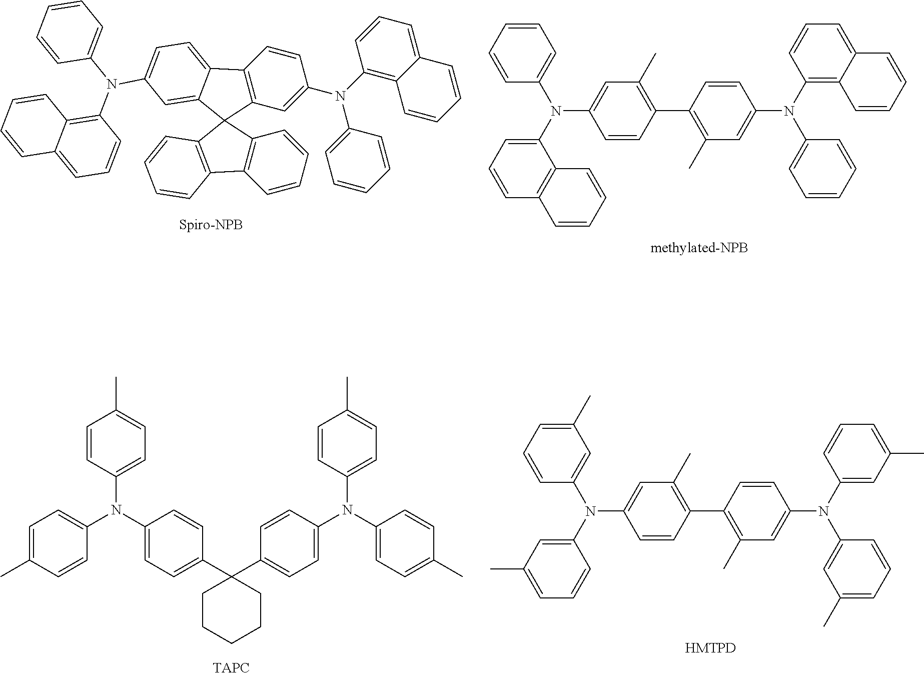

A thickness of the hole transport region may be in a range of about 50 angstroms (Å) to about 10,000 Å, e.g., about 100 Å to about 4,000 Å. When the hole transport region includes a hole injection layer, a hole transport layer, or any combinations thereof, a thickness of the hole injection layer may be in a range of about 100 Å to about 9,000 Å, e.g., about 100 Å to about 1,000 Å, and a thickness of the hole transport layer may be in a range of about 50 Å to about 2,000 Å, e.g., about 100 Å to about 1,500 Å. When the thicknesses of the hole transport region, the hole injection layer, and the hole transport layer are within these ranges, satisfactory hole transporting characteristics may be obtained without a substantial increase in driving voltage.

The emission auxiliary layer is a layer that increases light emission efficiency by compensating for an optical resonance distance according to a wavelength of light emitted from the emission layer of the interlayer 130. The electron blocking layer may be a layer that prevents electron leakage from the emission layer of the interlayer 130 to the hole transport region. Materials that may be included in the hole transport region may be included in the emission auxiliary layer and the electron blocking layer.

The hole transport region may further include, in addition to the aforementioned materials, a charge-generation material for the improvement of conductive properties. The charge-generation material may be uniformly or non-uniformly dispersed in the hole transport region (e.g., in the form of a single layer including or consisting of the charge-generation material).

The charge generation material may be a p-dopant, for example.

In an embodiment, the p-dopant may have a lowest unoccupied molecular orbital (“LUMO”) energy level of about −3.5 electron-volts (eV) or less, for example.

In an embodiment, the p-dopant may include a quinone derivative, a cyano group-containing compound, a compound including element EL1 and element EL2, or any combinations thereof.

In an embodiment, the quinone derivative may include TCNQ, F4-TCNQ, or the like.

In an embodiment, the cyano group-containing compound may include HAT-CN and a compound represented by Formula 221:

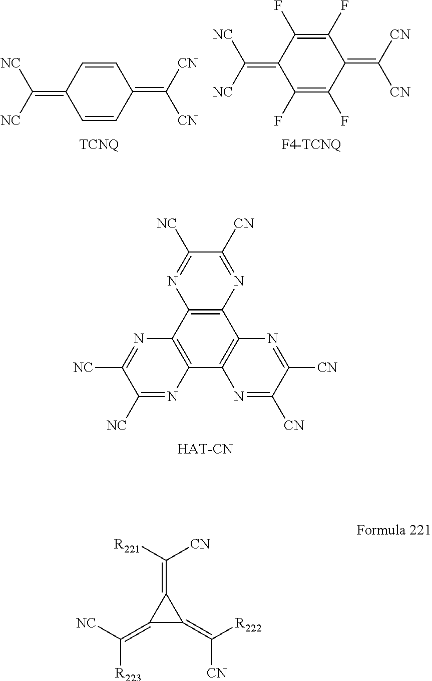

where, in Formula 221,
R₂₂₁ to R²²³ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combinations thereof; or any combinations thereof.

In the compound including the element EL1 and the element EL2, the element EL1 may be a metal, a metalloid, or any combinations thereof, and the element EL2 may be a non-metal, a metalloid, or any combinations thereof.

In an embodiment, the metal may include: alkali metal (e.g., lithium (Li), sodium (Na), potassium (K), rubidium (Rb), cesium (Cs), etc.); alkaline earth metal (e.g., beryllium (Be), magnesium (Mg), calcium (Ca), strontium (Sr), barium (Ba), etc.); transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); post-transition metal (e.g., zinc (Zn), indium (In), tin (Sn), etc.); lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.); or the like.

In an embodiment, the metalloid may include silicon (Si), antimony (Sb), tellurium (Te), or the like.

In an embodiment, the non-metal may include oxygen (O), a halogen (e.g., F, Cl, Br, I, etc.), or the like.

In an embodiment, the compound including element EL1 and element EL2 may include metal oxide, metal halide (e.g., metal fluoride, metal chloride, metal bromide, metal iodide, etc.), metalloid halide (e.g., metalloid fluoride, metalloid chloride, metalloid bromide, metalloid iodide, etc.), metal telluride, or any combinations thereof, for example.

In an embodiment, the metal oxide may include a tungsten oxide (e.g., WO, W₂O₃, WO₂, WO₃, W₂O₅, etc.), a vanadium oxide (e.g., VO, V₂O₃, VO₂, V₂O₅, etc.), a molybdenum oxide (e.g., MoO, Mo₂O₃, MoO₂, MoO₃, Mo₂O₅, etc.), a rhenium oxide (e.g., ReO₃, etc.), or the like.

In an embodiment, the metal halide may include alkali metal halide, alkaline earth metal halide, transition metal halide, post-transition metal halide, lanthanide metal halide, or the like.

In an embodiment, the alkali metal halide may include LiF, NaF, KF, RbF, CsF, LiCl, NaCl, KCl, RbCI, CsCl, LiBr, NaBr, KBr, RbBr, CsBr, Lil, Nal, KI, Rbl, Csl, or the like.

In an embodiment, the alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, Bel₂, Mgl₂, Cal₂, Srl₂, Bal₂, or the like.

In an embodiment, the transition metal halide may include a titanium halide (e.g., TiF₄, TiCl₄, TiBr₄, Til₄, etc.), a zirconium halide (e.g., ZrF₄, ZrCl₄, ZrBr₄, Zrl₄, etc.), a hafnium halide (e.g., HfF₄, HfCl₄, HfBr₄, Hfl₄, etc.), a vanadium halide (e.g., VF₃, VCl₃, VBr₃, Vl₃, etc.), a niobium halide (e.g., NbF₃, NbCl₃, NbBr₃, Nbl₃, etc.), a tantalum halide (e.g., TaF₃, TaCl₃, TaBr₃, Tal₃, etc.), a chromium halide (e.g., CrF₃, CrCl₃, CrBr₃, Crl₃, etc.), a molybdenum halide (e.g., MoF₃, MoCl₃, MoBr₃, Mol₃, etc.), a tungsten halide (e.g., WF₃, WCl₃, WBr₃, Wl₃, etc.), a manganese halide (e.g., MnF₂, MnCl₂, MnBr₂, Mnl₂, etc.), a technetium halide (e.g., TcF₂, TcCl₂, TcBr₂, Tcl₂, etc.), a rhenium halide (e.g., ReF₂, ReCl₂, ReBr₂, Rel₂, etc.), a ferrous halide (e.g., FeF₂, FeCl₂, FeBr₂, Fel₂, etc.), a ruthenium halide (e.g., RuF₂, RuCl₂, RuBr₂, Rul₂, etc.), an osmium halide (e.g., OsF₂, OsCl₂, OsBr₂, Osl₂, etc.), a cobalt halide (e.g., CoF₂, CoCl₂, CoBr₂, Col₂, etc.), a rhodium halide (e.g., RhF₂, RhCl₂, RhBr₂, Rhl₂, etc.), an iridium halide (e.g., IrF₂, IrCl₂, IrBr₂, Irl₂, etc.), a nickel halide (e.g., NiF₂, NiCl₂, NiBr₂, Nil₂, etc.), a palladium halide (e.g., PdF₂, PdCl₂, PdBr₂, Pdl₂, etc.), a platinum halide (e.g., PtF₂, PtCl₂, PtBr₂, Ptl₂, etc.), a cuprous halide (e.g., CuF, CuCl, CuBr, Cul, etc.), a silver halide (e.g., AgF, AgCI, AgBr, Agl, etc.), a gold halide (e.g., AUF, AuCI, AuBr, Aul, etc.), or the like.

In an embodiment, the post-transition metal halide may include a zinc halide (e.g., ZnF₂, ZnCl₂, ZnBr₂, Znl₂, etc.), an indium halide (e.g., Inl₃, etc.), a tin halide (e.g., Snl₂, etc.), or the like.

In an embodiment, the lanthanide metal halide may include YbF, YbF₂, YbF₃, SmF₃, YbCl, YbCl₂, YbCl₃, SmCl₃, YbBr, YbBr₂, YbBr₃, SmBr₃, Ybl, Ybl₂, Ybl₃, Sml₃, or the like.

In an embodiment, the metalloid halide may include an antimony halide (e.g., SbCl₅, etc.) or the like.

In an embodiment, the metal telluride may include an alkali metal telluride (e.g., LizTe, NazTe, K₂Te, Rb₂Te, Cs₂Te, etc.), an alkaline earth metal telluride (e.g., BeTe, MgTe, CaTe, SrTe, BaTe, etc.), a transition metal telluride (e.g., TiTe₂, ZrTe₂, HfTe₂, V₂Te₃, Nb₂Te₃, Ta₂Tes, Cr₂Te₃, MozTe₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), a post-transition metal telluride (e.g., ZnTe, etc.), a lanthanide metal telluride (e.g., LaTe, CeTe, PrTe, NdTe, PmTe, EuTe, GdTe, TbTe, DyTe, HoTe, ErTe, TmTe, YbTe, LuTe, etc.), or the like.

The emission layer may be arranged on the hole transport region. When the light-emitting device 10 is a full-color light-emitting device, the emission layer may be patterned into a red emission layer, a green emission layer, and/or a blue emission layer, according to a sub-pixel. In an embodiment, the emission layer may have a stacked structure in which two or more layers among a red emission layer, a green emission layer, and a blue emission layer contact each other or are separated from each other to emit white light. In an embodiment, the emission layer may have a structure in which two or more materials among a red light-emitting material, a green light-emitting material, and a blue light-emitting material are mixed with each other in a single layer to emit white light.

In an embodiment, the emission layer may include a host and a dopant. The dopant may include a phosphorescent dopant, a fluorescent dopant, or any combinations thereof.

An amount of the dopant in the emission layer may be in a range of about 0.01 parts by weight to about 15 parts by weight based on 100 parts by weight of the host.

In an embodiment, the emission layer may include quantum dots. These quantum dots may serve as a dopant.

In an embodiment, the emission layer may include a delayed fluorescence material. The delayed fluorescence material may serve as a host or a dopant in the emission layer.

A thickness of the emission layer may be in a range of about 100 Å to about 1,000 Å, e.g., about 200 Å to about 600 Å. When the thickness of the emission layer is within these ranges, excellent luminescence characteristics may be obtained without a substantial increase in driving voltage.

In an embodiment, the host may include a compound represented by Formula 301:

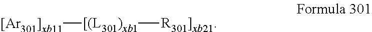

In Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer selecting from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃) , —N(Q₃₀₁)(Q₃₀₂) , —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer selecting from 1 to 5, and
Q₃₀₁ to Q₃₀₃ may each be the same as described in connection with Q₁.

In an embodiment, when xb11 in Formula 301 is 2 or more, two or more of Ar₃₀₁ may be linked to each other via a single bond, for example.

In an embodiment, the host may further include a compound represented by Formula 301-1, a compound represented by Formula 301-2, or any combinations thereof:

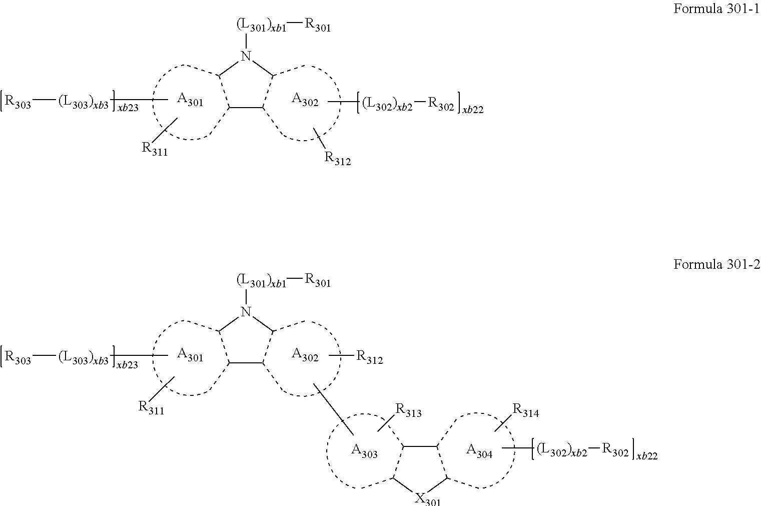

where, in Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N[(L₃₀₄) xb4-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each be the same as described elsewhere herein,
L₃₀₂ to L₃₀₄ may each independently be the same as described in connection with L₃₀₁,
xb2 to xb4 may each independently be as described in connection with xb1, and
R₃₀₂ to R₃₀₅ and R₃₁₁ to R³¹⁴ may each be the same as described in connection with R₃₀₁.

In an embodiment, the host may include an alkali earth metal complex, a post-transition metal complex, or any combinations thereof. In an embodiment, the host may include a Be complex (e.g., Compound H55), an Mg complex, a Zn complex, or any combinations thereof.

In an embodiment, the host may include: one of Compounds H1 to H128; 9,10-di(2-naphthyl) anthracene (“ADN”); 2-methyl-9,10-bis(naphthalen-2-yl) anthracene (“MADN”); 9,10-di-(2-naphthyl)-2-t-butyl-anthracene (“TBADN”); 4,4′-bis(N-carbazolyl)-1,1′-biphenyl (“CBP”); 1,3-di(carbazol-9-yl)benzene (“mCP”); 1,3,5-tri (carbazol-9-yl)benzene (“TCP”); or any combinations thereof:

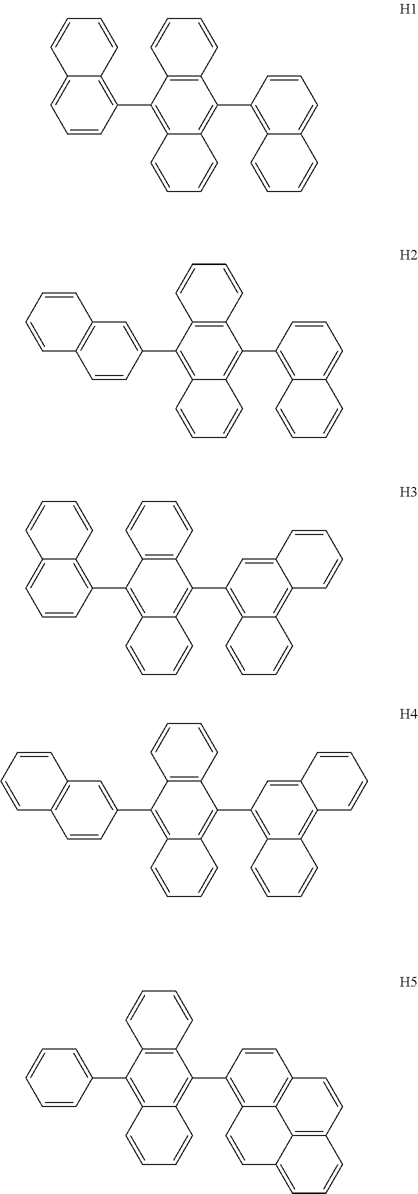

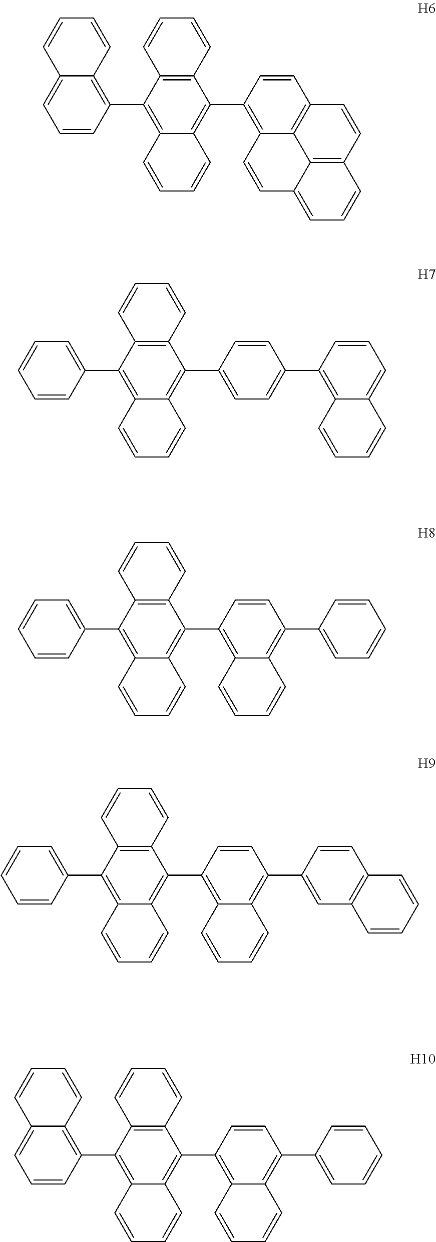

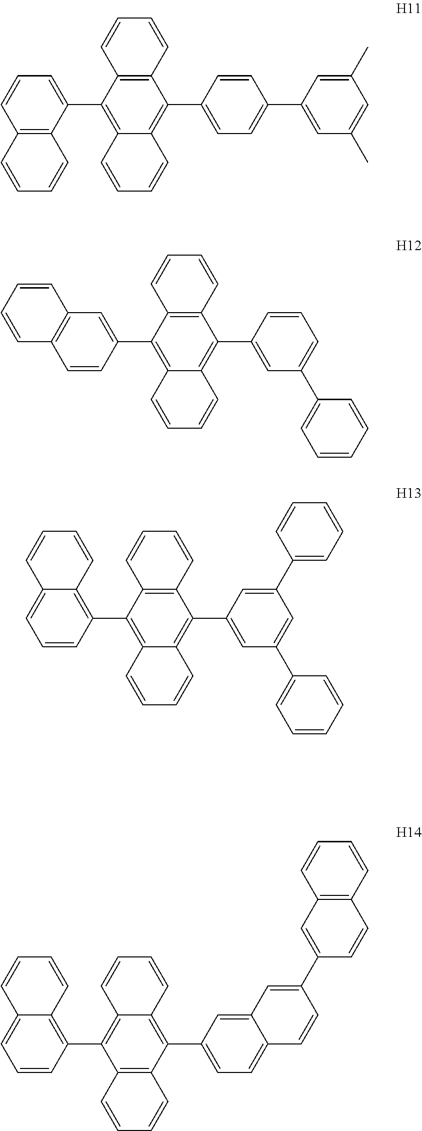

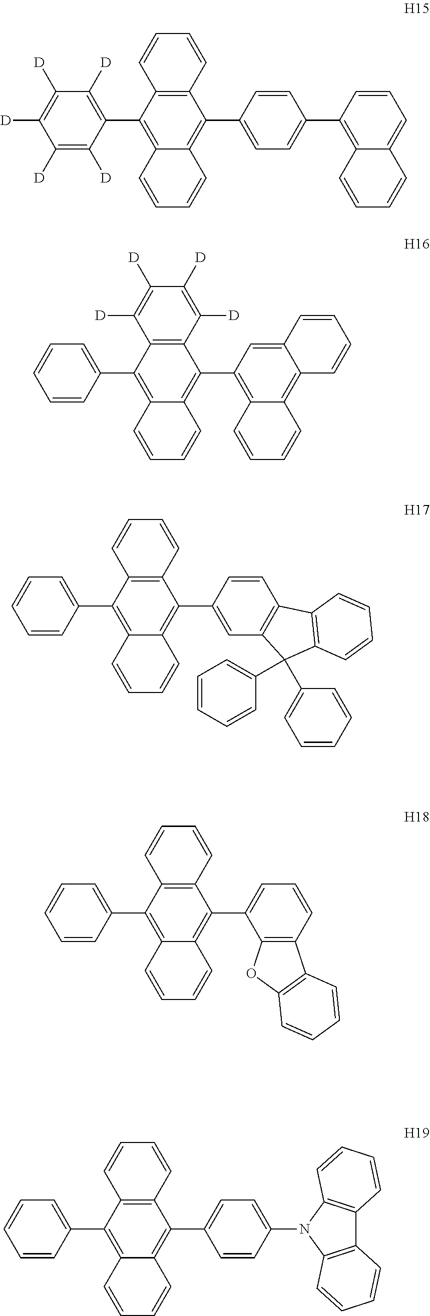

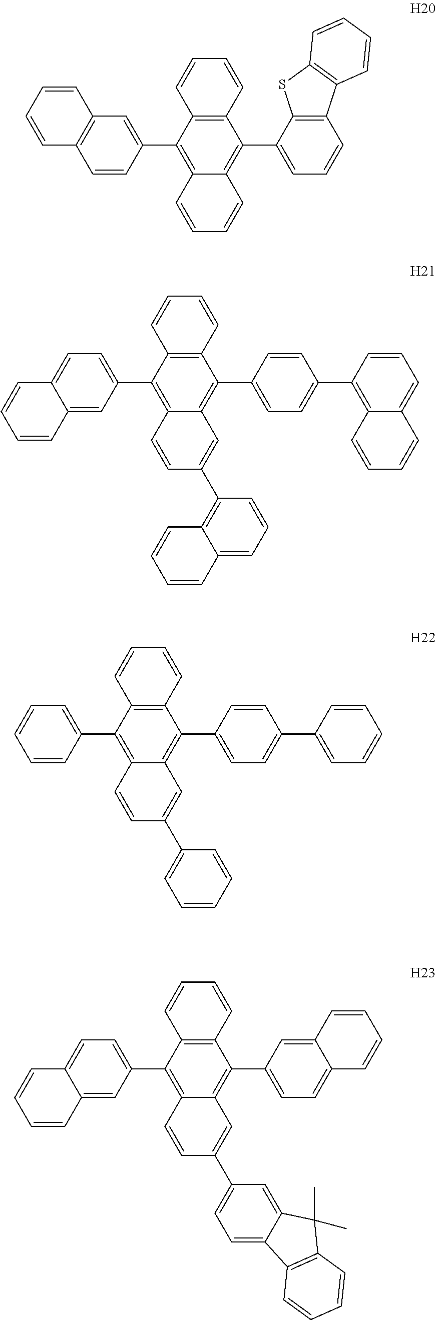

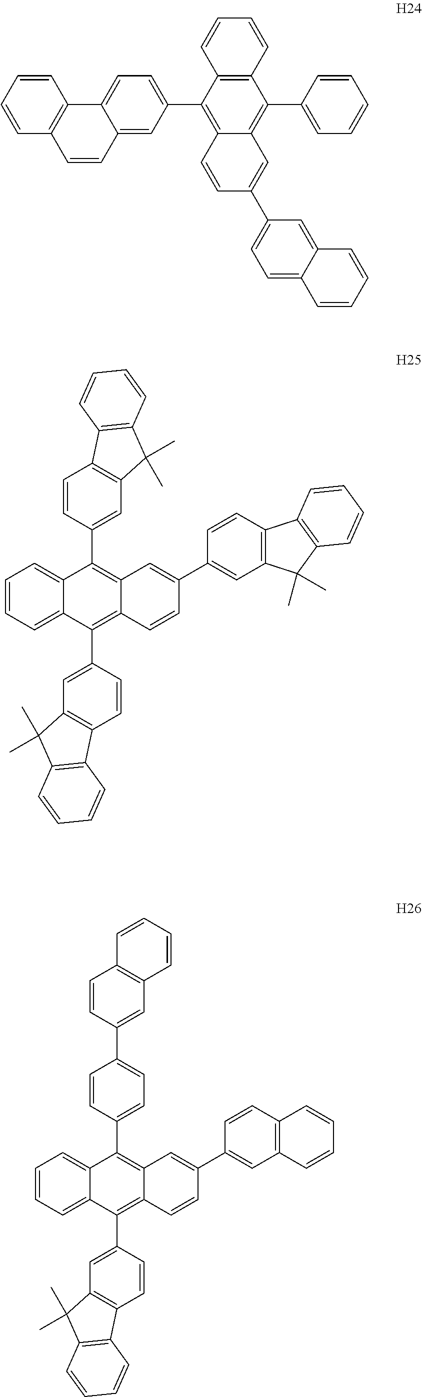

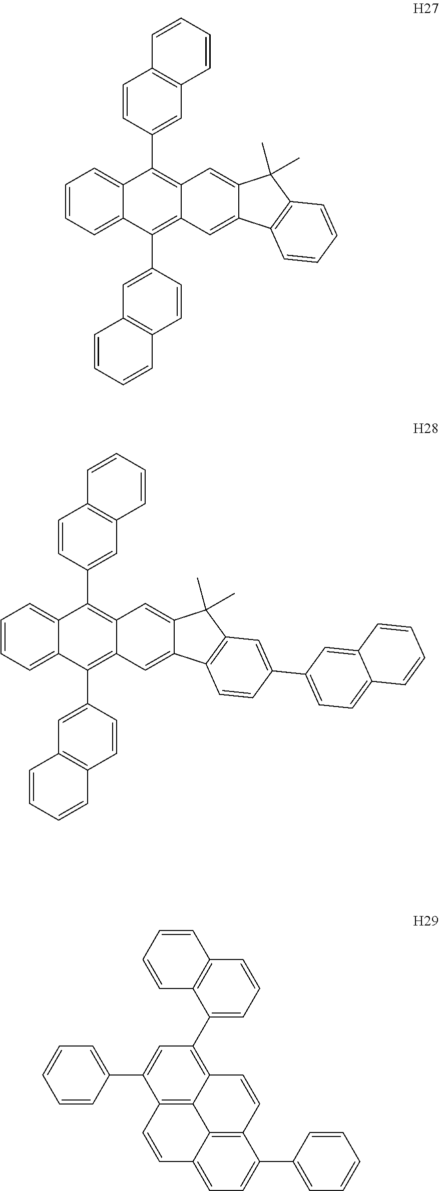

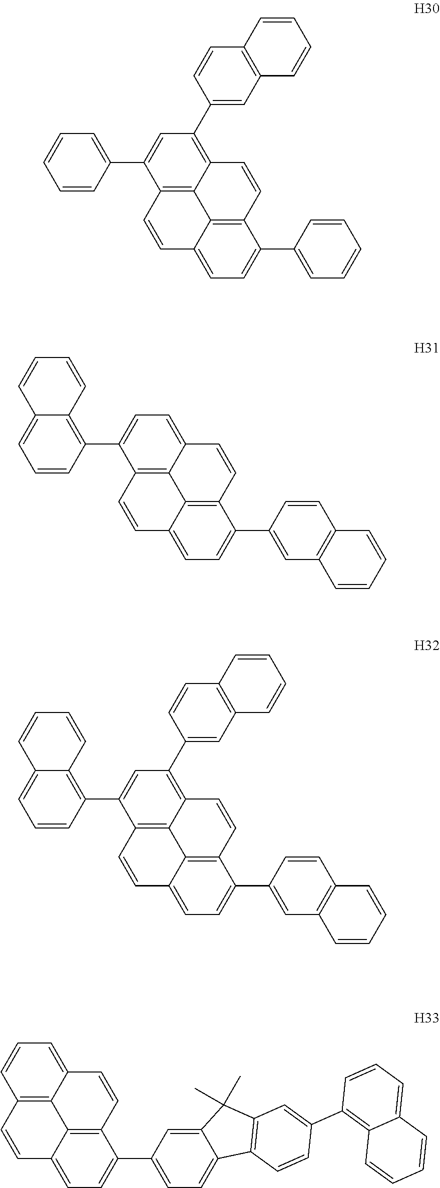

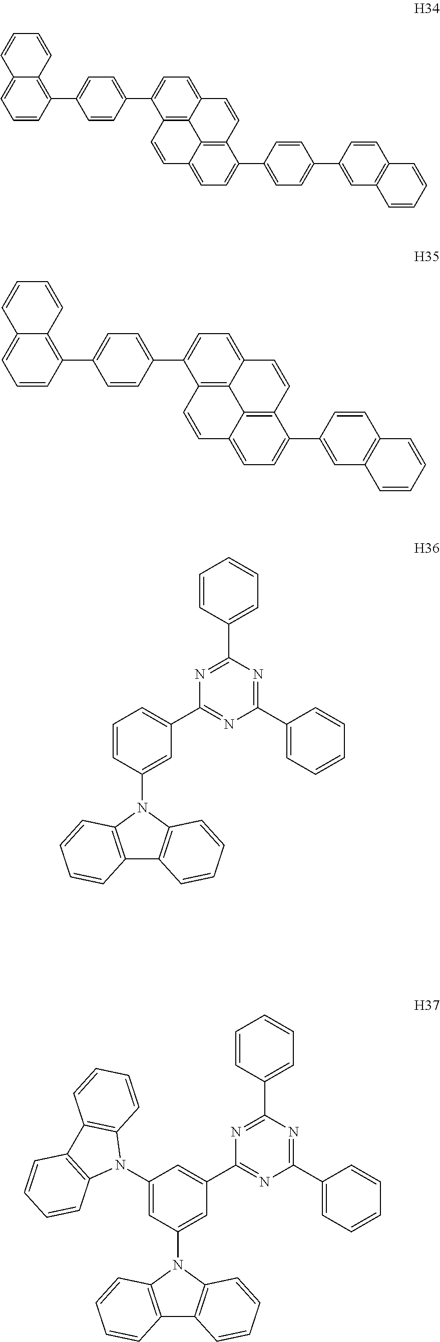

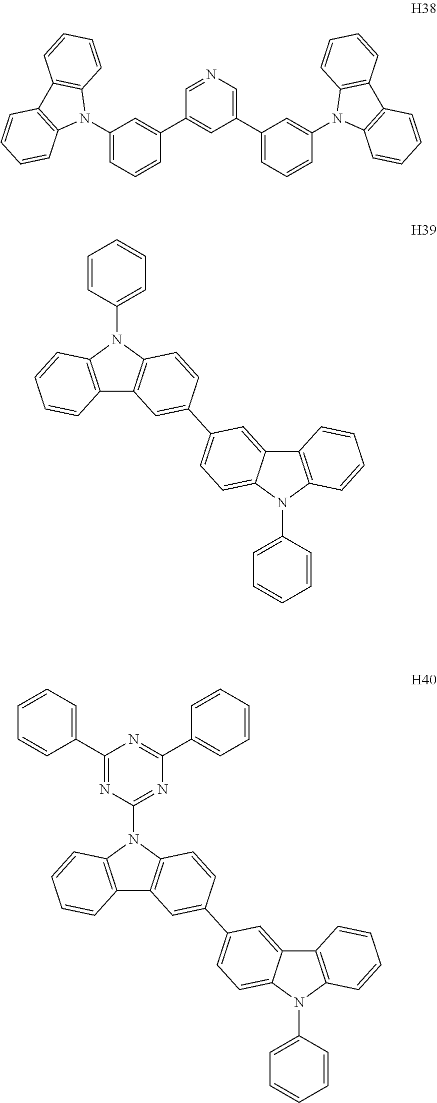 [SMILES: c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1]

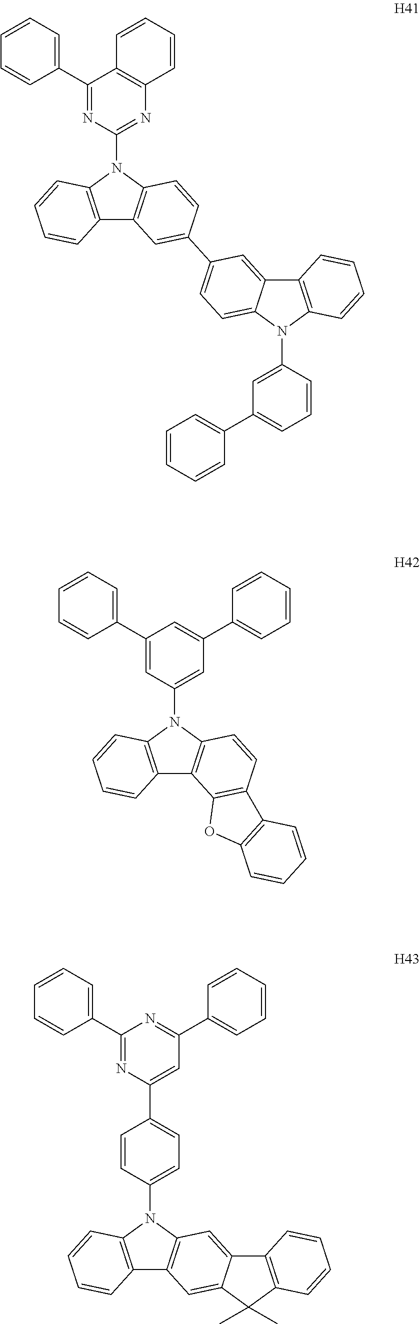 [SMILES: c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1ccc(-c2cc(-c3ccccc3)nc(-c3ccccc3)n2)cc1]

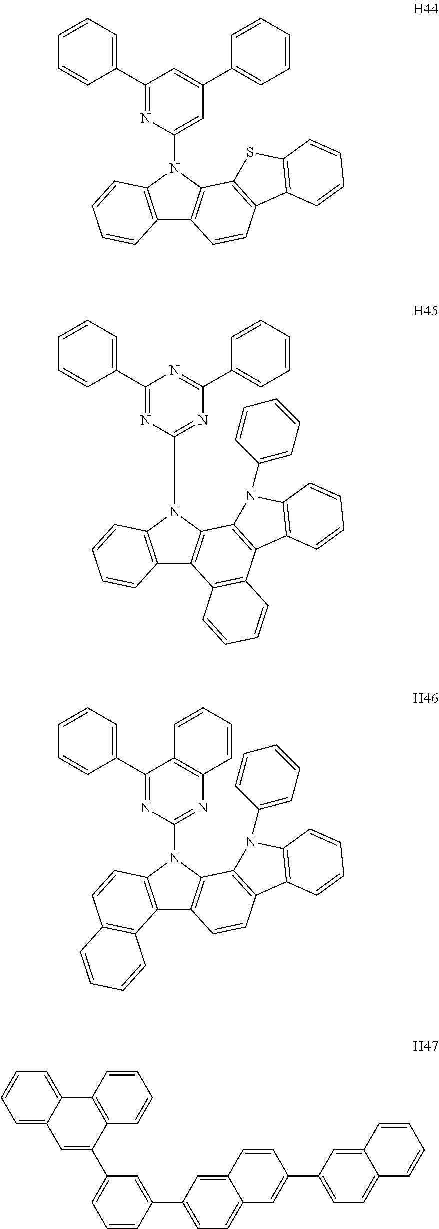

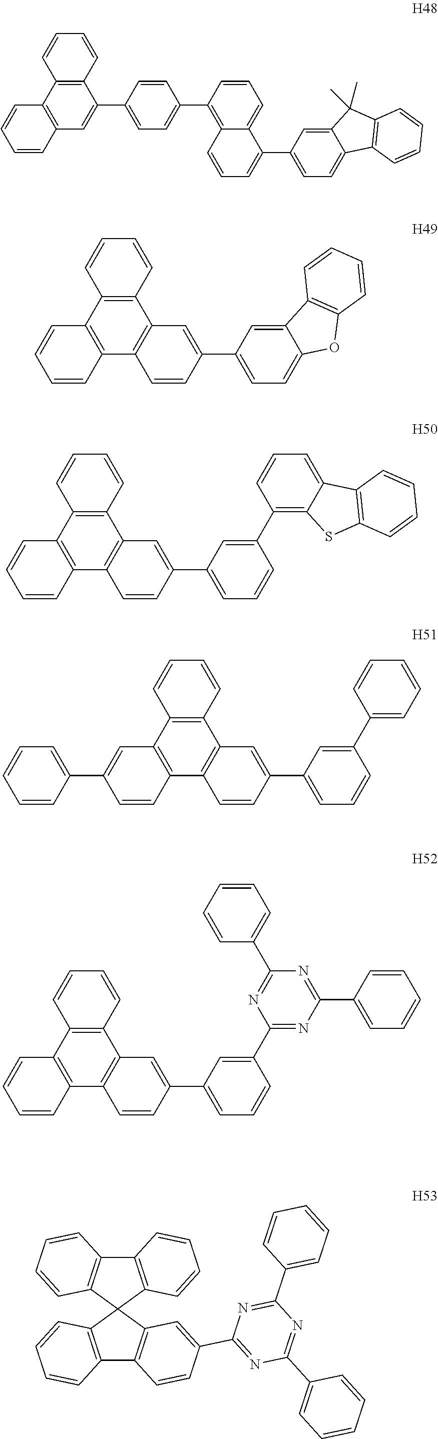

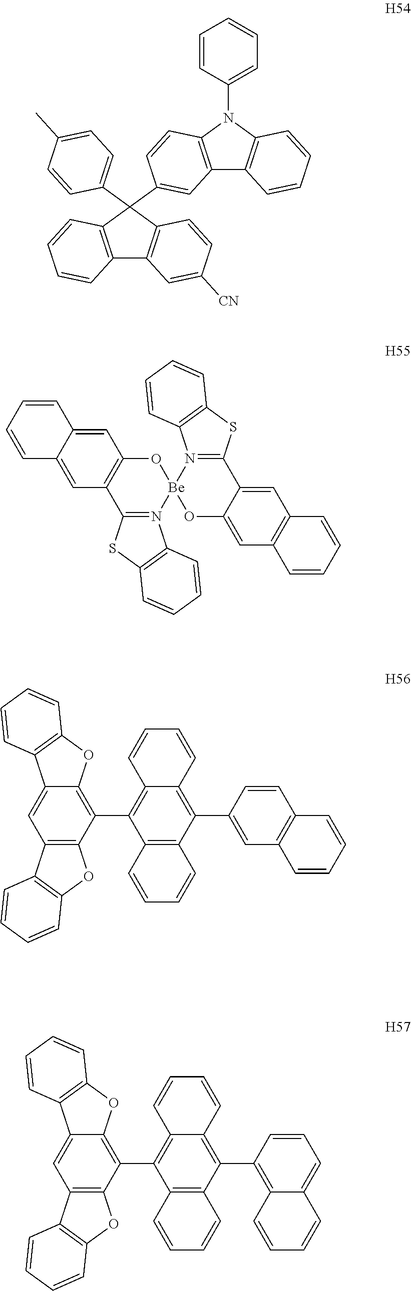

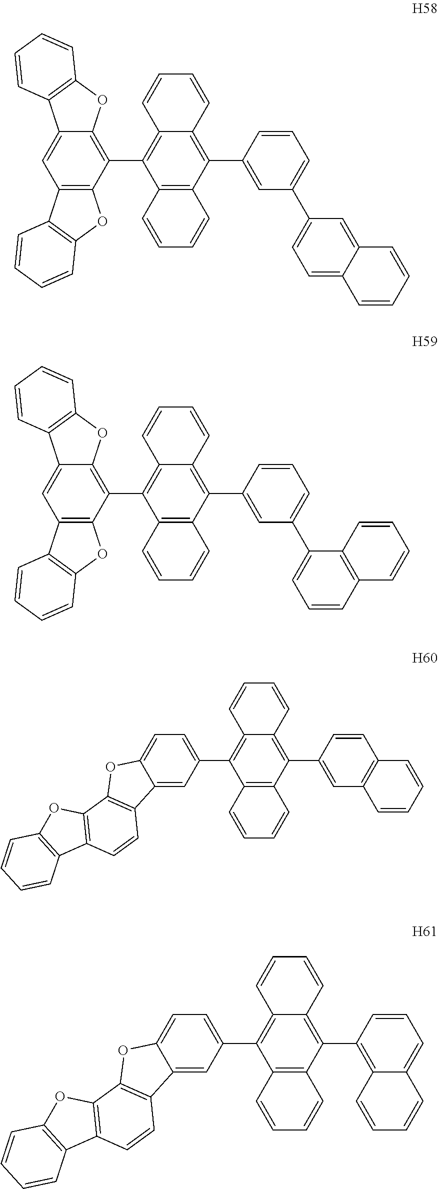 [SMILES: c1cc(-c2ccc3ccccc3c2)cc(-c2c3ccccc3c(-c3c4oc5ccccc5c4cc4c3oc3ccccc34)c3ccccc23)c1 ; c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1]

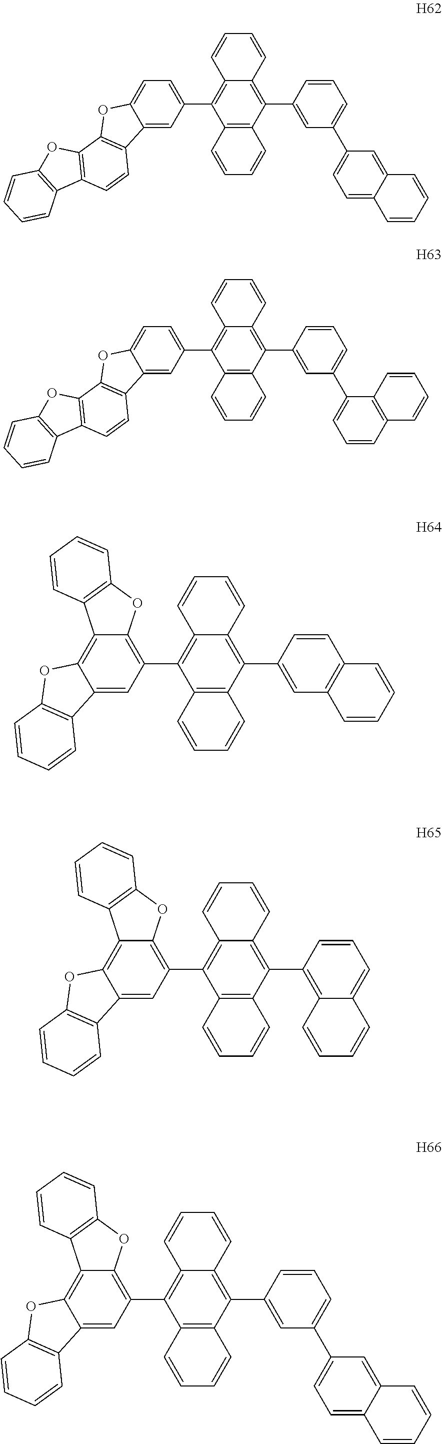 [SMILES: c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1 ; c1ccc2c(-c3c4ccccc4c(-c4cc5c6ccccc6oc5c5c4oc4ccccc45)c4ccccc34)cccc2c1 ; c1cc(-c2ccc3ccccc3c2)cc(-c2c3ccccc3c(-c3cc4c5ccccc5oc4c4c3oc3ccccc34)c3ccccc23)c1]

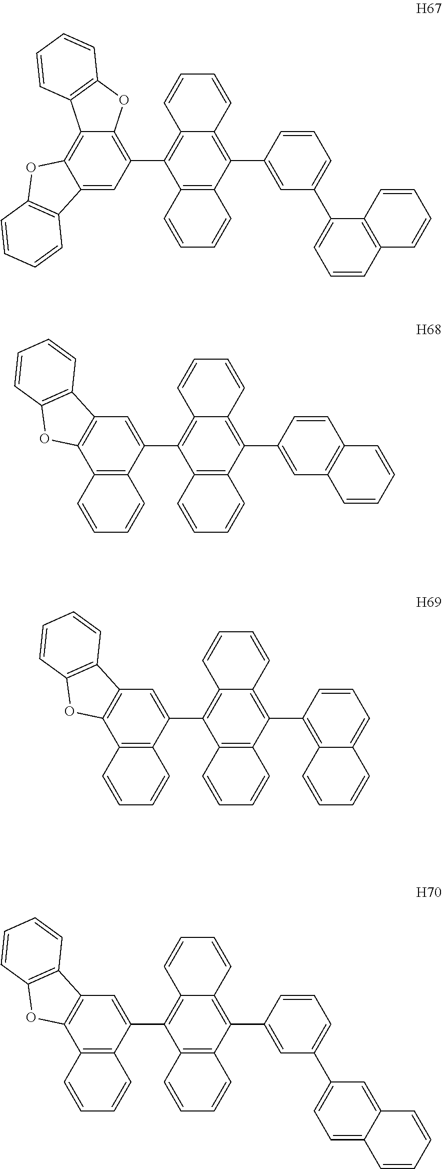 [SMILES: c1cc(-c2cccc3ccccc23)cc(-c2c3ccccc3c(-c3cc4c5ccccc5oc4c4c3oc3ccccc34)c3ccccc23)c1 ; c1ccc2cc(-c3c4ccccc4c(-c4cc5c6ccccc6oc5c5ccccc45)c4ccccc34)ccc2c1 ; c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1]

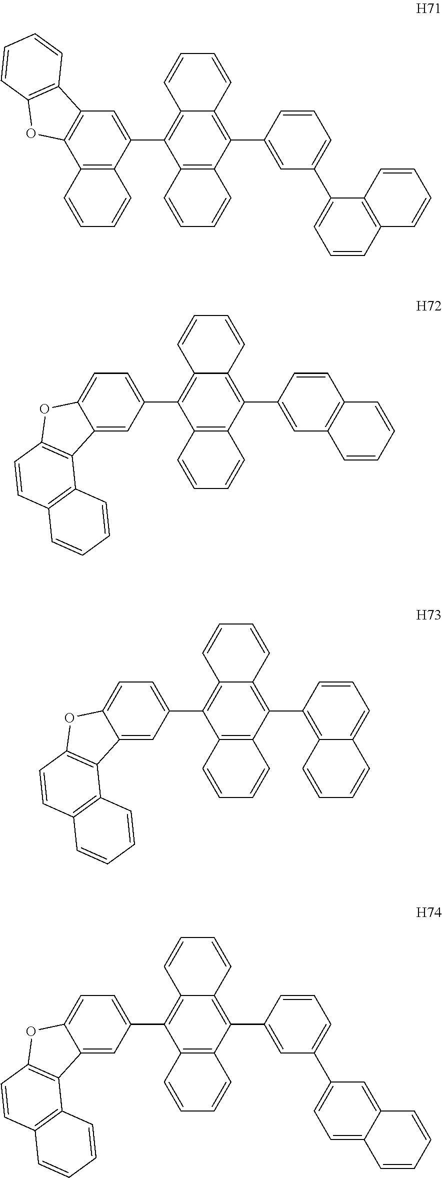 [SMILES: c1cc(-c2cccc3ccccc23)cc(-c2c3ccccc3c(-c3cc4c5ccccc5oc4c4ccccc34)c3ccccc23)c1 ; c1ccc2cc(-c3c4ccccc4c(-c4ccc5oc6ccc7ccccc7c6c5c4)c4ccccc34)ccc2c1 ; c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1]

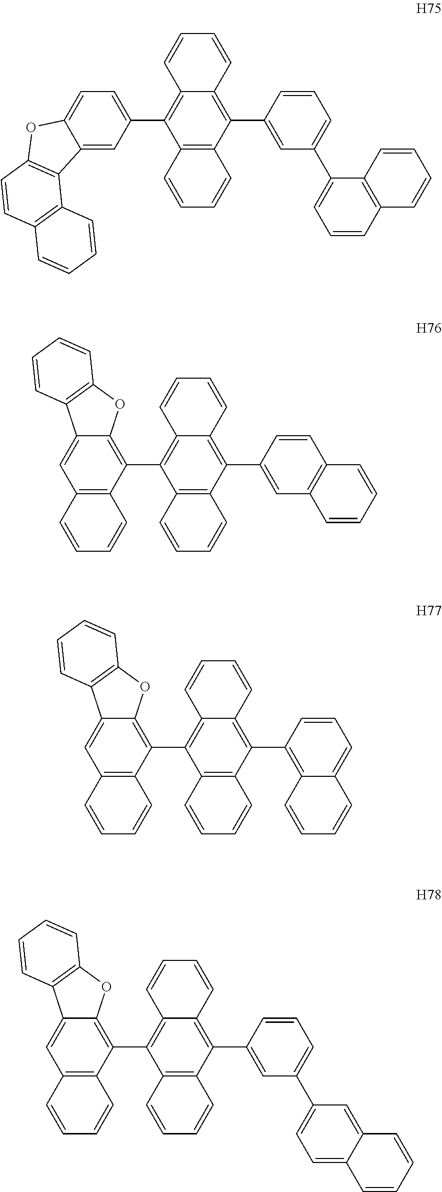 [SMILES: c1cc(-c2cccc3ccccc23)cc(-c2c3ccccc3c(-c3ccc4oc5ccc6ccccc6c5c4c3)c3ccccc23)c1 ; c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1]

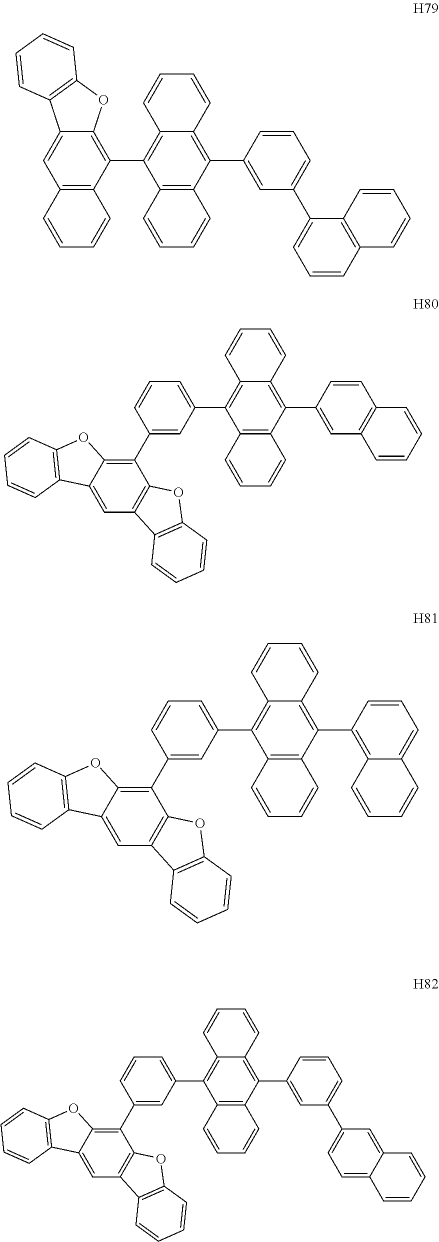 [SMILES: c1cc(-c2cccc3ccccc23)cc(-c2c3ccccc3c(-c3c4ccccc4cc4c3oc3ccccc34)c3ccccc23)c1 ; c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1]

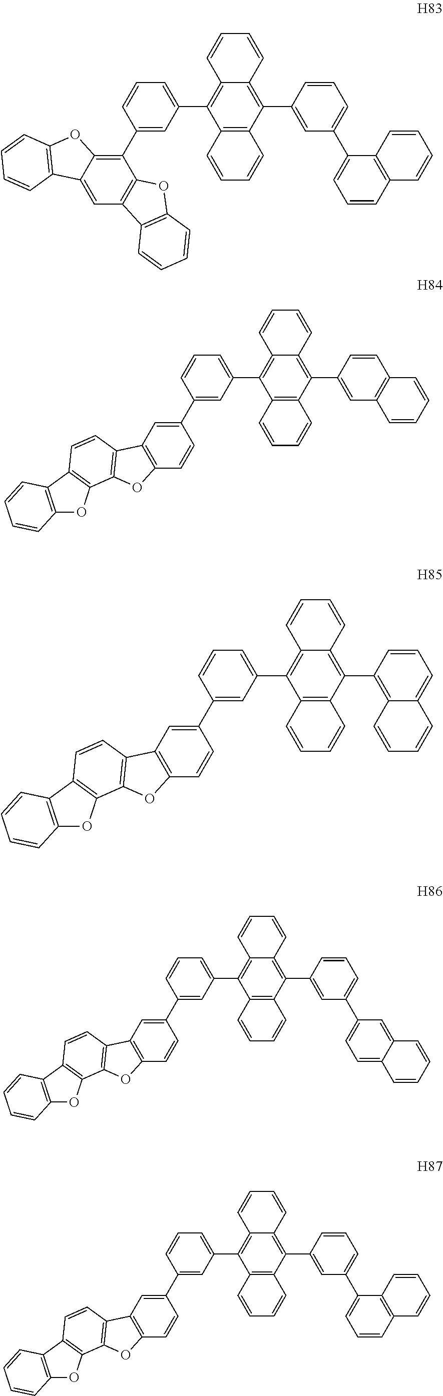 [SMILES: c1cc(-c2cccc3ccccc23)cc(-c2c3ccccc3c(-c3cccc(-c4c5oc6ccccc6c5cc5c4oc4ccccc45)c3)c3ccccc23)c1 ; c1cc(-c2ccc3oc4c(ccc5c6ccccc6oc54)c3c2)cc(-c2c3ccccc3c(-c3ccc4ccccc4c3)c3ccccc23)c1 ; c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1]

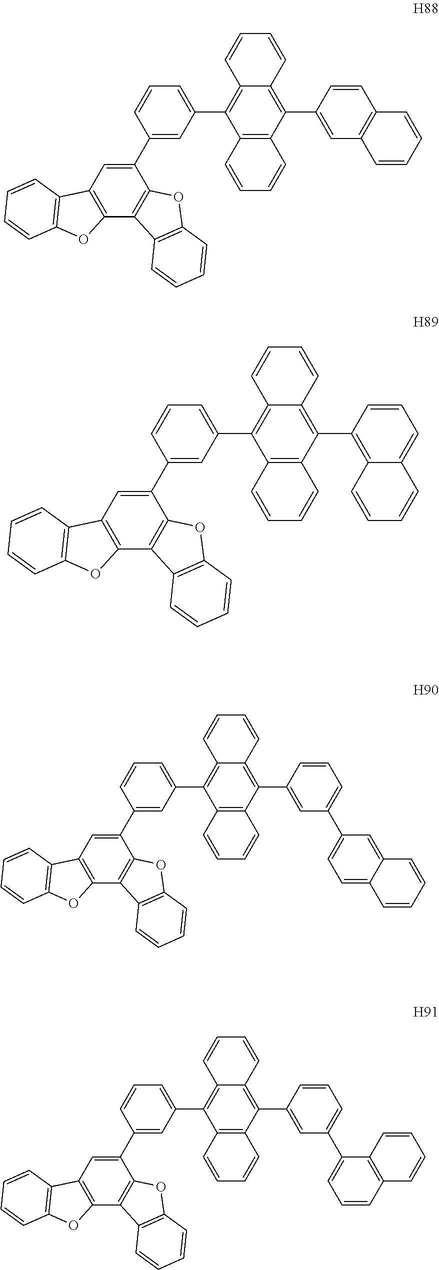 [SMILES: c1cc(-c2c3ccccc3c(-c3ccc4ccccc4c3)c3ccccc23)cc(-c2cc3c4ccccc4oc3c3c2oc2ccccc23)c1 ; c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1]

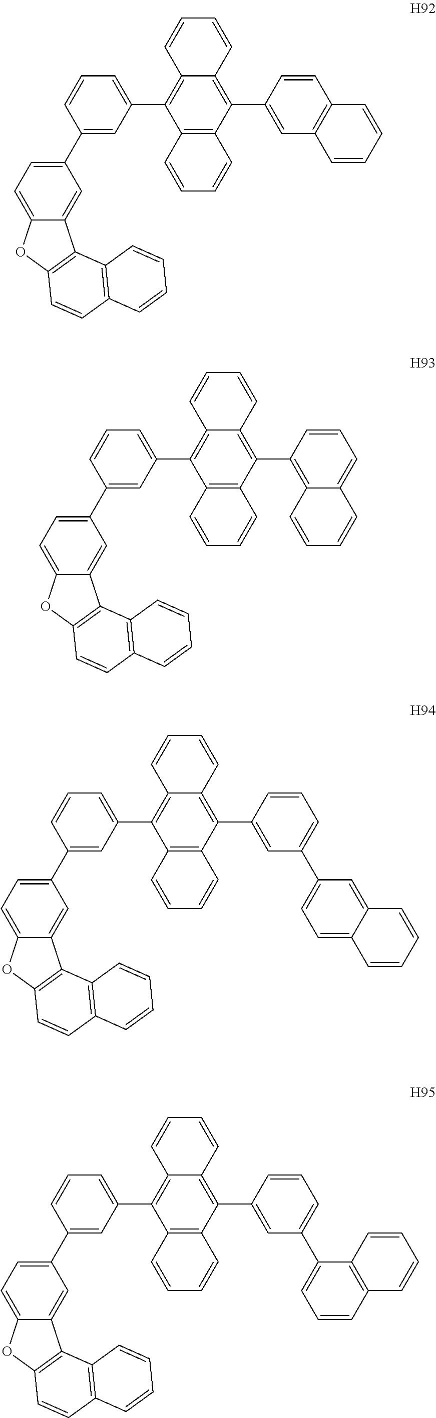 [SMILES: c1cc(-c2ccc3oc4ccc5ccccc5c4c3c2)cc(-c2c3ccccc3c(-c3ccc4ccccc4c3)c3ccccc23)c1 ; c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1]

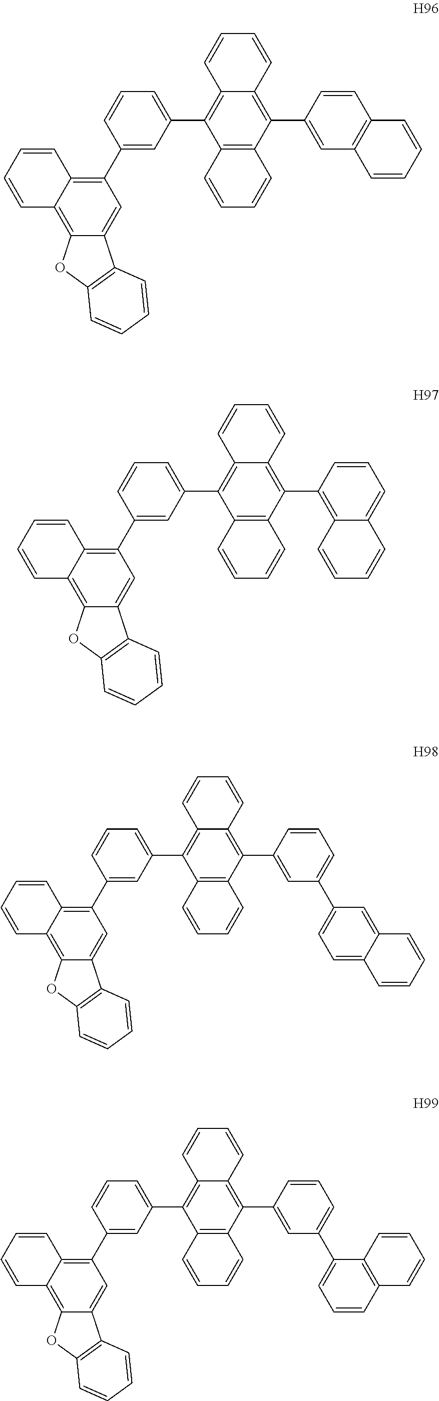 [SMILES: c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1]

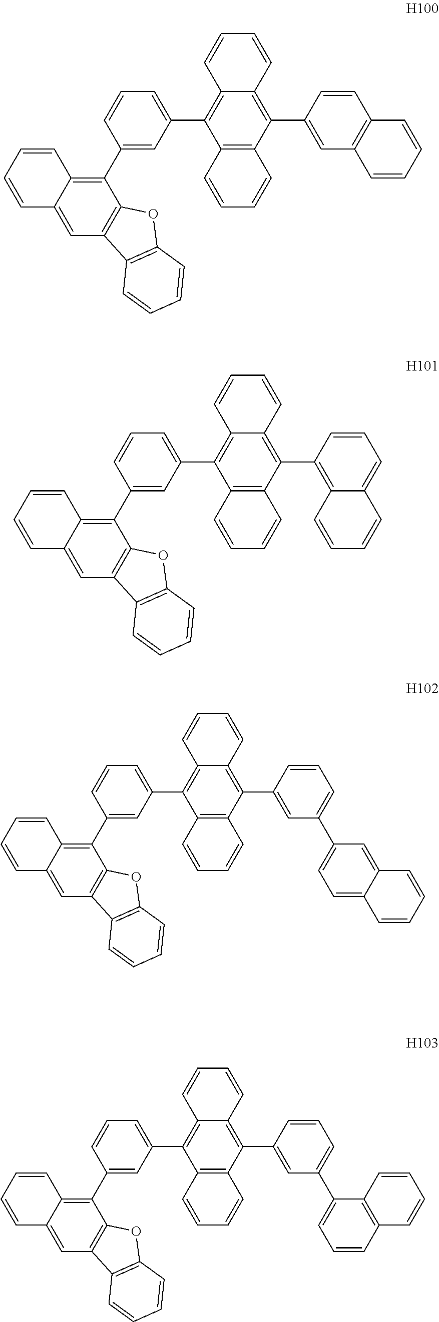 [SMILES: c1cc(-c2c3ccccc3c(-c3ccc4ccccc4c3)c3ccccc23)cc(-c2c3ccccc3cc3c2oc2ccccc23)c1 ; c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1]

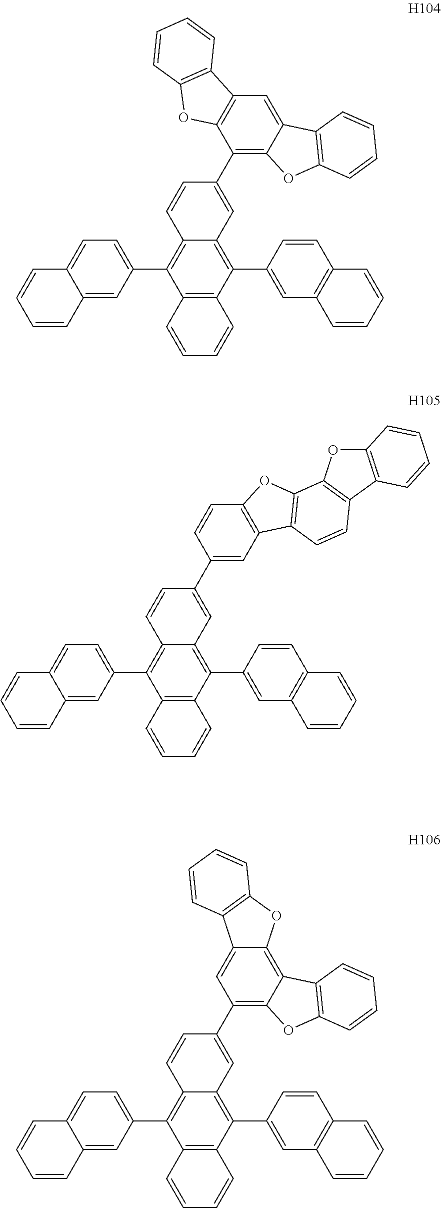 [SMILES: c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1]

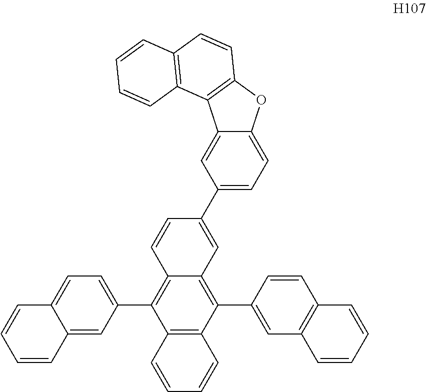 [SMILES: c1ccc2cc(-c3c4ccccc4c(-c4ccc5ccccc5c4)c4cc(-c5ccc6oc7ccc8ccccc8c7c6c5)ccc34)ccc2c1]

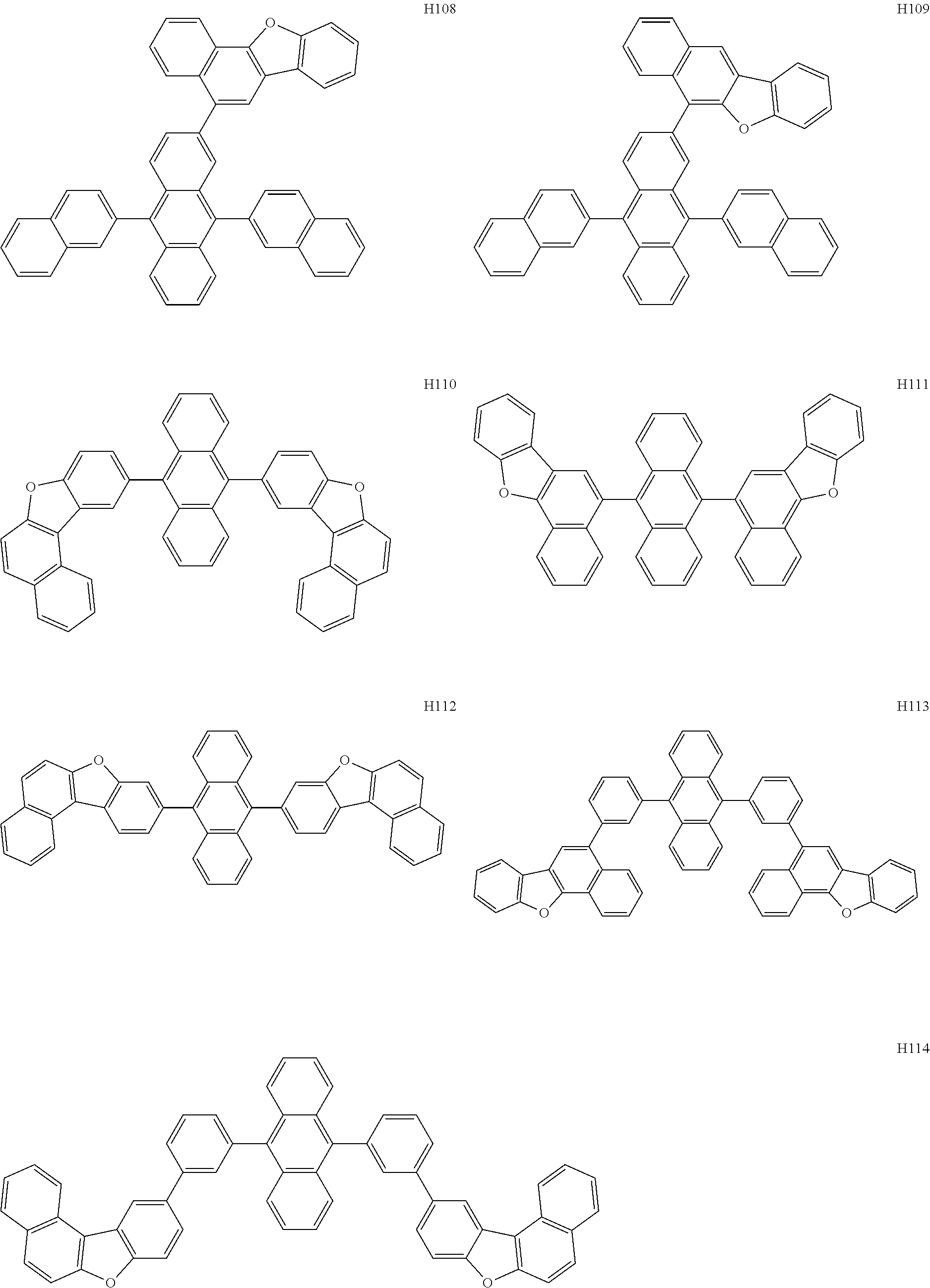

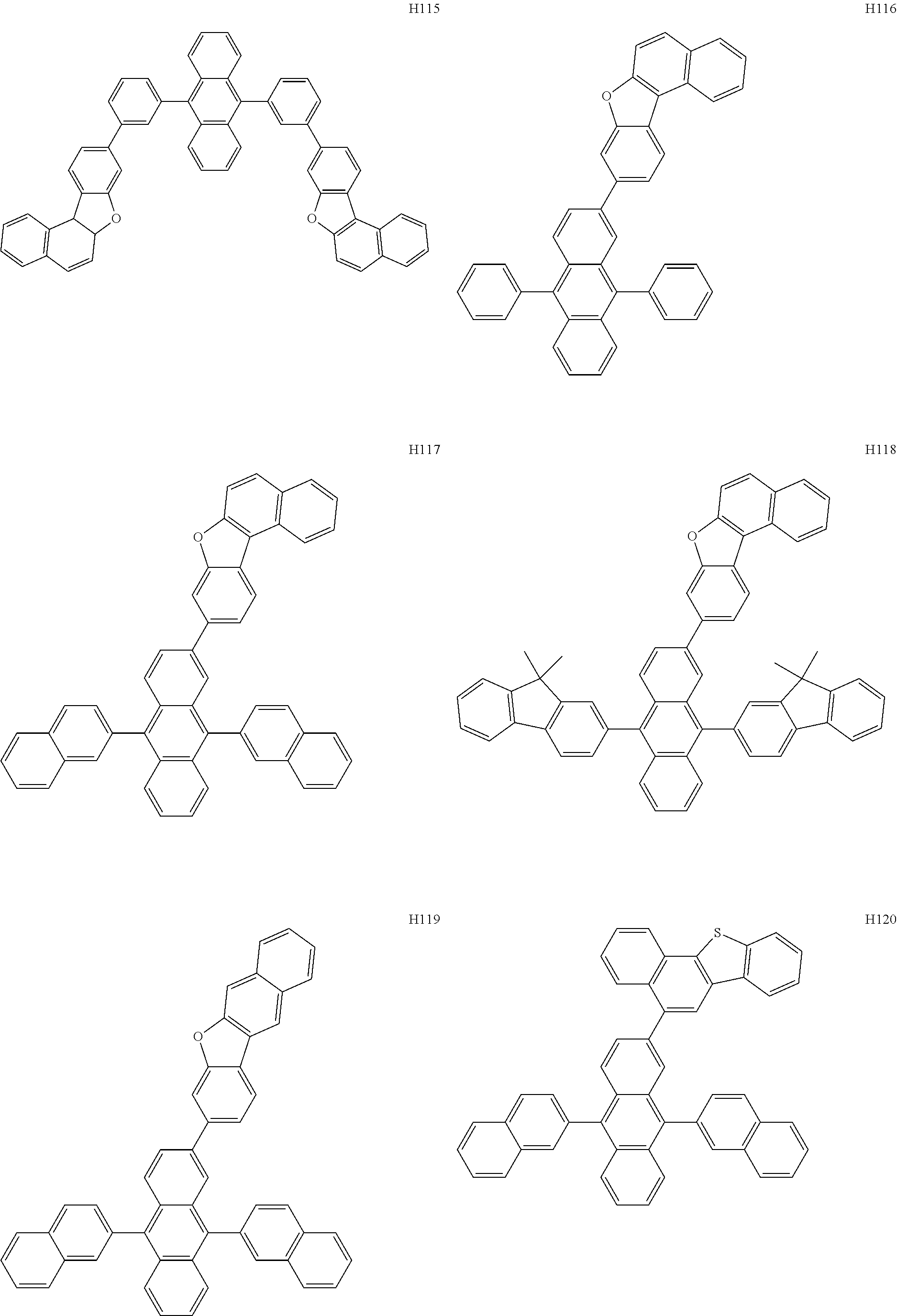

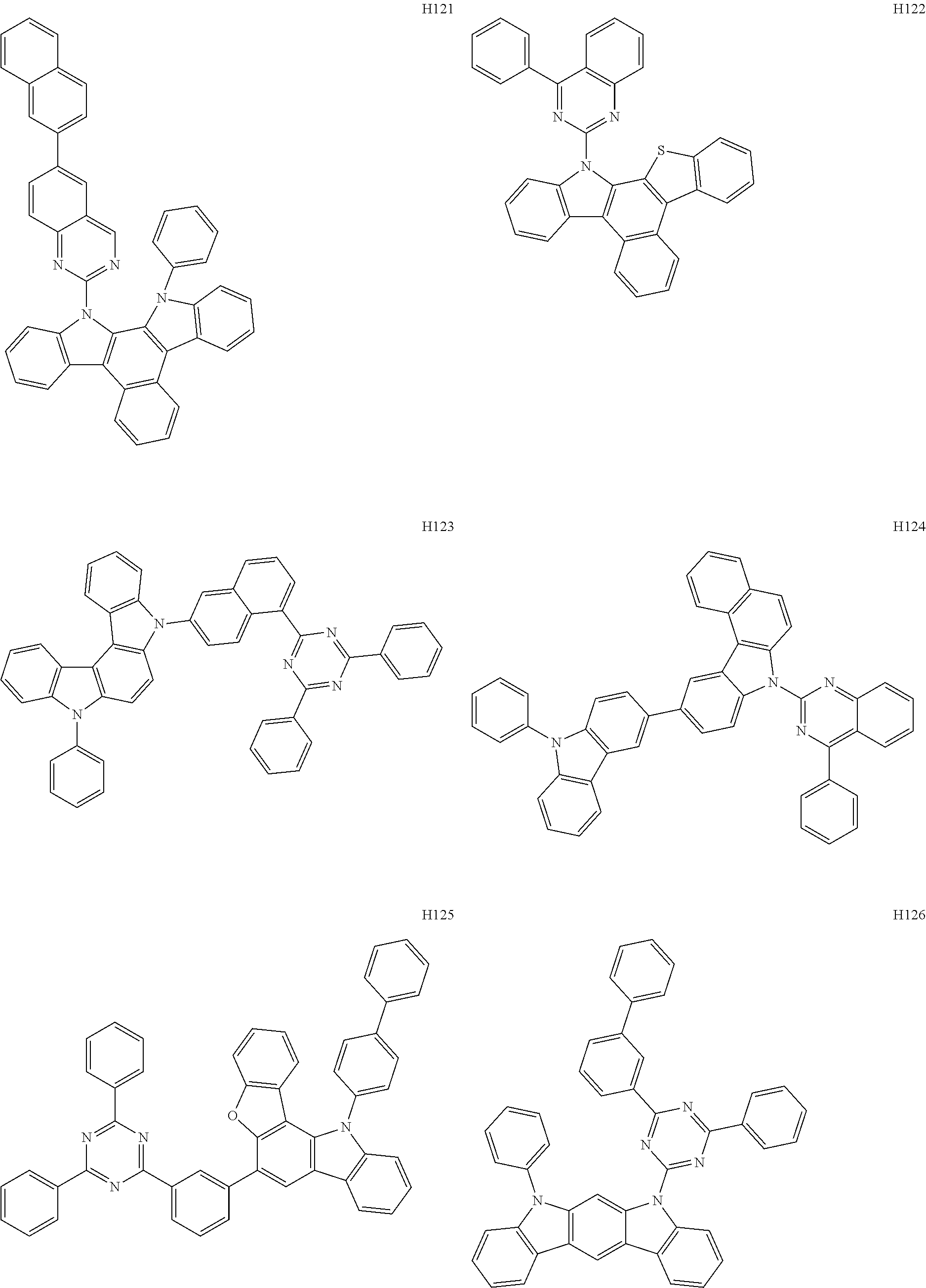

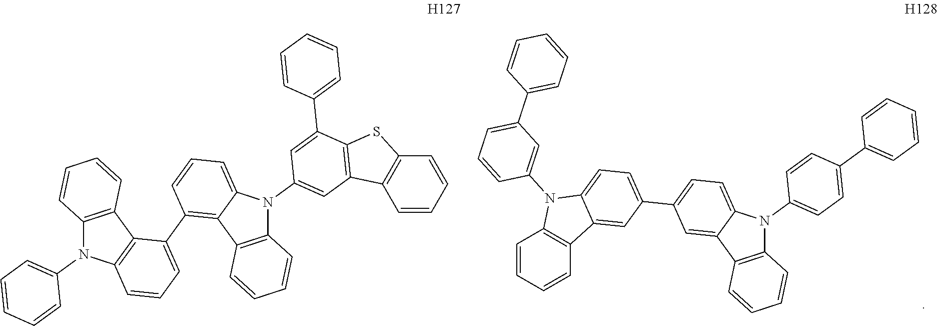

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combinations thereof.

The phosphorescent dopant may be electrically neutral.

In an embodiment, the phosphorescent dopant may include an organometallic compound represented by Formula 401:

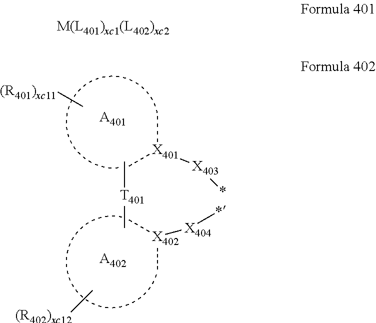

where, in Formulae 401 and 402,
M may be a transition metal (e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein, when xc1 is 2 or more, two or more L₄₀₁(s) may be identical to or different from each other,
L₄₀₂ may be an organic ligand, and xc2 may be 0, 1, 2, 3, or 4, where, when xc2 is 2 or more, two or more of L₄₀₂ may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O —*, *—S—*, *—C(═O)—**, *—N(Q₄₁₁)-*, *—C(Q₄₁₁)(Q₄₁₂)-, *—C(Q₄₁₁)═C(Q₄₁₂)-**, *—C(Q₄₁₁)=*′, or *=C═*′,
X₄₀₃ and X₄₀₄ may each independently be a chemical bond (e.g., a covalent bond or a coordination bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each be the same as described in connection with Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each be the same as described in connection with Q₁,
xc11 and xc12 may each independently be an integer selecting from 0 to 10, and
* and ** in Formula 402 each indicate a binding site to M in Formula 401.

In an embodiment, in Formula 402, i) X₄₀₁ may be nitrogen and X₄₀₂ may be carbon, or ii) each of X₄₀₁ and X₄₀₂ may be nitrogen, for example.

In an embodiment, when xc1 in Formula 401 is 2 or more, two ring A₄₀₁(s) among two or more of L₄₀₁ may optionally be linked to each other via T₄₀₂, which is a linking group, and two ring A₄₀₂(s) among two or more of L₄₀₁ may optionally be linked to each other via T₄₀₃, which is a linking group (refer to Compounds PD1 to PD4 and PD7). T₄₀₂ and T₄₀₃ may each be the same as described in connection with T₄₀₁.

In Formula 401, L₄₀₂ may be an organic ligand. In an embodiment, L₄₀₂ may include a halogen group, a diketone group (e.g., an acetylacetonate group), a carboxylic acid group (e.g., a picolinate group), —C(═O) group, an isonitrile group, a-CN group, a phosphorus-containing group (e.g., a phosphine group, a phosphite group, etc.), or any combinations thereof, for example.

The phosphorescent dopant may include one of Compounds PD1 to PD40 or any combinations thereof, for example:

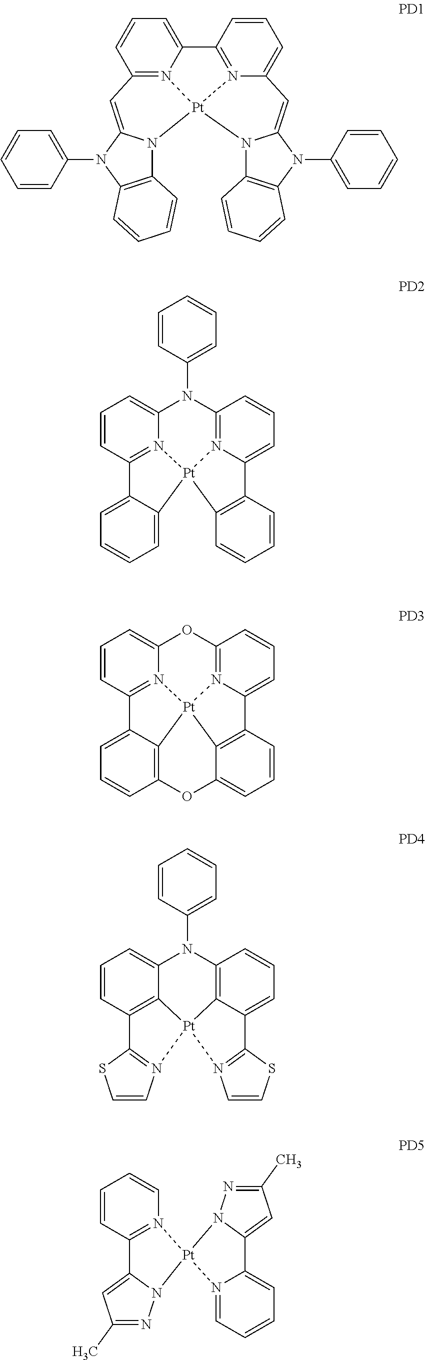

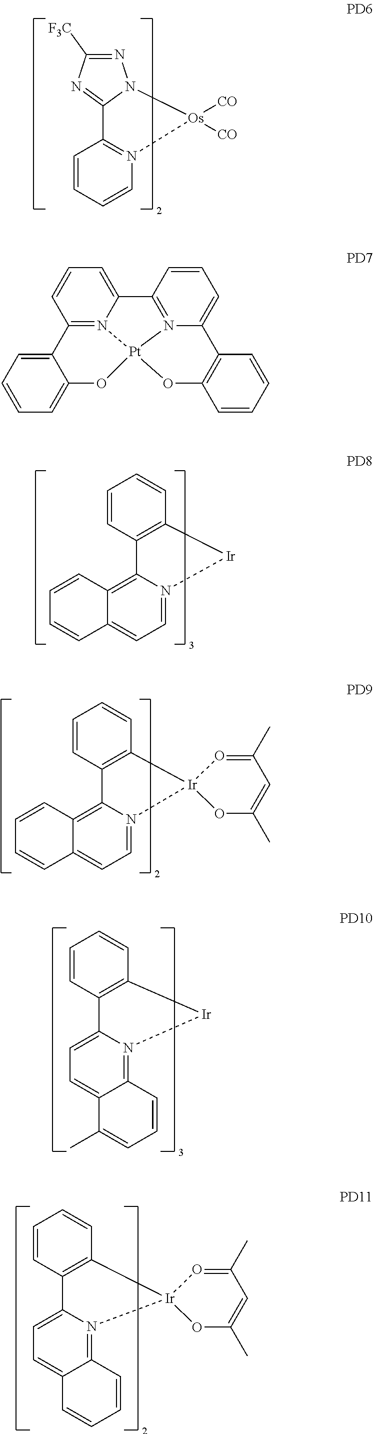

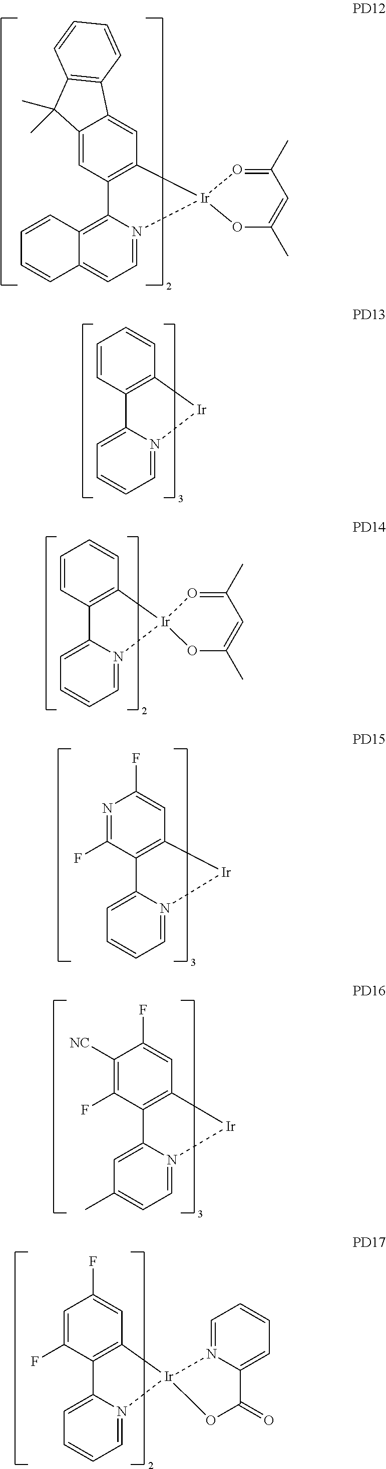

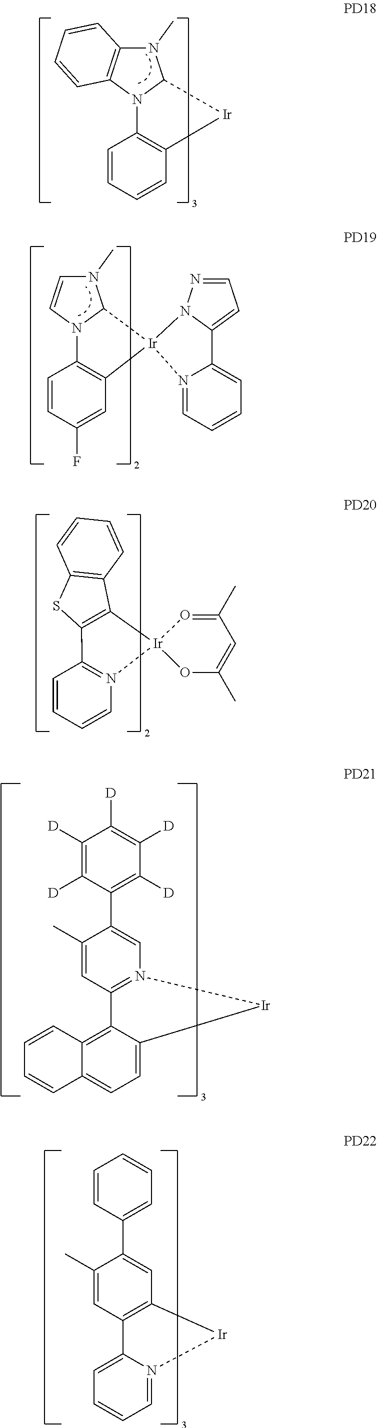

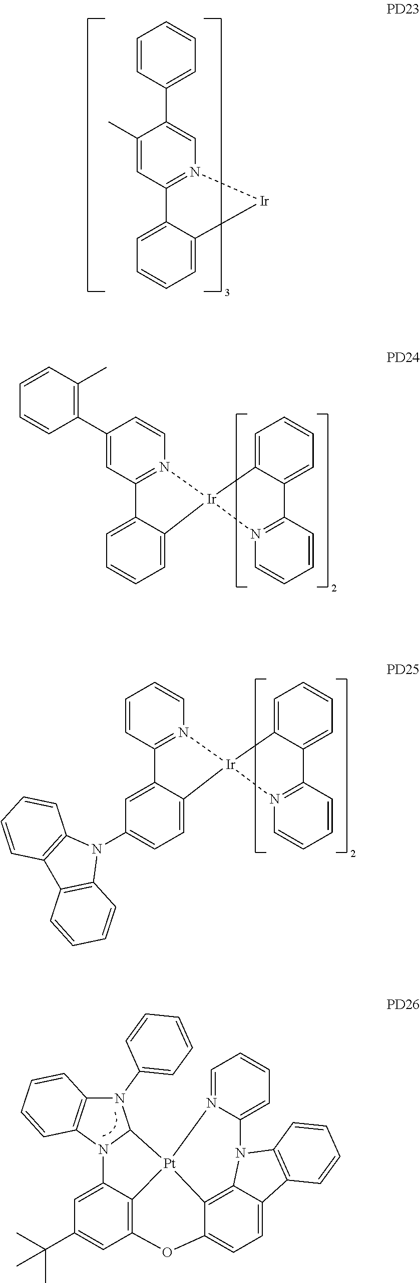

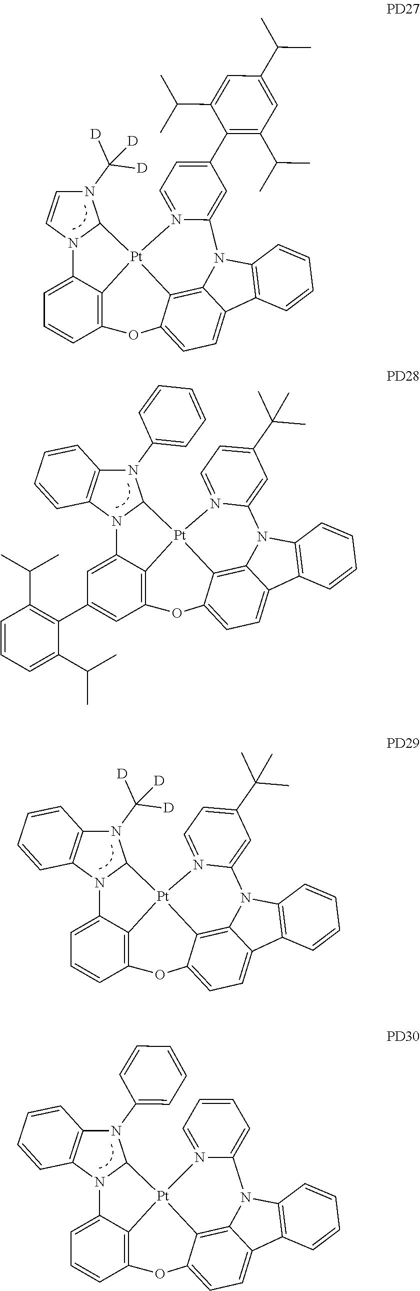

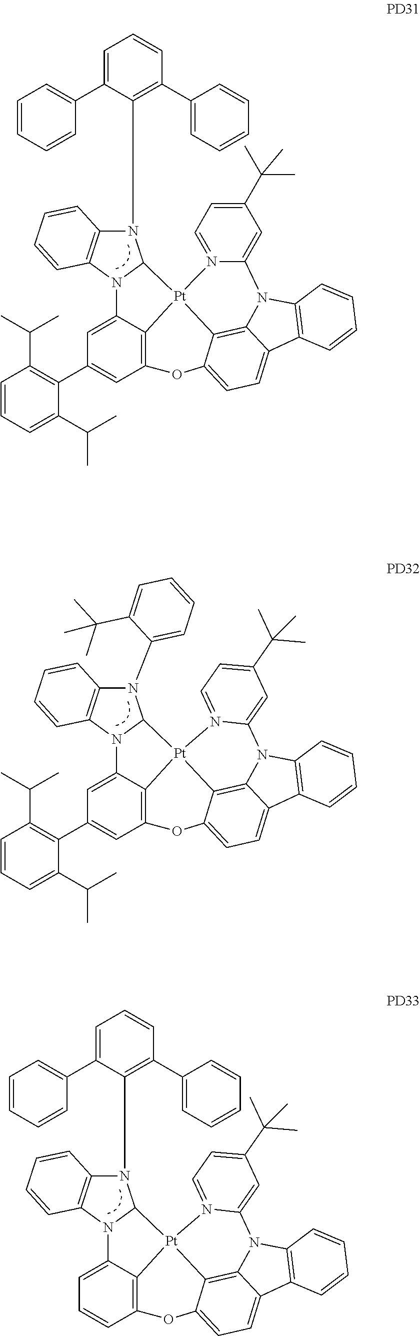

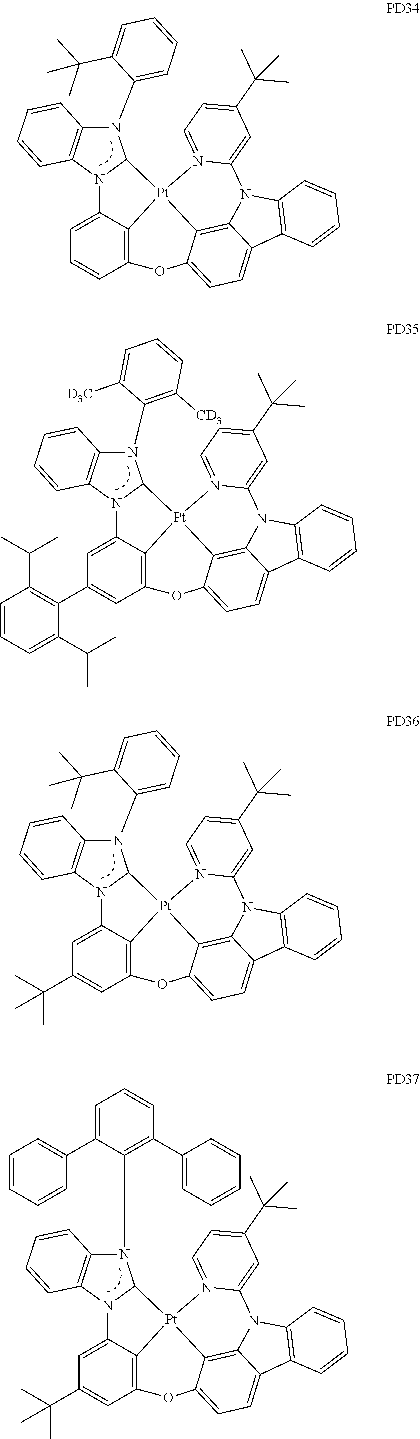

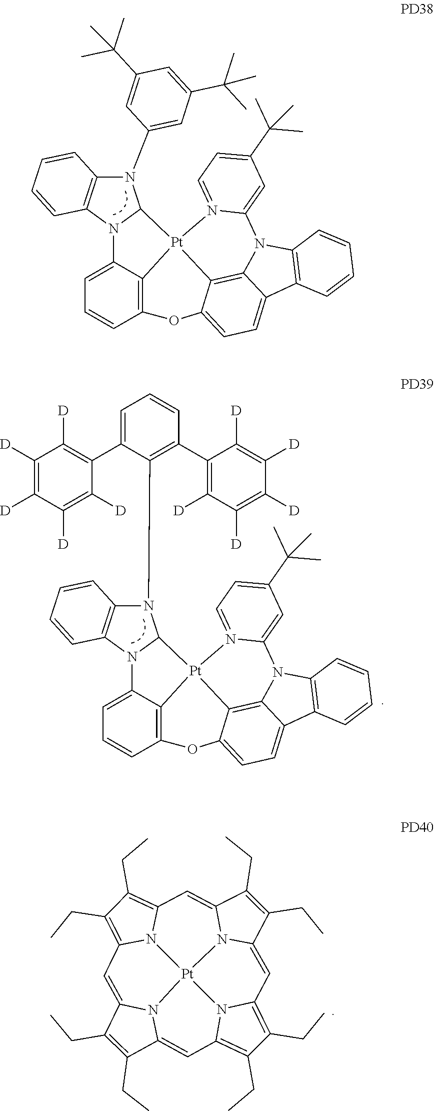

The fluorescent dopant may include an amine group-containing compound, a styryl group-containing compound, or any combinations thereof.

In an embodiment, the fluorescent dopant may include a compound represented by Formula 501, for example:

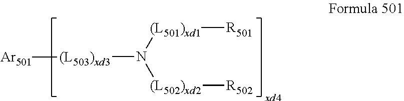

where, in Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

In an embodiment, Ar₅₀₁ in Formula 501 may be a condensed cyclic group (e.g., an anthracene group, a chrysene group, a pyrene group, etc.) in which three or more monocyclic groups are condensed with each other, for example.

In an embodiment, xd4 in Formula 501 may be 2, for example.

In an embodiment, the fluorescent dopant may include: one of Compounds FD1 to FD37; DPVBi; DPAVBi; or any combinations thereof, for example:

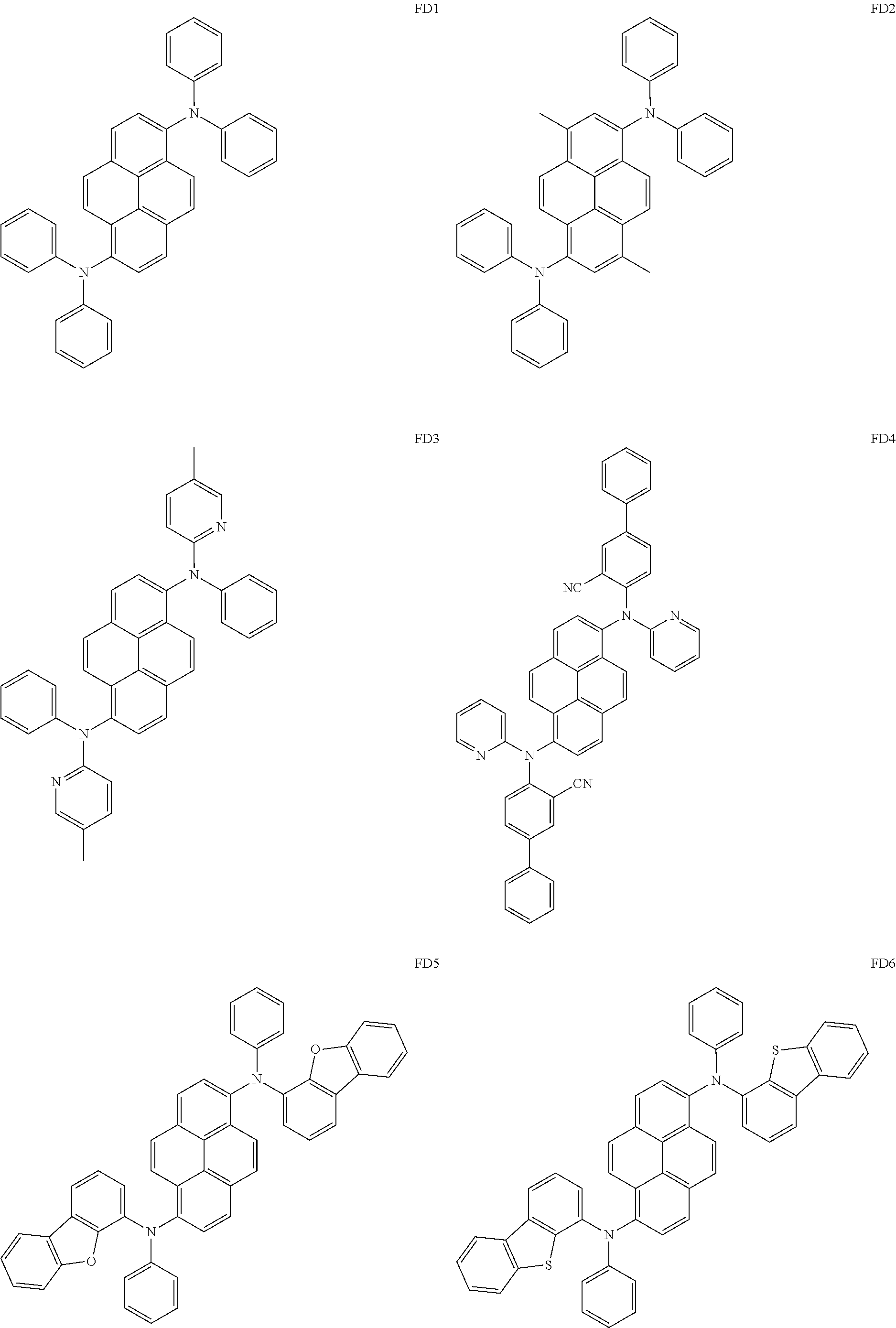 [SMILES: c1ccc(N(c2ccccc2)c2ccc3ccc4c(N(c5ccccc5)c5ccccc5)ccc5ccc2c3c54)cc1 ; Cc1cc(N(c2ccccc2)c2ccccc2)c2ccc3c(C)cc(N(c4ccccc4)c4ccccc4)c4ccc1c2c34 ; Cc1ccc(N(c2ccccc2)c2ccc3ccc4c(N(c5ccccc5)c5ccc(C)cn5)ccc5ccc2c3c54)nc1 ; N#Cc1cc(-c2ccccc2)ccc1N(c1ccccn1)c1ccc2ccc3c(N(c4ccccn4)c4ccc(-c5ccccc5)cc4C#N)ccc4ccc1c2c43 ; c1ccc(N(c2ccc3ccc4c(N(c5ccccc5)c5cccc6c5oc5ccccc56)ccc5ccc2c3c54)c2cccc3c2oc2ccccc23)cc1 ; c1ccc(N(c2ccc3ccc4c(N(c5ccccc5)c5cccc6c5sc5ccccc56)ccc5ccc2c3c54)c2cccc3c2sc2ccccc23)cc1]

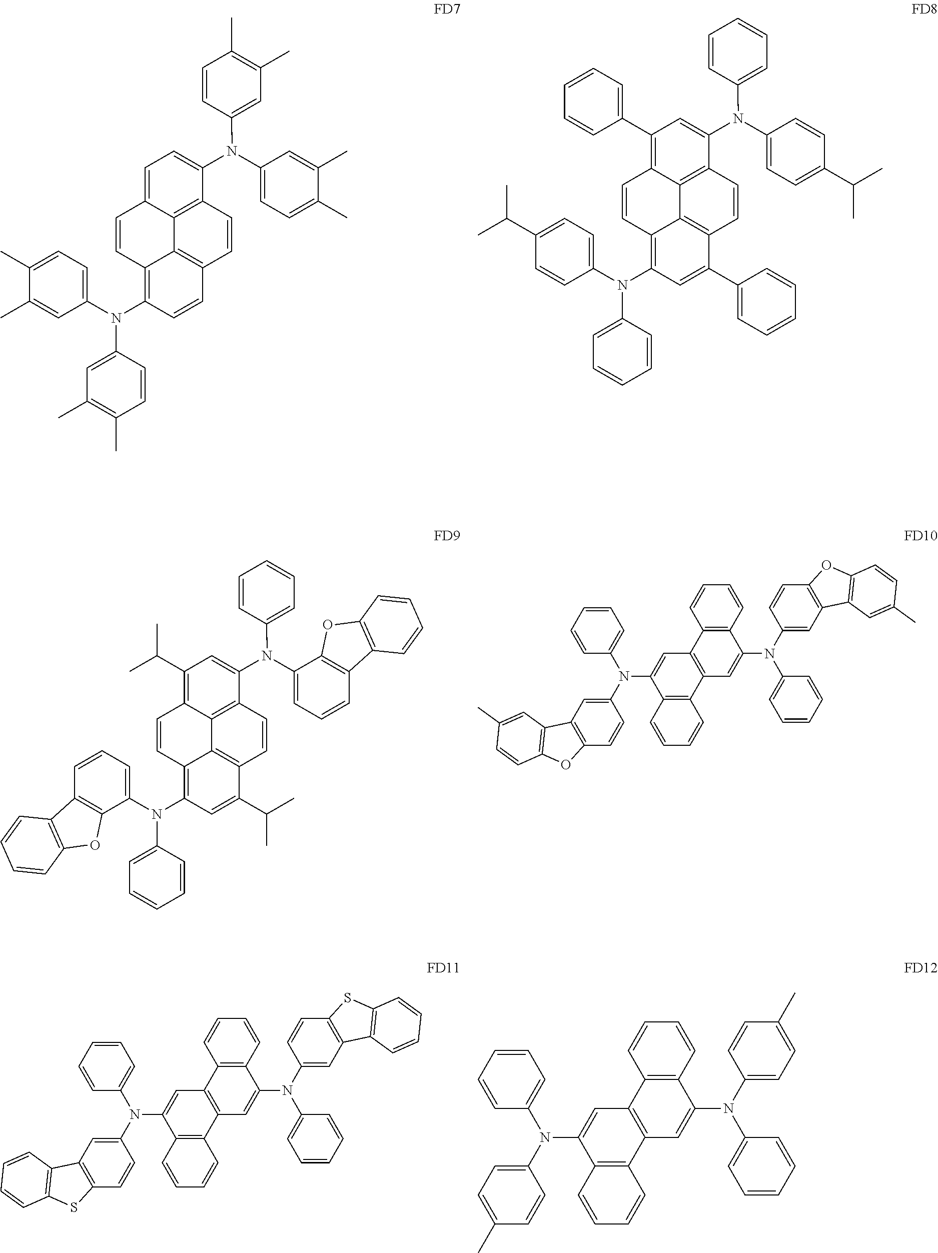

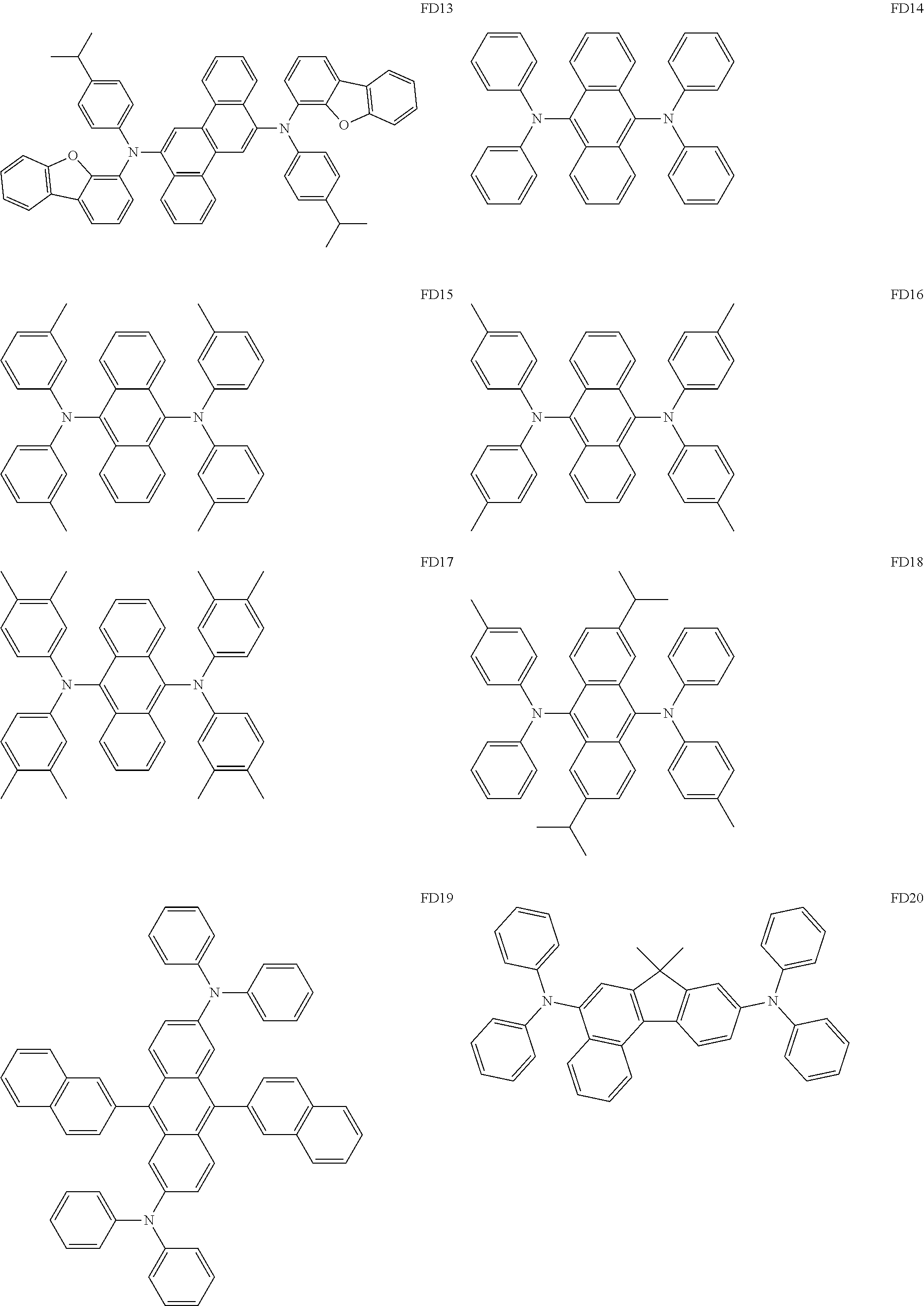

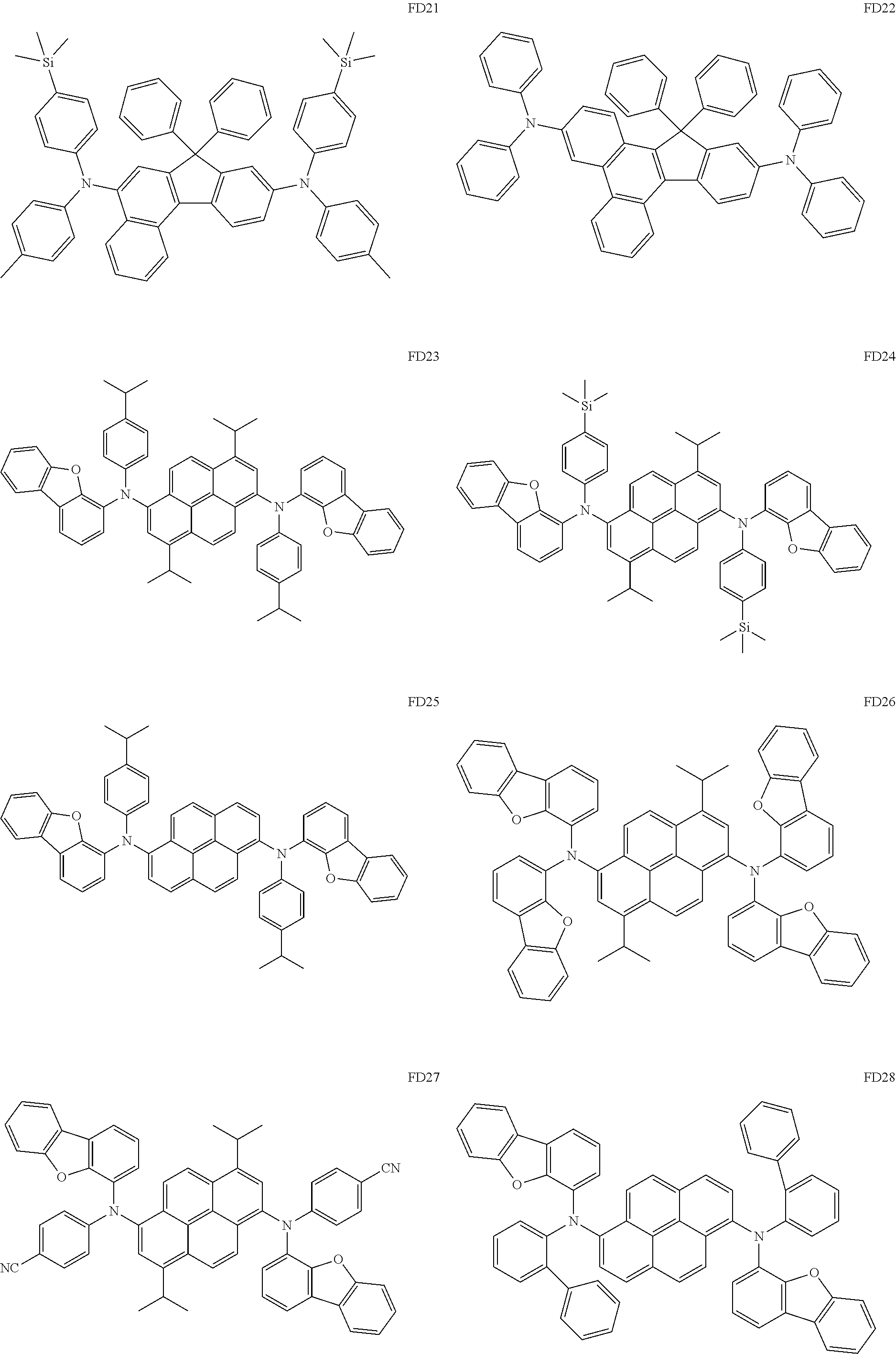

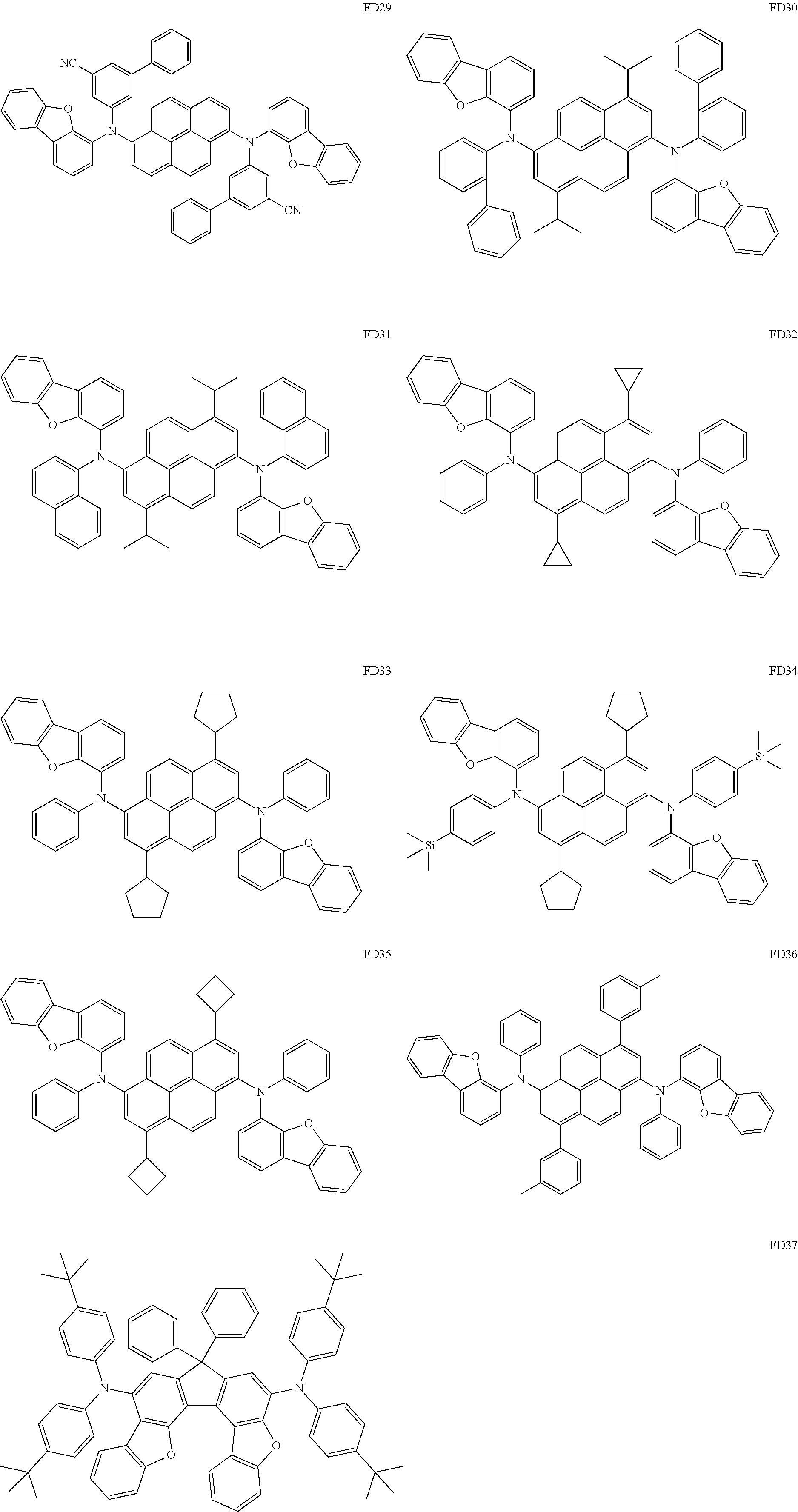

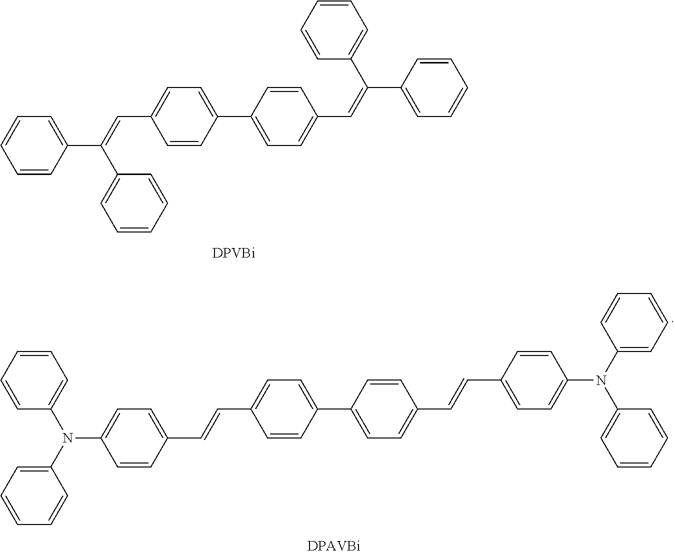

The emission layer may include a delayed fluorescence material.

The delayed fluorescence material described herein may include or consist of compounds capable of emitting delayed fluorescence based on a delayed fluorescence emission mechanism.

The delayed fluorescence material included in the emission layer may act as a host or a dopant, depending on the type of other materials included in the emission layer.

In an embodiment, a difference between a triplet energy level (eV) of the delayed fluorescence material and a singlet energy level (eV) of the delayed fluorescence material may be in a range of about 0 eV to about 0.5 eV. When the difference between the triplet energy level (eV) of the delayed fluorescence material and the singlet energy level (eV) of the delayed fluorescence material is satisfied within the range above, up-conversion from the triplet state to the singlet state of the delayed fluorescence materials may effectively occur, and thus, the light-emitting device 10 may have improved luminescence efficiency.

In an embodiment, the delayed fluorescence material may include i) a material including at least one electron-donating group (e.g., an π electron-rich C₃-C₆₀ cyclic group, such as a carbazole group, etc.) and at least one electron-withdrawing group (e.g., a sulfoxide group, a cyano group, an π electron-deficient nitrogen-containing C₁-C₆₀ cyclic group, etc.), and ii) a material including a C₈-C₆₀ polycyclic group in which two or more cyclic groups are condensed with each other while sharing a B atom, for example.

In an embodiment, the delayed fluorescence material may include at least one of Compounds DF1 to DF14:

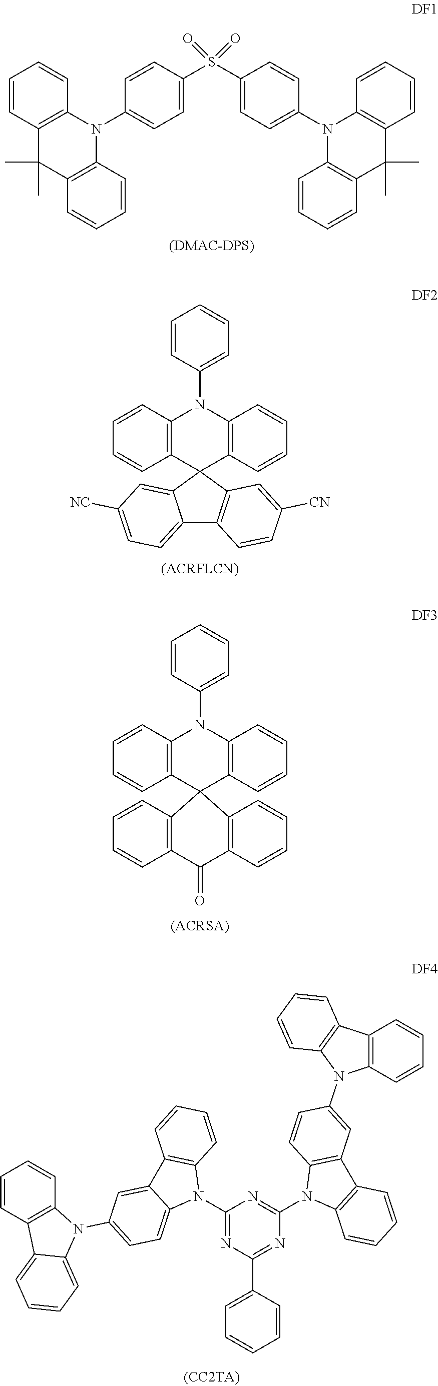

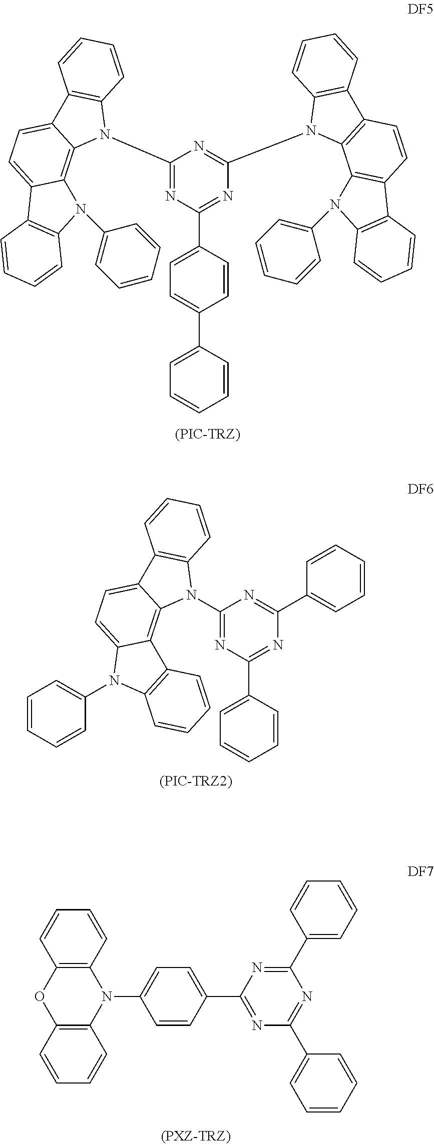 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1]

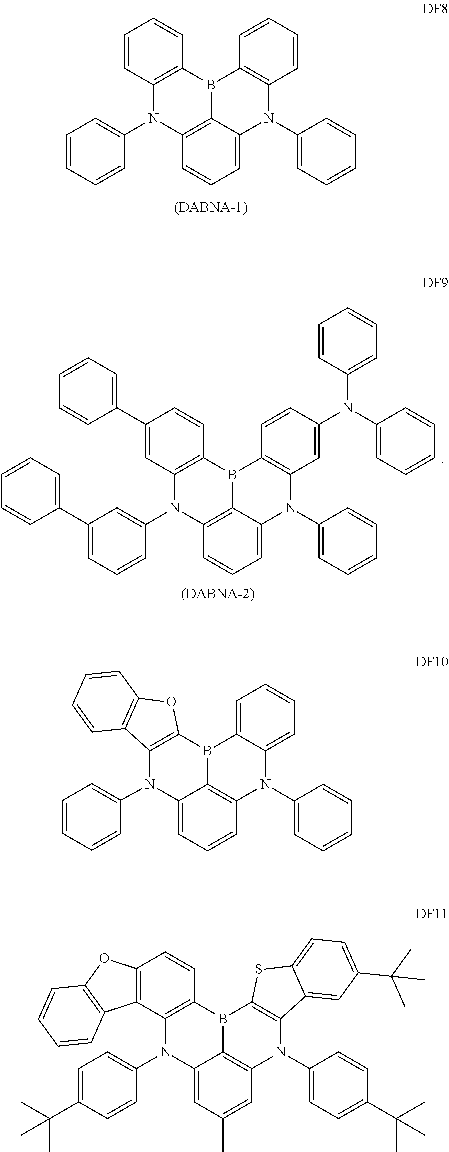

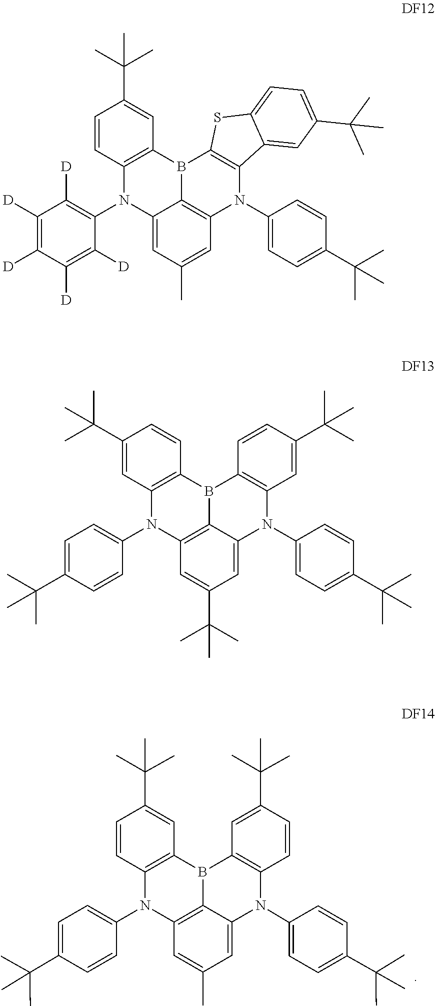

In an embodiment, the emission layer may include the quantum dots. The emission layer may include the quantum dots, and may further include quantum dots different from the aforementioned quantum dots.

In the specification, the quantum dots may refer to crystals of a semiconductor compound. The quantum dots may emit light of various emission wavelengths depending on the size of crystals. The quantum dots may emit light of various emission wavelengths by adjusting a ratio of elements constituting the quantum dots.

A diameter of the quantum dots may be in a range of about 1 nanometer (nm) to about 10 nm, for example

The quantum dots may be synthesized by a wet chemical process, a metal organic chemical vapor deposition (“MOCVD”) process, a molecular beam epitaxy (“MBE”) process, or any process similar thereto.

The wet chemical process is a method including mixing a precursor material with an organic solvent and then growing quantum dot particle crystals. When the crystals grow, the organic solvent naturally acts as a dispersant coordinated on the surface of the quantum dot crystals and controls the growth of the crystals so that the growth of quantum dot particles may be controlled through a process which costs lower and is easier than vapor deposition methods, such as MOCVD or MBE.

The quantum dots may include: semiconductor compounds having Group II-VI elements; semiconductor compounds having Group III-V elements; semiconductor compounds having Group III-VI elements; semiconductor compounds having Group I—III-VI elements; semiconductor compounds having Groups IV-VI elements; Group IV element; semiconductor compounds having Group IV elements; or any combinations thereof.

In an embodiment, the semiconductor compounds having Group II-VI elements may include: a binary compound, such as CdS, CdSe, CdTe, ZnS, ZnSe, ZnTe, ZnO, HgS, HgSe, HgTe, MgSe, MgS, or the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or the like; a quaternary compound, such as CdZnSeS, CdZnSeTe, CdZnSTe, CdHgSeS, CdHgSeTe, CdHgSTe, HgZnSeS, HgZnSeTe, HgZnSTe, or the like; or any combinations thereof.

In an embodiment, the semiconductor compounds having Group III-V elements may include: a binary compound, such as GaN, GaP, GaAs, GaSb, AlN, AIP, AIAs, AISb, InN, InP, InAs, InSb, etc.; a ternary compound, such as GaNP, GaNAs, GaNSb, GaPAs, GaPSb, AlNP, AlNAs, AlNSb, AIPAS, AIPSb, InGaP, InNP, InAIP, InNAs, InNSb, InPAs, InPSb, etc.; a quaternary compound, such as GaAINP, GaAINAs, GaAINSb, GaAIPAs, GaAIPSb, GalnNP, GalnNAs, GalnNSb, GalnPAs, GalnPSb, InAINP, InAINAs, InAINSb, InAIPAs, InAIPSb, etc.; or any combinations thereof. The semiconductor compounds having Group III-V elements may further include Group II elements, and embodiments thereof may include InZnP, InGaZnP, InAIZnP, or the like.

In an embodiment, the semiconductor compounds having Group III-VI elements may include: a binary compound, such as GaS, Ga₂Se₃, GaTe, InS, InSe, In₂S₃, In₂Se₃, InTe, etc.; a ternary compound, such as InGaS₃, InGaSe₃, etc.; or any combinations thereof.

In an embodiment, the semiconductor compounds having Group I—III-VI elements may include: a ternary compound, such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAIO₂, etc.; a quaternary compound, such as CuInGaS, CuInGaS₂, AgInGaS, AglnGaS₂, AgInGaSe, AglnGaSe₂, etc.; or any combinations thereof.

In an embodiment, the semiconductor compounds having Group IV-VI elements may include: a binary compound, such as SnS, SnSe, SnTe, PbS, PbSe, or PbTe; a ternary compound, such as SnSeS, SnSeTe, SnSTe, PbSeS, PbSeTe, PbSTe, SnPbS, SnPbSe, SnPbTe, etc.; a quaternary compound, such as SnPbSSe, SnPbSeTe, SnPbSTe, etc.; or any combinations thereof.

The Group IV element and the compounds having Group IV elements may include: a single element, such as Si, Ge, etc.; a binary compound, such as SiC, SiGe, etc.; or any combinations thereof.

Each element included in a multi-element compound, such as the binary compound, the ternary compound, and the quaternary compound, may be at a uniform concentration or non-uniform concentration in a particle. That is, the formulae above refer to types of elements included in the compound, and the element ratios within the compound may vary. In an embodiment, AgInGaS₂ may refer to AgInxGa₁₋ₓS₂ (where x is a real number satisfying 0<x<1), for example.

In an embodiment, the quantum dots may have a single structure in which the concentration of each element in the quantum dots is uniform, or a core-shell dual structure. In an embodiment, materials included in the core and materials included in the shell may be different from each other, for example.

The shell of the quantum dots may act as a protective layer that prevents chemical degeneration of the core to maintain semiconductor characteristics, and/or as a charging layer that imparts electrophoretic characteristics to the quantum dots. The shell may be single-layered or multi-layered. The interface between the core and the shell may have a concentration gradient in which the concentration of an element existing in the shell decreases toward the center of the core.

In an embodiment, the shell of the quantum dots may include: an oxide of metal or non-metal; a semiconductor compound: or any combinations thereof. In an embodiment, the oxide of metal or non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, etc.; a ternary compound, such as MgAl₂O₄, CoFe₂O₄, NiFe₂O₄, CoMn₂O₄, etc.; or any combinations thereof. In an embodiment, the semiconductor compounds may include, as described herein, semiconductor compounds having Group III-VI elements, semiconductor compounds having Group II-VI elements, semiconductor compounds having Group III-V elements, semiconductor compounds having Group I—III-VI elements, semiconductor compounds having Group IV-VI elements, semiconductor compounds having Group VI elements, or any combinations thereof. In an embodiment, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AIP, AISb, or any combinations thereof, for example.

A full width of half maximum (“FWHM”) of an emission wavelength spectrum of the quantum dots may be about 45 nm or less, e.g., about 40 nm or less, and for example, about 30 nm or less, and within these ranges, the color purity and/or color reproducibility of the quantum dots may be improved. In addition, since light emitted through the quantum dots is emitted in all directions, the wide viewing angle may be improved.

In addition, the quantum dots may be nanoparticles, nanotubes, nanowires, nanofibers, nanoplates, or the like, specifically in the form of spherical particles, pyramidal particles, multi-arm particles, or cubic particles.

Since the energy band gap may be controlled by adjusting the size of the quantum dots or the ratio of elements in the quantum dot compound, light of various wavelengths may be obtained from the quantum dot-containing emission layer. Therefore, by the aforementioned quantum dots (using quantum dots of different sizes or having different element ratios in the quantum dot compound), a light-emitting device emitting light of various wavelengths may be implemented. In detail, the control of the size of the quantum dots or the ratio of elements in the quantum dot compound may be selected to emit red light, green light, and/or blue light. In addition, the size of the quantum dots may be adjusted to emit white light by combination of light of various colors.

The electron transport region may have: i) a single-layer structure including or consisting of a single layer including or consisting of a single material, ii) a single-layer structure including or consisting of a single layer including or consisting of multiple materials that are different from each other, or iii) a multi-layer structure including multiple layers including multiple materials that are different from each other.

The electron transport region may include a buffer layer, a hole blocking layer, an electron control layer, an electron transport layer, an electron injection layer, or any combinations thereof.

In an embodiment, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, where constituent layers in each structure may be sequentially stacked from the emission layer, for example.

In an embodiment, the electron transport region (e.g., the buffer layer, the hole blocking layer, the electron control layer, or the electron transport layer in the electron transport region) may include a metal-free compound including at least one IT electron-deficient nitrogen-containing C₁-C₆₀ cyclic group.

In an embodiment, the electron transport region may include a compound represented by Formula 601, for example:

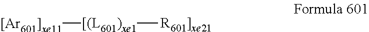

where, in Formula 601,
Ar₆₀₁ and L₆₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each be the same as described in connection with Q₁,
xe21 may be 1, 2, 3, 4, or 5, and
at least one of Ar₆₀₁, L₆₀₁, and R₆₀₁ may each independently be an π electron-deficient nitrogen-containing C₁-C₆₀ cyclic group unsubstituted or substituted with at least one R₁₀ₐ.

In an embodiment, when xe11 in Formula 601 is 2 or more, two or more of Ar₆₀₁ may be linked to each other via a single bond, for example.

In an embodiment, Ar₆₀₁ in Formula 601 may be an anthracene group that is unsubstituted or substituted with at least one R₁₀ₐ.

In an embodiment, the electron transport region may include a compound represented by Formula 601-1:

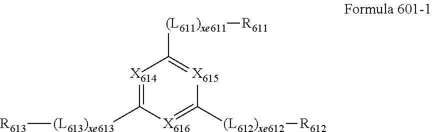

where, in Formula 601-1,
X₆₁₄ may be N or C(R₆₁₄), X₆₁₅ may be N or C(R₆₁₅), and X₆₁₆ may be N or C(R₆₁₆), where at least one of X₆₁₄ to X₆₁₆ may be N,
L₆₁₁ to L₆₁₃ may each be the same as described in connection with L₆₀₁,
xe611 to xe613 may each be the same as described in connection with xe1,
R₆₁₁ to R⁶¹³ may each be the same as described in connection with R₆₀₁, and
R₆₁₄ to R⁶¹⁶ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In an embodiment, xe1 and xe611 to xe613 in Formulae 601 and 601-1 may each independently be 0, 1, or 2.

In an embodiment, the electron transport region may include: one of Compounds ET1 to ET45; 2,9-dimethyl-4,7-diphenyl-1,10-phenanthroline (“BCP”); 4,7-diphenyl-1,10-phenanthroline (“Bphen”); Alq₃; BAIq; TAZ; NTAZ; or any combinations thereof:

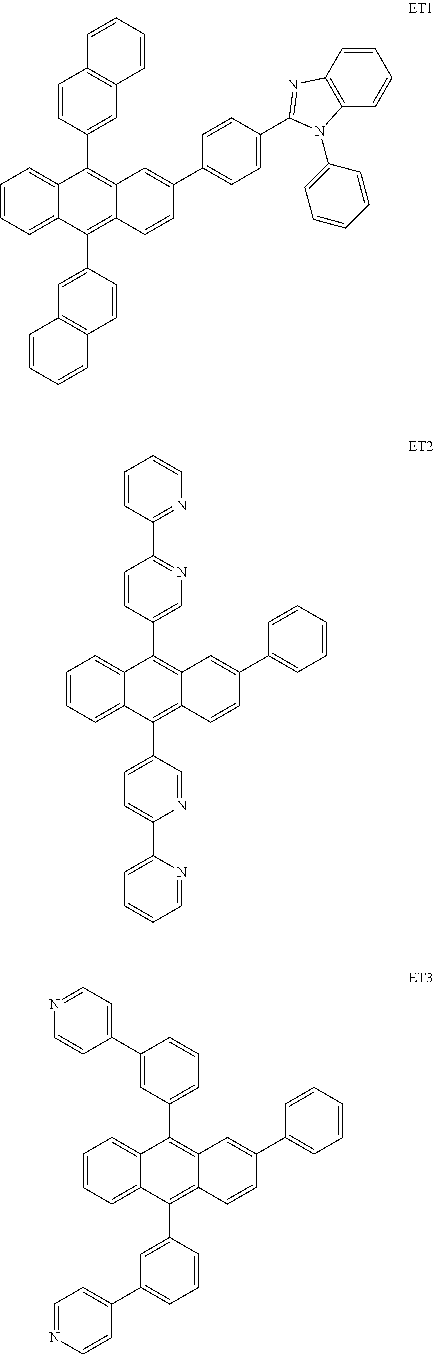 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

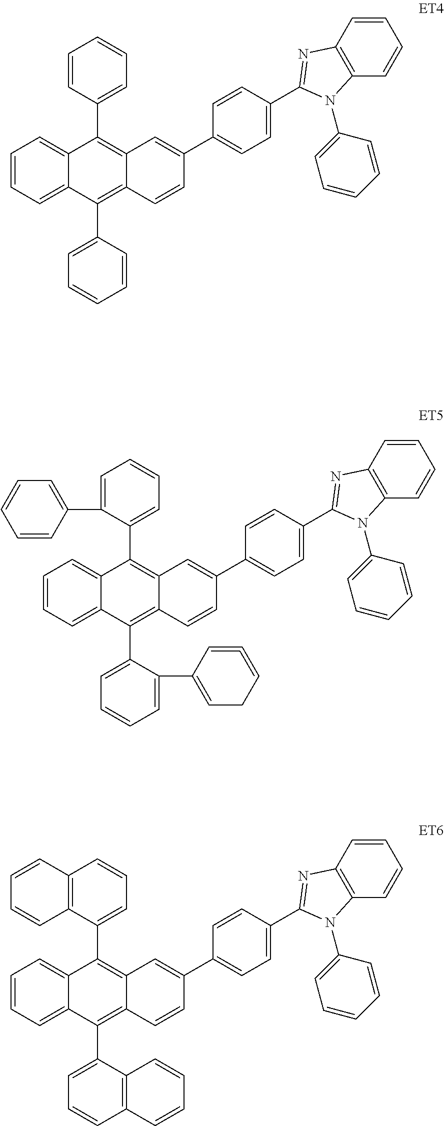 [SMILES: c1ccc(-c2c3ccccc3c(-c3ccccc3)c3cc(-c4ccc(-c5nc6ccccc6n5-c5ccccc5)cc4)ccc23)cc1 ; C1=CCC=C(c2ccccc2-c2c3ccccc3c(-c3ccccc3-c3ccccc3)c3cc(-c4ccc(-c5nc6ccccc6n5-c5ccccc5)cc4)ccc23)C=1 ; c1ccc(-n2c(-c3ccc(-c4ccc5c(-c6cccc7ccccc67)c6ccccc6c(-c6cccc7ccccc67)c5c4)cc3)nc3ccccc32)cc1]

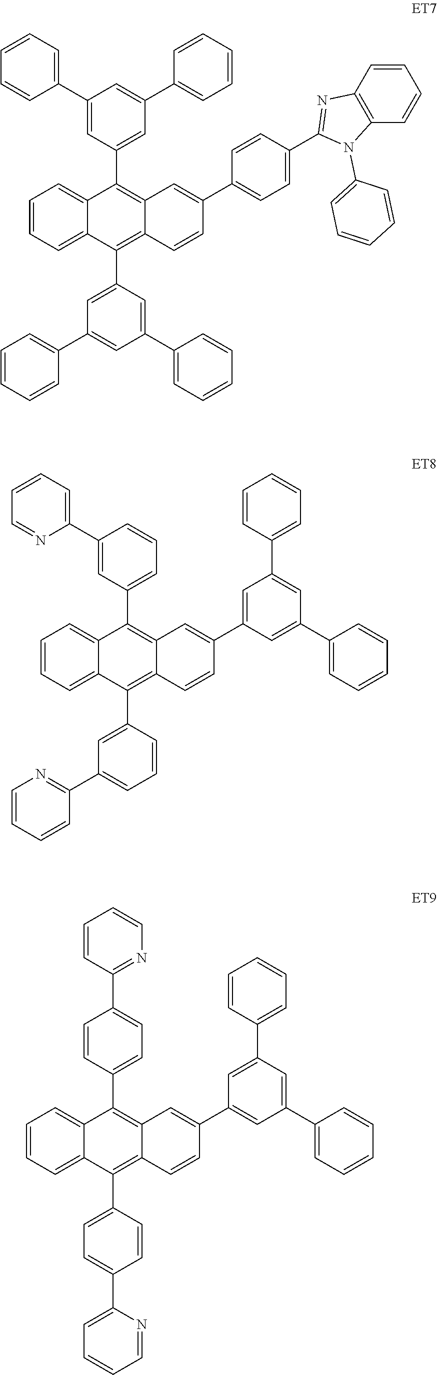 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

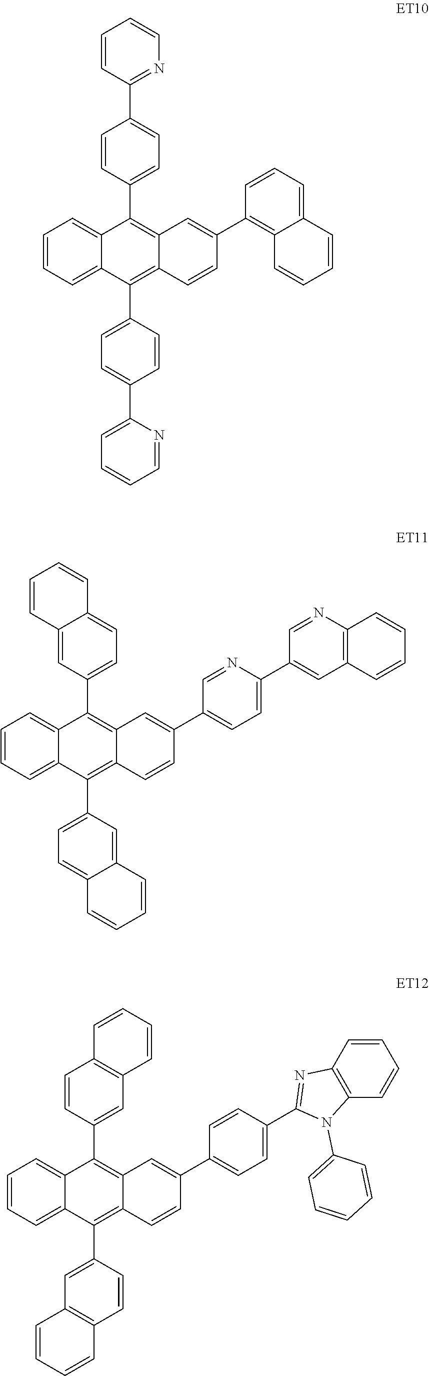 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1]

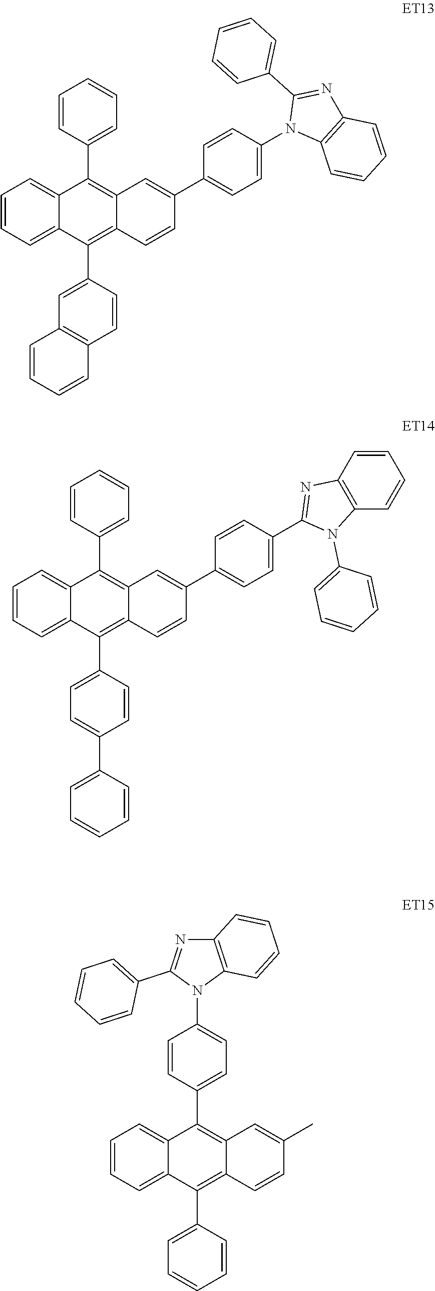 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5ccc(-c6nc7ccccc7n6-c6ccccc6)cc5)ccc34)cc2)cc1 ; Cc1ccc2c(-c3ccccc3)c3ccccc3c(-c3ccc(-n4c(-c5ccccc5)nc5ccccc54)cc3)c2c1]

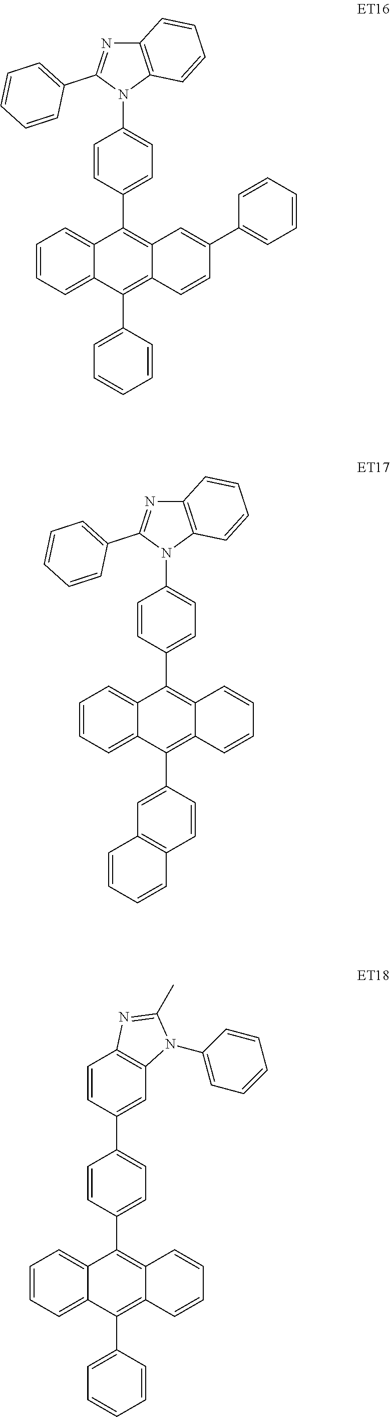 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

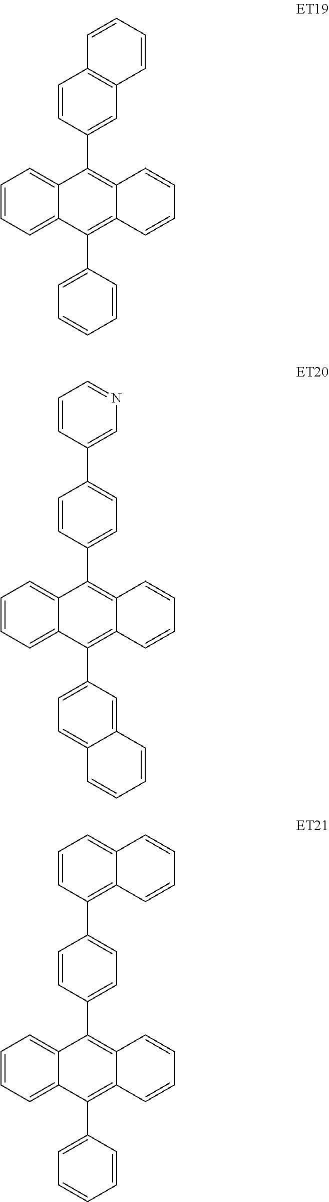

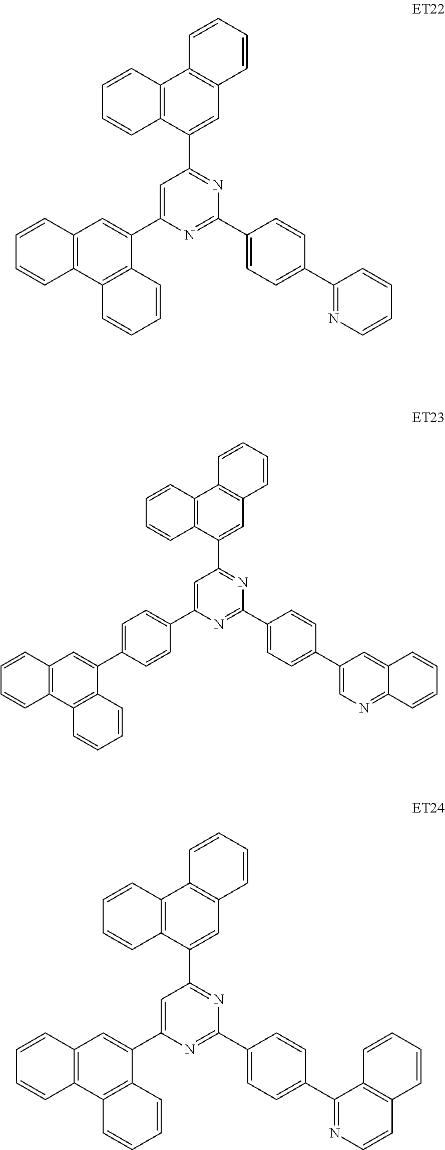 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

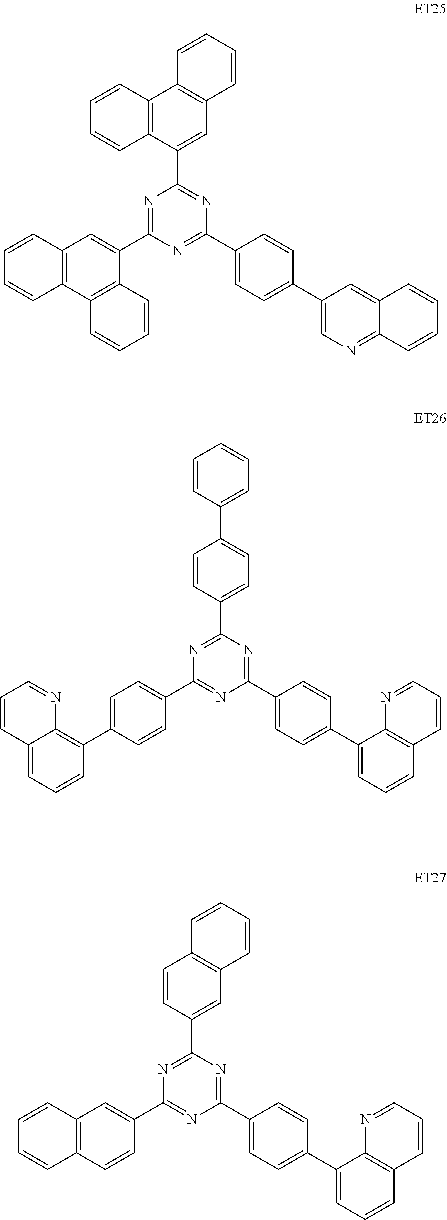 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

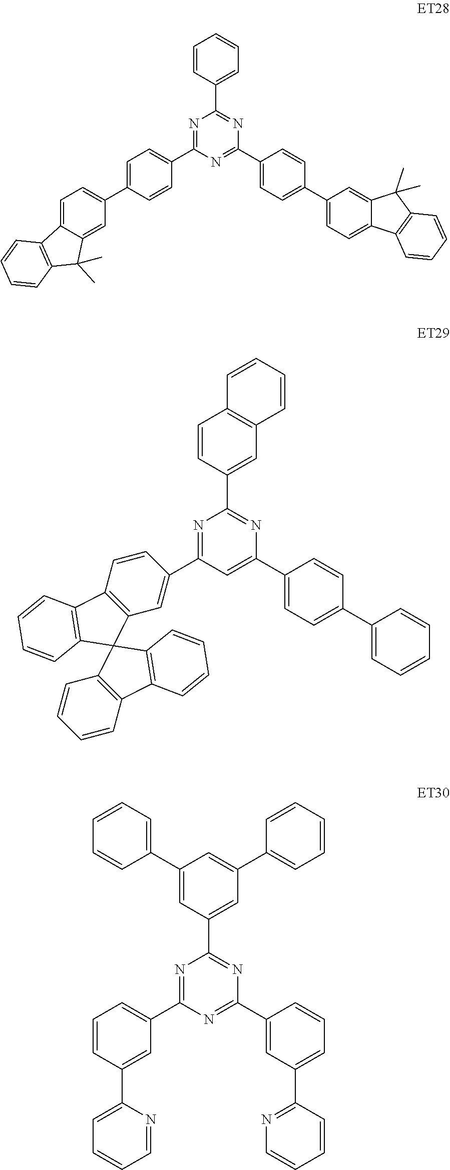 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

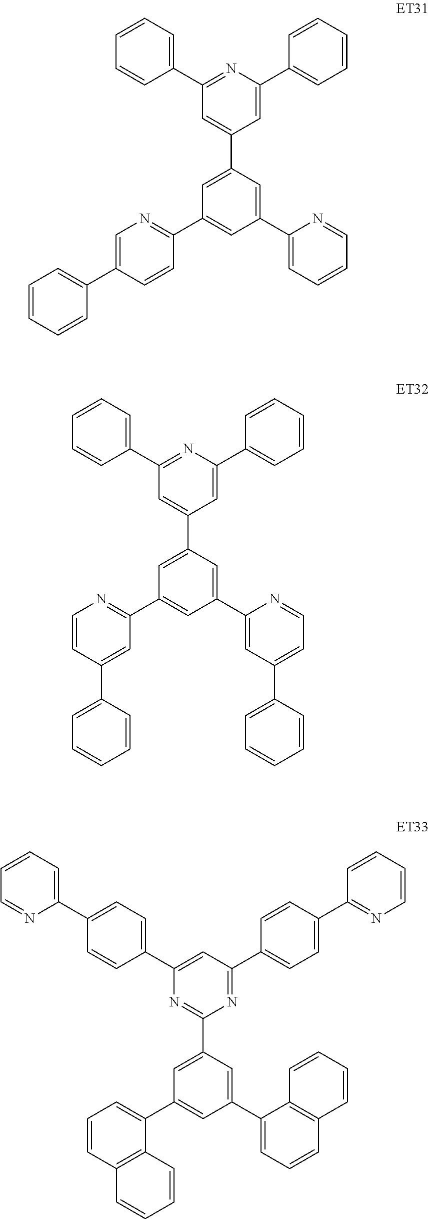 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

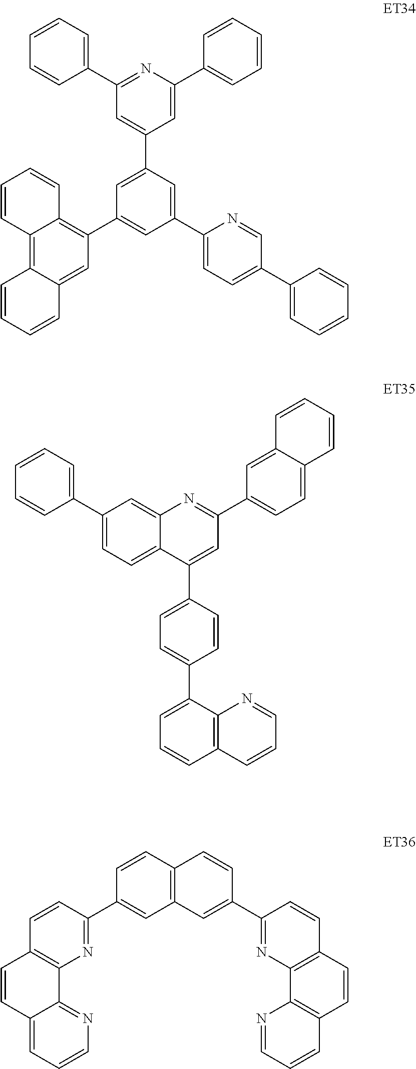 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

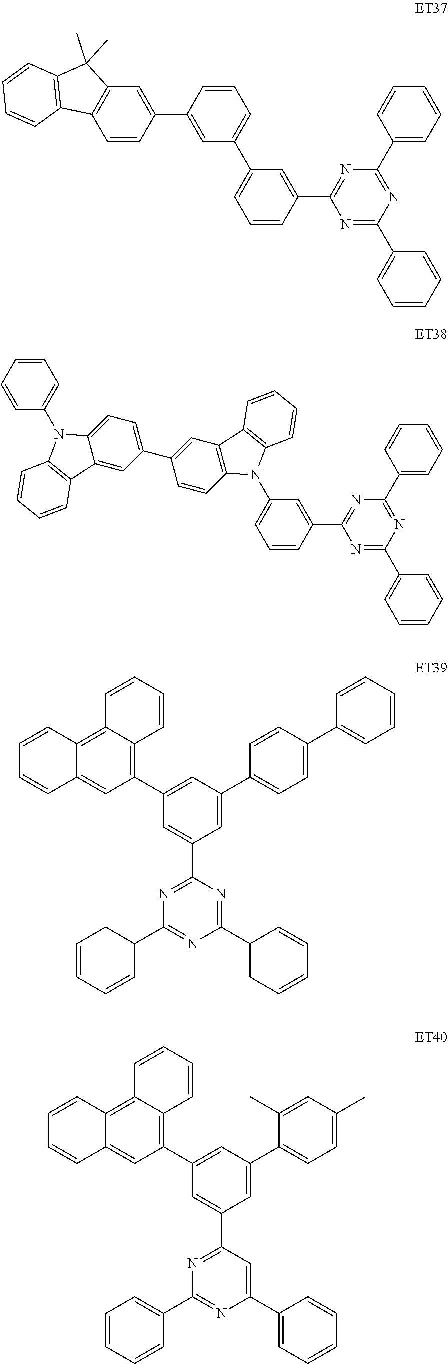 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; C1=CCC(c2nc(-c3cc(-c4ccc(-c5ccccc5)cc4)cc(-c4cc5ccccc5c5ccccc45)c3)nc(C3C=CC=CC3)n2)C=C1 ; Cc1ccc(-c2cc(-c3cc(-c4ccccc4)nc(-c4ccccc4)n3)cc(-c3cc4ccccc4c4ccccc34)c2)c(C)c1]

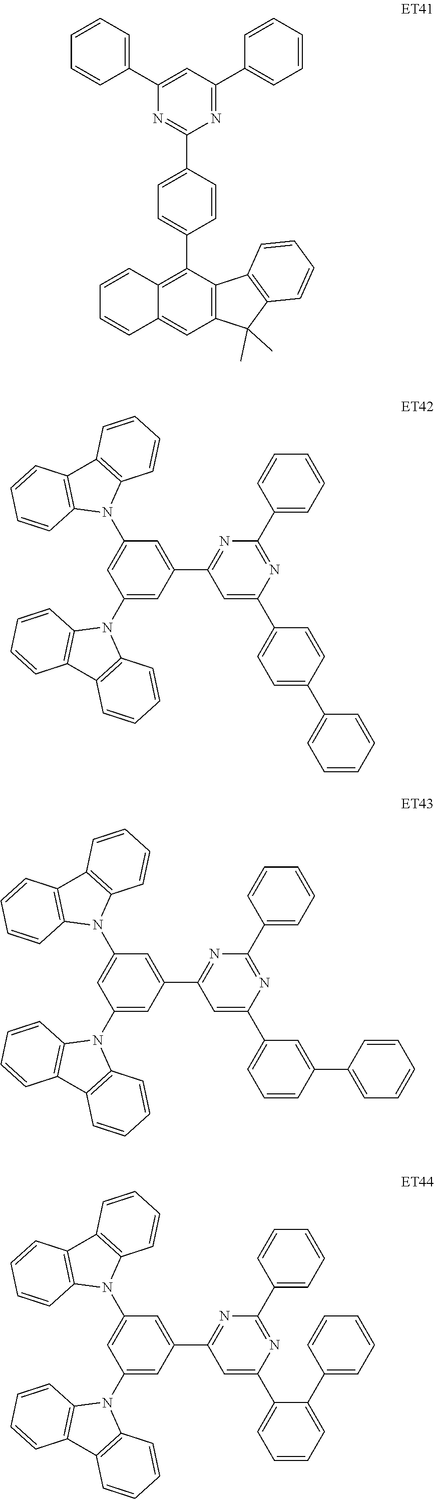 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1]

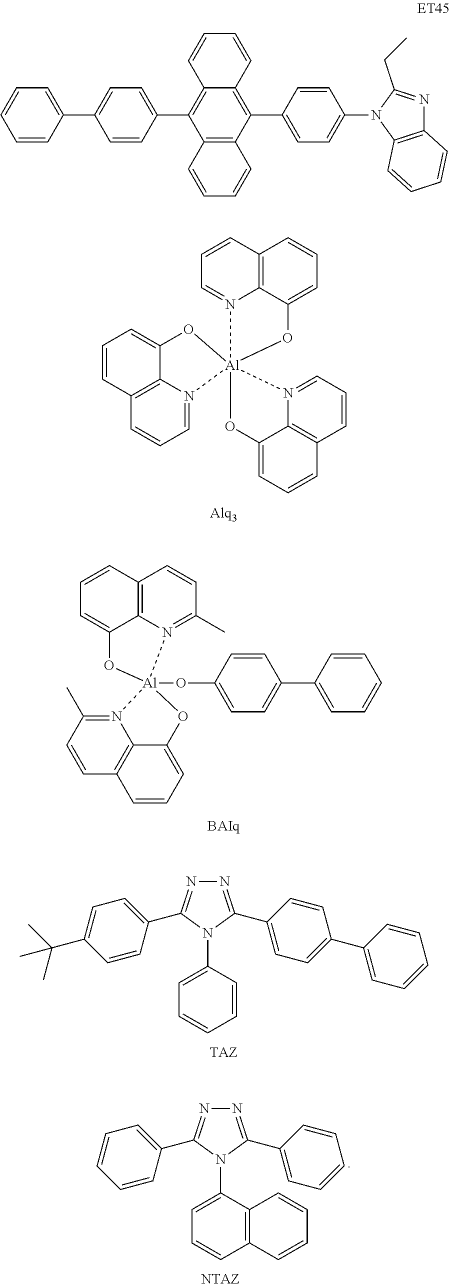

A thickness of the electron transport region may be in a range of about 100 Å to about 5,000 Å, e.g., about 160 Å to about 4,000 Å. When the electron transport region includes a buffer layer, a hole blocking layer, an electron control layer, an electron transport layer, or any combinations thereof, a thickness of the buffer layer, the hole blocking layer, or the electron control layer may each independently be in a range of about 20 Å to about 1,000 Å, e.g., about 30 Å to about 300 Å, and a thickness of the electron transport layer may be in a range of about 100 Å to about 1,000 Å, e.g., about 150 Å to about 500 Å. When the thicknesses of the buffer layer, the hole blocking layer, the electron control layer, the electron transport layer, and/or the electron transport region are within these ranges, satisfactory electron transporting characteristics may be obtained without a substantial increase in driving voltage.

The electron transport region (e.g., an electron transport layer in the electron transport region) may further include, in addition to the aforementioned materials, a metal-containing material.

The metal-containing material may include an alkali metal complex, an alkaline earth metal complex, or any combinations thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the metal ion of the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combinations thereof.

In an embodiment, the metal-containing material may include a Li complex, for example. The Li complex may include Compound ET-D1 (Liq) or ET-D2, for example:

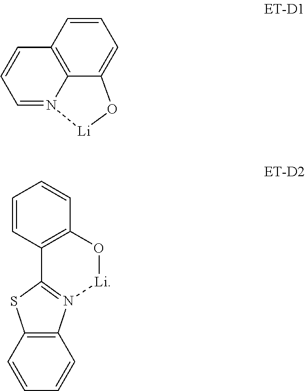

The electron transport region may include an electron injection layer that facilitates the injection of electrons from the second electrode 150. The electron injection layer may be in direct contact with the second electrode 150.

The electron injection layer may have: i) a single-layer structure consisting of a single layer consisting of a single material, ii) a single-layer structure consisting of a single layer consisting of multiple layers that are different from each other, or iii) a multi-layer structure including multiple layers including multiple materials that are different from each other.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combinations thereof.

The alkali metal may include Li, Na, K, Rb, Cs, or any combinations thereof. The alkaline earth metal may include Mg, Ca, Sr, Ba, or any combinations thereof. The rare earth metal may include Sc, Y, Ce, Tb, Yb, Gd, or any combinations thereof.

The alkali metal-containing compound, the alkaline earth metal-containing compound, and the rare earth metal-containing compound may be oxides, halides (e.g., fluorides, chlorides, bromides, or iodides), or tellurides of the alkali metal, the alkaline earth metal, and the rare earth metal, or any combinations thereof.

The alkali metal-containing compound may include: an alkali metal oxide, such as Li₂O, Cs₂O, K₂O, or the like; alkali metal halides, such as LiF, NaF, CsF, KF, Lil, Nal, Csl, KI, or the like; or any combinations thereof. The alkaline earth metal-containing compound may include an alkaline earth metal compound, such as BaO, SrO, CaO, BaₓSr₁₋ₓO (where x is a real number satisfying 0<x<1), BaₓCa₁₋ₓO (where x is a real number satisfying 0<x<1), or the like. The rare earth metal-containing compound may include YbF₃, ScF₃, Sc₂O₃, Y₂O₃, Ce₂O₃, GdF₃, TbF₃, Ybl₃, Scl₃, Tbl₃, or any combinations thereof. In an embodiment, the rare earth metal-containing compound may include lanthanide metal telluride. In an embodiment, the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂ Te₃, Ce₂Te₃, Pr₂Te₃, Nd₂Te₃, Pm₂Te₃, Sm₂Tes, Eu₂Tes, Gd₂Te₃, Tb₂Te₃, Dy₂Te₃, HO₂Te₃, Er₂Te₃, Tm₂Te₃, Yb₂Te₃, Lu₂Te₃, or the like.

The alkali metal complex, the alkaline earth-metal complex, and the rare earth metal complex may include i) one of metal ions of the alkali metal, the alkaline earth metal, and the rare earth metal, and ii) as a ligand bonded to the metal ions, e.g., a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combinations thereof.

In an embodiment, the electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combinations thereof, as described above. In an embodiment, the electron injection layer may further include an organic material (e.g., the compound represented by Formula 601).

In an embodiment, the electron injection layer may consist of i) an alkali metal-containing compound (e.g., an alkali metal halide), or ii) a) an alkali metal-containing compound (e.g., an alkali metal halide), and b) an alkali metal, an alkaline earth metal, a rare earth metal, or any combinations thereof. In an embodiment, the electron injection layer may be a KI: Yb co-deposited layer, an Rbl: Yb co-deposited layer, a LiF: Yb co-deposited layer, or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combinations thereof may be uniformly or non-uniformly dispersed in a matrix including the organic material.

A thickness of the electron injection layer may be in a range of about 1 Å to about 100 Å, and, for example, about 3 Å to about 90 Å. When the thickness of the electron injection layer is within these ranges, satisfactory electron injection characteristics may be obtained without a substantial increase in driving voltage.

The second electrode 150 may be arranged on the electron transport region. The second electrode 150 may be a cathode, which is an electron injection electrode, and as a material for forming the second electrode 150, a metal, an alloy, an electrically conductive compound, or any combinations thereof, each having a low-work function, may be used.

The second electrode 150 may include Li, Ag, Mg, Al, Al—Li, Ca, Mg—In, Mg—Ag, Yb, Ag—Yb, ITO, IZO, or any combinations thereof. The second electrode 150 may be a transmissive electrode, a semi-transmissive electrode, or a reflective electrode.

The second electrode 150 may have a single-layer structure or a multi-layer structure including multiple layers.

Although not shown in FIG. 1, the light-emitting device 10 may further include a capping layer arranged outside the first electrode 110 and/or outside the second electrode 150.

In an embodiment, the light-emitting device 10 may further include a first capping layer arranged outside the first electrode 110. In an embodiment, the light-emitting device 10 may further include a second capping layer arranged outside the second electrode 150. In an embodiment, the light-emitting device 10 may further include both a first capping layer arranged outside the first electrode 110 and a second capping layer arranged outside the second electrode 150.

Light generated in the emission layer of the interlayer 130 of the light-emitting device 10 may be extracted toward the outside through the first electrode 110, which is a semi-transmissive electrode or a transmissive electrode, and the first capping layer. Light generated in the emission layer of the interlayer 130 of the light-emitting device 10 may be extracted toward the outside through the second electrode 150, which is a semi-transmissive electrode or a transmissive electrode, and the second capping layer.

The first capping layer and the second capping layer may serve to increase external emission efficiency according to the principle of constructive interference. Accordingly, the light extraction efficiency of the light-emitting device 10 may be increased, and accordingly, the luminescence efficiency of the light-emitting device 10 may be improved.

Each of the first capping layer and the second capping layer may include a material having a refractive index of about 1.2 or more (at a wavelength of 550 nm).

The first capping layer and the second capping layer may each independently be an organic capping layer including organic materials, an inorganic capping layer including inorganic materials, or an organic-inorganic composite capping layer including organic materials and inorganic materials.

At least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combinations thereof. The carbocyclic compound, the heterocyclic compound, and the amine group-containing compound may optionally be substituted with a substituent including O, N, S, Se, Si, F, Cl, Br, I, or any combinations thereof. In an embodiment, at least one of the first capping layer and the second capping layer may each independently include an amine group-containing compound.

In an embodiment, at least one of the first capping layer and the second capping layer may each independently include the compound represented by Formula 201, the compound represented by Formula 202, or any combinations thereof.

In an embodiment, at least one of the first capping layer and the second capping layer may each independently include one of Compounds HT28 to HT33, one of Compounds CP1 to CP6, β-NPB, or any combinations thereof:

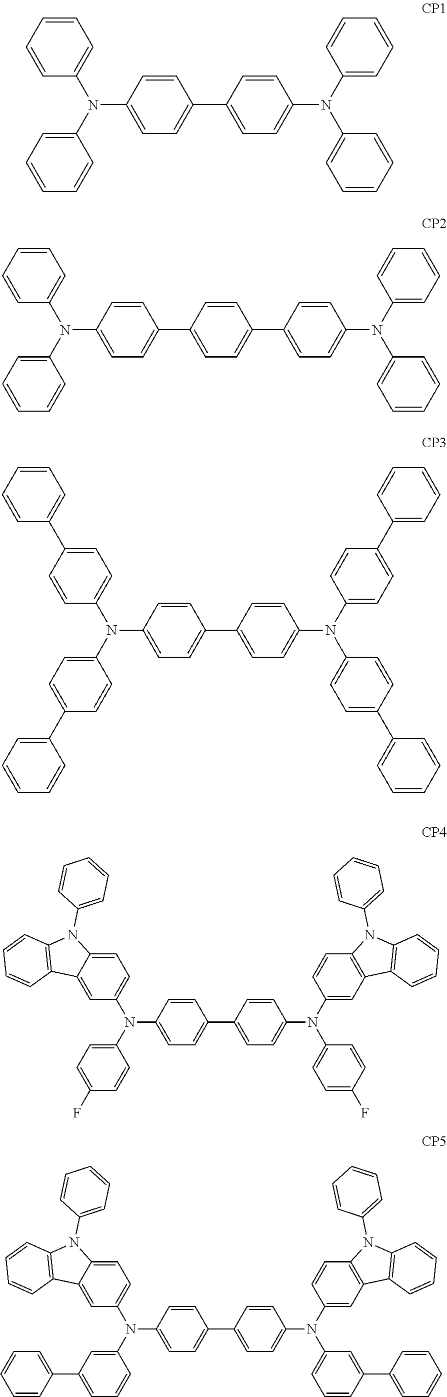 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

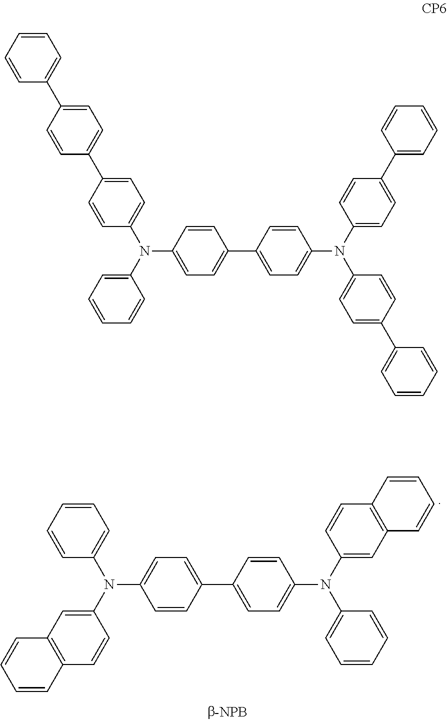 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

FIG. 2 is a view of an embodiment of the interlayer 130 included in the light-emitting device 10 of FIG. 1.

Referring to FIG. 2, an interlayer 130_1 may include a first stack ST1, a second stack ST2 arranged on the first stack ST1, and a charge generation layer CGL arranged between the first stack ST1 and the second stack ST2. The first stack ST1 may include a first hole transport region, a first emission layer, and a first electron transport region that are sequentially stacked from the first electrode 110. The second stack ST2 may include a second hole transport region 131-2, a second emission layer 133-2, and a second electron transport region 135-2 that are sequentially stacked from the first electrode 110. Although not shown in FIG. 2, the charge generation layer CGL may include an n-type charge generation layer adjacent to the first electrode and a p-type charge generation layer adjacent to the second electrode 150. In an embodiment, the n-type charge generation layer may be adjacent to the first stack ST1, and the p-type charge generation layer may be adjacent to the second stack ST2 and arranged on the n-type charge generation layer, for example.

In an embodiment, the second hole transport region 131-2 may include at least one first compound represented by Formula 1, and the charge generation layer CGL may include at least one second compound represented by Formula 2.

In an embodiment, the second hole transport region 131-2 and the charge generation layer CGL may be in direct contact with each other. The second hole transport region 131-2 may include the hole transport layer, the charge generation layer CGL may include the p-type charge generation layer, and the hole transport layer and the p-type charge generation layer may be in direct contact with each other. FIG. 2 illustrates an interlayer 130_1 including two stacks (ST1 and ST2), but the interlayer 130 in an embodiment may include three or more stacks. Hereinafter, the interlayer 130 including three or more stacks will be described.

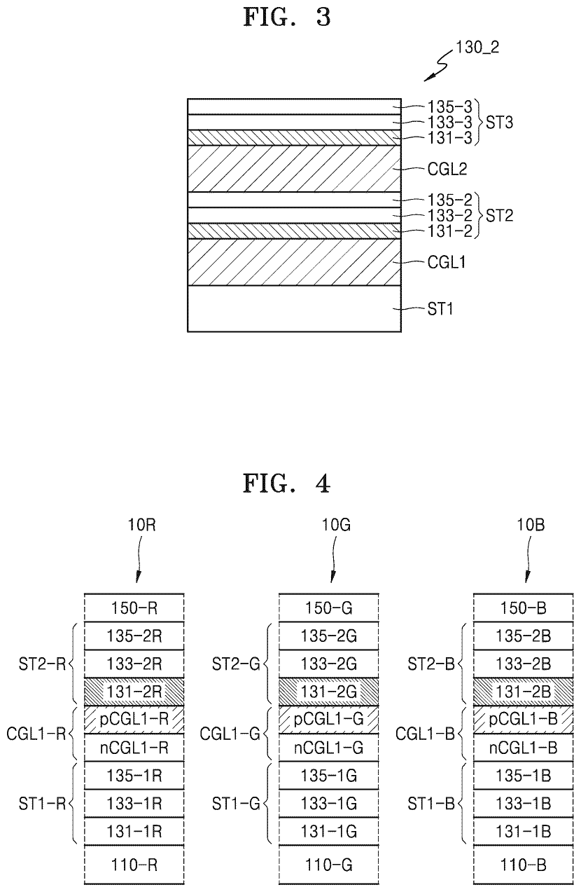

FIG. 3 is a view of another embodiment of the interlayer 130 included in the light-emitting device 10 of FIG. 1.

Referring to FIG. 3, an interlayer 130_2 may include a first stack ST1, a second stack ST2 arranged on the first stack ST1, a first charge generation layer CGL1 between the first stack ST1 and the second stack ST2, a third stack ST3 arranged on the second stack ST2, and a second charge generation layer CGL2 arranged between the second stack ST2 and the third stack ST3. The first stack ST1, the second stack ST2, and the first charge generation layer CGL1 may be referred to those described in FIG. 2.

The third stack ST3 may include a third hole transport region 131-3, a third emission layer 133-3, and a third electron transport region 135-3 that are sequentially stacked from the first electrode 110. The third hole transport region 131-3 may be arranged on the second electron transport region 135-2 and the second charge generation layer CGL2. The third emission layer 133-3 may be arranged on the third hole transport region 131-3. The third electron transport region 135-3 may be arranged on the third emission layer 133-3.

The first charge generation layer CGL1 may include a first n-type charge generation layer and a first p-type charge generation layer arranged on the first n-type charge generation layer.

The second charge generation layer CGL2 may include a second n-type charge generation layer and a second p-type charge generation layer arranged on the second n-type charge generation layer.

In an embodiment, the second hole transport region 131-2 may include at least one first compound represented by Formula 1, and the first charge generation layer CGL1 may include at least one second compound represented by Formula 2. In an embodiment, the hole transport layer included in the second hole transport region 131-2 may include the first compound, and the p-type charge generation layer included in the first charge generation layer CGL1 may include the second compound, for example.

In an embodiment, the second hole transport region 131-2 and the first charge generation layer CGL1 may be in direct contact with each other. In an embodiment, the second hole transport region 131-2 may include a second hole transport layer, the first charge generation layer CGL1 may include a first p-type charge generation layer, and the second hole transport layer and the first p-type charge generation layer may be in direct contact with each other, for example.

In an embodiment, the third hole transport region 131-3 may include at least one first compound represented by Formula 1, and the second charge generation layer CGL2 may include at least one second compound represented by Formula 2. In an embodiment, the hole transport layer included in the third hole transport region 131-3 may include the first compound, and the p-type charge generation layer included in the second charge generation layer CGL2 may include the second compound, for example.

In an embodiment, the third hole transport region 131-3 and the second charge generation layer CGL2 may be in direct contact with each other. In an embodiment, the third hole transport region 131-3 may include a third hole transport layer, the second charge generation layer CGL2 may include a second p-type charge generation layer, and the third hole transport layer and the second p-type charge generation layer may be in direct contact with each other, for example.

In an embodiment, each of the second hole transport region 131-2 and the third hole transport region 131-3 may include at least one first compound represented by Formula 1, and each of the first charge generation layer CGL1 and the second charge generation layer CGL2 may include at least one second compound represented by Formula 2.

FIG. 3 illustrates an interlayer 130_2 including three stacks (ST1, ST2, and ST3), but the interlayer 130 in an embodiment may include four or more stacks.

FIG. 4 is a schematic view of a plurality of light-emitting devices included in a display apparatus.

Referring to FIG. 4, a display apparatus may include a first light-emitting device 10R, a second light-emitting device 10G, and a third light-emitting device 10B. Each of the first light-emitting device 10R, the second light-emitting device 10G, and the third light-emitting device 10B may be arranged on the substrate, the first light-emitting device 10R may be disposed in a first region of the substrate, the second light-emitting device 10G may be disposed in a second region of the substrate, and the third light-emitting device 10B may be disposed in a third region of the substrate.

The first light-emitting device 10R may include a first-1 electrode 110-R, a first-2 electrode 150-R facing the first-1 electrode 110-R, and a first interlayer arranged between the first-1 electrode 110-R and the first-2 electrode 150-R. FIG. 4 illustrates an embodiment in which the first light-emitting device 10R includes two stacks, but the first light-emitting device 10R may include three or more stacks as shown in FIG. 3. The first interlayer may include a first-1 stack ST1-R, a first-2 stack ST2-R, and a first charge generation layer CGL1-R arranged between the first-1 stack ST1-R and the first-2 stack ST2-R.

The first-1 stack ST1-R may include a first-1 hole transport region 131-1R, a first-1 emission layer 133-1R, and a first-1 electron transport region 135-1R that are sequentially arranged on the first-1 electrode 110-R.

The first charge generation layer CGL1-R may include a first n-type charge generation layer nCGL1-R and a first p-type charge generation layer pCGL1-R.

The first-2 stack ST2-R may include a first-2 hole transport region 131-2R, a first-2 emission layer 133-2R, and a first-2 electron transport region 135-2R that are sequentially arranged on the first-1 electrode 110-R.

The second light-emitting device 10G may include a second-1 electrode 110-G, a second-2 electrode 150-G facing the second-1 electrode 110-G, and a second interlayer arranged between the second-1 electrode 110-G and the second-2 electrode 150-G. FIG. 4 illustrates an embodiment in which the second light-emitting device 10G includes two stacks, but the second light-emitting device 10G may include three or more stacks as shown in FIG. 3. The second interlayer may include a second-1 stack ST1-G, a second-2 stack ST2-G, and a second charge generation layer CGL1-G arranged between the second-1 stack ST1-G and the second-2 stack ST2-G.

The second-1 stack ST1-G may include a second-1 hole transport region 131-1G, a second-1 emission layer 133-1G, and a second-1 electron transport region 135-1G that are sequentially arranged on the second-1 electrode 110-G.

The second charge generation layer CGL1-G may include a second n-type charge generation layer nCGL1-G and a second p-type charge generation layer pCGL1-G.

The second-2 stack ST2-G may include a second-2 hole transport region 131-2G, a second-2 emission layer 133-2G, and a second-2 electron transport region 135-2G that are sequentially arranged on the second-1 electrode 110-G.

The third light-emitting device 10B may include a third-1 electrode 110-B, a third-2 electrode 150-B facing the third-1 electrode 110-B, and a third interlayer arranged between the third-1 electrode 110-B and the third-2 electrode 150-B. FIG. 4 illustrates an embodiment in which the third light-emitting device 10B includes two stacks, but the third light-emitting device 10B may include three or more stacks as shown in FIG. 3. The third interlayer may include a third-1 stack ST1-B, a third-2 stack ST2-B, and a third charge generation layer CGL1-B arranged between the third-1 stack ST1-B and the third-2 stack ST2-B.

The third-1 stack ST1-B may include a third-1 hole transport region 131-1B, a third-1 emission layer 133-1B, and a third-1 electron transport region 135-1B that are sequentially arranged on the third-1 electrode 110-B.

The third charge generation layer CGL1-B may include a third n-type charge generation layer nCGL1-B and a third p-type charge generation layer pCGL1-B.

The third-2 stack ST2-B may include a third-2 hole transport region 131-2B, a third-2 emission layer 133-2B, and a third-2 electron transport region 135-2B that are sequentially arranged on the third-1 electrode 110-B.

In FIG. 4, the components included in each of the first light-emitting device 10R, the second light-emitting device 10G, and the third light-emitting device 10B are depicted as separate and distinct from each other, but some of the components may be connected to each other and form a common layer having a single body.

In an embodiment, the first p-type charge generation layer pCGL1-R and the second p-type charge generation layer pCGL1-G may be connected to each other and form a common layer. The second p-type charge generation layer pCGL1-G and the third p-type charge generation layer pCGL1-B may be connected to each other and form a common layer. The first p-type charge generation layer pCGL1-R, the second p-type charge generation layer pCGL1-G, and the third p-type charge generation layer pCGL1-B may be connected to each other and form a common layer having a single body.

In an embodiment, the first-2 hole transport region 131-2R and the second-2 hole transport region 131-2G may be connected to each other and form a common layer. The second-2 hole transport region 131-2G and the third-2 hole transport region 131-2B may be connected to each other and form a common layer. The first-2 hole transport region 131-2R, the second-2 hole transport region 131-2G, and the third-2 hole transport region 131-2B may be connected to each other and form a common layer having a single body. In an embodiment, the hole transport layer included in the first-2 hole transport region 131-2R, the hole transport layer included in the second-2 hole transport region 131-2G, and the hole transport layer included in the third-2 hole transport region 131-2B may form a common layer.

In an embodiment, at least one of the first-2 hole transport region 131-2R, the second-2 hole transport region 131-2G, and the third-2 hole transport region 131-2B may include at least one first compound represented by Formula 1.

In an embodiment, at least one of the first charge generation layer CGL1-R, the second charge generation layer CGL1-G, and the third charge generation layer CGL1-B may include at least one second compound represented by Formula 2. In an embodiment, at least one of the first p-type charge generation layer pCGL1-R, the second p-type charge generation layer pCGL1-G, and the third p-type charge generation layer pCGL1-B may include at least one second compound represented by Formula 2.

In an embodiment, the first-2 hole transport region 131-2R may include at least one first compound, and the first charge generation layer CGL1-R may include at least one second compound.

In an embodiment, each of the first-2 hole transport region 131-2R and the second-2 hole transport region 131-2G may include at least one first compound, and each of the first charge generation layer CGL1-R and the second charge generation layer CGL1-G may include at least one second compound.

In an embodiment, each of the first-2 hole transport region 131-2R, the second-2 hole transport region 131-2G, and the third-2 hole transport region 131-2B may include at least one first compound, and each of the first charge generation layer CGL1-R, the second charge generation layer CGL1-G, and the third charge generation layer CGL1-B may include at least one second compound.

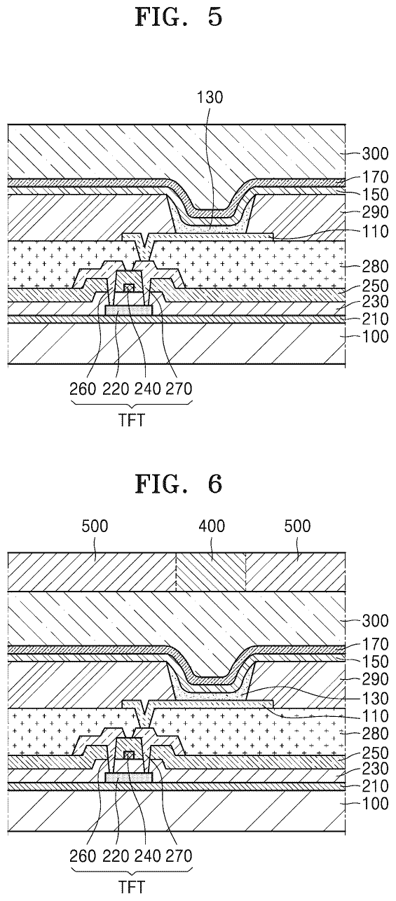

FIG. 5 is a schematic cross-sectional view of an embodiment of a display apparatus.

A display apparatus of FIG. 5 may include a substrate 100, a thin-film transistor TFT, a light-emitting device, and an encapsulation portion 300.

The substrate 100 may be a flexible substrate, a glass substrate, or a metal substrate. A buffer layer 210 may be arranged on the substrate 100. The buffer layer 210 may prevent penetration of impurities through the substrate 100 and may provide a flat surface on the substrate 100.

The TFT may be arranged on the buffer layer 210. The TFT may include an active layer 220, a gate electrode 240, a source electrode 260, and a drain electrode 270.

The active layer 220 may include an inorganic semiconductor, such as silicon or polysilicon, an organic semiconductor, or an oxide semiconductor, and may include a source region, a drain region, and a channel region.

A gate insulating film 230 for insulating the active layer 220 from the gate electrode 240 may be disposed on the active layer 220, and the gate electrode 240 may be disposed on the gate insulating film 230.

An inter-insulating film 250 may be arranged on the gate electrode 240. The inter-insulating film 250 may be disposed between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be arranged on the inter-insulating film 250. The inter-insulating film 250 and the gate insulating film 230 may be formed to expose the source region and the drain region of the active layer 220, and the source electrode 260 and the drain electrode 270 may be arranged in contact with the exposed portions of the source region and the drain region of the active layer 220.

The TFT may be electrically connected to a light-emitting device to drive the light-emitting device, and may be covered and protected by a passivation layer 280. The passivation layer 280 may include an inorganic insulating film, an organic insulating film, or any combinations thereof. The light-emitting device may be provided on the passivation layer 280. The light-emitting device includes the first electrode 110, the interlayer, and the second electrode 150.

The first electrode 110 may be arranged on the passivation layer 280. The passivation layer 280 may be arranged to expose a portion of the drain electrode 270 without fully covering the drain electrode 270, and the first electrode 110 may be arranged to be connected to the exposed portion of the drain electrode 270.

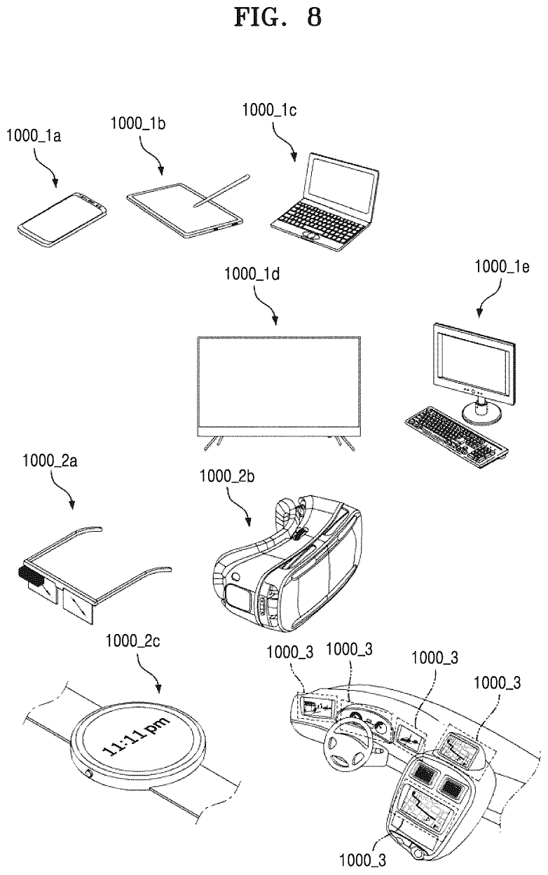

The pixel-defining film 290 including an insulating material may be arranged on the first electrode 110. The pixel-defining layer 290 may expose a predetermined region of the first electrode 110, and the interlayer may be formed in the exposed region of the first electrode 110. The pixel-defining layer 290 may be a polyimide-based organic film or a polyacrylic-based organic film. Although not shown in FIG. 8, at least some layers of the interlayer may extend to the upper portion of the pixel-defining layer 290 and may be arranged in the form of a common layer.

The second electrode 150 may be arranged on the interlayer, and a capping layer 170 may be additionally formed on the second electrode 150. The capping layer 170 may be formed to cover the second electrode 150.

The encapsulation portion 300 may be arranged on the capping layer 170. The encapsulation portion 300 may be disposed on the light-emitting device to protect the light-emitting device from moisture or oxygen. The encapsulation portion 300 may include: an inorganic film including silicon nitride (SiNx), silicon oxide (SiOx), ITO, IZO, or any combinations thereof; an organic film including PET, polyethylene naphthalate, polycarbonate, polyimide, polyethylene sulfonate, polyoxymethylene, PAR, hexamethyldisiloxane, an acrylic-based resin (e.g., polymethyl methacrylate, polyacrylic acid, etc.), an epoxy-based resin (e.g., aliphatic glycidyl ether (“AGE”), etc.), or any combinations thereof; or any combination of the inorganic films and the organic films.

FIG. 6 is a schematic cross-sectional view of an embodiment of a display apparatus.

A display apparatus of FIG. 6 is the same as the display apparatus of FIG. 5, except that light-shielding patterns 500 and a functional region 400 are additionally arranged on the encapsulation portion 300. The functional region 400 may include i) a color filter area, ii) a color conversion area, or iii) a combination of a color filter area and a color conversion area. In an embodiment, a light-emitting device included in the display apparatus of FIG. 6 may be a tandem light-emitting device.

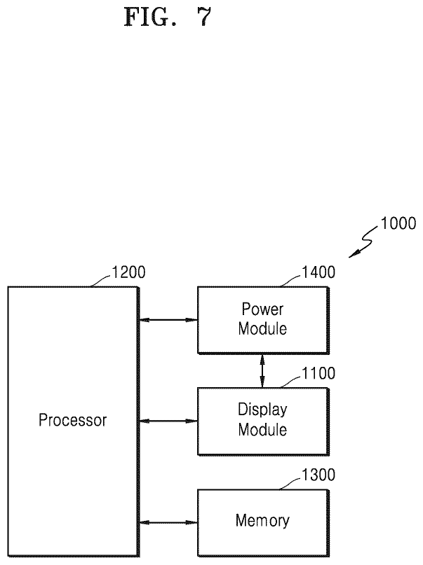

FIG. 7 is a block diagram of an embodiment of an electronic apparatus including the display apparatus.

The display apparatus including the light-emitting device 10 may be applied to various electronic apparatuses 1000. An electronic apparatus 1000 in an embodiment includes the aforementioned display apparatus, and may further include, in addition to the display apparatus, a module or an apparatus having additional functions.

Referring to FIG. 7, the electronic apparatus 1000 in an embodiment may include a display module 1100, a processor 1200, a memory 1300, and a power module 1400.

The display module 1100 may emit light to display images such as moving images or still images, and may include the aforementioned display apparatus, for example.

The processor 1200 may include at least one of a central processing unit (“CPU”), an application processor (“AP”), a graphic processing unit (“GPU”), a communication processor (“CP”), an image signal processor (“ISP”), and a controller.

Data information desired for the operation of the processor 1200 or the display module 1100 may be stored in the memory 1300. When the processor 1200 executes an application stored in the memory 1300, an image data signal and/or an input control signal is transmitted to the display module 1100, and the display module 1100 may process the received signal and output image information through a display screen.

The power module 1400 may include: a power supply module, such as a power adapter or a battery device; and a power conversion module that converts power supplied by the power supply module to generate power desired for the operation of the electronic apparatus 1000.

At least one of components of the electronic apparatus 1000 may be included in the display apparatus according to the aforementioned embodiments. In an embodiment, some of individual modules functionally included in a single module may be included in the display apparatus, and others may be provided separately from the display apparatus. In an embodiment, the display apparatus may include the display module 1100, and the processor 1200, the memory 1300, and the power module 1400 may be provided in the form of other apparatuses in the electronic apparatus 1000 other than the display apparatus, for example.

In an embodiment, the electronic apparatus 1000 may be one of a flat panel display, a curved display, a computer monitor, a medical monitor, a television, a billboard, an indoor light, an outdoor light, a signal light, a head-up display, a fully or partially transparent display, a flexible display, a rollable display, a foldable display, a stretchable display, smart glasses, a head-mounted display, a smart watch, a laser printer, a telephone, a mobile phone, a tablet, a phablet, a personal digital assistant (“PDA”), a wearable device, a laptop computer, a digital camera, a camcorder, a viewfinder, a micro display, a three dimensional (“3D”) display, a virtual reality display, an augmented reality display, a vehicle gauge, a center information display (“CID”) in a vehicle, a head-up display for a vehicle, a room mirror display, a video wall including multiple displays tiled together, a theater or stadium screen, a phototherapy device, and a signboard.

FIG. 8 is a schematic view of embodiments of an electronic apparatus.

Referring to FIG. 8, various electronic apparatuses 1000 to which the display apparatus in embodiments is applied may include: an electronic apparatus for displaying an image, such as a smart phone 1000_1a, a tablet personal computer (“PC”) 1000_1b, a laptop 1000_1c, a television (“TV”) 1000_1d, a desk monitor 1000_1e, or the like; a wearable electronic apparatus including a display module, such as smart glasses 1000_2a, a head-mount display 1000_2b, a smart watch 1000_2c, or the like; and an automotive electronic apparatus 1000_3 including a display module, such as a vehicle gauge, a centre fascia, a CID on a dashboard, a room mirror display, or the like.

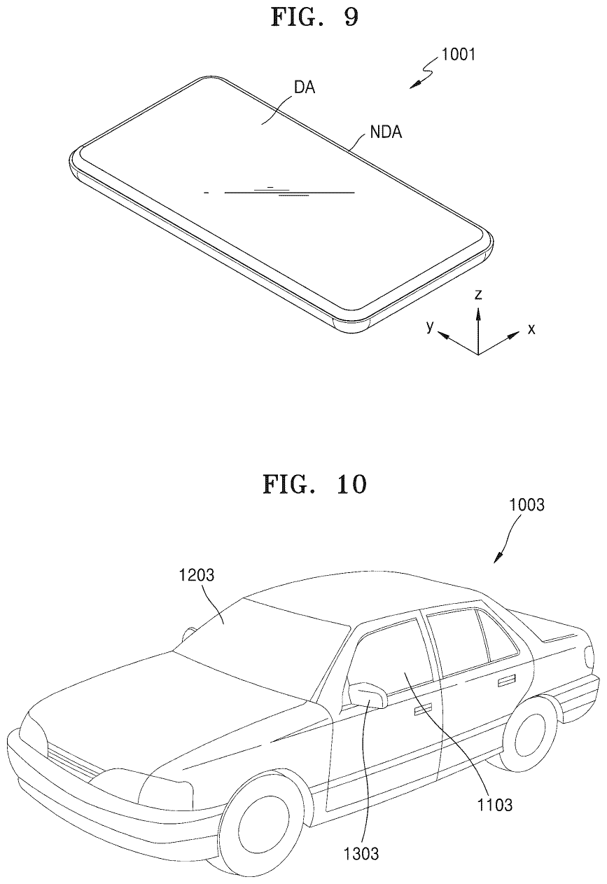

FIG. 9 is a schematic perspective view of an embodiment of an electronic apparatus 1001 including the light-emitting device 10. The electronic apparatus 1001 may be, as an apparatus that displays a moving image or a still image, portable electronic equipment, such as a mobile phone, a smart phone, a tablet PC, a mobile communication terminal, an electronic notebook, an electronic book, a portable multimedia player (“PMP”), a navigation, or a ultra-mobile PC(“UMPC”), as well as various products or a part thereof, such as a television, a laptop, a monitor, a billboard, or an Internet of things (“IoT”). In addition, the electronic apparatus 1001 may be a wearable device or a part thereof, such as a smart watch, a watch phone, a glasses-type display, or a head mounted display (“HMD”). However, the disclosure is not limited thereto. In an embodiment, the electronic apparatus 1001 may be a dashboard of a vehicle, a center information display (“CID”) arranged on a center fascia or dashboard of a vehicle, a room mirror display instead of a side-view mirror of a vehicle, an entertainment for the back seat of a vehicle, or a display arranged on the back of the front seat of a vehicle, a head up display (“HUD”) installed on the front of a vehicle or projected on a front window glass, or a computer generated hologram augmented reality HUD (“CGH AR HUD”). FIG. 8 illustrates an embodiment in which the electronic apparatus 1001 is a smart phone for convenience of description.

The electronic apparatus 1001 may include a display area DA and a non-display area NDA outside the display area DA. The electronic apparatus 1001 may implement an image through an array of a plurality of pixels that are two-dimensionally arranged in the display area DA.

The non-display area NDA is an area that does not display an image, and may surround an entirety of the display area DA. On the non-display area NDA, a driver for providing electrical signals or power to display devices arranged on the display area DA may be arranged. On the non-display area NDA, a pad, which is an area to which an electronic element or a printed circuit board, may be electrically connected may be arranged.

The electronic apparatus 1001 may have different lengths in the x-axis direction and in the y-axis direction. In an embodiment, as shown in FIG. 5, the length in the x-axis direction may be less than the length in the y-axis direction. In an embodiment, the length in the x-axis direction may be the same as the length in the y-axis direction. In an embodiment, the length in the x-axis direction may be greater than the length in the y-axis direction.

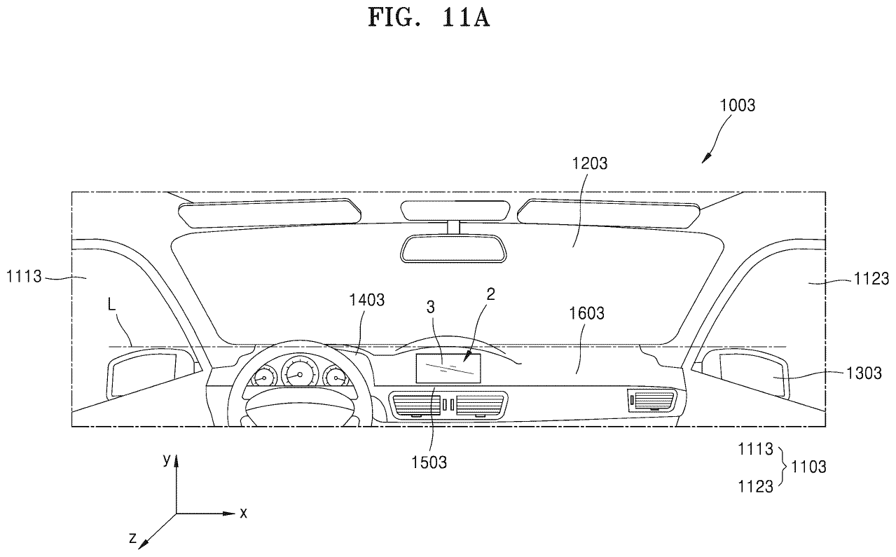

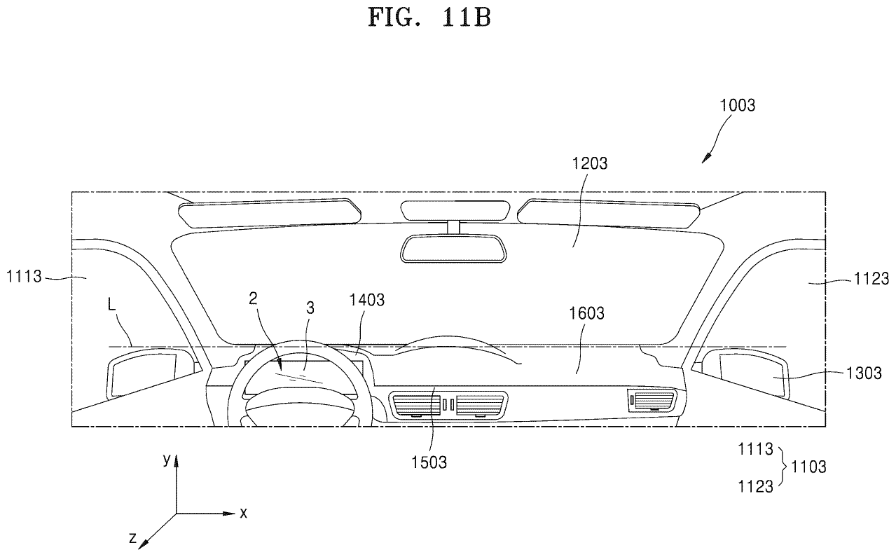

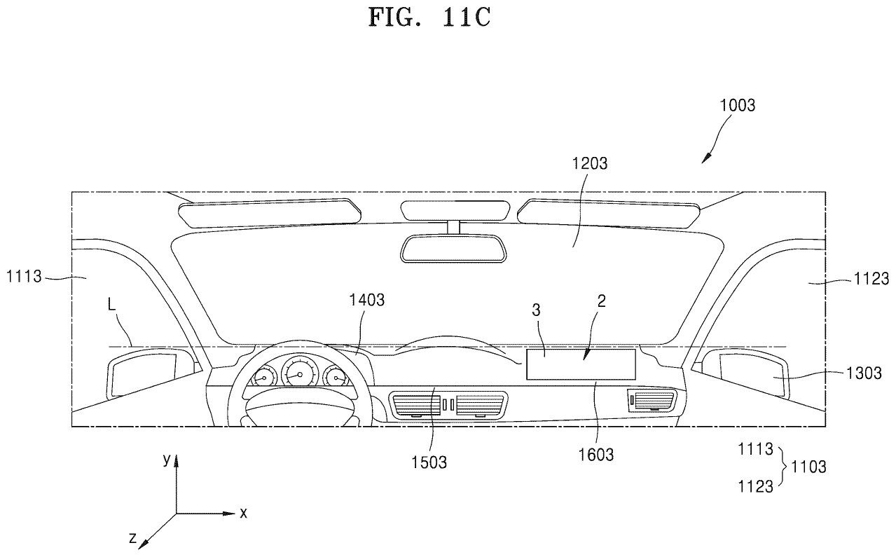

FIG. 10 is a schematic view of an embodiment of the exterior of a vehicle 1003 as an electronic apparatus including the light-emitting device 10. FIGS. 11A to 11C are each a schematic view of embodiments of the interior of the vehicle 1003.

Referring to FIGS. 10, 11A, 11B, and 11C, the vehicle 1003 may refer to various apparatuses for moving a subject to be transported, such as a human, an object, or an animal, from a departure point to a destination point. The vehicle 1003 may include a vehicle traveling on a road or a track, a vessel moving over the sea or river, an airplane flying in the sky using the action of air, or the like.

The vehicle 1003 may travel on roads or tracks. The vehicle 1003 may move in a predetermined direction based on rotation of at least one wheel. In an embodiment, the vehicle 1003 may include a three- or four-wheeled vehicle, a construction machine, a two-wheeled vehicle, a motorized device, a bicycle, and a train running on a track, for example.

The vehicle 1003 may include a body having an interior and an exterior, and a chassis in which mechanical apparatuses desired for driving are installed as the remaining parts except for the body. The exterior of the body may include a front panel, a bonnet, a roof panel, a rear panel, a trunk, a pillar provided at a boundary between doors, or the like. The chassis of the vehicle 1003 may include a power generating apparatus, a power transmitting apparatus, a traveling apparatus, a steering apparatus, a braking apparatus, a suspension apparatus, a transmission apparatus, a fuel apparatus, front and rear left and right wheels, or the like.

The vehicle 1003 may include a side window glass 1103, a front window glass 1203, a side mirror 1303, a cluster 1403, a center fascia 1503, a passenger seat dashboard 1603, and a display apparatus 2.

The side window glass 1103 and the front window glass 1203 may be partitioned by a pillar arranged between the side window glass 1103 and the front window glass 1203.

The side window glass 1103 may be installed on a side of the vehicle 1003. In an embodiment, the side window glass 1103 may be installed on a door of the vehicle 1003. A plurality of side window glasses 1103 may be provided and may face each other. In an embodiment, the side window glass 1103 may include a first side window glass 1113 and a second side window glass 1123. In an embodiment, the first side window glass 1113 may be arranged adjacent to the cluster 1403. In an embodiment, the second side window glass 1123 may be arranged adjacent to the passenger seat dashboard 1603.

In an embodiment, the side window glasses 1103 may be spaced apart from each other in the x direction or -x direction. In an embodiment, the first side window glass 1113 and the second side window glass 1123 may be spaced apart from each other in the x direction or -x direction, for example. In other words, an imaginary straight line L connecting the side window glasses 1103 may extend in the x direction or -x direction. In an embodiment, the imaginary straight line L connecting the first side window glass 1113 and the second side window glass 1123 to each other may extend in the x direction or -x direction, for example.

The front window glass 1203 may be installed on a front of the vehicle 1003. The front window glass 1203 may be arranged between the side window glasses 1103 facing each other.

The side mirror 1303 may provide a view of the rear of the vehicle 1003. The side mirror 1303 may be installed on the exterior of the body of the vehicle. In an embodiment, a plurality of side mirrors 1303 may be provided. Any one of the plurality of side mirrors 1303 may be disposed outside the first side window glass 1113. Another one of the plurality of side mirrors 1303 may be disposed outside the second side window glass 1123.

The cluster 1403 may be arranged in front of a steering wheel. The cluster 1403 may include a tachometer, a speedometer, a coolant thermometer, a fuel gauge, a turn signal indicator, a high beam indicator, a warning light, a seat belt warning light, an odometer, a tachograph, an automatic shift selector indicator lamp, a door open warning light, an engine oil warning light, and/or a low fuel warning light.

The center fascia 1503 may include a control panel on which a plurality of buttons for adjusting an audio device, an air conditioning device, and a seat heater are disposed. The center fascia 1503 may be on one side of the cluster 1403.

A passenger seat dashboard 1603 may be spaced apart from the cluster 1403, and the center fascia 1503 may be arranged between the cluster 1403 and the passenger seat dashboard 1603. In an embodiment, the cluster 1403 may be disposed to correspond to a seat of a driver (not shown), and the passenger seat dashboard 1603 may be disposed to correspond to a seat of a passenger (not shown). In an embodiment, the cluster 1403 may be adjacent to the first side window glass 1113, and the passenger seat dashboard 1603 may be adjacent to the second side window glass 1123.

In an embodiment, the display apparatus 2 may include a display panel 3, and the display panel 3 may display an image. The display apparatus 2 may be arranged in the interior of the vehicle 1003. In an embodiment, the display apparatus 2 may be arranged between the side window glasses 1103 facing each other. The display apparatus 2 may be on at least one of the cluster 1403, the center fascia 1503, and the passenger seat dashboard 1603.

The display apparatus 2 may include an organic light-emitting display apparatus, an inorganic light-emitting display apparatus, a quantum dot display apparatus, or the like.

Referring to FIG. 11A, the display apparatus 2 may be arranged on the center fascia 1503. In an embodiment, the display apparatus 2 may display navigation information. In an embodiment, the display apparatus 2 may display information regarding audio settings, video setting, or vehicle settings.

Referring to FIG. 11B, the display apparatus 2 may be arranged on the cluster 1403. In this embodiment, the cluster 1403 may show driving information or the like by the display apparatus 2. That is, the cluster 1403 may digitally implement driving information or the like. The cluster 1403 may digitally implement vehicle information and driving information as images. In an embodiment, a needle and a gauge of a tachometer and various warning light icons may be displayed by a digital signal.

Referring to FIG. 11C, the display apparatus 2 may be arranged on the passenger seat dashboard 1603. The display apparatus 2 may be embedded in the passenger seat dashboard 1603 or disposed on the passenger seat dashboard 1603. In an embodiment, the display apparatus 2 arranged on the passenger seat dashboard 1603 may display an image related to information displayed on the cluster 1403 and/or information displayed on the center fascia 1503. In an embodiment, the display apparatus 2 arranged on the passenger seat dashboard 1603 may display information different from information displayed on the cluster 1403 and/or information displayed on the center fascia 1503.

The term “C₃-C₆₀ carbocyclic group” as used herein refers to a cyclic group including or consisting of carbon atoms as the only ring-forming atoms and having 3 to 60 carbon atoms.

The term “C₁-C₆₀ heterocyclic group” as used herein refers to a cyclic group that has 1 to 60 carbon atoms and further has, in addition to carbon atoms, a heteroatom as a ring-forming atom.

The C₃-C₆₀ carbocyclic group and the C₁-C₆₀ heterocyclic group may each be: a monocyclic group including or consisting of one ring; or a polycyclic group in which two or more rings are condensed with each other. In an embodiment, the number of ring-forming atoms of the C₁-C₆₀ heterocyclic group may be from 3 to 61, for example.

The term “cyclic group” as used herein may include both the C₃-C₆₀ carbocyclic group and the C₁-C₆₀ heterocyclic group.

The term “IT electron-rich C₃-C₆₀ cyclic group” as used herein refers to a cyclic group that has 3 to 60 carbon atoms and does not include *—N═*′ as a ring-forming moiety.

The term “π electron-deficient nitrogen-containing C₁-C₆₀ cyclic group” as used herein refers to a heterocyclic group that has 1 to 60 carbon atoms and includes *—N═** as a ring-forming moiety.

In an embodiment:
the C₃-C₆₀ carbocyclic group may be i) Group T₁ or ii) a condensed cyclic group in which two or more of Group T₁ are condensed with each other (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group);
the C₁-C₆₀ heterocyclic group may be i) Group T₂, ii) a condensed cyclic group in which two or more of Group T₂ are condensed with each other, or iii) a condensed cyclic group in which at least one Group T₂ and at least one Group T₁ are condensed with each other (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, a xanthene group, or the like);
the electron-rich C₃-C₆₀ cyclic group may be i) Group T₁, ii) a condensed cyclic group in which two or more of Group T₁ are condensed with each other, iii) Group T₃, iv) a condensed cyclic group in which two or more of Group T₃ are condensed with each other, or v) a condensed cyclic group in which at least one Group T₃ and at least one Group T₁ are condensed with each other (e.g., the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, benzothienodibenzothiophene group, or the like); and
the π electron-deficient nitrogen-containing C₁-C₆₀ cyclic group may be i) Group T₄, ii) a condensed cyclic group in which two or more Groups T₄ are condensed with each other, iii) a condensed cyclic group in which at least one Group T₄ and at least one Group T₁ are condensed with each other, iv) a condensed cyclic group in which at least one Group T₄ and at least one Group T₃ are condensed with each other, or v) a condensed cyclic group in which at least one Group T₄, at least one Group T₁, and at least one Group T₃ are condensed with one another (e.g., a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, or the like).

Group T₁ may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group.

Group T₂ may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group.

Group T₃ may be a furan group, a thiophene group, a 1H-pyrrole group, a silole group, or a borole group.

Group T₄ may include a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group, the C₃-C₆₀ carbocyclic group, the C₁-C₆₀ heterocyclic group, the π electron-rich C₃-C₆₀ cyclic group, or the IT electron-deficient nitrogen-containing C₁-C₆₀ cyclic group” as used herein refer to i) a group condensed to any cyclic group, ii) a monovalent group, or iii) a polyvalent group (e.g., a divalent group, a trivalent group, a tetravalent group, etc.), according to the structure of a formula for which the corresponding term is used.

In an embodiment, the “benzene group” may be a benzo group, a phenyl group, a phenylene group, or the like, which may be easily understood by those of ordinary skill in the art according to the structure of a formula including the “benzene group.”

In an embodiment, the monovalent C₃-C₆₀ carbocyclic group and monovalent C₁-C₆₀ heterocyclic group are a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

In an embodiment, the divalent C₃-C₆₀ carbocyclic group and the divalent C₁-C₆₀ heterocyclic group are a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein refers to a linear or branched aliphatic hydrocarbon monovalent group that has 1 to 60 carbon atoms, and illustrative embodiments thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group.

The term “C₁-C₆₀ alkylene group” as used herein refers to a divalent group having the same structure as that of the C₁-C₆₀ alkyl group.

The term “C₂-C₆₀ alkenyl group” as used herein refers to a monovalent hydrocarbon group having at least one carbon-carbon double bond in the middle or at the terminus of the C₂-C₆₀ alkyl group, and embodiments thereof may include an ethenyl group, a propenyl group, a butenyl group, or the like.

The term “C₂-C₆₀ alkenylene group” as used herein refers to a divalent group having the same structure as that of the C₂-C₆₀ alkenyl group.

The term “C₂-C₆₀ alkynyl group” as used herein refers to a monovalent hydrocarbon group having at least one carbon-carbon triple bond in the middle or at the terminus of the C₂-C₆₀ alkyl group, and embodiments thereof may include an ethynyl group, a propynyl group, or the like.

The term “C₂-C₆₀ alkynylene group” as used herein refers to a divalent group having the same structure as that of the C₂-C₆₀ alkynyl group.

The term “C₁-C₆₀ alkoxy group” as used herein refers to a monovalent group represented by -OA₁₀₁ (where A₁₀₁ is the C₁-C₆₀ alkyl group), and embodiments thereof may include a methoxy group, an ethoxy group, an isopropyloxy group, or the like.

The term “C₃-C₁₀ cycloalkyl group” as used herein refers to a monovalent saturated hydrocarbon cyclic group having 3 to 10 carbon atoms, and embodiments thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, or the like.

The term “C₃-C₁₀ cycloalkylene group” as used herein refers to a divalent group having the same structure as that of the C₃-C₁₀ cycloalkyl group.

The term “C₁-C₁₀ heterocycloalkyl group” as used herein refers to a monovalent cyclic group of 1 to 10 carbon atoms, further including, in addition to carbon atoms, at least one heteroatom as ring-forming atoms, and illustrative embodiments thereof may include a 1,2,3,4-oxatriazolidinyl group, a tetrahydrofuranyl group, a tetrahydrothiophenyl group, or the like.

The term “C₁-C₁₀ heterocycloalkylene group” as used herein refers to a divalent group having the same structure as that of the C₁-C₁₀ heterocycloalkyl group.

The term “C₃-C₁₀ cycloalkenyl group” as used herein refers to a monovalent cyclic group that 3 to 10 carbon atoms, at least one carbon-carbon double bond in the ring thereof, and no aromaticity, and illustrative embodiments thereof may include a cyclopentenyl group, a cyclohexenyl group, a cycloheptenyl group, or the like.

The term “C₃-C₁₀ cycloalkenylene group” as used herein refers to a divalent group having the same structure as that of the C₃-C₁₀ cycloalkyl group.

The term “C₁-C₁₀ heterocycloalkenyl group” as used herein refers to a monovalent cyclic group of 1 to 10 carbon atoms, further including, in addition to carbon atoms, at least one heteroatom as ring-forming atoms and at least one carbon-carbon double bond in the cyclic structure thereof. In an embodiment, the C₁-C₁₀ heterocycloalkenyl group may include a 4,5-dihydro-1,2,3,4-oxatriazolyl group, a 2,3-dihydrofuranyl group, a 2,3-dihydrothiophenyl group, or the like.

The term “C₁-C₁₀ heterocycloalkenylene group” as used herein refers to a divalent group having the same structure as that of the C₁-C₁₀ heterocycloalkenyl group.

The term “C₆-C₆₀ aryl group” as used herein refers to a monovalent group having a carbocyclic aromatic system of 6 to 60 carbon atoms.

The term “C₆-C₆₀ arylene group” as used herein refers to a divalent group having a carbocyclic aromatic system of 6 to 60 carbon atoms.

In an embodiment, the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, or the like.

When the C₆-C₆₀ aryl group and the C₆-C₆₀ arylene group each include two or more rings, the two or more rings may be condensed with each other.

The term “C₁-C₆₀ heteroaryl group” as used herein refers to a monovalent group having a heterocyclic aromatic system of 1 to 60 carbon atoms, further including, in addition to carbon atoms, at least one heteroatom, as ring-forming atoms.

The term “C₁-C₆₀ heteroarylene group” as used herein refers to a divalent group having a heterocyclic aromatic system of 1 to 60 carbon atoms, further including, in addition to carbon atoms, at least one heteroatom, as ring-forming atoms.

In an embodiment, the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, or the like.

When the C₁-C₆₀ heteroaryl group and the C₁-C₆₀ heteroarylene group each include two or more rings, the two or more rings may be condensed with each other.

The term “monovalent non-aromatic condensed polycyclic group” as used herein refers to a monovalent group (e.g., having 8 to 60 carbon atoms) having two or more rings condensed to each other, only carbon atoms as ring-forming atoms, and no aromaticity in the entirety of the molecular structure. In an embodiment, the monovalent non-aromatic condensed polycyclic group may include an indenyl group, a fluorenyl group, a spiro-bifluorenyl group, a benzofluorenyl group, an indenophenanthrenyl group, an indeno anthracenyl group, or the like.

The term “divalent non-aromatic condensed polycyclic group” as used herein refers to a divalent group having the same structure as that of the monovalent non-aromatic condensed polycyclic group.

The term “monovalent non-aromatic hetero-condensed polycyclic group” as used herein refers to a monovalent group (e.g., having 1 to 60 carbon atoms) having two or more rings condensed to each other, further including, in addition to carbon atoms, at least one heteroatom, as ring-forming atoms, and having non-aromaticity in its entire molecular structure. In an embodiment, the monovalent non-aromatic hetero-condensed polycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, benzonaphthothiophenyl group, a benzonaphthosilolyl group, a benzofurodibenzofuranyl group, a benzofurodibenzothiophenyl group, and a benzothienodibenzothiophenyl group.

The term “divalent non-aromatic condensed heteropolycyclic group” as used herein refers to a divalent group having the same structure as that of the monovalent non-aromatic condensed heteropolycyclic group.

The term “C₆-C₆₀ aryloxy group” as used herein indicates -OA₁₀₂ (where A₁₀₂ is the C₆-C₆₀ aryl group).

The term “C₆-C₆₀ arylthio group” as used herein indicates -SA₁₀₃ (where A₁₀₃ is the C₆-C₆₀ aryl group).

The term “C₇-C₆₀ arylalkyl group” as used herein refers to -A₁₀₄A₁₀₅ (where A₁₀₄ is a C₁-C₅₄ alkylene group, and A₁₀₅ is a C₆-C₅₉ aryl group).

The term “C₂-C₆₀ heteroarylalkyl group” as used herein refers to -A₁₀₆A₁₀₇ (where A₁₀₆ is a C₁-C₅₉ alkylene group, and A₁₀₇ is a C₁-C₅₉ heteroaryl group).

The term “R₁₀ₐ” as used herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₃-C₆₀ heterocyclic group, a C₆-C₆₀ aryloxy group, a C₆-C₆₀ arylthio group, a C₇-C₆₀ arylalkyl group, a C₃-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combinations thereof;
a C₅-C₆₀ carbocyclic group, a C₃-C₆₀ heterocyclic group, a C₆-C₆₀ aryloxy group, a C₆-C₆₀ arylthio group, a C₇-C₆₀ arylalkyl group, or a C₃-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₃-C₆₀ heterocyclic group, a C₆-C₆₀ aryloxy group, a C₆-C₆₀ arylthio group, a C₇-C₆₀ arylalkyl group, a C₃-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combinations thereof; or —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁ to Q₃, Q₁₁ to Q₁₃, Q₂₁ to Q₂₃ and Q₃₁ to Q₃₃ as used herein may each independently be: hydrogen; deuterium; —F; —Cl; —Br; —I; a hydroxyl group; a cyano group; a nitro group; or C₁-C₆₀ alkyl group; C₂-C₆₀ alkenyl group; C₂-C₆₀ alkynyl group; C₁-C₆₀ alkoxy group, a C₅-C₆₀ carbocyclic group or a C₃-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combinations thereof.

The term “heteroatom” as used herein refers to any atom other than a carbon atom. The heteroatom may include O, S, N, P, Si, B, Ge, Se, and any combinations thereof.

The term “transition metal” as used herein may include Hf, Ta, W, Re, Os, Ir, Pt, Au, or the like.

In the specification, “D” may refer to deuterium, “Ph” may refer to a phenyl group, “Me” may refer to a methyl group, “Et” may refer to an ethyl group, “tert-Bu”, “Bu”, or “Bu” may refer to a tert-butyl group, and “OMe” may refer to a methoxy group.

The term “biphenyl group” as used herein refers to “a phenyl group that is substituted with a phenyl group.” In other words, the “biphenyl group” may be a substituted phenyl group having a C₆-C₆₀ aryl group as a substituent.

The term “terphenyl group” as used herein refers to “a phenyl group substituted with a biphenyl group.” The “terphenyl group” may belong to i) “a substituent phenyl group” which is “a C₆-C₆₀ aryl group in which a substituent is substituted with a C₆-C₆₀ aryl group”, or ii) “a substituted phenyl group” having two substituents, each of which is “a C₆-C₆₀ aryl group.”

* and * as used herein, unless defined otherwise, each refer to a binding site to a neighboring atom in a corresponding formula or moiety.

In the specification, the x-axis, y-axis, and z-axis are not limited to three axes in an orthogonal coordinate system, and may be interpreted in a broad sense including these axes. In an embodiment, the x-axis, y-axis, and z-axis may describe axes that are orthogonal to each other, or may describe axes that are in different directions that are not orthogonal to each other, for example.

In the specification, a unit for ohm per square may be either ohm/sq or Ω/□.

### Embodiment 1

ITO 70 Å/Ag 850 Å/ITO 50 Å (anode) was cut to a size of 50 millimeter (mm)×50 mm×0.7 mm, sonicated with isopropyl alcohol and pure water each for 5 minutes, and then cleaned by exposure to ultraviolet rays and ozone for 30 minutes. The resultant glass substrate was placed in a vacuum deposition apparatus.

HAT-CN was vacuum-deposited on the substrate to form a first hole injection layer having a thickness of 150 Å. Next, NPB as a hole-transporting compound was vacuum-deposited to form a first hole transport layer having a thickness of 1100 Å.

CBP as a host and DMAC-TRZ as a dopant were deposited on the first hole transport layer to form a first emission layer having a thickness of 20 nm (weight ratio of host: dopant=9:1).

TPM-TAZ and Liq (weight ratio of 5:5) were deposited on the first emission layer to form a first electron transport layer having a thickness of 300 Å, thereby forming a first stack.

Amorphous Zn—Si—O (a-ZSO) was vacuum-deposited on the first stack to form an n-type charge generation layer having a thickness of 150 nm. Compound A1 as the first compound and Compound B1 as the second compound (weight ratio of 9:1) were vacuum-deposited on the n-type charge generation layer to form a p-type charge generation layer having a thickness of 100 Å, thereby forming a first charge generation layer.

Compound A1 was vacuum-deposited on the first charge generation layer to form a second hole transport layer having a thickness of 500 Å.

CBP as a host and DMAC-TRZ as a dopant were deposited on the second hole transport layer to form a second emission layer having a thickness of 20 nm (weight ratio of host: dopant=9:1).

TPM-TAZ and Liq (weight ratio of 5:5) were deposited on the second emission layer to form a second electron transport layer having a thickness of 300 Å, thereby forming a second stack.

Yb was deposited on the second stack to a thickness of 10 Å, and AgMg was continuously vacuum-deposited thereto to form a cathode having a thickness of 100 Å (Mg doping 5 wt %), thereby completing the manufacture of a light-emitting device.

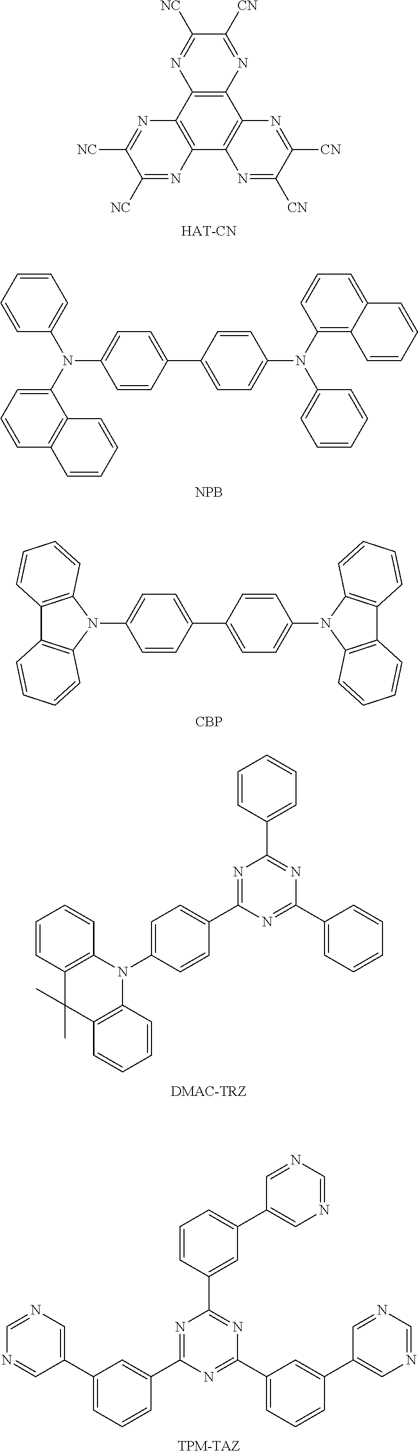

### Embodiments 2 to 19 and Comparative Examples 1 to 7

Light-emitting devices of Embodiments 2 to 19 and Comparative Examples 1 to 7 were manufactured respectively in substantially the same manner as in Embodiment 1, except that materials for forming a p-type charge generation layer and a second hole transport layer were each changed as shown in Table 1.

### Evaluation Embodiment 1

Before manufacturing the light-emitting devices of the Embodiments and the Comparative Examples, the surface resistance (ohm/sq) of the second hole transport layer, which was formed on the p-type charge generation layer, was measured by a transmission line method (“TLM”), and the results are shown in Table 1.

### Evaluation Embodiment 2

To evaluate the characteristics of the light-emitting devices of the Embodiments and the Comparative Examples, the luminescence efficiency (cd/A/y) at 330 nit and lifespan (in terms of hour (hr)) at 2000 nit were measured by a source meter (manufactured by Keithley Instrument, 2400 series) and a luminance meter PR650, and the results are shown in Table 1. The lifespan was measured as the time (T₉₅, hr) desired to reach 95% of the initial luminance.

TABLE 1

| | | | Luminescence | | Surface |
|---|---|---|---|---|---|
| | First | Second | efficiency | Lifespan | resistance |
| No. | compound | compound | (cd/A/y) | (T₉₅, hr) | (ohm/sq) |
| Embodiment 1 | A1 | B1 | 356 | 790 | 4.8 × 10⁹ |
| Embodiment 2 | A1 | B2 | 310 | 681 | 2.5 × 10⁹ |
| Embodiment 3 | A10 | B2 | 387 | 724 | 1.8 × 10¹⁰ |
| Embodiment 4 | A10 | B1 | 392 | 765 | 9.2 × 10⁹ |
| Embodiment 5 | A15 | B3 | 362 | 796 | 8.5 × 10⁹ |
| Embodiment 6 | A15 | B2 | 368 | 739 | 7.8 × 10⁹ |
| Embodiment 7 | A45 | B1 | 383 | 737 | 5.4 × 10⁹ |
| Embodiment 8 | A117 | B1 | 381 | 691 | 2.7 × 10⁹ |
| Embodiment 9 | A121 | B1 | 392 | 689 | 3.8 × 10⁹ |
| Embodiment 10 | A125 | B1 | 377 | 697 | 6.8 × 10⁹ |
| Embodiment 11 | A129 | B1 | 405 | 727 | 9.4 × 10⁹ |
| Embodiment 12 | A133 | B1 | 400 | 737 | 2.5 × 10⁹ |
| Embodiment 13 | A137 | B1 | 330 | 701 | 1.6 × 10¹⁰ |
| Embodiment 14 | A141 | B1 | 342 | 703 | 8.1 × 10⁹ |
| Embodiment 15 | A151 | B1 | 370 | 736 | 4.2 × 10⁹ |
| Embodiment 16 | A152 | B1 | 400 | 734 | 6.9 × 10⁹ |
| Embodiment 17 | A153 | B1 | 369 | 684 | 3.2 × 10⁹ |
| Embodiment 18 | A157 | B1 | 358 | 689 | 5.4 × 10⁹ |
| Embodiment 19 | A158 | B1 | 344 | 714 | 7.2 × 10⁹ |
| Comparative | AR1 | BR1 | 350 | 761 | 5.3 × 10⁸ |
| Example 1 | | | | | |
| Comparative | A1 | BR1 | 384 | 758 | 4.7 × 10⁸ |
| Example 2 | | | | | |
| Comparative | A10 | BR1 | 315 | 774 | 4.8 × 10⁷ |
| Example 3 | | | | | |
| Comparative | A15 | BR1 | 402 | 750 | 3.5 × 10⁷ |
| Example 4 | | | | | |
| Comparative | AR1 | B1 | 315 | 774 | 4.8 × 10⁷ |
| Example 5 | | | | | |
| Comparative | AR1 | B2 | 411 | 750 | 6.2 × 10⁷ |
| Example 6 | | | | | |
| Comparative | AR1 | B3 | 395 | 768 | 9.8 × 10⁷ |
| Example 7 | | | | | |

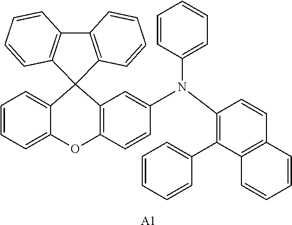

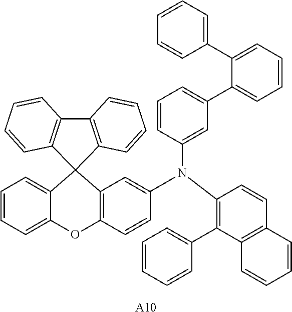

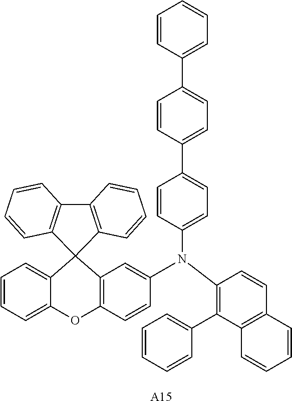

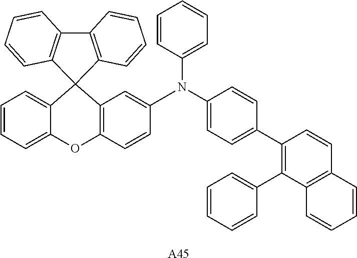 [SMILES: c1ccc(-c2c(-c3ccc(N(c4ccccc4)c4ccc5c(c4)C4(c6ccccc6O5)c5ccccc5-c5ccccc54)cc3)ccc3ccccc23)cc1 ; "A45"]

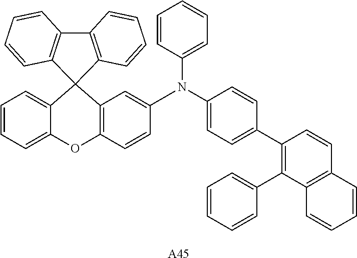 [SMILES: c1ccc(-c2c(-c3ccc(N(c4ccccc4)c4ccc5c(c4)C4(c6ccccc6O5)c5ccccc5-c5ccccc54)cc3)ccc3ccccc23)cc1 ; "A45"]

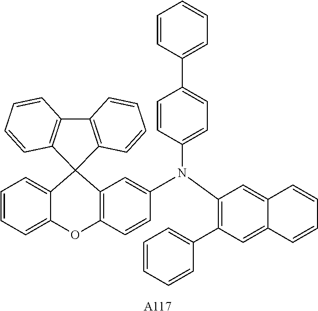

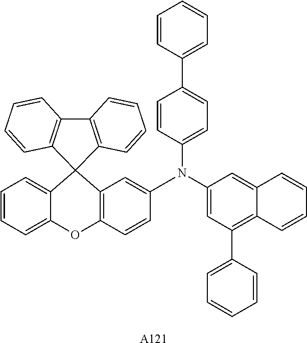 [SMILES: c1ccc(-c2ccc(N(c3ccc4c(c3)C3(c5ccccc5O4)c4ccccc4-c4ccccc43)c3cc(-c4ccccc4)c4ccccc4c3)cc2)cc1 ; "A121"]

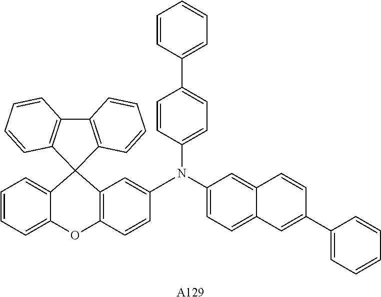 [SMILES: c1ccc(-c2ccc(N(c3ccc4c(c3)C3(c5ccccc5O4)c4ccccc4-c4ccccc43)c3ccc4cc(-c5ccccc5)ccc4c3)cc2)cc1 ; "A129"]

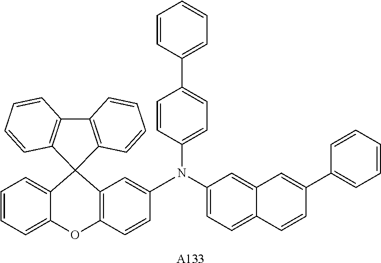 [SMILES: c1ccc(-c2ccc(N(c3ccc4c(c3)C3(c5ccccc5O4)c4ccccc4-c4ccccc43)c3ccc4ccc(-c5ccccc5)cc4c3)cc2)cc1 ; "A133"]

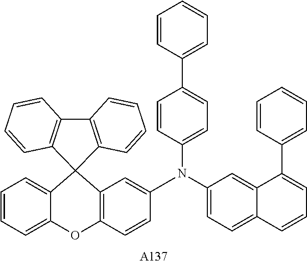

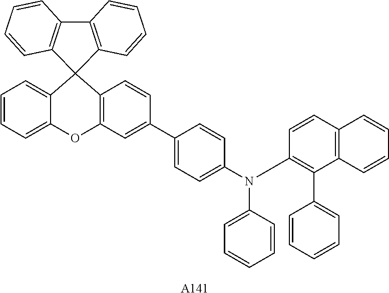 [SMILES: c1ccc(-c2c(N(c3ccccc3)c3ccc(-c4ccc5c(c4)Oc4ccccc4C54c5ccccc5-c5ccccc54)cc3)ccc3ccccc23)cc1 ; "A141"]

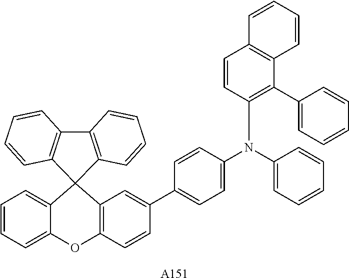 [SMILES: c1ccc(-c2c(N(c3ccccc3)c3ccc(-c4ccc5c(c4)C4(c6ccccc6O5)c5ccccc5-c5ccccc54)cc3)ccc3ccccc23)cc1 ; "A151"]

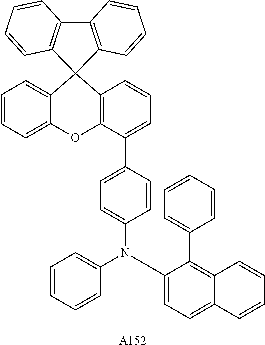 [SMILES: c1ccc(-c2c(N(c3ccccc3)c3ccc(-c4cccc5c4Oc4ccccc4C54c5ccccc5-c5ccccc54)cc3)ccc3ccccc23)cc1 ; "A152"]

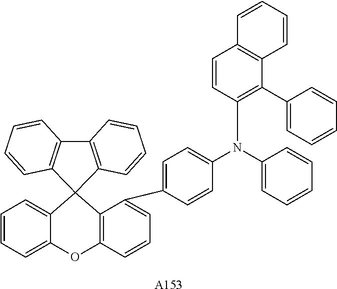 [SMILES: c1ccc(-c2c(N(c3ccccc3)c3ccc(-c4cccc5c4C4(c6ccccc6O5)c5ccccc5-c5ccccc54)cc3)ccc3ccccc23)cc1 ; "A153"]

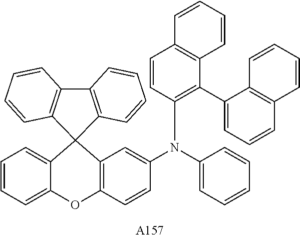

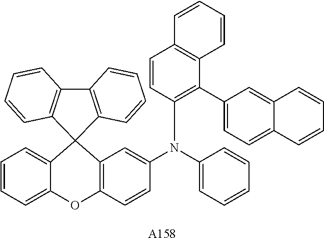

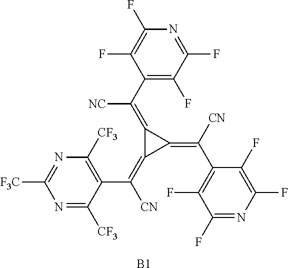 [SMILES: N#C/C(=C1\C(=C(\C#N)c2c(F)c(F)nc(F)c2F)\C1=C(\C#N)c1c(F)c(F)nc(F)c1F)c1c(C(F)(F)F)nc(C(F)(F)F)nc1C(F)(F)F ; "B1"]

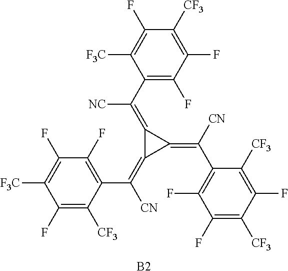 [SMILES: N#CC(=C1C(=C(C#N)c2c(F)c(F)c(C(F)(F)F)c(F)c2C(F)(F)F)C1=C(C#N)c1c(F)c(F)c(C(F)(F)F)c(F)c1C(F)(F)F)c1c(F)c(F)c(C(F)(F)F)c(F)c1C(F)(F)F ; "B2"]

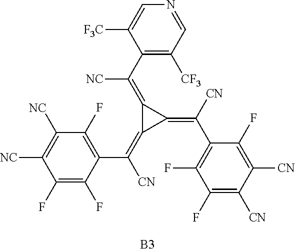

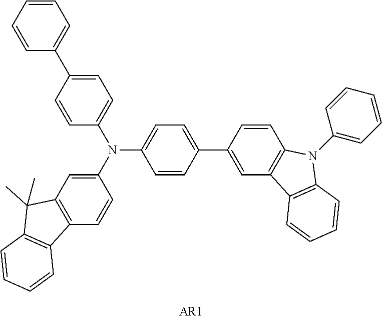 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; "AR1"]

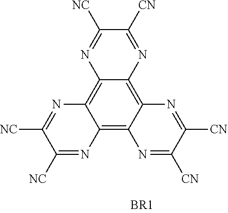 [SMILES: N#Cc1nc2c3nc(C#N)c(C#N)nc3c3nc(C#N)c(C#N)nc3c2nc1C#N]

Referring to Table 1, it was confirmed that the light-emitting devices of the Embodiments had a similar level of luminescence efficiency and a similar level of lifespan as the light-emitting devices of the Comparative Examples, while effectively having superior surface resistance.

In an embodiment, when a light-emitting device includes both a first compound represented by Formula 1 and a second compound represented by Formula 2, the surface resistance of a hole transport layer or the like that may be applied as a common layer may increase. Accordingly, the lateral flow of current through such a common layer may be prevented or reduced. Therefore, the controllability of the light-emitting device may be improved, and color mixing between the light-emitting devices may be reduced.

In addition, a combination of the first compound and the second compound does not significantly impair the characteristics of the light-emitting device, such as efficiency and lifespan, so that the light-emitting device having this combination may have relatively good characteristics.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A light-emitting device comprising:
a first electrode;
a second electrode facing the first electrode; and
an interlayer arranged between the first electrode and the second electrode, the interlayer including:
an emission layer;
a hole transport region between the first electrode and the emission layer, the hole transport region including at least one first compound represented by Formula 1; and
a charge generation layer between the first electrode and the hole transport region, the charge generation layer including at least one second compound represented by Formula 2: 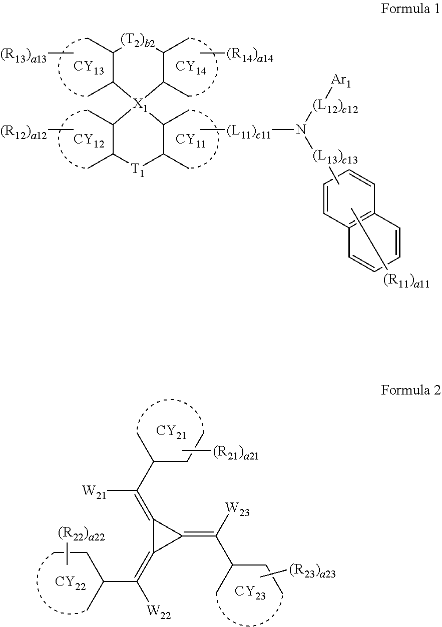
wherein, in the Formulae 1 and 2,
X₁ is C or Si,
T₁ is O or S,
T₂ is O, S, N(R₁₅), C(R₁₆)(R₁₇), or Si(R₁₈)(R₁₉),
b2 is 0 or 1,
CY₁₁ to CY₁₄ and CY₂₁ to CY₂₃ are each independently a C₅-C₆₀ carbocyclic group or a C₃-C₆₀ heterocyclic group,
L₁₁ to L₁₃ are each independently a C₅-C₆₀ carbocyclic group unsubstituted or substituted with at least one R₁₀ₐ or a C₃-C₆₀ heterocyclic group unsubstituted or substituted with at least one R₁₀ₐ,
c11 to c13 are each independently 0, 1, 2, 3, 4, or 5,
Ar₁ is a C₅-C₆₀ carbocyclic group unsubstituted or substituted with at least one R₁₀ₐ or a C₃-C₆₀ heterocyclic group unsubstituted or substituted with at least one R₁₀ₐ,
R₁₁ to R₁₉ and R₂₁ to R₂₃ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₅-C₆₀ carbocyclic group unsubstituted or substituted with at least one R₁₀ₐ, a C₃-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a11 is an integer selecting from 0 to 7,
a12 to a14 and a21 to a23 are each independently an integer selecting from 0 to 20,
W₂₁ to W₂₃ are each independently:
—F, —Cl, —Br, —I, a hydroxyl group, a cyano group, or a nitro group;
a C₁-C₆₀ alkyl group substituted with —F, —Cl, —Br, —I, a hydroxyl group, a cyano group, a nitro group, or any combinations thereof;
a C₅-C₆₀ carbocyclic group substituted with —F, —Cl, —Br, —I, a hydroxyl group, a cyano group, a nitro group, or any combinations thereof; or
a C₃-C₆₀ heterocyclic group substituted with —F, —Cl, —Br, —I, a hydroxyl group, a cyano group, a nitro group, or any combinations thereof,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₃-C₆₀ heterocyclic group, a C₆-C₆₀ aryloxy group, a C₆-C₆₀ arylthio group, a C₇-C₆₀ aryl alkyl group, a C₃-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combinations thereof;
a C₅-C₆₀ carbocyclic group, a C₃-C₆₀ heterocyclic group, a C₆-C₆₀ aryloxy group, a C₆-C₆₀ arylthio group, a C₇-C₆₀ aryl alkyl group, or a C₃-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₃-C₆₀ heterocyclic group, a C₆-C₆₀ aryloxy group, a C₆-C₆₀ arylthio group, a C₇-C₆₀ aryl alkyl group, a C₃-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combinations thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently:
hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, or a C₃-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combinations thereof.

2. The light-emitting device of claim 1, wherein the hole transport region has a surface resistance in a range of about 1.0×10⁹ ohm/sq to about 1.0×10¹¹ ohm/sq.

3. The light-emitting device of claim 1, wherein the hole transport region and the charge generation layer are in direct contact with each other.

4. The light-emitting device of claim 1, wherein
the hole transport region includes a hole transport layer, and
the hole transport layer includes the at least one first compound.

5. The light-emitting device of claim 1, wherein
the charge generation layer includes a p-type charge generation layer, and
the p-type charge generation layer includes the at least one second compound.

6. The light-emitting device of claim 1, wherein
the interlayer includes:
a first stack including a first hole transport region, a first emission layer arranged on the first hole transport region, and a first electron transport region arranged on the first emission layer;
a second stack including a second hole transport region arranged on the first electron transport region, a second emission layer arranged on the second hole transport region, and a second electron transport region arranged on the second emission layer; and
a first charge generation layer between the first stack and the second stack,
wherein the second hole transport region is the hole transport region including the at least one first compound, and
the first charge generation layer is the charge generation layer including the at least one second compound.

7. The light-emitting device of claim 1, wherein
the interlayer includes:
a first stack including a first hole transport region, a first emission layer arranged on the first hole transport region, and a first electron transport region arranged on the first emission layer;
a second stack including a second hole transport region arranged on the first electron transport region, a second emission layer arranged on the second hole transport region, and a second electron transport region arranged on the second emission layer;
a first charge generation layer between the first stack and the second stack;
a third stack including a third hole transport region arranged on the second electron transport region, a third emission layer arranged on the third hole transport region, and a third electron transport region arranged on the third emission layer; and
a second charge generation layer between the second stack and the third stack,
wherein at least one of the second hole transport region and the third hole transport region is the hole transport region including the at least one first compound, and
at least one of the first charge generation layer and the second charge generation layer is the charge generation layer including the at least one second compound.

8. The light-emitting device of claim 7, wherein the second hole transport region and the first charge generation layer are in direct contact with each other.

9. The light-emitting device of claim 7, wherein the third hole transport region and the second charge generation layer are in direct contact with each other.

10. The light-emitting device of claim 7, wherein
the second hole transport region includes the at least one first compound, and
the first charge generation layer includes the at least one second compound.

11. The light-emitting device of claim 7, wherein
the third hole transport region includes the at least one first compound, and
the second charge generation layer includes the at least one second compound.

12. The light-emitting device of claim 7, wherein
each of the second hole transport region and the third hole transport region includes the at least one first compound, and
each of the first charge generation layer and the second charge generation layer includes the at least one second compound.

13. The light-emitting device of claim 1, wherein the at least one first compound is represented by Formula 1-1: 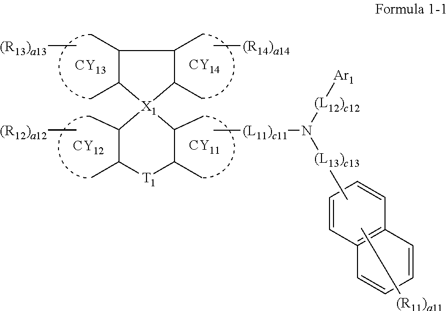
wherein, in the Formula 1-1, X₁, T₁, CY₁₁ to CY₁₄, L₁₁ to L₁₃, Ar₁, R₁₁ to R₁₄, a11 to a14, and c11 to c13 are each the same as defined in the Formula 1.

14. The light-emitting device of claim 1, wherein the at least one first compound is represented by Formula 1-2: 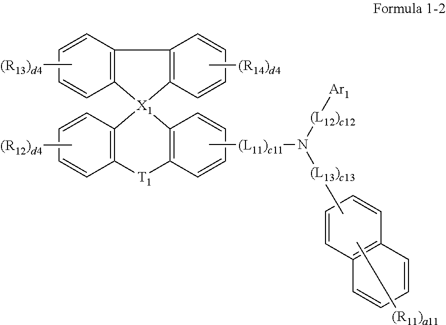
wherein, in the Formula 1-2, X₁, T₁, L₁₁ to L₁₃, Ar₁, a11, R₁₁ to R₁₄, and c11 to c13 are each the same as defined in the Formula 1, and
d4 is an integer selecting from 0 to 4.

15. A display apparatus comprising:
a substrate including a first region, a second region, and a third region which are spaced apart from each other;
a first light-emitting device including:
a first-1 electrode arranged on the substrate within the first region;
a first-2 electrode facing the first-1 electrode; and
a first interlayer arranged between the first-1 electrode and the first-2 electrode, the first interlayer including:
a first-1 emission layer;
a first-1 hole transport region arranged between the first-1 electrode and the first-1 emission layer; and
a first-1 charge generation layer arranged between the first-1 electrode and the first-1 hole transport region;
a second light-emitting device including:
a second-1 electrode arranged on the substrate within the second region;
a second-2 electrode facing the second-1 electrode; and
a second interlayer arranged between the second-1 electrode and the second-2 electrode, the second interlayer including:
a second-1 emission layer;
a second-1 hole transport region arranged between the second-1 electrode and the second-1 emission layer; and
a second-1 charge generation layer arranged between the second-1 electrode and the second-1 hole transport region; and
a third light-emitting device including:
a third-1 electrode arranged on the substrate within the third region;
a third-2 electrode facing the third-1 electrode; and
a third interlayer arranged between the third-1 electrode and the third-2 electrode, the third interlayer including:
a third-1 emission layer;
a third-1 hole transport region arranged between the third-1 electrode and the third-1 emission layer; and
a third-1 charge generation layer arranged between the third-1 electrode and the third-1 hole transport region,
wherein at least one of the first-1 hole transport region, the second-1 hole transport region, and the third-1 hole transport region includes at least one first compound represented by Formula 1, and
at least one of the first-1 charge generation layer, the second-1 charge generation layer, and the third-1 charge generation layer includes at least one second compound represented by Formula 2: 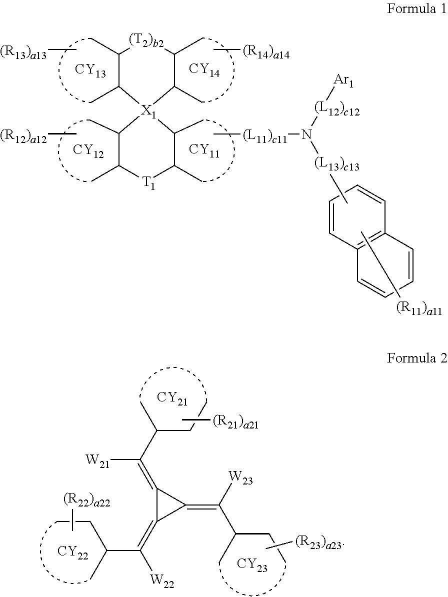
wherein, in the Formulae 1 and 2,
X₁ is C or Si,
T₁ is O or S,
T₂ is O, S, N(R₁₅), C(R₁₆)(R₁₇), or Si(R₁₈)(R₁₉),
b2 is 0 or 1, CY₁₁ to CY₁₄ and CY₂₁ to CY₂₃ are each independently a C₅-C₆₀ carbocyclic group or a C₃-C₆₀ heterocyclic group,
L₁₁ to L₁₃ are each independently a C₅-C₆₀ carbocyclic group unsubstituted or substituted with at least one R₁₀ₐ or a C₃-C₆₀ heterocyclic group unsubstituted or substituted with at least one R₁₀ₐ,
c11 to c13 are each independently 0, 1, 2, 3, 4, or 5,
Ar₁ is a C₅-C₆₀ carbocyclic group unsubstituted or substituted with at least one R₁₀ₐ or a C₃-C₆₀ heterocyclic group unsubstituted or substituted with at least one R₁₀ₐ,
R₁₁ to R₁₉ and R₂₁ to R₂₃ are each independently hydrogen, deuterium, —F, —C₁, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₅-C₆₀ carbocyclic group unsubstituted or substituted with at least one R₁₀ₐ, a C₃-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a11 is an integer selecting from 0 to 7,
a12 to a14 and a21 to a23 are each independently an integer selecting from 0 to 20,
W₂₁ to W₂₃ are each independently:
—F, —Cl, —Br, —I, a hydroxyl group, a cyano group, or a nitro group;
a C₁-C₆₀ alkyl group substituted with —F, —Cl, —Br, —I, a hydroxyl group, a cyano group, a nitro group, or any combinations thereof;
a C₅-C₆₀ carbocyclic group substituted with —F, —Cl, —Br, —I, a hydroxyl group, a cyano group, a nitro group, or any combinations thereof; or
a C₃-C₆₀ heterocyclic group substituted with —F, —Cl, —Br, —I, a hydroxyl group, a cyano group, a nitro group, or any combinations thereof,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₃-C₆₀ heterocyclic group, a C₆-C₆₀ aryloxy group, a C₆-C₆₀ arylthio group, a C₇-C₆₀ aryl alkyl group, a C₃-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combinations thereof;
a C₅-C₆₀ carbocyclic group, a C₃-C₆₀ heterocyclic group, a C₆-Coo aryloxy group, a C₆-C₆₀ arylthio group, a C₇-C₆₀ aryl alkyl group, or a C₃-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₃-C₆₀ heterocyclic group, a C₆-C₆₀ aryloxy group, a C₆-C₆₀ arylthio group, a C₇-C₆₀ aryl alkyl group, a C₃-C₆₀ heteroaryl alkyl group, —Si(Q₂₁)(Q₂₂)(Q₂₃), —N(Q₂₁) (Q₂₂), —B(Q₂₁) (Q₂₂), —C(═O) (Q₂₁), —S(═O)₂(Q₂₁), —P(═O) (Q₂₁) (Q₂₂), or any combinations thereof; or
—Si(Q₃₁) (Q₃₂) (Q₃₃), —N(Q₃₁) (Q₃₂), —B(Q₃₁) (Q₃₂), —C(═O) (Q₃₁), —S(═O)₂(Q₃₁), or —P(═O) (Q₃₁) (Q₃₂), and
Q₁ to Q₃, Q₁₁ to Q₁₃, Q₂₁ to Q₂₃, and Q₃₁ to Q₃₃ are each independently:
hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, or a C₃-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combinations thereof.

16. The display apparatus of claim 15, wherein
the first-1 hole transport region includes the at least one first compound, and the first-1 charge generation layer includes the at least one second compound,
each of the first-1 hole transport region and the second-1 hole transport region includes the at least one first compound, and each of the first-1 charge generation layer and the second-1 charge generation layer includes the at least one second compound, or
each of the first-1 hole transport region, the second-1 hole transport region, and the third-1 hole transport region includes the at least one first compound, and each of the first-1 charge generation layer, the second-1 charge generation layer, and the third-1 charge generation layer includes the at least one second compound.

17. The display apparatus of claim 15, wherein the first-1 hole transport region and the second-1 hole transport region are connected to each other and form a common layer having a single body.

18. The display apparatus of claim 15, wherein the first-1 charge generation layer and the second-1 charge generation layer are common layers connected to each other.

19. An electronic apparatus comprising:
the display apparatus of claim 15; and
a processor configured to transmit signals to the display apparatus.

20. The electronic apparatus of claim 19, wherein the electronic apparatus is one of a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, smart glasses, a head-mounted display, a smart watch, a laser printer, a telephone, a portable phone, a tablet personal computer, a phablet, a personal digital assistant, a wearable device, a laptop computer, a digital camera, a camcorder, a viewfinder, a micro display, a three-dimensional display, a virtual reality display, an augmented reality display, a vehicle gauge, a center information display in a vehicle, a room mirror, a video wall with multiple displays tiled together, a theater or stadium screen, a phototherapy device, and a signboard.
